(19) United States
(12) Patent Application Publication
(10) Pub. No.: US 2023/0314942 A1
(43) Pub. Date: Oct. 5, 2023

(54) POLYCYCLIC POLYPHENOLIC RESIN, COMPOSITION, METHOD FOR PRODUCING POLYCYCLIC POLYPHENOLIC RESIN, COMPOSITION FOR FILM FORMATION, RESIST COMPOSITION, RESIST PATTERN FORMATION METHOD, RADIATION-SENSITIVE COMPOSITION, COMPOSITION FOR UNDERLAYER FILM FORMATION FOR LITHOGRAPHY, METHOD FOR PRODUCING UNDERLAYER FILM FOR LITHOGRAPHY, CIRCUIT PATTERN FORMATION METHOD, AND COMPOSITION FOR OPTICAL MEMBER FORMATION

(71) Applicant: Mitsubishi Gas Chemical Company, Inc., Tokyo (JP)

(72) Inventors: Kodai MATSUURA, Hiratsuka-shi, Kanagawa (JP); Junya Horiuchi, Hiratsuka-shi, Kanagawa (JP); Takashi MAKINOSHIMA, Hiratsuka-shi, Kanagawa (JP); Masatoshi ECHIGO, Tokyo (JP)

(21) Appl. No.: 18/016,093

(22) PCT Filed: Jul. 15, 2021
(86) PCT No.: PCT/JP2021/026669

§ 371 Date: Jan. 13, 2023

(30) Foreign Application Priority Data
Jul. 15, 2020 (JP) 2020-121288
Jul. 15, 2020 (JP) 2020-121595
Jul. 15, 2020 (JP) 2020-121615

(51) Int. Cl. G03F 7/039; C08F 216/18; C08L 71/10; G03F 7/004; G03F 7/11

(52) U.S. Cl. CPC G03F 7/0397; C08F 216/18; C08L 71/10; G03F 7/0045; G03F 7/0048; G03F 7/11

(57) ABSTRACT

A polycyclic polyphenolic resin having repeating units derived from at least one monomer selected from the group consisting of aromatic hydroxy compounds represented by the formulas (1A) and (1B); or a polycyclic polyphenolic resin having repeating units derived from an aromatic hydroxy compound represented by the formula (C-1A), wherein the repeating units are linked to each other by a direct bonding between aromatic rings:

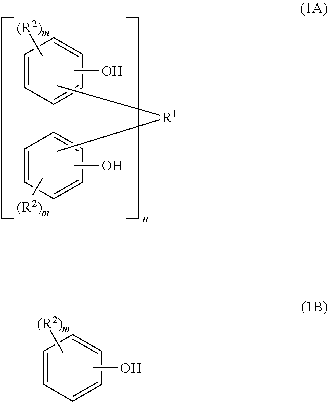

wherein in the formula (1A), R¹ is a 2n-valent group having 1 to 60 carbon atoms or a single bond, each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group, and each m is independently an integer of 0 to 3; each n is independently an integer of 1 to 4; and in the formula (1B), R² and m are as defined in the formula (1A), and

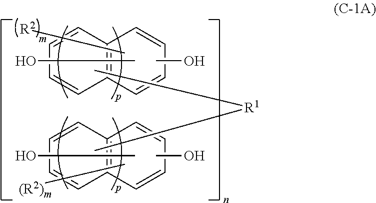

wherein in the formula (C-1A), R¹ is a 2n-valent group having 1 to 60 carbon atoms or a single bond, each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group, and each m is independently an integer of 0 to 9; and n is an integer of 1 to 4, and each p is independently an integer of 0 to 3.

### TECHNICAL FIELD

The present invention relates to a polycyclic polyphenolic resin, a composition, a method for producing a polycyclic polyphenolic resin, a composition for film formation, a resist composition, a resist pattern formation method, a radiation-sensitive composition, a composition for an underlayer film formation for lithography, a method for producing an underlayer film for lithography, a circuit pattern formation method, and a composition for optical member formation.

### BACKGROUND ART

Polyphenol-based resins having a repeating unit derived from a hydroxy-substituted aromatic compound or the like are known as sealants, coating agents, resist materials, and semiconductor underlayer film forming materials for semiconductors. For example, Patent Literatures 1 and 2 propose the use of a polyphenol compound or resin having a specific skeleton.

Meanwhile, as a method for producing a polyphenol-based resin, there is known a method for producing a novolac resin or a resol resin by addition-condensation of a phenol and formalin in the presence of an acid or an alkali catalyst. However, in the method for producing a phenol resin, formaldehyde, which has been pointed out to have a risk of impairing human health in recent years, is used as a raw material for the phenol resin, and various other methods using a substance instead of formaldehyde have been studied from the viewpoint of safety. As a method for producing a polyphenol-based resin to solve this problem, there has been proposed a method for producing a phenol polymer by oxidative polymerization of a phenol in a solvent such as water or an organic solvent using an enzyme having a peroxidase activity such as peroxidase and a peroxide such as hydrogen peroxide. Further, there is also known a method for producing polyphenylene oxide (PPO) by oxidative polymerization of 2,6-dimethylphenol (see Non Patent Literature 1).

In the production of semiconductor devices, fine processing is practiced by lithography using photoresist materials. In recent years, further miniaturization based on pattern rules has been demanded along with increase in the integration and speed of LSI. Lithography using light exposure, which is currently used as a general purpose technique, is approaching the limit of essential resolution derived from the wavelength of a light source.

The light source for lithography used upon forming resist patterns has been shifted to ArF excimer laser (193 nm) having a shorter wavelength from KrF excimer laser (248 nm). However, as the miniaturization of resist patterns proceeds, the problem of resolution or the problem of collapse of resist patterns after development arises. Therefore, resists have been desired to have a thinner film. If resists merely have a thinner film in response to such a demand, it is difficult to obtain the film thicknesses of resist patterns sufficient for substrate processing. Therefore, there has been a need for a process of preparing a resist underlayer film between a resist and a semiconductor substrate to be processed, and imparting functions as a mask for substrate processing to this resist underlayer film in addition to a resist pattern.

Various resist underlayer films for such a process are currently known. Examples thereof can include resist underlayer films for lithography having the selectivity of a dry etching rate close to that of resists, unlike conventional resist underlayer films having a fast etching rate. As a material for forming such resist underlayer films for lithography, an underlayer film forming material for a multilayer resist process containing a resin component having at least a substituent that generates a sulfonic acid residue by eliminating a terminal group under application of predetermined energy, and a solvent has been suggested (see, for example, Patent Literature 3). Another example thereof can include resist underlayer films for lithography having the selectivity of a dry etching rate smaller than that of resists. As a material for forming such resist underlayer films for lithography, a resist underlayer film material comprising a polymer having a specific repeat unit has been suggested (see, for example, Patent Literature 4). Further examples thereof can include resist underlayer films for lithography having the selectivity of a dry etching rate smaller than that of semiconductor substrates. As a material for forming such resist underlayer films for lithography, a resist underlayer film material comprising a polymer prepared by copolymerizing a repeat unit of an acenaphthylene and a repeat unit having a substituted or unsubstituted hydroxy group has been suggested (see, for example, Patent Literature 5). A resist underlayer film material comprising an oxidized polymer of a specific bisnaphthol compound has been suggested (see, for example, Patent Literature 6).

Meanwhile, as materials having high etching resistance for this kind of resist underlayer film, amorphous carbon underlayer films formed by chemical vapour deposition (hereinafter also referred to as “CVD”) using methane gas, ethane gas, acetylene gas, or the like as a raw material are well known. However, resist underlayer film materials that can form resist underlayer films by a wet process such as spin coating or screen printing have been demanded from the viewpoint of a process.

Recently, layers to be processed having a complicated shape have been desired to form a resist underlayer film for lithography. Thus, there is a demand for a resist underlayer film material that can form an underlayer film excellent in embedding properties or film surface flattening properties.

As for methods for forming an intermediate layer used in the formation of a resist underlayer film in a three-layer process, for example, a method for forming a silicon nitride film (see, for example, Patent Literature 7) and a CVD formation method for a silicon nitride film (see, for example, Patent Literature 8) are known. Also, as intermediate layer materials for a three-layer process, materials comprising a silsesquioxane-based silicon compound are known (see, for example, Patent Literature 9).

The present inventors have suggested a composition for underlayer film formation for lithography comprising a specific compound or resin (see, for example, Patent Literature 10).

Various compositions for optical component formation have been suggested, and, for example, an acrylic resin (see, for example, Patent Literatures 11 and 12) and polyphenol having a specific structure derived from an allyl group (see, for example, Patent Literature 13) have been suggested.

### CITATION LIST

### Patent Literature

Patent Literature 1: International Publication No. WO 2013/024778
Patent Literature 2: International Publication No. WO 2013/024779
Patent Literature 3: Japanese Patent Laid-Open No. 2004-177668
Patent Literature 4: Japanese Patent Laid-Open No. 2004-271838
Patent Literature 5: Japanese Patent Laid-Open No. 2005-250434
Patent Literature 6: Japanese Patent Laid-Open No. 2020-027302
Patent Literature 7: Japanese Patent Laid-Open No. 2002-334869
Patent Literature 8: International Publication No. WO 2004/066377
Patent Literature 9: Japanese Patent Laid-Open No. 2007-226204
Patent Literature 10: International Publication No. WO 2013/024779
Patent Literature 11: Japanese Patent Laid-Open No. 2010-138393
Patent Literature 12: Japanese Patent Laid-Open No. 2015-174877
Patent Literature 13: International Publication No. WO 2014/123005

### Non Patent Literature

Non Patent Literature 1: Hideyuki Higashimura, Shiro Kobayashi, Chemistry and Industry, 53, 501 (2000)

### SUMMARY OF INVENTION

### Technical Problem

The materials described in Patent Literatures 1 and 2 still have room for improvement in performance such as heat resistance and etching resistance, and there is a need to develop new materials that are even better in these properties.

The polyphenolic resin obtained based on the method of Non Patent Literature 1 usually contains, as constituent units, both an oxyphenol unit obtained by forming a bond between a carbon atom constituting an aromatic ring of one phenol as a monomer and a phenolic hydroxy group of the other phenol, and a unit having a phenolic hydroxy group in a molecule obtained by bonding between carbon atoms on an aromatic ring of a phenol as a monomer. Such a polyphenol-based resin becomes a polymer having flexibility because the aromatic rings are bonded to each other via an oxygen atom, but is not preferable from the viewpoint of crosslinkability and heat resistance because the phenolic hydroxy group disappears.

As mentioned above, a large number of film forming materials for lithography have heretofore been suggested. However, none of these materials achieve both of heat resistance and etching resistance at high level. Thus, the development of novel materials is required.

Also, a large number of compositions for optical members have heretofore been suggested. However, none of these compositions achieve all of heat resistance, transparency, and refractive index at high dimensions. Thus, the development of novel materials is required.

To solve the above problems, the present invention provides a polycyclic polyphenolic resin having excellent heat resistance and etching resistance, and a method for producing the polycyclic polyphenolic resin; and using the polycyclic polyphenolic resin, a composition, a composition for film formation, a resist composition, a radiation-sensitive composition, a composition for an underlayer film formation for lithography, a resist pattern formation method, a method for producing an underlayer film for lithography, a circuit pattern formation method, and a composition for optical member formation.

### Solution to Problem

The present inventors have, as a result of devoted examinations to solve the above problems, found out that use of a polycyclic polyphenolic resin having a specific structure can solve the above problems, and reached the present invention.

Specifically, the present invention includes the following aspects.

[1]

A polycyclic polyphenolic resin having repeating units derived from at least one monomer selected from the group consisting of aromatic hydroxy compounds represented by the formulas (1A) and (1B); or a polycyclic polyphenolic resin having repeating units derived from an aromatic hydroxy compound represented by the formula (C-1A),

wherein the repeating units are linked to each other by a direct bonding between aromatic rings:

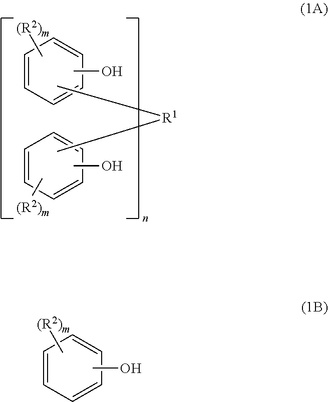

wherein in the formula (1A), R¹ is a 2n-valent group having 1 to 60 carbon atoms or a single bond, each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group, and each m is independently an integer of 0 to 3; each n is independently an integer of 1 to 4; and in the formula (1B), R² and m are as defined in the formula (1A), and

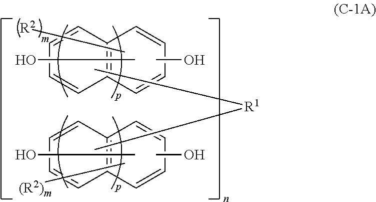

wherein in the formula (C-1A), R¹ is a 2n-valent group having 1 to 60 carbon atoms or a single bond, each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group, and each m is independently an integer of 0 to 9; and n is an integer of 1 to 4, and each p is independently an integer of 0 to 3.
[2]

The polycyclic polyphenolic resin according to [1], wherein the aromatic hydroxy compounds represented by the formulas (1A) and (1B) are aromatic hydroxy compounds represented by the formulas (2A) and (2B), respectively:

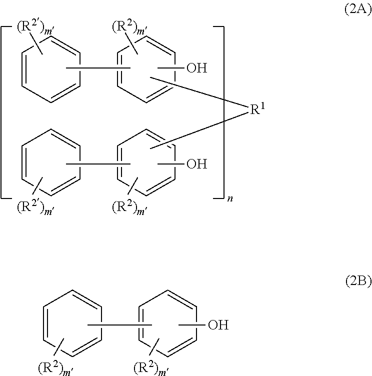

wherein in the formula (2A), each R²′ is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, or a carboxyl group, and each m′ is independently an integer of 0 to 3, and R¹, R², and n are as defined in the formula (1A); and in the formula (2B), each R²′ is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, or a carboxyl group, and R², m, and m′ are as defined in the formula (1B).
[3]

The polycyclic polyphenolic resin according to [2], wherein the aromatic hydroxy compounds represented by the formulas (2A) and (2B) are aromatic hydroxy compounds represented by the formulas (3A) and (3B), respectively:

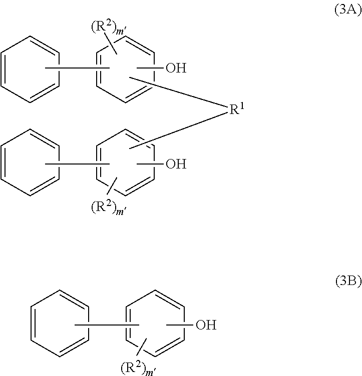

wherein in the formula (3A), R¹, R², and m′ are as defined in the formula (2A); and in the formula (3B), R² and m′ are as defined in the formula (2B).
[4]

The polycyclic polyphenolic resin according to [1], the polycyclic polyphenolic resin having repeating units derived from at least one monomer selected from the group consisting of aromatic hydroxy compounds represented by the formulas (D-1A) and (D-2B),

wherein the repeating units are linked to each other by a direct bonding between aromatic rings:

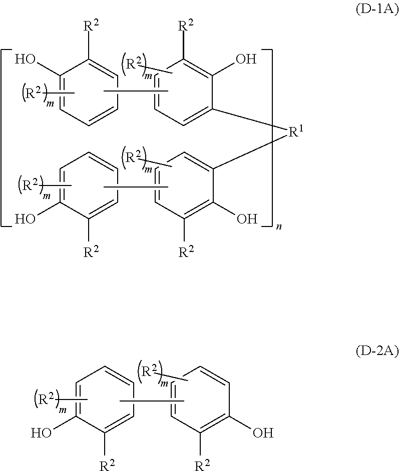

wherein in the formula (D-1A), R¹ is a 2n-valent group having 1 to 60 carbon atoms or a single bond, each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group, each m is independently an integer of 0 to 3, and n is an integer of 1 to 4; and in the formula (D-2A), R² and m are as defined in the formula (D-1A).
[5]

The polycyclic polyphenolic resin according to [4], wherein the aromatic hydroxy compounds represented by the formulas (D-1A) and (D-2A) are aromatic hydroxy compounds represented by the formulas (D-1) and (D-2), respectively:

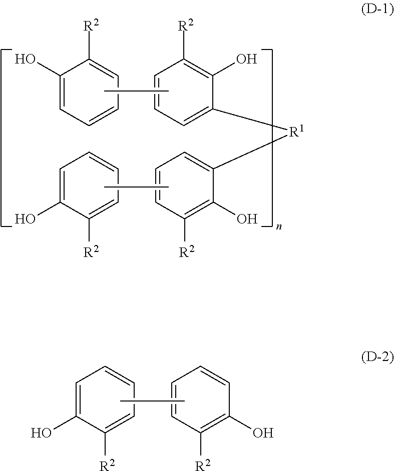

wherein in the formula (D-1), R¹, R², and n are as defined in the formula (D-1A); and in the formula (D-2), R² is as defined in the formula (D-2A).
[6]

The polycyclic polyphenolic resin according to [5], wherein the aromatic hydroxy compounds represented by the formulas (D-1) and (D-2) are aromatic hydroxy compounds represented by the following formulas (D-1-1) and (D-2-1), respectively:

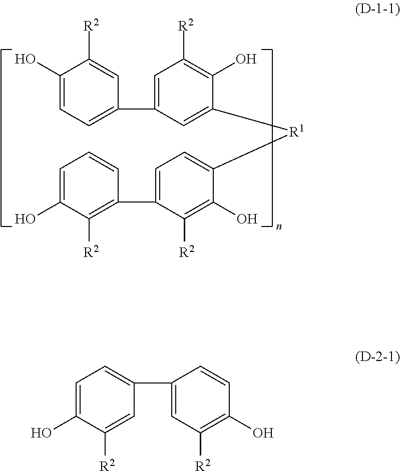

wherein in the formula (D-1-1), R¹, R², and n are as defined in the formula (D-1); and in the formula (D-2-1), R² is as defined in the formula (D-2).
[7]

The polycyclic polyphenolic resin according to [1], wherein the aromatic hydroxy compound represented by the formula (C-1A) is an aromatic hydroxy compound represented by the following formula (C-1):

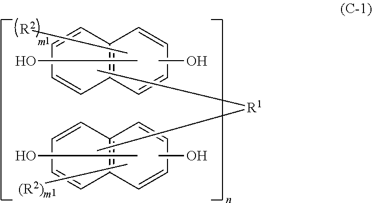

wherein in the formula (C-1), R¹, R², and n are as defined in the formula (C-1A); and each m¹ is independently an integer of 0 to 5.
[8]

The polycyclic polyphenolic resin according to [7], wherein the aromatic hydroxy compound represented by the formula (C-1) is an aromatic hydroxy compound represented by the following formula (C-1-1):

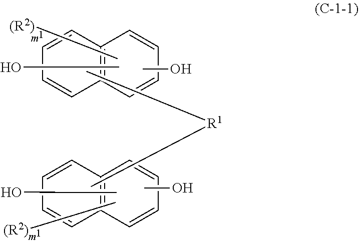

wherein in the formula (C-1-1), R¹, R², and m¹ are as defined in the formula (C-1).
[9]

The polycyclic polyphenolic resin according to any one of [1] to [8], further comprising a modified portion derived from a crosslinking compound.

[10]

The polycyclic polyphenolic resin according to any one of [1] to [9], further comprising, as another repeating unit, a repeating unit having an ether bond formed by condensation of a phenolic hydroxy group.

[11]

The polycyclic polyphenolic resin according to [10], wherein a proportion of the ether bond to the entire resin is 0.01 to 99 mol %.

[12]

The polycyclic polyphenolic resin according to any one of [1] to [11], comprising two or more different repeating units derived from aromatic hydroxy compounds.

[13]

The polycyclic polyphenolic resin according to any one of [1] to [12], which has a weight-average molecular weight of 400 to 100,000.

[14]

The polycyclic polyphenolic resin according to any one of [1] to [13], which has a solubility in 1-methoxy-2-propanol and/or propylene glycol monomethyl ether acetate of 1% by mass or more.

[15]

The polycyclic polyphenolic resin according to any one of [1] to [13], which has a solubility in propylene glycol monomethyl ether and/or propylene glycol monomethyl ether acetate of 1% by mass or more.

[16]

The polycyclic polyphenolic resin according to any one of [1] to [15], wherein R¹ is a group represented by R^{A}—R^{B}, wherein R^{A} is a methine group, and R^{B} is an aryl group having 6 to 40 carbon atoms and optionally having a substituent.

[17]

A composition comprising the polycyclic polyphenolic resin according to any one of [1] to [16].

[18]

The composition according to [17], further comprising a solvent.

[19]

The composition according to [18], wherein the solvent comprises one or more selected from the group consisting of propylene glycol monomethyl ether, propylene glycol monomethyl ether acetate, cyclohexanone, cyclopentanone, ethyl lactate, and methyl hydroxyisobutyrate.

[20]

The composition according to any one of [17] to [19], wherein a content of impurity metal is less than 500 ppb for each metal species.

[21]

The composition according to [20], wherein the impurity metal comprises at least one selected from the group consisting of copper, manganese, iron, cobalt, ruthenium, chromium, nickel, tin, lead, silver, and palladium.

[22]

The composition according to [20] or [21], wherein the content of the impurity metal is 1 ppb or less for each metal species.

[23]

A method for producing the polycyclic polyphenolic resin according to any one of [1] to [16], comprising the step of:

polymerizing one kind or two or more kinds of the aromatic hydroxy compounds in the presence of an oxidizing agent.

[24]

The method for producing the polycyclic polyphenolic resin according to [23], wherein the oxidizing agent is a metal salt or a metal complex containing at least one selected from the group consisting of copper, manganese, iron, cobalt, ruthenium, chromium, nickel, tin, lead, silver, and palladium.

[25]

A composition for film formation comprising the polycyclic polyphenolic resin according to any one of [1] to [16].

[26]

A resist composition comprising the composition for film formation according to [25].

[27]

The resist composition according to [26], further comprising at least one selected from the group consisting of a solvent, an acid generating agent, and an acid diffusion controlling agent.

[28]

A resist pattern formation method, comprising the steps of:
forming a resist film on a substrate using the resist composition according to [26] or [27];
exposing at least a portion of the formed resist film; and
developing the exposed resist film, thereby forming a resist pattern.
   [29]

A radiation-sensitive composition comprising the composition for film formation according to [25], an optically active diazonaphthoquinone compound, and a solvent,

wherein a content of the solvent is 20 to 99 parts by mass based on 100 parts by mass in total of the radiation-sensitive composition, and

a content of a solid content except for the solvent is 1 to 80 parts by mass based on 100 parts by mass in total of the radiation-sensitive composition.

[30]

A resist pattern formation method, comprising the steps of:
forming a resist film on a substrate using the radiation-sensitive composition according to [29];
exposing at least a portion of the formed resist film; and
developing the exposed resist film, thereby forming a resist pattern.
   [31]

A composition for underlayer film formation for lithography comprising the composition for film formation according to [25].

[32]

The composition for underlayer film formation for lithography according to [31], further comprising at least one selected from the group consisting of a solvent, an acid generating agent, and a crosslinking agent.

[33]

A method for producing an underlayer film for lithography, comprising the step of forming an underlayer film on a substrate using the composition for underlayer film formation for lithography according to [31] or [32].

[34]

A resist pattern formation method, comprising the steps of:
forming an underlayer film on a substrate using the composition for underlayer film formation for lithography according to [31] or [32];
forming at least one photoresist layer on the underlayer film; and
irradiating a predetermined region of the photoresist layer with radiation for development, thereby forming a resist pattern.
   [35]

A circuit pattern formation method, comprising the steps of:
forming an underlayer film on a substrate using the composition for underlayer film formation for lithography according to [31] to [32];
forming an intermediate layer film on the underlayer film using a resist intermediate layer film material containing a silicon atom;
forming at least one photoresist layer on the intermediate layer film;
irradiating a predetermined region of the photoresist layer with radiation for development, thereby forming a resist pattern;
etching the intermediate layer film with the resist pattern as a mask, thereby forming an intermediate layer film pattern;
etching the underlayer film with the intermediate layer film pattern as an etching mask, thereby forming an underlayer film pattern; and
etching the substrate with the underlayer film pattern as an etching mask, thereby forming a pattern on the substrate.
   [36]

A composition for optical member formation comprising the composition for film formation according to [26].

[37]

The composition for optical member formation according to [36], further comprising at least one selected from the group consisting of a solvent, an acid generating agent, and a crosslinking agent.

### Advantageous Effects of Invention

According to the present invention, it is possible to provide a polycyclic polyphenolic resin having excellent heat resistance and etching resistance, and a method for producing the polycyclic polyphenolic resin; and using the polycyclic polyphenolic resin, a composition, a composition for film formation, a resist composition, a radiation-sensitive composition, a composition for an underlayer film formation for lithography, a resist pattern formation method, a method for producing an underlayer film for lithography, a circuit pattern formation method, and a composition for optical member formation.

### DESCRIPTION OF EMBODIMENTS

An embodiment for carrying out the present invention (which will be simply referred to as “present embodiment” hereinafter) will now be described in detail. The present embodiment described below is only illustrative of the present invention and is not intended to limit the present invention to the contents of the following description. The present invention can be carried out with appropriate modifications falling within the gist of the invention.

### [Polycyclic Polyphenolic Resin]

A polycyclic polyphenolic resin of the present embodiment is a polycyclic polyphenolic resin having repeating units derived from at least one monomer selected from the group consisting of aromatic hydroxy compounds represented by the formulas (1A) and (1B); or a polycyclic polyphenolic resin having repeating units derived from an aromatic hydroxy compound represented by the formula (C-1A),

wherein the repeating units are linked to each other by a direct bonding between aromatic rings. In the polycyclic polyphenolic resin of the present embodiment, the repeating units are linked to each other by a direct bonding between aromatic rings. Since the polycyclic polyphenolic resin of the present embodiment is configured as described above, it has more excellent performance in terms of performance such as heat resistance and etching resistance.

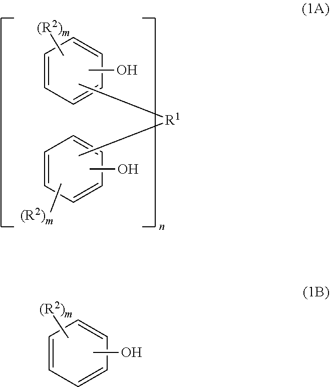

(In the formula (1A), R¹ is a 2n-valent group having 1 to 60 carbon atoms or a single bond, each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group, and each m is independently an integer of 0 to 3. n is an integer of 1 to 4. In the formula (1B), R² and m are as defined in the formula (1A).)

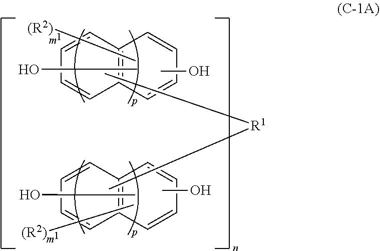

(In the formula (C-1A), R¹ is a 2n-valent group having 1 to 60 carbon atoms or a single bond, each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group, and each m is independently an integer of 0 to 9. n is an integer of 1 to 4, and each p is independently an integer of 0 to 3.)

In the present specification, unless otherwise defined, the term “substituted” means that one or more hydrogen atoms in a functional group are substituted with a substituent. Examples of the “substituent” include, but are not particularly limited to, a halogen atom, a hydroxy group, a carboxyl group, a cyano group, a nitro group, a thiol group, or a heterocyclic group, an alkyl group having 1 to 30 carbon atoms, an aryl group having 6 to 20 carbon atoms, an alkoxyl group having 1 to 30 carbon atoms, an alkenyl group having 2 to 30 carbon atoms, an alkynyl group having 2 to 30 carbon atoms, an acyl group having 1 to 30 carbon atoms, and an amino group having 0 to 30 carbon atoms.

The “alkyl group” also includes, unless otherwise defined, linear aliphatic hydrocarbon groups, branched aliphatic hydrocarbon groups, and cyclic aliphatic hydrocarbon groups.

As for structural formulas described in the present specification, for example, as the following formulas, when a line indicating a bond to a certain group C is in contact with a ring A and a ring B, it means that C may be bonded to any of the ring A and the ring B. That is, n groups C in the following formula may be independently bonded to either ring A or ring B, respectively.

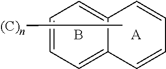

The polycyclic polyphenolic resin of the present embodiment typically has the following characteristics (1) to (4), but is not limited thereto.
(1) The polycyclic polyphenolic resin of the present embodiment has excellent solubility in an organic solvent (particularly, a safe solvent). Therefore, for example, when the polycyclic polyphenolic resin of the present embodiment is used as a film forming material for lithography, films for lithography can be formed by a wet process such as spin coating or screen printing.
(2) In the polycyclic polyphenolic resin of the present embodiment, the carbon concentration is relatively high and the oxygen concentration is relatively low. In addition, since the polycyclic polyphenolic resin of the present embodiment has a phenolic hydroxy group in the molecule, it is useful for formation of a cured product through the reaction with a curing agent, but it can also form a cured product on its own through the crosslinking reaction of the phenolic hydroxy group upon baking at a high temperature. Due to the above, the polycyclic polyphenolic resin of the present embodiment can exhibit high heat resistance, and when used as a film forming material for lithography, degradation of the film upon baking at a high temperature is suppressed and a film for lithography excellent in etching resistance to oxygen plasma etching and the like can be formed.
(3) The polycyclic polyphenolic resin of the present embodiment can exhibit high heat resistance and etching resistance, as described above, and also has excellent adhesiveness to a resist layer and a resist intermediate layer film material. Therefore, when the polycyclic polyphenolic resin according to the present embodiment is used as a film forming material for lithography, films for lithography excellent in resist pattern formability can be formed. The term “resist pattern formability” herein refers to a property in which there are no major defects in the resist pattern shape and both resolution and sensitivity are excellent.
(4) The polycyclic polyphenolic resin of the present embodiment has a high refractive index due to its high aromatic ring density, and even after a heat treatment, coloration is suppressed and transparency is excellent. Therefore, the polycyclic polyphenolic resin of the present embodiment is also useful as various compositions for optical member formation.

It is considered that the polycyclic polyphenolic resin of the present embodiment can be preferably applied as a film forming material for lithography due to such properties, and thus the above desired characteristics are imparted to the composition, the composition for film formation, the resist composition, the radiation-sensitive composition, the composition for an underlayer film formation for lithography, and the composition for optical member formation of the present embodiment (hereinafter, these compositions may be collectively referred to simply as “the composition of the present embodiment”). In particular, since the aromatic ring density is higher than that of a resin crosslinked with a divalent organic group, an oxygen atom, or the like, and the carbon-carbon atoms of the aromatic rings are directly linked to each other by a direct bonding, even if the molecular weight is relatively low, the polycyclic polyphenolic resin is considered to have more excellent performance in terms of performance such as heat resistance and etching resistance. Furthermore, according to the resist pattern formation method, the method for producing an underlayer film for lithography, the circuit pattern formation method using the composition of the present embodiment, in addition to heat resistance and etching resistance of the pattern, excellent resist pattern formability can be exhibited such as reactivity of the resist pattern to electron beam irradiation; embedding properties of the underlayer film; resolution, sensitivity, resist pattern shape after development; optical characteristics such as refractive index, extinction coefficient, and transparency; and reduction in the number of defects of the film.

<Polycyclic Polyphenolic Resin Having Repeating Units Derived from at Least One Monomer Selected from the Group Consisting of Aromatic Hydroxy Compounds Represented by the Formulas (1A) and (1B)>

Hereinafter, the above formulas (1A) and (1B) will be described in detail.

In the formula (1A), R¹ is a 2n-valent group having 1 to 60 carbon atoms or a single bond.

The 2n-valent group having 1 to 60 carbon atoms refers to, for example, a 2n-valent hydrocarbon group, and the hydrocarbon group may have various functional groups described later as substituents. Further, the 2n-valent hydrocarbon group refers to an alkylene group having 1 to 60 carbon atoms when n is 1, an alkanetetrayl group having 1 to 60 carbon atoms when n is 2, an alkanehexayl group having 2 to 60 carbon atoms when n is 3, and an alkaneoctayl group having 3 to 60 carbon atoms when n is 4. Examples of the 2n-valent hydrocarbon group include in which a 2n+1 valent hydrocarbon group is bonded to a linear hydrocarbon group, a branched hydrocarbon group, or an alicyclic hydrocarbon group. Herein, the alicyclic hydrocarbon group also includes a bridged alicyclic hydrocarbon group.

Examples of the 2n+1-valent hydrocarbon group include, but are not limited to, a 3-valent methine group and an ethyne group.

Further, the 2n-valent hydrocarbon group may have a double bond, a heteroatom, and/or an aryl group having 6 to 59 carbon atoms. R¹ may include a group derived from a compound having a fluorene skeleton such as fluorene or benzofluorene.

In the present embodiment, the 2n-valent group may contain a halogen group, a nitro group, an amino group, a hydroxy group, an alkoxy group, a thiol group, or an aryl group having 6 to 40 carbon atoms. Furthermore, the 2n-valent group may contain an ether bond, a ketone bond, an ester bond, or a double bond.

In the present embodiment, from the viewpoint of heat resistance, the 2n-valent group preferably includes a branched hydrocarbon group or an alicyclic hydrocarbon group rather than a linear hydrocarbon group, and more preferably includes an alicyclic hydrocarbon group. Further, in the present embodiment, it is particularly preferably that the 2n-valent group has an aryl group having 6 to 60 carbon atoms.

Examples of the linear hydrocarbon group and the branched hydrocarbon group which may be contained in the 2n-valent group as a substituent include, but are not particularly limited to, an unsubstituted methyl group, an ethyl group, a n-propyl group, an i-propyl group, a n-butyl group, an i-butyl group, a t-butyl group, a n-pentyl group, a n-hexyl group, a n-dodecyl group, and a barrel group.

Examples of an alicyclic hydrocarbon group and an aromatic group having 6 to 60 carbon atoms which may be contained in the 2 n-valent group as a substituent include, but are not particularly limited to, an unsubstituted phenyl group, a naphthalene group, a biphenyl group, an anthracyl group, a pyrenyl group, a cyclohexyl group, a cyclododecyl group, a dicyclopentyl group, a tricyclodecyl group, an adamantyl group, a phenylene group, a naphthalenediyl group, a biphenyldiyl group, an anthracenediyl group, a pyrendiyl group, a cyclohexanediyl group, a cyclododecanediyl group, a dicyclopentanediyl group, a tricyclodecanediyl group, an adamantanediyl group, a benzenetriyl group, a naphthalenetriyl group, a biphenyltriyl group, an anthracenetriyl group, a pyrenetriyl group, a cyclohexanetriyl group, a cyclododecanetriyl group, a dicyclopentanetriyl group, a tricyclodecanetriyl group, an adamantanetriyl group, a benzenetetrayl group, a naphthalenetetrayl group, a biphenyltetrayl group, an anthracenetetrayl group, a pyrenetetrayl group, a cyclohexanetetrayl group, a cyclododecanetetrayl group, a dicyclopentanetetrayl group, a tricyclodecantetrayl group, and an adamantanetetrayl group.

Each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group. The alkyl group may be linear, branched or cyclic.

Examples of the alkyl group having 1 to 40 carbon atoms include, but are not limited to, a methyl group, an ethyl group, a n-propyl group, an i-propyl group, a n-butyl group, an i-butyl group, a t-butyl group, a n-pentyl group, a n-hexyl group, a n-dodecyl group, and a barrel group.

Examples of the aryl group having 6 to 40 carbon atoms include, but are not limited to, a phenyl group, a naphthalene group, a biphenyl group, an anthracyl group, a pyrenyl group, and a perylene group.

Examples of the alkenyl group having 2 to 40 carbon atoms include, but are not limited to, an ethynyl group, a propenyl group, a butynyl group, and a pentynyl group.

Examples of the alkynyl group having 2 to 40 carbon atoms include, but are not limited to, an acetylene group, an ethynyl group.

Examples of the alkoxy group having 1 to 40 carbon atoms include, but are not limited to, a methoxy group, an ethoxy group, a propoxy group, a butoxy group, and a pentoxy group.

Examples of the halogen atom include, but are not limited to, fluorine, chlorine, bromine, and iodine.

Examples of the heterocycles such as pyridine, pyrrole, pyridazine, thiophene, imidazole, furan, pyrazole, oxazole, triazole, thiazole, or benzo-fused rings thereof.

Each m is independently an integer of 0 to 3. m is preferably 1 to 3, still more preferably 1 to 2 from the viewpoint of solubility, and is preferably 1 from the viewpoint of availability of raw materials.

In the formula (1B), R² and m are as defined in the formula (1A).

In the present embodiment, as the aromatic hydroxy compound, those represented by the formula (1A) or (1B) can be used alone, or two or more kinds thereof can be used together. In the present embodiment, from the viewpoint of heat resistance, it is preferable to adopt the compound represented by the formula (1A) as the aromatic hydroxy compound. From the viewpoint of solubility, it is preferable to adopt the compound represented by the formula (1B) as the aromatic hydroxy compound.

In the present embodiment, the aromatic hydroxy compounds represented by the formulas (1A) and (1B) are preferably compounds represented by the following formulas (2A) and (2B), respectively, from the viewpoint of achieving both heat resistance and solubility and ease of production.

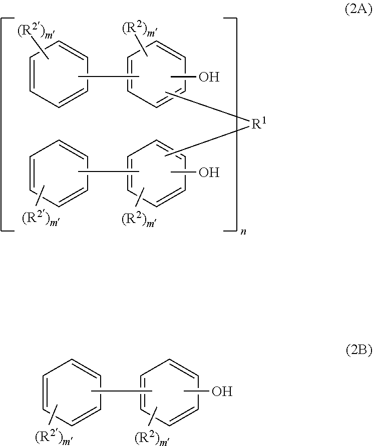

(In the formula (2A), each R²′ is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, or a carboxyl group, and each m′ is independently an integer of 0 to 3, and R¹, R², and n are as defined in the formula (1A). In the formula (2B), each R²′ is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, or a carboxyl group, and R², m, and m′ are as defined in the formula (1B).)

In the present embodiment, the aromatic hydroxy compound represented by the formula (2A) is preferably the compound represented by the following formula (2A′) from the viewpoint of ease of production.

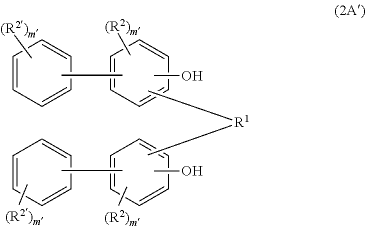

(In the formula (2A′), R¹, R², R²′, and m′ are as defined in the formula (2A).)

In the present embodiment, the aromatic hydroxy compound represented by the formula (2A) or (2B) is preferably a compound represented by the following formula (3A) or (3B), respectively, from the viewpoint of ease of production.

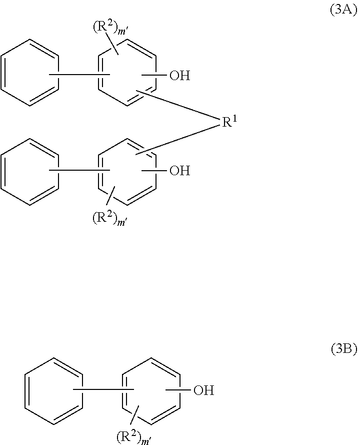

(In the formula (3A), R¹, R², and m′ are as defined in the formula (2A). In the formula (3B), R² and m′ are as defined in the formula (2B).)

In the formulas (1A), (2A), (2A′), and (3A), m′ is particularly preferably 0 from the viewpoint of heat resistance and etching resistance.

In the formulas (1A), (2A), (2A′), and (3A), R¹ preferably contains an aryl group having 6 to 40 carbon atoms and optionally having a substituent from the viewpoint of achieving both high heat resistance and solubility. In the present embodiment, the aryl group having 6 to 40 carbon atoms may be, but are not limited to, for example, a benzene ring, or various known fused rings such as naphthalene, anthracene, naphthacene, pentacene, benzopyrene, chrysene, pyrene, triphenylene, corannulene, coronene, and ovalene. R¹ may be a group having a fluorene skeleton such as fluorene, benzofluorene, and dibenzofluorene. In the present embodiment, R¹ is preferably a group derived from various fused rings such as naphthalene, anthracene, naphthacene, pentacene, benzopyrene, chrysene, pyrene, triphenylene, corannulene, coronene, ovalene, fluorene, benzofluorene, and dibenzofluorene, from the viewpoint of heat resistance. Further, R¹ is preferably naphthalene or anthracene because the n-value and the k-value at wavelengths 193 nm used in ArF exposure are low and pattern transferability tends to be excellent. Examples of R¹ include, in addition to the aromatic hydrocarbon rings described above, heterocycles such as pyridine, pyrrole, pyridazine, thiophene, imidazole, furan, pyrazole, oxazole, triazole, thiazole, or benzo-fused rings thereof. In the present embodiment, R¹ is preferably an aromatic hydrocarbon ring or a heterocycle, and more preferably an aromatic hydrocarbon ring.

In the formulas (1A), (2A), (2A′), and (3A), it is preferable that R¹ is a group represented by R^{A}—R^{B}, in which R^{A} is a methine group, and R^{B} is an aryl group having 6 to 40 carbon atoms and optionally having a substituent, from the viewpoint of having both further high heat resistance and solubility. R¹ may also be an aryl group other than a group derived from a compound having a fluorene skeleton such as fluorene or benzofluorene. Thus, it is presumed that when R¹ is a group represented by R^{A}—R^{B}, the free volume is increased via a methine group, thereby improving the solubility and the like.

Further, R^{B} is not particularly limited, but from the point of view of solubility, R^{B} is preferably a biaryl skeleton, and more preferably biphenyl. Further, although not particularly limited, but from the point of view of heat resistance, R^{B} is preferably a polycyclic aromatic, and more preferably pyrene.

Specific examples of the aromatic hydroxy compounds represented by the formulas (1A), (2A), (2A′), and (3A) will be listed below, but are not limited thereto.

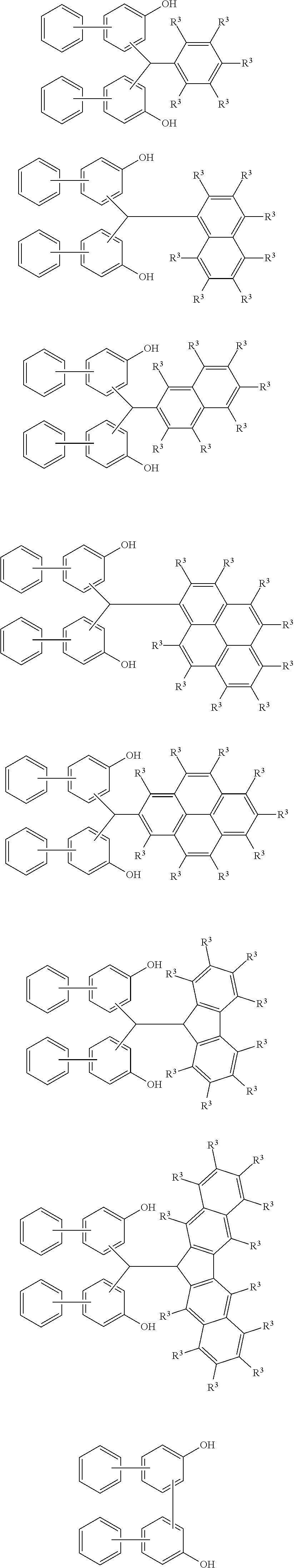

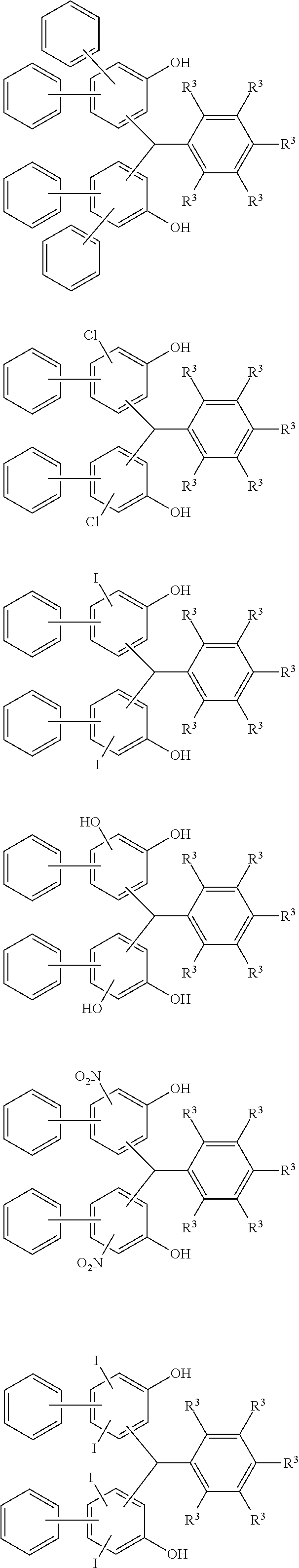

In the respective formulas, each R³ is independently a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group. The alkyl group may be linear, branched or cyclic.

Further specific examples of the aromatic hydroxy compounds represented by the formulas (1A), (2A), (2A′), and (3A) will be listed below, but are not limited thereto.

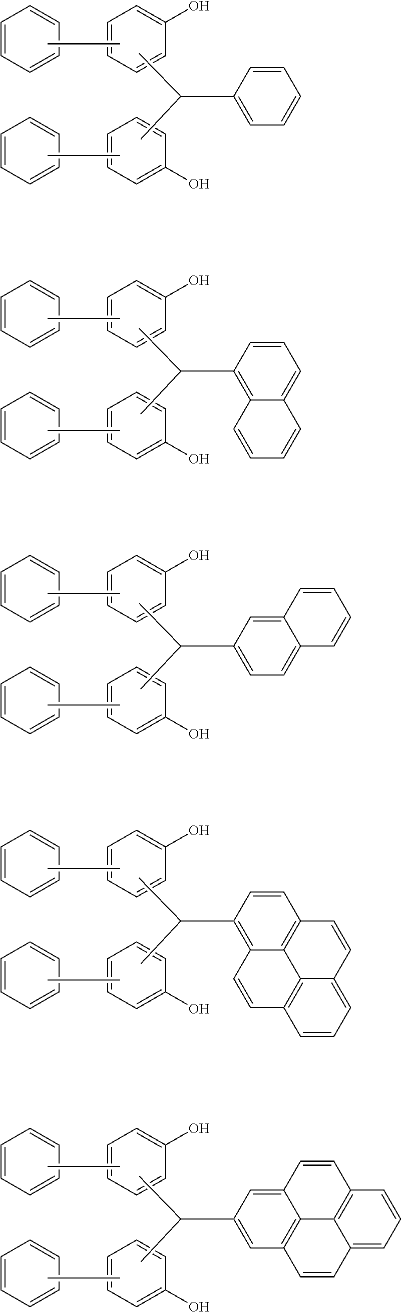

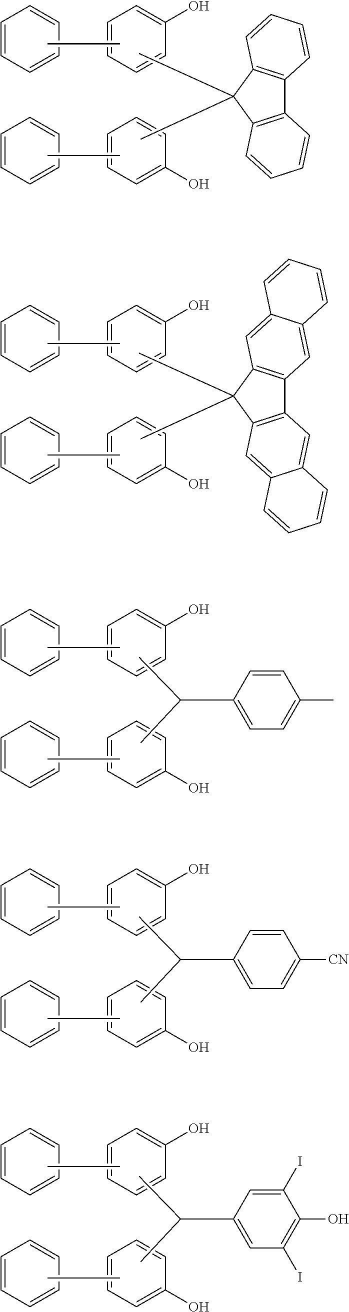

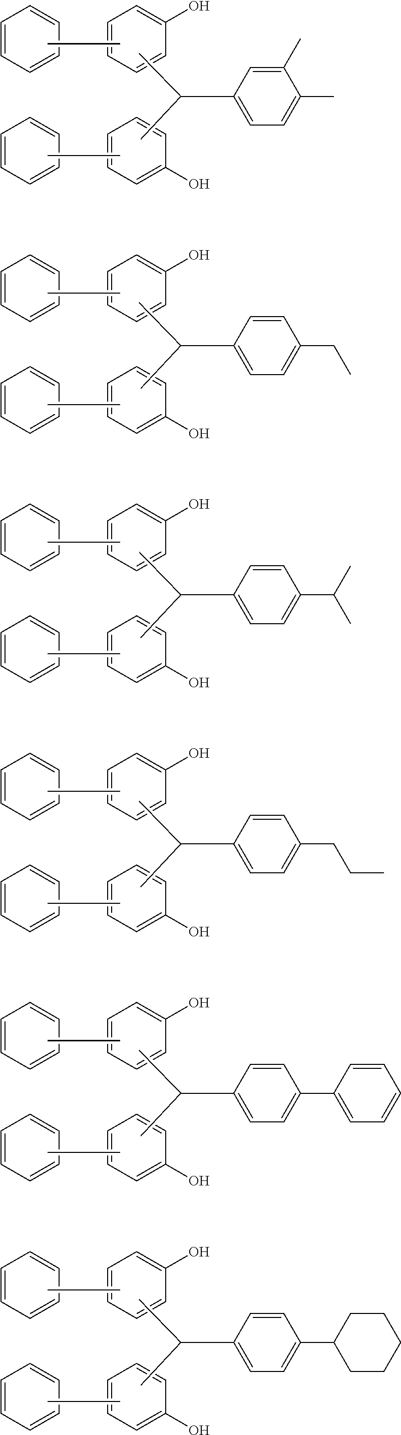

Specific examples of the aromatic hydroxy compounds represented by the formulas (1B), (2B), and (3B) will be listed below, but are not limited thereto.

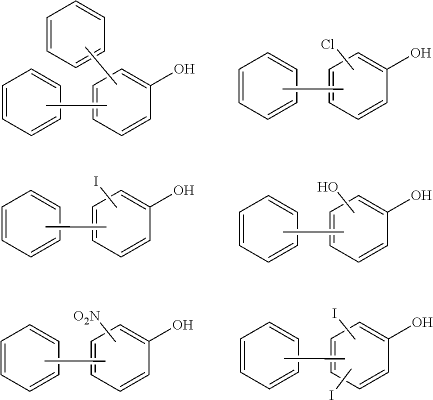

In the polycyclic polyphenolic resin of the present embodiment, the number and ratio of the respective repeating units are not particularly limited, but are preferably appropriately regulated in consideration of the application and the following values of molecular weight.

Further, the polycyclic polyphenolic resin of the present embodiment may be constituted only by the repeating unit (1A) and/or (1B), but may also contain other repeating units within a range that does not impair the performance according to the application. Examples of another of repeating units include a repeating unit having an ether bond formed by condensation of a phenolic hydroxy group and a repeating unit having a ketone structure. These other repeating units may also be directly bonded to the repeating unit (1A) and/or (1B) through the aromatic rings.

For example, the molar ratio [Y/X] of the total amount (Y) of the repeating unit (1A) and/or (1B) to the total amount (X) of the polycyclic polyphenolic resin of the present embodiment may be set to 0.01 to 1.00, and more preferably 0.45 to 1.00.

From the viewpoint of curability and the like, it is preferable that a certain amount of another of repeating units described above (in particular, a repeating unit having an ether bond formed by condensation of a phenolic hydroxy group, and a repeating unit having a ketone structure) is contained, and an aspect of containing them will be described later.

The weight-average molecular weight of the polycyclic polyphenolic resin of the present embodiment is not particularly limited, but is preferably in the range of 400 to 100,000, more preferably 500 to 15,000, and still more preferably 500 to 12,000.

The range of the ratio of the weight-average molecular weight (Mw) to the number-average molecular weight (Mn) (Mw/Mn) is not particularly limited because the ratio required varies depending on the application, but as those having a more homogeneous molecular weight, for example, those having a ratio in the range of 3.0 or less are preferable, those having a ratio in the range of 1.05 or more and 3.0 or less are more preferable, those having a ratio in the range of 1.05 or more and less than 2.0 are particularly preferable, and those having a ratio in the range of 1.05 or more and less than 1.5 are yet still further preferable from the viewpoint of heat resistance.

The binding order of the repeating units of the polycyclic polyphenolic resin of the present embodiment in the resin is not particularly limited. For example, only one unit derived from an aromatic hydroxy compound represented by the formula (1A) or (1B) may be contained as two or more repeating units, or a plurality of units derived from an aromatic hydroxy compound represented by the formula (1A) or (1B) may be contained as one or more repeating units. The order may be either block copolymerization or random copolymerization.

The position at which the repeating units are directly bonded to each other of the polycyclic polyphenolic resin in the present embodiment is not particularly limited, and when the repeating unit is represented by the general formula (1A) or (1B), any one carbon atom to which the phenolic hydroxy group and other substituents are not bonded is involved in the direct bonding between the monomers.

In the polycyclic polyphenolic resin of the present embodiment, examples of “the repeating units are linked to each other by a direct bonding between the aromatic rings” include an aspect in which the repeating units (1A) in the polycyclic polyphenolic resin are directly bonded by a single bond between a carbon atom constituting an aromatic ring represented by an aryl structure in the parenthesis in the formula of one of repeating units (1A) and a carbon atom constituting an aromatic ring represented by an aryl structure in the parenthesis in the formula of another of repeating units (1A), that is, without any other atom such as a carbon atom, an oxygen atom or a sulfur atom.

Further, the present embodiment may include the following aspects.
(1) Aspect wherein in one of repeating units (1A), when either R¹ and R² is an aryl group (including when R¹ is a 2n valent group having an aryl group), an atom constituting the aromatic ring of the aryl group and an atom constituting the aromatic ring represented by an aryl structure in A in the formula of another of another of repeating units (1A) are directly bonded by a single bond.
(2) Aspect wherein in one and another of another of repeating units (1A), when either R¹ and R² is an aryl group (including when R¹ is a 2n valent group having an aryl group), atoms constituting the aromatic rings of the aryl groups represented by R¹ and R² are directly bonded by a single bond between one and another of another of repeating units (1A).

In the present embodiment, from the viewpoint of heat resistance, it is preferable that any one carbon atom of the aromatic ring having a phenolic hydroxy group is preferably involved in direct bond between aromatic rings in any of the aspects (1) and (2). In other words, when two repeating units (1A) are bonded to one of repeating units (1A), each of the two aryl structures in the formula (1A) is preferably bonded to another of repeating units. When each of the two aryl structures is bonded to another of repeating units another of repeating units (1A), the positions of the carbon atoms bonded to another of repeating units another of repeating units in each aryl structure may be different from each other, or may be the corresponding positions (for example, bonding to the o- and p-positions of the carbons having the hydroxy groups of both aryl rings). From the viewpoint of heat resistance and etching resistance, preferred is an aspect in which based on the total amount, 30 mol % or more, more preferably 50 mol % or more, still more preferably 80 mol % or more, particularly preferably 85 mol % or more of the repeating units (1A) in the polycyclic polyphenolic resin are directly bonded by a single bond between a carbon atom constituting an aromatic ring represented by an aryl structure in the parenthesis in the formula of one of repeating units (1A) and a carbon atom constituting an aromatic ring represented by an aryl structure in the parenthesis in the formula of another of repeating units another of repeating units (1A).

As described above, the polycyclic polyphenolic resin of the present embodiment may contain two or more different repeating units derived from aromatic hydroxy compounds so as to contain a repeating unit having an ether bond formed by condensation of a phenolic hydroxy group within a range that does not impair the performance according to the application. The polycyclic polyphenolic resin of the present embodiment may also contain a ketone structure. Preferred examples of the polycyclic polyphenolic resin of the present embodiment include a polycyclic polyphenolic resin in which the proportion of the repeating unit having an ether bond or the repeating unit having a ketone structure is in a range of 80 mol % or less, and more preferred examples include a polycyclic polyphenolic resin in which the proportion of the repeating unit having an ether bond or the repeating unit having a ketone structure is in a range of 50 mol % or less.

More specifically, the content of the total amount (Z) of the repeating unit having an ether bond formed by condensation of a phenolic hydroxy group and the repeating unit having a ketone structure based on the total amount (X) of the polycyclic polyphenolic resin of the present embodiment is, for example, preferably 0.01 to 99 mol %, more preferably 0.01 to 80 mol %, and still more preferably 0.01 mol % to 20 mol % from the viewpoints of film density after film formation and heat resistance.

From the viewpoint of heat resistance, any one carbon atom of the aromatic ring having a phenolic hydroxy group is preferably involved in direct bonding between aromatic rings. In other words, when two repeating units (1A) are bonded to one of repeating units (1A), each of the two aryl structures in the formula (1A) is preferably bonded to another of repeating units another of repeating units. When each of the two aryl structures is bonded to another of repeating units another of repeating units (1A), the positions of the carbon atoms bonded to another of repeating units another of repeating units in each aryl structure may be different from each other, or may be the corresponding positions (for example, bonding to the 7-positions of both naphthalene rings).

In addition, another of repeating units another of repeating units described above preferably includes the repeating unit having an ether bond formed by condensation of a phenolic hydroxy group. Examples of the “repeating unit having an ether bond formed by condensation of a phenolic hydroxy group” include the unit (A1) or unit (B1) described above are bonded to each other via an oxygen atom derived from the phenolic hydroxy group. In a case where the polycyclic polyphenolic resin has, as another of repeating units another of repeating units, a repeating unit having an ether bond formed by condensation of a phenolic hydroxy group, or the like, the proportion of the ether bond to the entire resin is preferably 0.01 to 99 mol %, still more preferably 0.01 to 80 mol %, and particularly preferably 0.01 to 20 mol % from the viewpoint of solubility and coatability.

The polycyclic polyphenolic resin of the present embodiment preferably has high solubility in a solvent from the viewpoint of easier application to a wet process, etc. More specifically, in the case of using 1-methoxy-2-propanol (PGME) and/or propylene glycol monomethyl ether acetate (PGMEA) as a solvent, it is preferable that the polycyclic polyphenolic resin of the present embodiment has a solubility of 1% by mass or more in the solvent at a temperature of 23° C., more preferably 5% by mass or more, still more preferably 10% by mass or more, particularly preferably 20% by mass or more, and particularly preferably 30% by mass or more. Here, the solubility in PGME and/or PGMEA is defined as “mass of the resin/(mass of the resin+mass of the solvent)×100 (% by mass)”. For example, 10 g of the polycyclic polyphenolic resin is evaluated as being dissolved in 90 g of PGMEA when the solubility of the polycyclic polyphenolic resin in the PGMEA is “10% by mass or more”; 10 g of the resin is evaluated as being not dissolved in 90 g of PGMEA when the solubility is “less than 10% by mass”.

The polycyclic polyphenolic resin of the present embodiment is assumed to be applicable to at least one application selected from the group consisting of a composition to be described later, a method for producing a polycyclic polyphenolic resin, a composition for film formation, a resist composition, a resist pattern formation method, a radiation-sensitive composition, a composition for underlayer film formation for lithography, a method for producing an underlayer film for lithography, a circuit pattern formation method, and a composition for optical member formation, and from the viewpoint of further enhancing heat resistance and etching resistance, it is particularly preferable that the polycyclic polyphenolic resin of the present embodiment is at least one selected from the group consisting of BisP-1, BisP-2, BisP-3, BisP-4, and BisP-5 described in the embodiments to be described later.

<Polycyclic Polyphenolic Resin Having Repeating Units Derived from at Least One Monomer Selected from the Group Consisting of Aromatic Hydroxy Compounds Represented by the Formulas (D-1A) and (D-2B)>

The polycyclic polyphenolic resin having repeating units derived from at least one monomer selected from the group consisting of aromatic hydroxy compounds represented by the formulas (1A) and (1B) may be a polycyclic polyphenolic resin having repeating units derived from at least one monomer selected from the group consisting of aromatic hydroxy compounds represented by the following formula (D-1A) and the formula (D-2A).

The polycyclic polyphenolic resin of the present embodiment is a polycyclic polyphenolic resin having repeating units derived from at least one monomer selected from the group consisting of aromatic hydroxy compounds represented by the following formulas (D-1A) and (D-2A), wherein the repeating units are linked to each other by a direct bonding between aromatic rings. Since the polycyclic polyphenolic resin of the present embodiment is configured as described above, it has more excellent performance in terms of performance such as heat resistance and etching resistance.

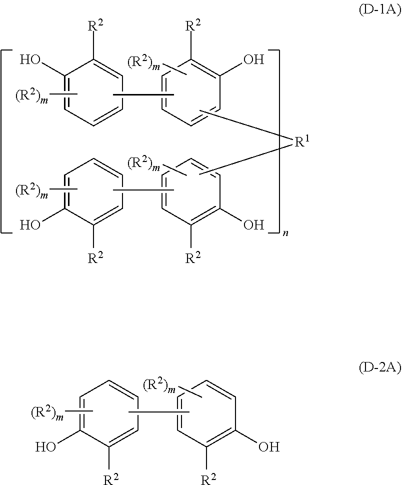

(In the formula (D-1A), R¹ is a 2n-valent group having 1 to 60 carbon atoms or a single bond, each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group, each m is independently an integer of 0 to 3, and n is an integer of 1 to 4. In the formula (D-2A), R² and m are as defined in the formula (D-1A).)

Hereinafter, the above formulas (D-1A) and (D-2A) will be described in detail.

In the formula (D-1A), R¹ is a 2n-valent group having 1 to 60 carbon atoms or a single bond.

The 2n-valent group having 1 to 60 carbon atoms refers to, for example, a 2n-valent hydrocarbon group, and the hydrocarbon group may have various functional groups described later as substituents. Further, the 2n-valent hydrocarbon group refers to an alkylene group having 1 to 60 carbon atoms when n is 1, an alkanetetrayl group having 1 to 60 carbon atoms when n is 2, an alkanehexayl group having 2 to 60 carbon atoms when n is 3, and an alkaneoctayl group having 3 to 60 carbon atoms when n is 4. Examples of the 2n-valent hydrocarbon group include in which a 2n+1 valent hydrocarbon group is bonded to a linear hydrocarbon group, a branched hydrocarbon group, or an alicyclic hydrocarbon group. Herein, the alicyclic hydrocarbon group also includes a bridged alicyclic hydrocarbon group.

Examples of the 2n+1-valent hydrocarbon group include, but are not limited to, a 3-valent methine group and an ethyne group.

Further, the 2n-valent hydrocarbon group may have a double bond, a heteroatom, and/or an aryl group having 6 to 59 carbon atoms. R¹ may include a group derived from a compound having a fluorene skeleton such as fluorene or benzofluorene.

In the present embodiment, the 2n-valent group may contain a halogen group, a nitro group, an amino group, a hydroxy group, an alkoxy group, a thiol group, or an aryl group having 6 to 40 carbon atoms. Furthermore, the 2n-valent group may contain an ether bond, a ketone bond, an ester bond, or a double bond.

In the present embodiment, from the viewpoint of heat resistance, the 2n-valent group preferably includes a branched hydrocarbon group or an alicyclic hydrocarbon group rather than a linear hydrocarbon group, and more preferably includes an alicyclic hydrocarbon group. Further, in the present embodiment, it is particularly preferably that the 2n-valent group has an aryl group having 6 to 60 carbon atoms.

Examples of the linear hydrocarbon group and the branched hydrocarbon group which may be contained in the 2n-valent group as a substituent include, but are not particularly limited to, an unsubstituted methyl group, an ethyl group, a n-propyl group, an i-propyl group, a n-butyl group, an i-butyl group, a t-butyl group, a n-pentyl group, a n-hexyl group, a n-dodecyl group, and a barrel group.

Examples of an alicyclic hydrocarbon group and an aromatic group having 6 to 60 carbon atoms which may be contained in the 2 n-valent group as a substituent include, but are not particularly limited to, an unsubstituted phenyl group, a naphthalene group, a biphenyl group, an anthracyl group, a pyrenyl group, a cyclohexyl group, a cyclododecyl group, a dicyclopentyl group, a tricyclodecyl group, an adamantyl group, a phenylene group, a naphthalenediyl group, a biphenyldiyl group, an anthracenediyl group, a pyrendiyl group, a cyclohexanediyl group, a cyclododecanediyl group, a dicyclopentanediyl group, a tricyclodecanediyl group, an adamantanediyl group, a benzenetriyl group, a naphthalenetriyl group, a biphenyltriyl group, an anthracenetriyl group, a pyrenetriyl group, a cyclohexanetriyl group, a cyclododecanetriyl group, a dicyclopentanetriyl group, a tricyclodecanetriyl group, an adamantanetriyl group, a benzenetetrayl group, a naphthalenetetrayl group, a biphenyltetrayl group, an anthracenetetrayl group, a pyrenetetrayl group, a cyclohexanetetrayl group, a cyclododecanetetrayl group, a dicyclopentanetetrayl group, a tricyclodecantetrayl group, and an adamantanetetrayl group.

In the formula (D-1A), each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group. The alkyl group may be linear, branched or cyclic.

Examples of the alkyl group having 1 to 40 carbon atoms include, but are not limited to, a methyl group, an ethyl group, a n-propyl group, an i-propyl group, a n-butyl group, an i-butyl group, a t-butyl group, a n-pentyl group, a n-hexyl group, a n-dodecyl group, and a barrel group.

Examples of the aryl group having 6 to 40 carbon atoms include, but are not limited to, a phenyl group, a naphthalene group, a biphenyl group, an anthracyl group, a pyrenyl group, and a perylene group.

Examples of the alkenyl group having 2 to 40 carbon atoms include, but are not limited to, an ethynyl group, a propenyl group, a butynyl group, and a pentynyl group.

Examples of the alkynyl group having 2 to 40 carbon atoms include, but are not limited to, an acetylene group, an ethynyl group.

Examples of the alkoxy group having 1 to 40 carbon atoms include, but are not limited to, a methoxy group, an ethoxy group, a propoxy group, a butoxy group, and a pentoxy group.

Examples of the halogen atom include fluorine, chlorine, bromine, and iodine.

Examples of the heterocycles such as pyridine, pyrrole, pyridazine, thiophene, imidazole, furan, pyrazole, oxazole, triazole, thiazole, or benzo-fused rings thereof.

In the formula (D-1A), each m is independently an integer of 0 to 3. m is preferably 0 to 1 from the viewpoint of solubility, and is preferably 0 from the viewpoint of availability of raw materials.

In the formula (D-1A), n is an integer of 1 to 4, preferably 1 to 2. Here, when n is an integer of 2 or larger, n structural formulas within the parentheses [ ] may be the same or different.

In the formula (D-2A), R² and m are as defined in the formula (D-1A).

In the present embodiment, as the aromatic hydroxy compound, those represented by the formula (D-1A) or (D-2A) can be used alone, or two or more kinds thereof can be used together. In the present embodiment, from the viewpoint of heat resistance, it is preferable to adopt the compound represented by the formula (D-1A) as the aromatic hydroxy compound. From the viewpoint of solubility, it is preferable to adopt the compound represented by the formula (D-2A) as the aromatic hydroxy compound.

In the present embodiment, the aromatic hydroxy compounds represented by the formulas (D-1A) and (D-2A) are preferably compounds represented by the following formulas (D-1A) and (D-2A) from the viewpoint of achieving both heat resistance and solubility and ease of production.

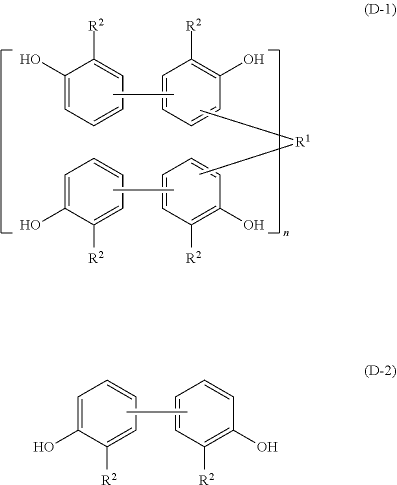

(In the formula (D-1), R¹, R², and n are as defined in the formula (D-1A). In the formula (D-2), R² is as defined in the formula (D-2A).)

In the present embodiment, the aromatic hydroxy compounds represented by the formulas (D-1) and (D-2) are preferably aromatic hydroxy compounds represented by the following formulas (D-1-1) and (D-2-1) from the viewpoint of achieving both heat resistance and solubility and ease of production.

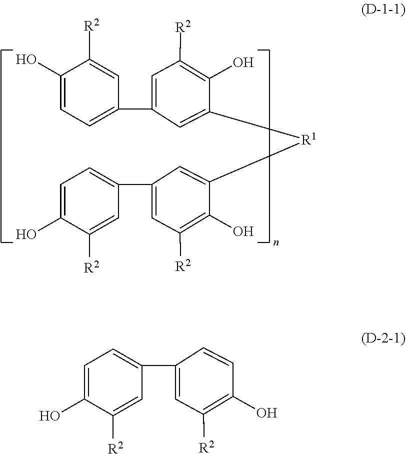

(In the formula (D-1-1), R¹, R², and n are as defined in the formula (D-1). In the formula (D-2-1), R² is as defined in the formula (D-2).)

In the present embodiment, the aromatic hydroxy compound represented by the formula (D-1-1) is preferably the compound represented by the following formula (D-1-2) from the viewpoint of ease of production.

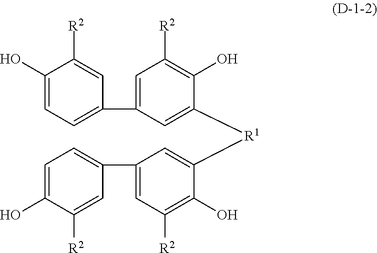

(In the formula (D-1-2), R¹ and R² are as defined in the formula (D-1).)

In the formulas (D-1A), (D-1), (D-1-1), and (D-1-2), R¹ preferably contains an aryl group having 6 to 40 carbon atoms and optionally having a substituent from the viewpoint of achieving both high heat resistance and solubility. In the present embodiment, the aryl group having 6 to 40 carbon atoms may be, but are not limited to, for example, a benzene ring, or various known fused rings such as naphthalene, anthracene, naphthacene, pentacene, benzopyrene, chrysene, pyrene, triphenylene, corannulene, coronene, ovalene, fluorene, benzofluorene, and dibenzofluorene. In the present embodiment, R¹ is preferably any of various fused rings such as naphthalene, anthracene, naphthacene, pentacene, benzopyrene, chrysene, pyrene, triphenylene, corannulene, coronene, ovalene, fluorene, benzofluorene, and dibenzofluorene, from the viewpoint of heat resistance. Further, R¹ is preferably naphthalene or anthracene because the n-value and the k-value at wavelengths 193 nm used in ArF exposure are low and pattern transferability tends to be excellent. Examples of R¹ include, in addition to the aromatic hydrocarbon rings described above, heterocycles such as pyridine, pyrrole, pyridazine, thiophene, imidazole, furan, pyrazole, oxazole, triazole, thiazole, or benzo-fused rings thereof. In the present embodiment, R¹ is preferably an aromatic hydrocarbon ring or a heterocycle, and more preferably an aromatic hydrocarbon ring, from the viewpoint of solubility. Further, R¹ may be an aromatic hydrocarbon ring other than a group derived from a compound having a fluorene skeleton such as fluorene or benzofluorene from the viewpoint of solubility.

In the formulas (D-1A), (D-1), (D-1-1), and (D-1-2), it is preferable that R¹ is a group represented by R^{A}—R^{B}, in which R^{A} is a methine group, and R^{B} is an aryl group having 6 to 40 carbon atoms and optionally having a substituent, from the viewpoint of having both further high heat resistance and solubility. Examples of the aryl include the aryl groups described above, and R¹ may also be an aryl group other than a group derived from a compound having a fluorene skeleton such as fluorene or benzofluorene. Thus, it is presumed that when R¹ is a group represented by R^{A}—R^{B}, the free volume is increased via a methine group, thereby improving the solubility and the like.

Further, although not particularly limited, from the point of view of solubility, R^{B} is preferably a biaryl skeleton, and more preferably biphenyl. Further, although not particularly limited, but from the point of view of heat resistance, R^{B} is preferably a polycyclic aromatic, and more preferably pyrene.

Specific examples of the aromatic hydroxy compound represented by the formulas (D-1A), (D-1), (D-1-1), and (D-1-2) will be listed below. However, the aromatic hydroxy compound in the present embodiment is not limited to the compounds listed below.

Specific examples of the polycyclic polyphenolic resin of the present embodiment include a polycyclic polyphenolic resin containing repeating units (D-1A) derived from an aromatic hydroxy compound represented by the following formula, in which the repeating units are linked to each other by a direct bonding between aromatic rings. Examples of such a polymer include RBisP-1, RBisP-2, RBisP-3, RBisP-4, and RBisP-5, which will be described later in Synthesis Working Examples. The polycyclic polyphenolic resin of the present embodiment is assumed to be applicable to all kinds of applications such as a composition to be described later, a method for producing a polycyclic polyphenolic resin, a composition for film formation, a resist composition, a resist pattern formation method, a radiation-sensitive composition, a composition for underlayer film formation for lithography, a method for producing an underlayer film for lithography, a circuit pattern formation method, and a composition for optical member formation, and from the viewpoint of further enhancing heat resistance and etching resistance, the polycyclic polyphenolic resin of the present embodiment may be at least one selected from the group consisting of RBisP-1, RBisP-2, RBisP-3, RBisP-4, and RBisP-5 described in the embodiments to be described later.

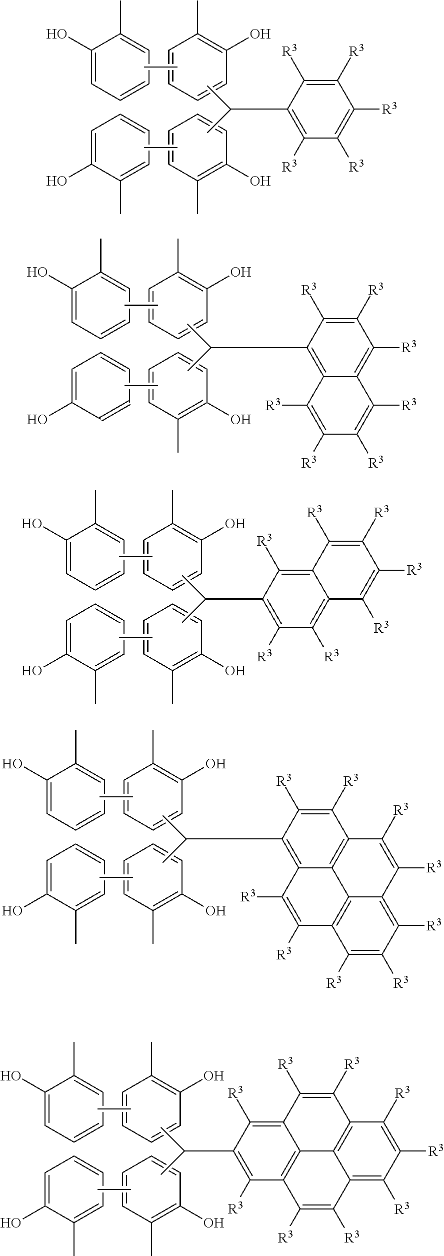

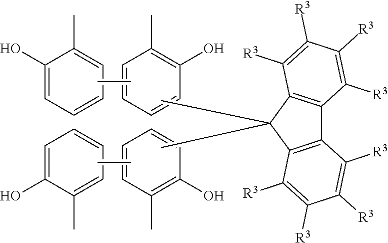

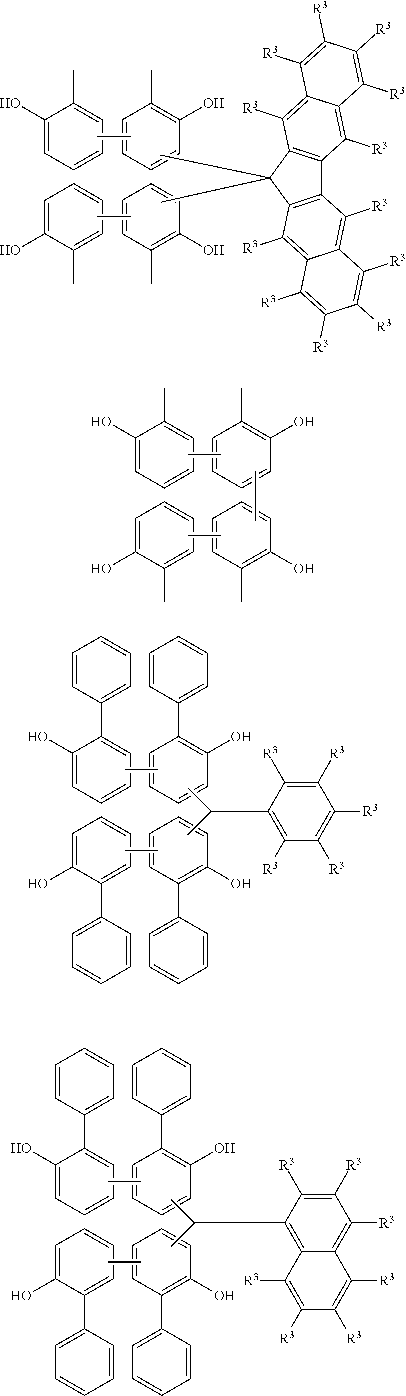

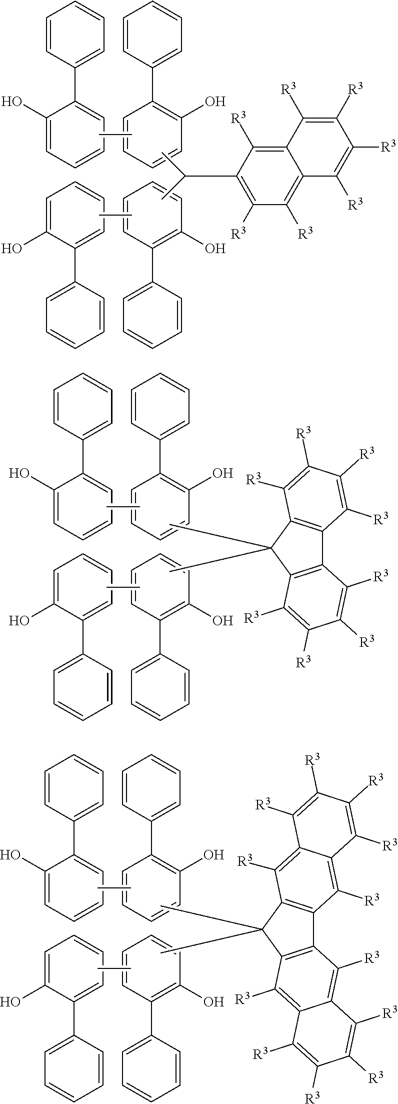

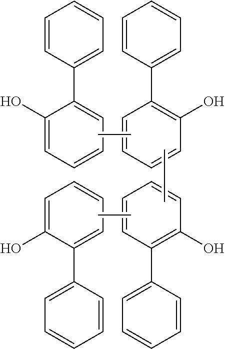

In the formulas described above, each R³ is independently a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group. The alkyl group may be linear, branched or cyclic.

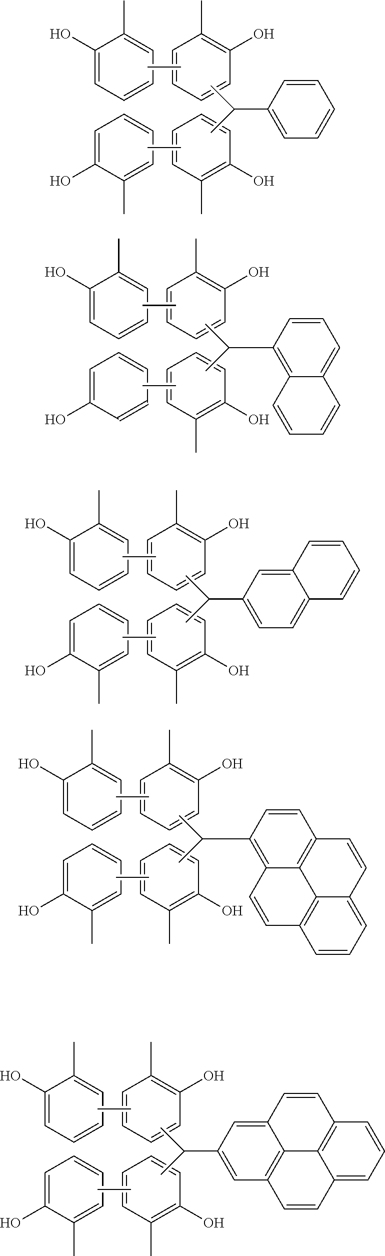

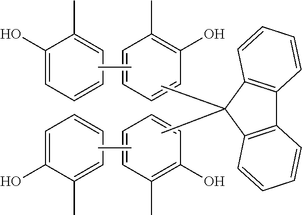

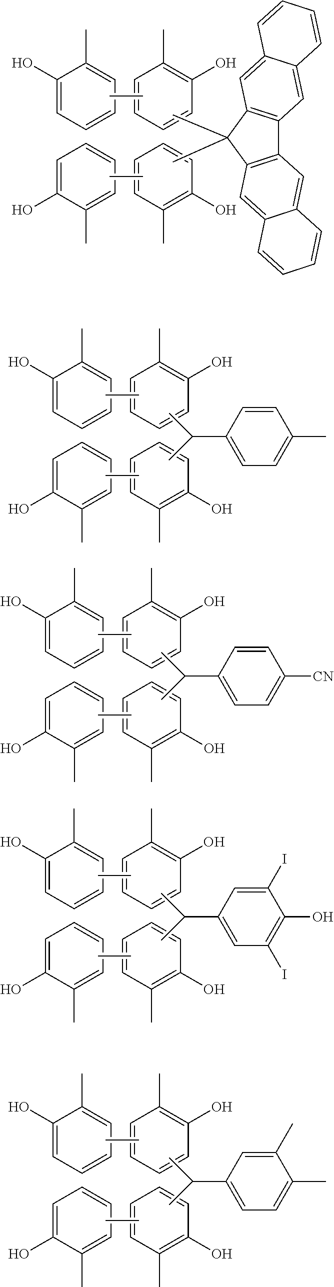

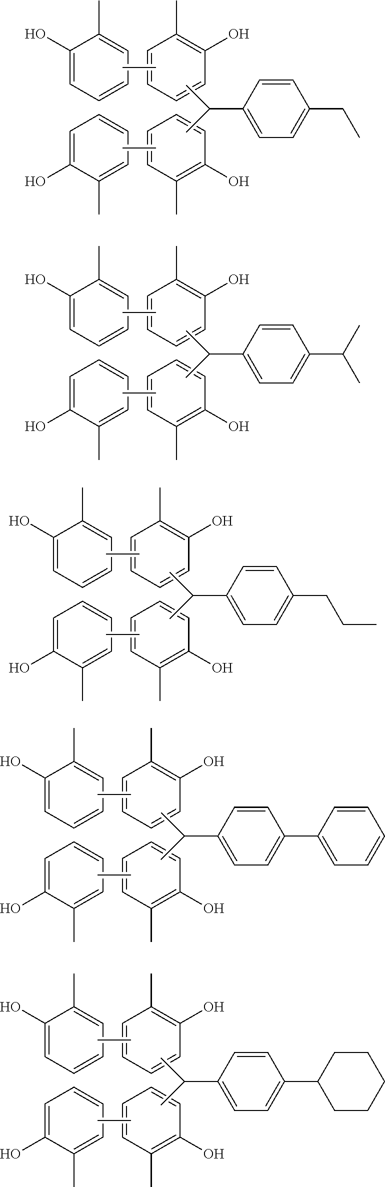

Specific examples of the aromatic hydroxy compound represented by the formulas (D-2A), (D-2), and (D-2-1) will be listed below. However, the aromatic hydroxy compound in the present embodiment is not limited to the compounds listed below.

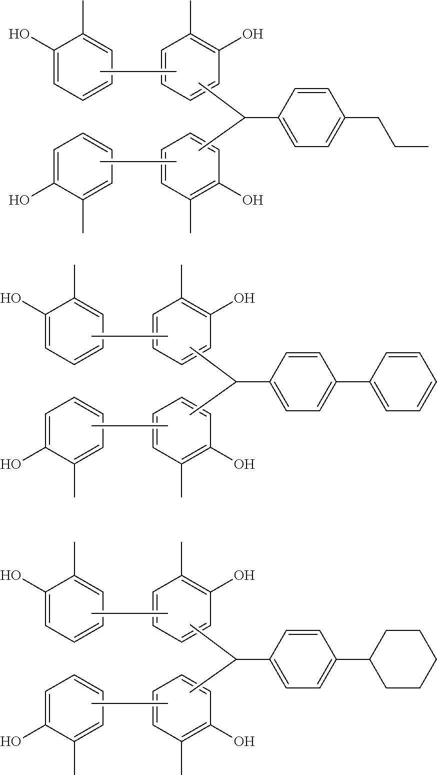

In the polycyclic polyphenolic resin of the present embodiment, the number and ratio of the respective repeating units are not particularly limited, but are preferably appropriately regulated in consideration of the application and the following values of molecular weight. Further, the polycyclic polyphenolic resin of the present embodiment may be constituted only by the repeating unit (D-1A) and/or (D-2A), but may also contain other repeating units within a range that does not impair the performance according to the application. Examples of another of repeating units another of repeating units include a repeating unit having an ether bond formed by condensation of a phenolic hydroxy group and a repeating unit having a ketone structure. These other repeating units may also be directly bonded to the repeating unit (D-1A) or (D-2A) through the aromatic rings. For example, the molar ratio [Y/X] of the total amount (Y) of the constituent unit (D-1A) and/or (D-2A) to the total amount [X] of the polycyclic polyphenolic resin of the present embodiment may be set to 0.05 to 1.00, and preferably 0.45 to 1.00.

The weight-average molecular weight of the polycyclic polyphenolic resin of the present embodiment is not particularly limited, but is preferably in the range of 400 to 100,000, more preferably 500 to 15,000, and still more preferably 3,200 to 12,000 from the viewpoint of having both heat resistance and solubility.

The range of the ratio of the weight-average molecular weight (Mw) to the number-average molecular weight (Mn) (Mw/Mn) is not particularly limited because the ratio required varies depending on the application, but as those having a more homogeneous molecular weight, for example, those having a ratio in the range of 3.0 or less are preferable, those having a ratio in the range of 1.05 or more and 3.0 or less are more preferable, those having a ratio in the range of 1.05 or more and less than 2.0 are particularly preferable, and those having a ratio in the range of 1.05 or more and less than 1.5 are yet still further preferable from the viewpoint of heat resistance.

The binding order of the repeating units of the polycyclic polyphenolic resin of the present embodiment in the resin is not particularly limited. For example, only one unit derived from an aromatic hydroxy compound represented by the formula (D-1A) or (D-2A) may be contained as two or more repeating units, or a plurality of units derived from an aromatic hydroxy compound represented by the formula (D-1A) or (D-2A) may be contained as one or more repeating units. The order may be either block copolymerization or random copolymerization.

In the polycyclic polyphenolic resin of the present embodiment, examples of “the repeating units are linked to each other by a direct bonding between the aromatic rings” include an aspect in which the repeating units (D-1A) in the polycyclic polyphenolic resin (alternatively, the repeating units (D-2A), or the repeating unit (D-1A) and the repeating unit (D-2A); hereinafter, these may be collectively referred to simply as “repeating unit (D-A)”) are directly bonded by a single bond between a carbon atom constituting an aromatic ring represented by an aryl structure in the parenthesis in the formula of one of repeating units (D-A) and a carbon atom constituting an aromatic ring represented by an aryl structure in the parenthesis in the formula of another of repeating units another of repeating units (D-A), that is, without any other atom such as a carbon atom, an oxygen atom or a sulfur atom.

Further, the present embodiment may include the following aspects.
(1) Aspect wherein in one of repeating units (D-A), when either R¹ or R² is an aryl group (including when R¹ is a group presented by R^{A}—R^{B} as described above and when R¹ is a 2n+1 valent group having an aryl group), an atom constituting the aromatic ring of the aryl group and a carbon atom constituting the aromatic ring represented by an aryl structure in parentheses in the formula of another of repeating units another of repeating units (D-A) are directly bonded by a single bond.
(2) Aspect wherein in one and another of repeating units another of repeating units (D-A), when either R¹ or R² is an aryl group (including when R¹ is a group presented by R^{A}—R^{B} as described above and when R¹ is a 2n+1 valent group having an aryl group), atoms on the aromatic rings of the aryl groups represented by R¹ and R² are directly bonded by a single bond between one and another of repeating units (D-A).

The position at which the repeating units are directly bonded to each other of the polycyclic polyphenolic resin in the present embodiment is not particularly limited, and when the repeating unit is represented by the general formula (D-1A) or (D-2A), any one carbon atom to which the phenolic hydroxy group and other substituents are not bonded is involved in the direct bonding between the monomers.

From the viewpoint of heat resistance, any one carbon atom of the aromatic ring having a phenolic hydroxy group is preferably involved in direct bonding between aromatic rings. In other words, when two repeating units (D-1A) are bonded to one of repeating units one of repeating units (D-1A), each of the two aryl structures in the formula (D-1A) is preferably bonded to another of repeating units. When each of the two aryl structures is bonded to another of repeating units (D-1A), the positions of the carbon atoms bonded to another of repeating units in each aryl structure may be different from each other, or may be the corresponding positions (for example, bonding to the o-position or p-position relative to the hydroxy group).

From the viewpoint of heat resistance and etching resistance, preferred is an aspect in which based on the total amount, 30 mol % or more, more preferably 50 mol % or more, still more preferably 80 mol % or more, more preferably 85 mol % or more of the repeating units (D-1A) in the polycyclic polyphenolic resin are directly bonded by a single bond between a carbon atom constituting an aromatic ring represented by an aryl structure in the parenthesis in the formula of one of repeating units one of repeating units (D-1A) and a carbon atom constituting an aromatic ring represented by an aryl structure in the parenthesis in the formula of another of repeating units (D-1A).

In the polycyclic polyphenolic resin of the present embodiment, all the repeating units (D-1A) are preferably bonded by a direct bond between aromatic rings, but a repeating unit (D-1A) bonded to another repeating unit via another atom such as oxygen or carbon may also be contained. Although not particularly limited, from the viewpoint of sufficiently exhibiting the effects of the present invention such as heat resistance and etching resistance, it is preferable that 50% or more, more preferably 90% or more of the repeating units (D-1A) on a bonding basis are bonded to other repeating units (D-1A) by a direct bond between aromatic rings in all the repeating unit (D-1A) in the polycyclic polyphenolic resin of the present embodiment.

The polycyclic polyphenolic resin of the present embodiment preferably has high solubility in a solvent from the viewpoint of easier application to a wet process, etc. More specifically, in the case of using propylene glycol monomethyl ether (PGME) and/or propylene glycol monomethyl ether acetate (PGMEA) as a solvent, it is preferable that the polycyclic polyphenolic resin of the present embodiment has a solubility of 1% by mass or more in PGME and/or PGMEA. Specifically, the solubility in the solvent at 23° C. is preferably 1% by mass or more, more preferably 5% by mass or more, still more preferably 10% by mass or more, particularly preferably 20% by mass or more, and particularly preferably 30% by mass or more. Here, the solubility in PGME and/or PGMEA is defined as “mass of the resin/(mass of the resin+mass of the solvent)×100 (% by mass)”. For example, 10 g of the polycyclic polyphenolic resin is evaluated as being dissolved in 90 g of PGMEA when the solubility of the polycyclic polyphenolic resin in the PGMEA is “10% by mass or more”; 10 g of the resin is evaluated as being not dissolved in 90 g of PGMEA when the solubility is “less than 10% by mass”.

<Polycyclic Polyphenolic Resin Having Repeating Units Derived from Aromatic Hydroxy Compound Represented by the Formula (C-1A)>

The polycyclic polyphenolic resin of the present embodiment is a polycyclic polyphenolic resin containing repeating units derived from an aromatic hydroxy compound represented by the following formula (C-1A) (hereinafter, may be simply referred to as “repeating unit (C-1A)”, and the repeating unit may be referred to as “repeating unit derived from monomer”), in which the repeating units are linked to each other by a direct bonding between aromatic rings. Since the polycyclic polyphenolic resin of the present embodiment is configured as described above, it has more excellent performance in terms of performance such as heat resistance and etching resistance.

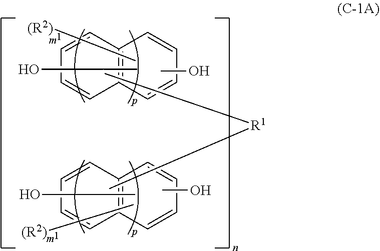

(In the formula (C-1A), R¹ is a 2n-valent group having 1 to 60 carbon atoms or a single bond, each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group, and each m is independently an integer of 0 to 9. n is an integer of 1 to 4, and each p is independently an integer of 0 to 3.)

Hereinafter, the above formula (C-1A) will be described in detail.

In the formula (C-1A), R¹ and R² are as defined in the above formula (1A). R¹ is a 2n-valent group having 1 to 60 carbon atoms or a single bond.

The 2n-valent group having 1 to 60 carbon atoms refers to, for example, a 2n-valent hydrocarbon group, and the hydrocarbon group may have various functional groups described later as substituents. Further, the 2n-valent hydrocarbon group refers to an alkylene group having 1 to 60 carbon atoms when n is 1, an alkanetetrayl group having 1 to 60 carbon atoms when n is 2, an alkanehexayl group having 2 to 60 carbon atoms when n is 3, and an alkaneoctayl group having 3 to 60 carbon atoms when n is 4. Examples of the 2n-valent hydrocarbon group include in which a 2n+1 valent hydrocarbon group is bonded to a linear hydrocarbon group, a branched hydrocarbon group, or an alicyclic hydrocarbon group. Herein, the alicyclic hydrocarbon group also includes a bridged alicyclic hydrocarbon group.

Examples of the 2n+1-valent hydrocarbon group include, but are not limited to, a 3-valent methine group and an ethyne group.

Further, the 2n-valent hydrocarbon group may have a double bond, a heteroatom, and/or an aryl group having 6 to 59 carbon atoms. R¹ may include a group derived from a compound having a fluorene skeleton such as fluorene or benzofluorene.

In the present embodiment, the 2n-valent group may contain a halogen group, a nitro group, an amino group, a hydroxy group, an alkoxy group, a thiol group, or an aryl group having 6 to 40 carbon atoms. Furthermore, the 2n-valent group may contain an ether bond, a ketone bond, an ester bond, or a double bond.

In the present embodiment, from the viewpoint of heat resistance, the 2n-valent group preferably includes a branched hydrocarbon group or an alicyclic hydrocarbon group rather than a linear hydrocarbon group, and more preferably includes an alicyclic hydrocarbon group. Further, in the present embodiment, it is particularly preferably that the 2n-valent group has an aryl group having 6 to 60 carbon atoms.

Examples of the linear hydrocarbon group and the branched hydrocarbon group which may be contained in the 2n-valent group as a substituent include, but are not particularly limited to, an unsubstituted methyl group, an ethyl group, a n-propyl group, an i-propyl group, a n-butyl group, an i-butyl group, a t-butyl group, a n-pentyl group, a n-hexyl group, a n-dodecyl group, and a barrel group.

Examples of an alicyclic hydrocarbon group and an aromatic group having 6 to 60 carbon atoms which may be contained in the 2 n-valent group as a substituent include, but are not particularly limited to, an unsubstituted phenyl group, a naphthalene group, a biphenyl group, an anthracyl group, a pyrenyl group, a cyclohexyl group, a cyclododecyl group, a dicyclopentyl group, a tricyclodecyl group, an adamantyl group, a phenylene group, a naphthalenediyl group, a biphenyldiyl group, an anthracenediyl group, a pyrendiyl group, a cyclohexanediyl group, a cyclododecanediyl group, a dicyclopentanediyl group, a tricyclodecanediyl group, an adamantanediyl group, a benzenetriyl group, a naphthalenetriyl group, a biphenyltriyl group, an anthracenetriyl group, a pyrenetriyl group, a cyclohexanetriyl group, a cyclododecanetriyl group, a dicyclopentanetriyl group, a tricyclodecanetriyl group, an adamantanetriyl group, a benzenetetrayl group, a naphthalenetetrayl group, a biphenyltetrayl group, an anthracenetetrayl group, a pyrenetetrayl group, a cyclohexanetetrayl group, a cyclododecanetetrayl group, a dicyclopentanetetrayl group, a tricyclodecantetrayl group, and an adamantanetetrayl group.

In the formula (C-1A), each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group. The alkyl group and the like may be linear, branched or cyclic.

Examples of the alkyl group having 1 to 40 carbon atoms include, but are not limited to, a methyl group, an ethyl group, a n-propyl group, an i-propyl group, a n-butyl group, an i-butyl group, a t-butyl group, a n-pentyl group, a n-hexyl group, a n-dodecyl group, and a barrel group.

Examples of the aryl group having 6 to 40 carbon atoms include, but are not limited to, a phenyl group, a naphthalene group, a biphenyl group, an anthracyl group, a pyrenyl group, and a perylene group.

Examples of the alkenyl group having 2 to 40 carbon atoms include, but are not limited to, an ethynyl group, a propenyl group, a butynyl group, and a pentynyl group.

Examples of the alkynyl group having 2 to 40 carbon atoms include, but are not limited to, an acetylene group, an ethynyl group.

Examples of the alkoxy group having 1 to 40 carbon atoms include, but are not limited to, a methoxy group, an ethoxy group, a propoxy group, a butoxy group, and a pentoxy group.

Examples of the halogen atom include fluorine, chlorine, bromine, and iodine.

Examples of the heterocycles such as pyridine, pyrrole, pyridazine, thiophene, imidazole, furan, pyrazole, oxazole, triazole, thiazole, or benzo-fused rings thereof.

In the formula (C-1A), each m is independently an integer of 0 to 9. m is preferably 0 to 3, more preferably 0 to 1, from the viewpoint of solubility, and is still more preferably 0 from the viewpoint of availability of raw materials.

In the formula (C-1A), n is an integer of 1 to 4, preferably 1 to 2. Here, when n is an integer of 2 or larger, n structural formulas within the parentheses [ ] may be the same or different.

In the formula (C-1A), each p is independently an integer of 0 to 3. When p is 0, the cyclic structure shown in the parentheses is a benzene ring, and when p is 1, the cyclic structure shown in the parentheses is a naphthalene ring. When p is 2, the cyclic structure shown in the parentheses is an aromatic ring of a tricyclic structure such as an anthracene ring or a phenanthrene ring, and when p is 3, the cyclic structure shown in the parentheses is an aromatic ring of a tetracyclic structure such as tetracene, pyrene, or chrysene.

Further, in the formula (C-1A), two aryl structures in the parentheses may be the same or different, but are preferably the same from the viewpoint of production.

In the present embodiment, as the polycyclic polyphenolic resin, those represented by the formula (C-1A) can be used alone, or two or more kinds thereof can be used together.

In the present embodiment, the aromatic hydroxy compound represented by the formula (C-1A) is preferably the compound represented by the following formula (C-1) from the viewpoint of ease of production. For example, since the structure represented by the formula (C-1) has two or more hydroxy groups on one aryl structure, high solubility in a solvent can be exhibited as compared with the case where the structure has only one hydroxy group.

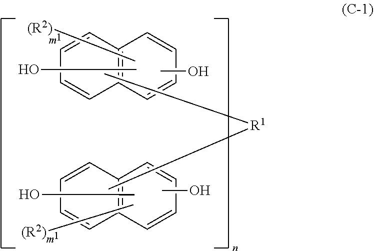

(In the formula (C-1), R¹, R², and n are as defined in the formula (C-1A). Each m¹ is independently an integer of 1 to 5.)

In the present embodiment, the aromatic hydroxy compound represented by the formula (C-1) is preferably the compound represented by the following formula (C-1) from the viewpoint of ease of production.

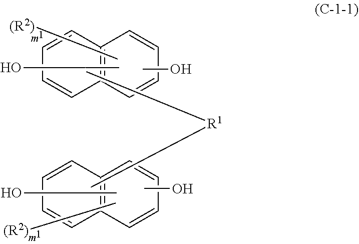

(In the formula (C-1-1), R¹, R², and m¹ are as defined in the formula (C-1).)

In the present embodiment, the aromatic hydroxy compound represented by the formula (C-1-1) is preferably the compound represented by the following formula (C-1-2) from the viewpoint of ease of production.

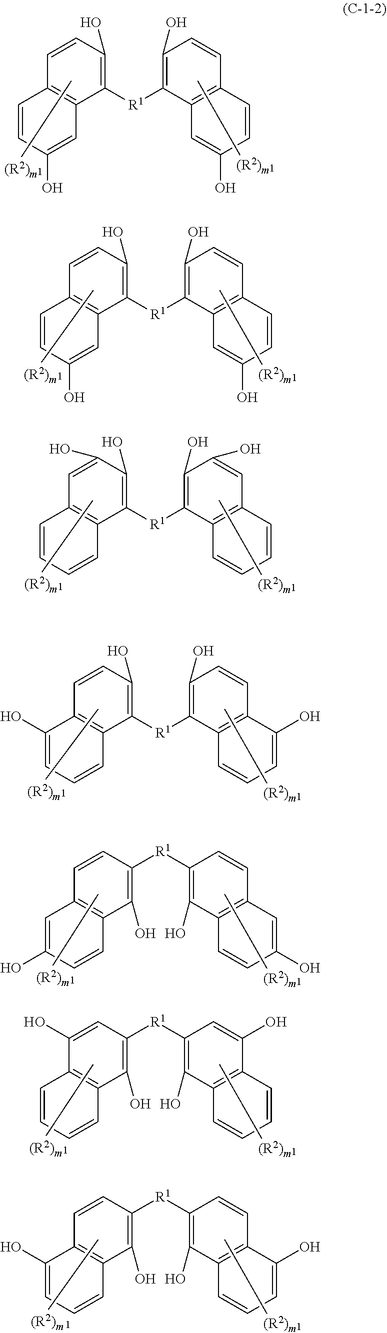

(In the formula (C-1-2), R¹, R², and m¹ are as defined in the formula (C-1-1).)

In the present embodiment, the aromatic hydroxy compound represented by the formula (C-1-2) is preferably the compound represented by the following formula (C-1-3) from the viewpoint of ease of production.

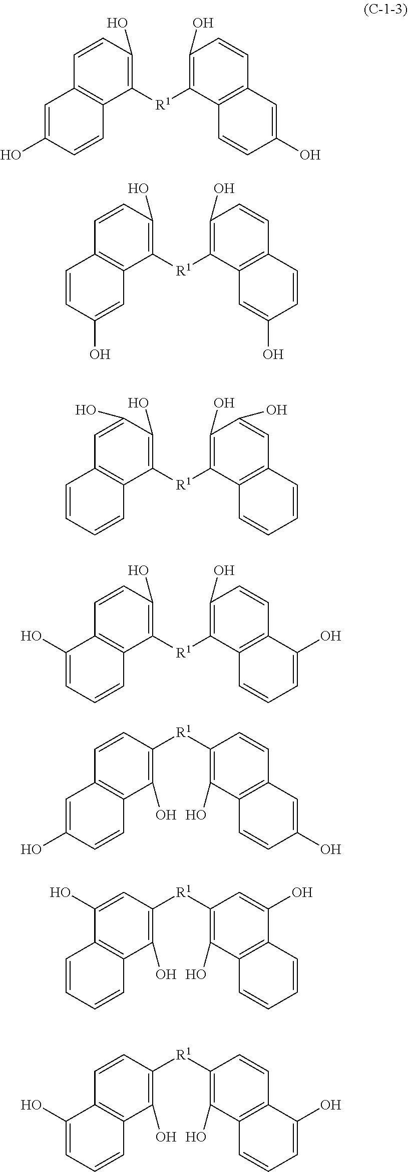

(In the formula (C-1-3), R¹ is as defined in the formula (C-1-2).)

In the formulas (C-1A), (C-1), (C-1-1), (C-1-2), and (C-1-3), R¹ preferably contains an aryl group having 6 to 40 carbon atoms and optionally having a substituent from the viewpoint of achieving both high heat resistance and solubility. In the present embodiment, the aryl group having 6 to 40 carbon atoms may be, but are not limited to, for example, a benzene ring, or various known fused rings such as naphthalene, anthracene, naphthacene, pentacene, benzopyrene, chrysene, pyrene, triphenylene, corannulene, coronene, ovalene, fluorene, benzofluorene, and dibenzofluorene. In the present embodiment, R¹ is preferably any of various fused rings such as naphthalene, anthracene, naphthacene, pentacene, benzopyrene, chrysene, pyrene, triphenylene, corannulene, coronene, ovalene, fluorene, benzofluorene, and dibenzofluorene, from the viewpoint of heat resistance. Further, R¹ is preferably naphthalene or anthracene because the n-value and the k-value at wavelengths 193 nm used in ArF exposure are low and pattern transferability tends to be excellent. Examples of R¹ include, in addition to the aromatic hydrocarbon rings described above, heterocycles such as pyridine, pyrrole, pyridazine, thiophene, imidazole, furan, pyrazole, oxazole, triazole, thiazole, or benzo-fused rings thereof. In the present embodiment, R¹ is preferably an aromatic hydrocarbon ring or a heterocycle, and more preferably an aromatic hydrocarbon ring. Further, R¹ may be an aromatic hydrocarbon ring other than a group derived from a compound having a fluorene skeleton such as fluorene or benzofluorene from the viewpoint of solubility.

In the formulas (C-1A), (C-1), (C-1-1), (C-1-2), and (C-1-3), it is preferable that R¹ is a group represented by R^{A}—R^{B}, in which R^{A} is a methine group, and R^{B} is an aryl group having 6 to 40 carbon atoms and optionally having a substituent, from the viewpoint of having both further high heat resistance and solubility. Examples of the aryl include the aryl groups described above, and R¹ may also be an aryl group other than a group derived from a compound having a fluorene skeleton such as fluorene or benzofluorene. Thus, it is presumed that when R¹ is a group represented by R^{A}—R^{B}, the free volume is increased via a methine group, thereby improving the solubility and the like.

Further, although not particularly limited, from the point of view of solubility, R^{B} is preferably a biaryl skeleton, and more preferably biphenyl. Further, although not particularly limited, but from the point of view of heat resistance, R^{B} is preferably a polycyclic aromatic, and more preferably pyrene.

Specific examples of the aromatic hydroxy compound represented by the formulas (C-1A), (C-1), (C-1-1), (C-1-2), and (C-1-3) will be listed below. However, the aromatic hydroxy compound in the present embodiment is not limited to the compounds listed below.

Specific examples of the polycyclic polyphenolic resin of the present embodiment include a polycyclic polyphenolic resin containing repeating units (C-1A) derived from an aromatic hydroxy compound represented by the following formula, in which the repeating units are linked to each other by a direct bonding between aromatic rings. Examples of such a polymer include RBisN-1, RBisN-2, RBisN-3, RBisN-4, RBisN-5, and RBisN-6, which will be described later in Synthesis Working Examples. The polycyclic polyphenolic resin of the present embodiment is assumed to be applicable to all kinds of applications such as a composition to be described later, a method for producing a polycyclic polyphenolic resin, a composition for film formation, a resist composition, a resist pattern formation method, a radiation-sensitive composition, a composition for underlayer film formation for lithography, a method for producing an underlayer film for lithography, a circuit pattern formation method, and a composition for optical member formation, and from the viewpoint of further enhancing heat resistance and etching resistance, the polycyclic polyphenolic resin of the present embodiment may be at least one selected from the group consisting of RBisN-1, RBisN-2, RBisN-3, RBisN-4, RBisN-5, and RBisN-6 described in the embodiments to be described later.

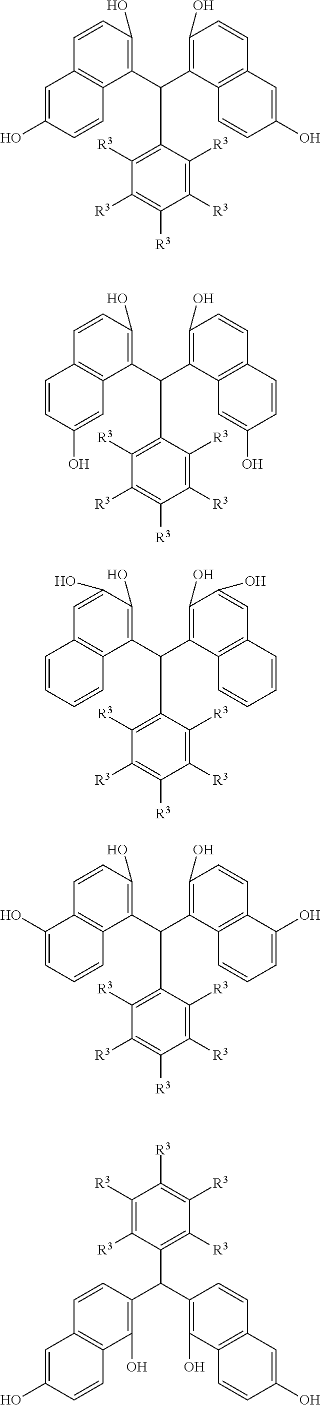

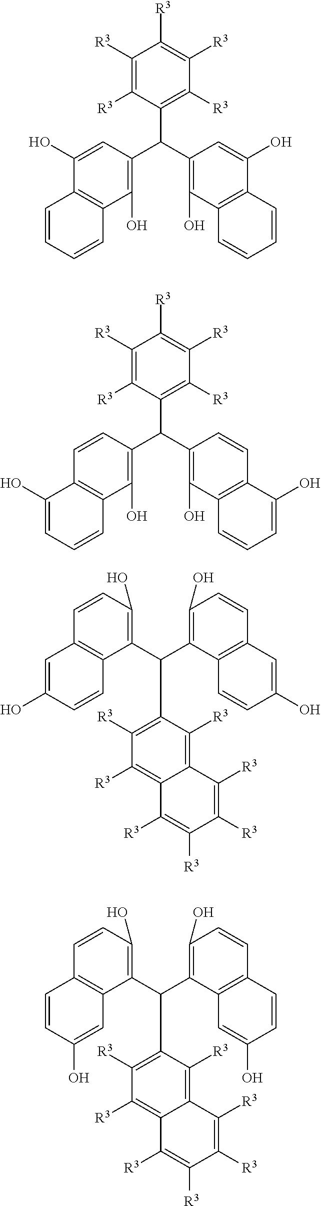

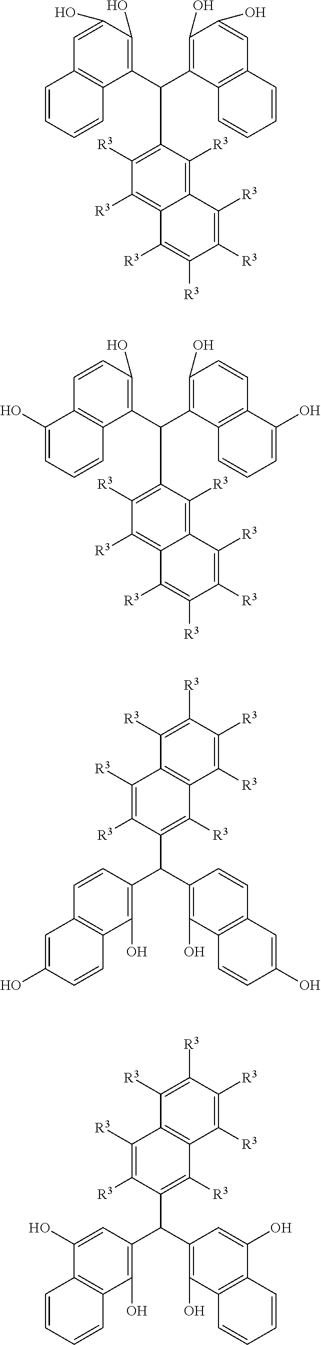

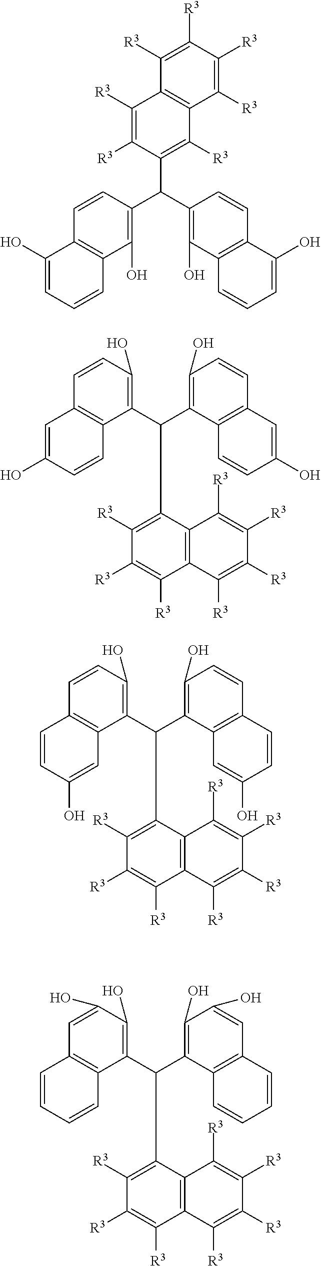

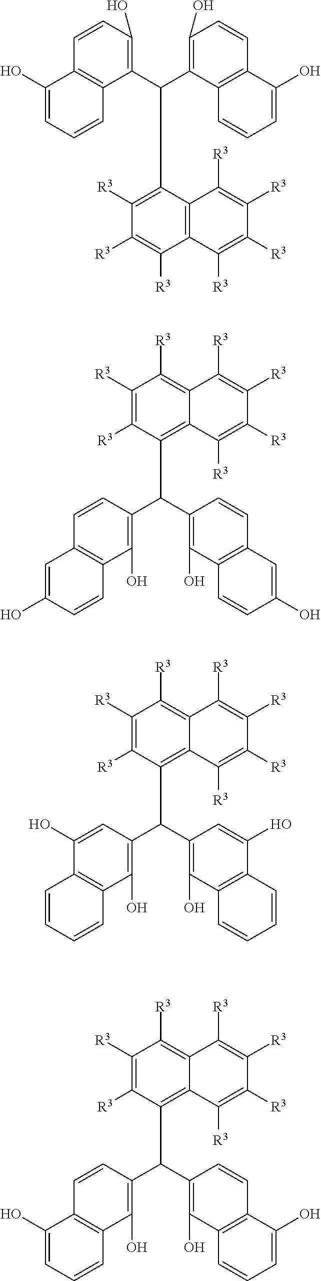

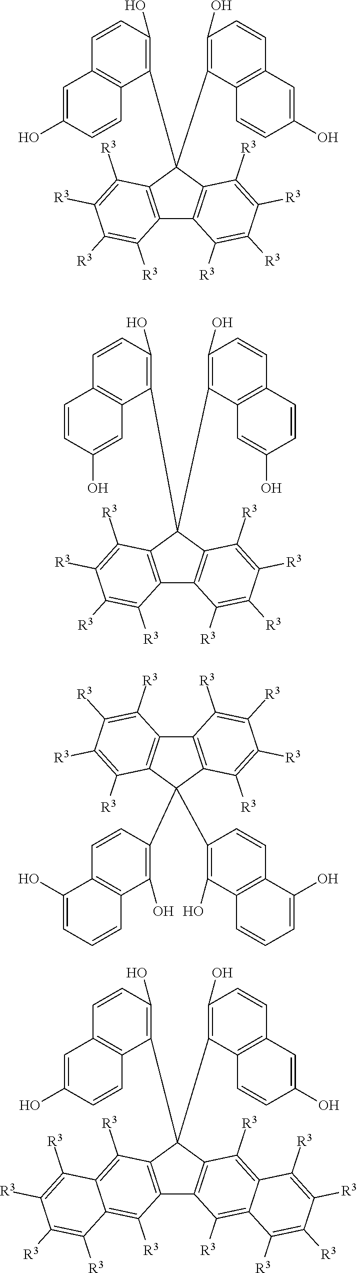

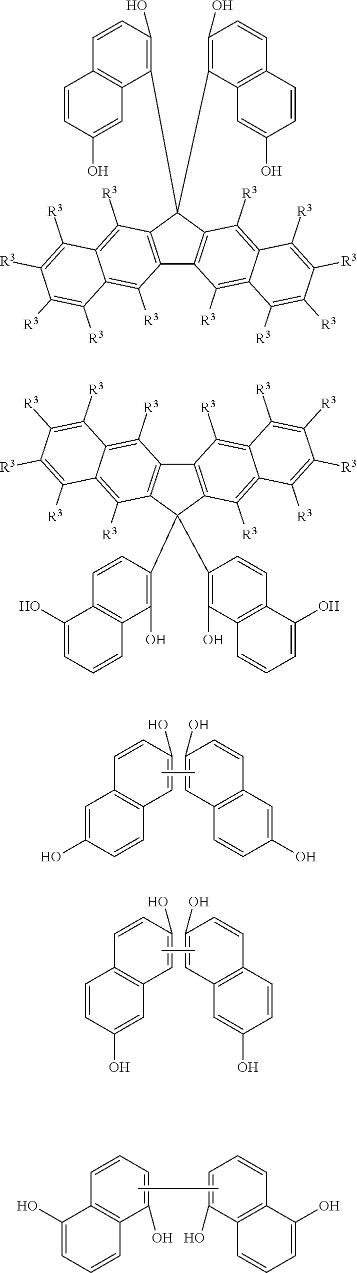

In the formulas described above, each R³ is independently a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group. The alkyl group may be linear, branched or cyclic.

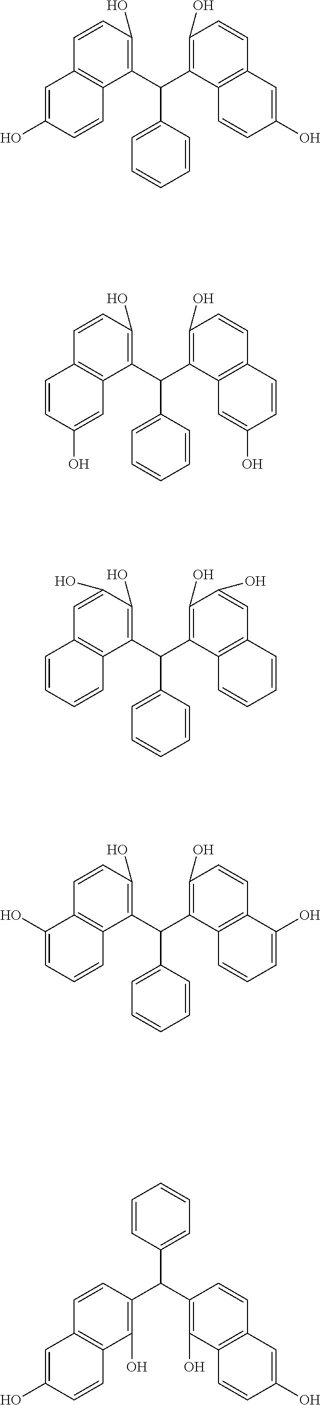 [SMILES: Oc1ccc2c(C(c3ccccc3)c3c(O)ccc4cc(O)ccc34)c(O)ccc2c1 ; Oc1ccc2ccc(O)c(C(c3ccccc3)c3c(O)ccc4ccc(O)cc34)c2c1 ; Oc1cc2ccccc2c(C(c2ccccc2)c2c(O)c(O)cc3ccccc23)c1O ; Oc1ccc2c(O)cccc2c1C(c1ccccc1)c1c(O)ccc2c(O)cccc12 ; Oc1ccc2c(O)c(C(c3ccccc3)c3ccc4cc(O)ccc4c3O)ccc2c1]

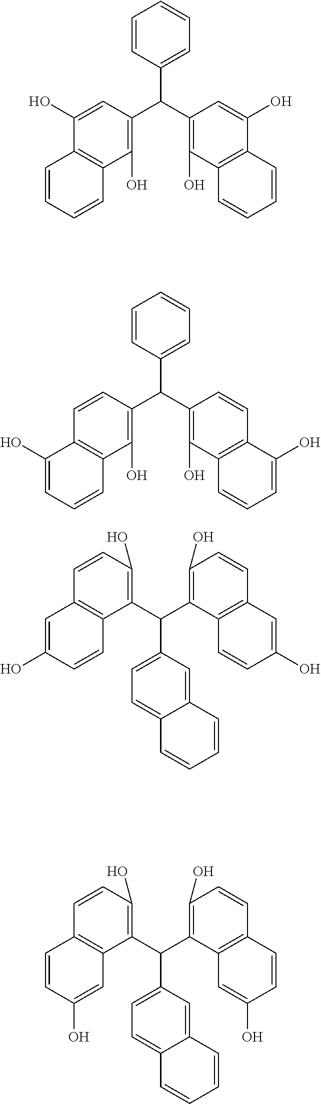 [SMILES: Oc1cc(C(c2ccccc2)c2cc(O)c3ccccc3c2O)c(O)c2ccccc12 ; Oc1cccc2c(O)c(C(c3ccccc3)c3ccc4c(O)cccc4c3O)ccc12 ; Oc1ccc2c(C(c3ccc4ccccc4c3)c3c(O)ccc4cc(O)ccc34)c(O)ccc2c1 ; Oc1ccc2ccc(O)c(C(c3ccc4ccccc4c3)c3c(O)ccc4ccc(O)cc34)c2c1]

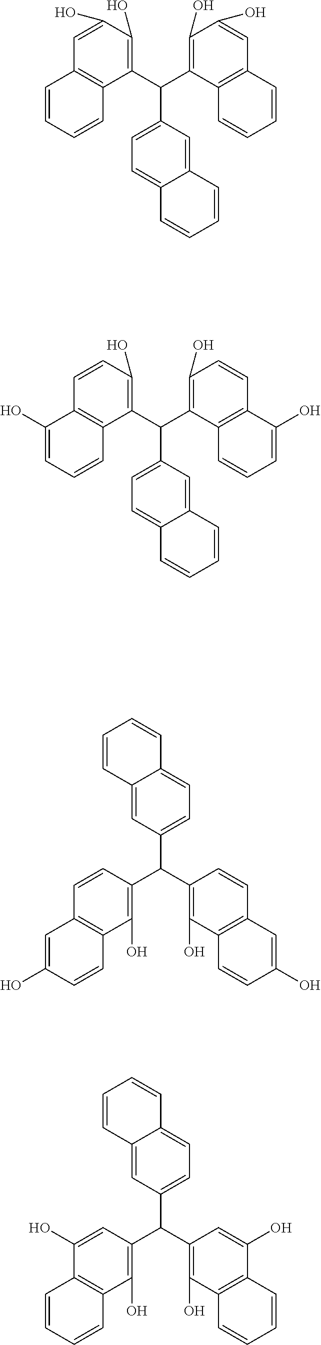 [SMILES: Oc1cc2ccccc2c(C(c2ccc3ccccc3c2)c2c(O)c(O)cc3ccccc23)c1O ; Oc1ccc2c(O)cccc2c1C(c1ccc2ccccc2c1)c1c(O)ccc2c(O)cccc12 ; Oc1ccc2c(O)c(C(c3ccc4ccccc4c3)c3ccc4cc(O)ccc4c3O)ccc2c1 ; Oc1cc(C(c2ccc3ccccc3c2)c2cc(O)c3ccccc3c2O)c(O)c2ccccc12]

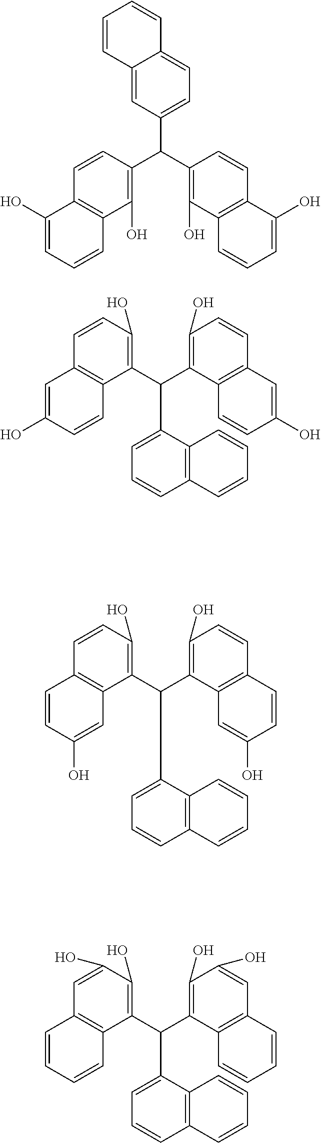 [SMILES: Oc1cccc2c(O)c(C(c3ccc4ccccc4c3)c3ccc4c(O)cccc4c3O)ccc12 ; Oc1ccc2c(C(c3cccc4ccccc34)c3c(O)ccc4cc(O)ccc34)c(O)ccc2c1 ; Oc1ccc2ccc(O)c(C(c3cccc4ccccc34)c3c(O)ccc4ccc(O)cc34)c2c1 ; Oc1cc2ccccc2c(C(c2cccc3ccccc23)c2c(O)c(O)cc3ccccc23)c1O]

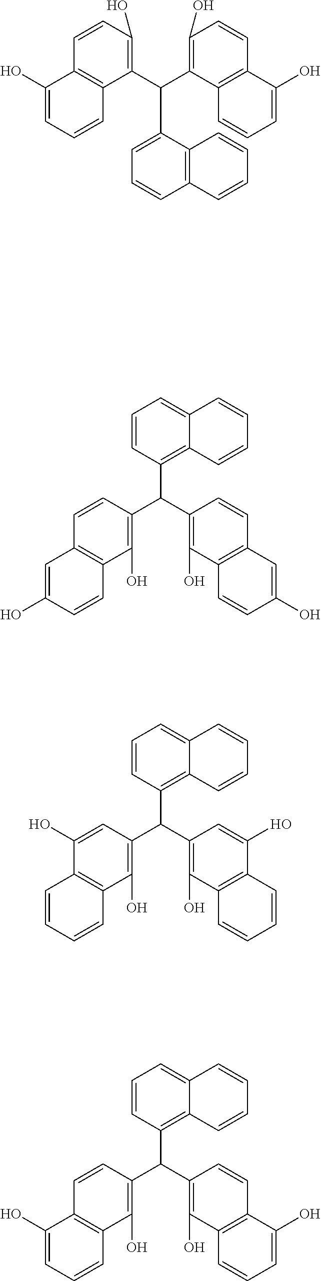 [SMILES: Oc1ccc2c(O)cccc2c1C(c1cccc2ccccc12)c1c(O)ccc2c(O)cccc12 ; Oc1ccc2c(O)c(C(c3ccc4cc(O)ccc4c3O)c3cccc4ccccc34)ccc2c1 ; Oc1cc(C(c2cc(O)c3ccccc3c2O)c2cccc3ccccc23)c(O)c2ccccc12 ; Oc1cccc2c(O)c(C(c3ccc4c(O)cccc4c3O)c3cccc4ccccc34)ccc12]

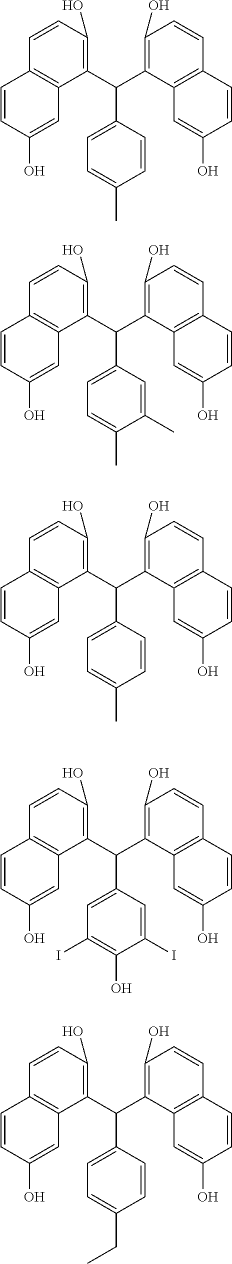 [SMILES: Cc1ccc(C(c2c(O)ccc3ccc(O)cc23)c2c(O)ccc3ccc(O)cc23)cc1 ; Cc1ccc(C(c2c(O)ccc3ccc(O)cc23)c2c(O)ccc3ccc(O)cc23)cc1C ; Cc1ccc(C(c2c(O)ccc3ccc(O)cc23)c2c(O)ccc3ccc(O)cc23)cc1 ; Oc1ccc2ccc(O)c(C(c3cc(I)c(O)c(I)c3)c3c(O)ccc4ccc(O)cc34)c2c1 ; CCc1ccc(C(c2c(O)ccc3ccc(O)cc23)c2c(O)ccc3ccc(O)cc23)cc1]

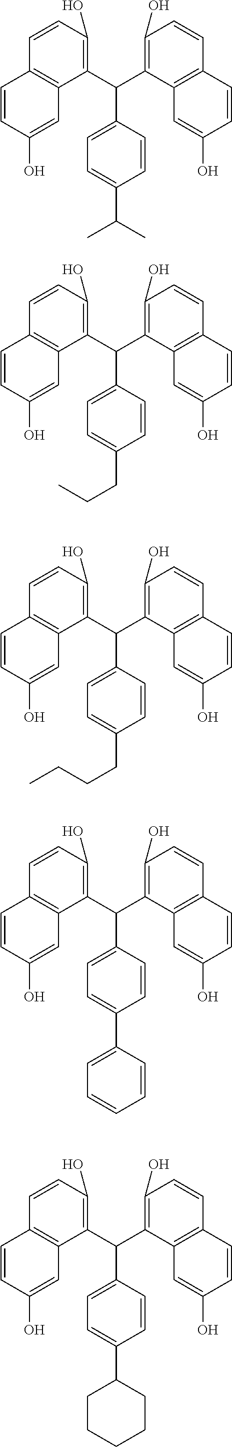

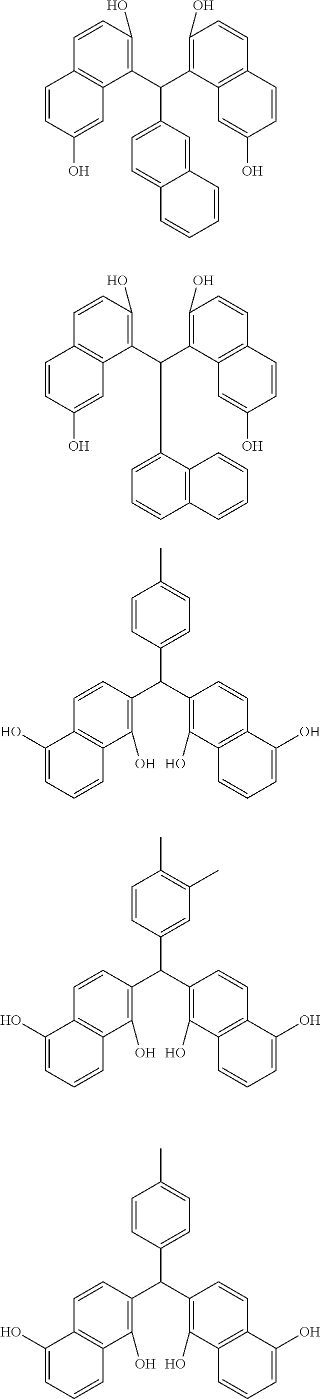

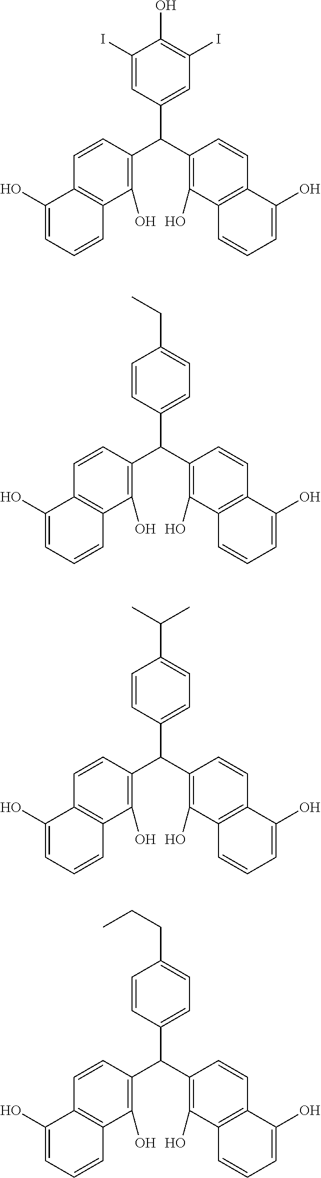 [SMILES: Oc1c(I)cc(C(c2ccc3c(O)cccc3c2O)c2ccc3c(O)cccc3c2O)cc1I ; CCc1ccc(C(c2ccc3c(O)cccc3c2O)c2ccc3c(O)cccc3c2O)cc1 ; CC(C)c1ccc(C(c2ccc3c(O)cccc3c2O)c2ccc3c(O)cccc3c2O)cc1 ; CCCc1ccc(C(c2ccc3c(O)cccc3c2O)c2ccc3c(O)cccc3c2O)cc1]

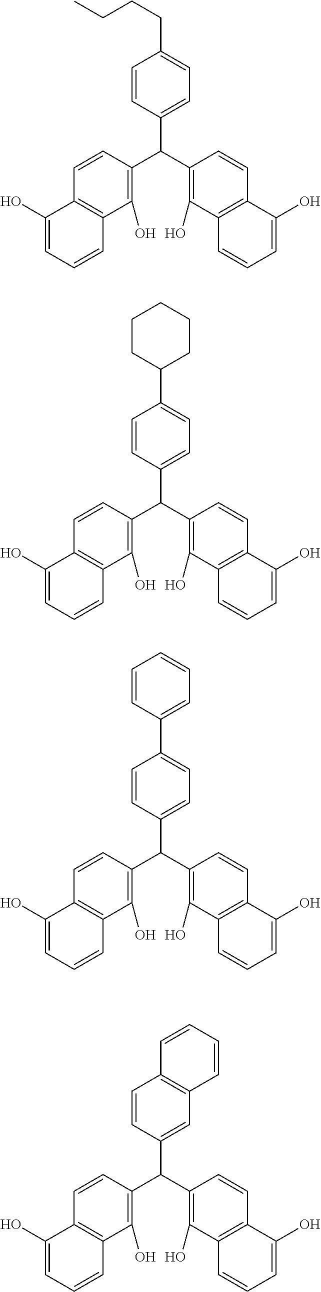 [SMILES: CCCCc1ccc(C(c2ccc3c(O)cccc3c2O)c2ccc3c(O)cccc3c2O)cc1 ; Oc1cccc2c(O)c(C(c3ccc(C4CCCCC4)cc3)c3ccc4c(O)cccc4c3O)ccc12 ; Oc1cccc2c(O)c(C(c3ccc(-c4ccccc4)cc3)c3ccc4c(O)cccc4c3O)ccc12 ; Oc1cccc2c(O)c(C(c3ccc4ccccc4c3)c3ccc4c(O)cccc4c3O)ccc12]

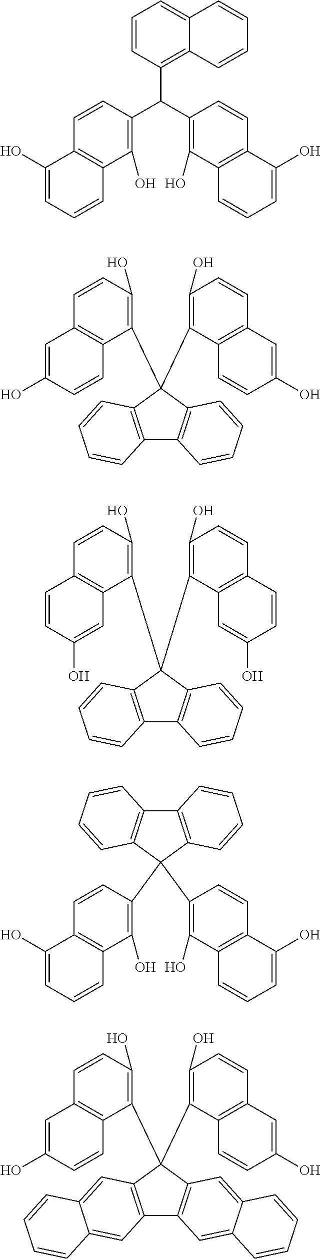

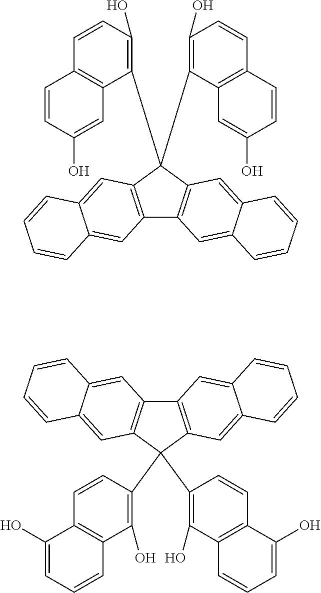 [SMILES: Oc1ccc2ccc(O)c(C3(c4c(O)ccc5ccc(O)cc45)c4cc5ccccc5cc4-c4cc5ccccc5cc43)c2c1 ; Oc1cccc2c(O)c(C3(c4ccc5c(O)cccc5c4O)c4cc5ccccc5cc4-c4cc5ccccc5cc43)ccc12]

In the polycyclic polyphenolic resin of the present embodiment, the number and ratio of the respective repeating units are not particularly limited, but are preferably appropriately regulated in consideration of the application and the following values of molecular weight. Further, the polycyclic polyphenolic resin of the present embodiment may be constituted only by the repeating unit (C-1A), but may also contain other repeating units within a range that does not impair the performance according to the application. Examples of another of repeating units include a repeating unit having an ether bond formed by condensation of a phenolic hydroxy group and a repeating unit having a ketone structure. These other repeating units may also be directly bonded to the repeating unit (C-1A) through the aromatic rings. For example, the molar ratio [Y/X] of the total amount (Y) of the repeating units (C-1A) to the total amount [X] of the polycyclic polyphenolic resin of the present embodiment may be set to 0.05 to 1.00, and preferably 0.45 to 1.00.

The weight-average molecular weight of the polycyclic polyphenolic resin of the present embodiment is not particularly limited, but is preferably in the range of 400 to 100,000, more preferably 500 to 15,000, and still more preferably 1,000 to 12,000 from the viewpoint of having both heat resistance and solubility.

The range of the ratio of the weight-average molecular weight (Mw) to the number-average molecular weight (Mn) (Mw/Mn) is not particularly limited because the ratio required varies depending on the application, but as those having a more homogeneous molecular weight, for example, those having a ratio in the range of 3.0 or less are preferable, those having a ratio in the range of 1.05 or more and 3.0 or less are more preferable, those having a ratio in the range of 1.05 or more and less than 2.0 are particularly preferable, and those having a ratio in the range of 1.05 or more and less than 1.5 are yet still further preferable from the viewpoint of heat resistance.

The binding order of the repeating units of the polycyclic polyphenolic resin of the present embodiment in the resin is not particularly limited. For example, only one unit derived from an aromatic hydroxy compound represented by the formula (C-1A) may be contained as two or more repeating units, or a plurality of units derived from an aromatic hydroxy compound represented by the formula (C-1A) may be contained as one or more repeating units. The order may be either block copolymerization or random copolymerization.

In the polycyclic polyphenolic resin of the present embodiment, examples of “the repeating units are linked to each other by a direct bonding between the aromatic rings” include an aspect in which the repeating units (C-1A) in the polycyclic polyphenolic resin are directly bonded by a single bond between a carbon atom constituting an aromatic ring represented by an aryl structure in the parenthesis in the formula of one of repeating units one of repeating units (C-1A) and a carbon atom constituting an aromatic ring represented by an aryl structure in the parenthesis in the formula of another of repeating units (C-1A), that is, without any other atom such as a carbon atom, an oxygen atom or a sulfur atom.

Further, the present embodiment may include the following aspects.
(1) Aspect wherein in one of repeating units (C-1A), when either R¹ or R² is an aryl group (including when R¹ is a group presented by R^{A}—R^{B} as described above and when R¹ is a 2n+1 valent group having an aryl group), an atom constituting the aromatic ring of the aryl group and a carbon atom constituting the aromatic ring represented by an aryl structure in parentheses in the formula of another of repeating units (C-1A) are directly bonded by a single bond.
(2) Aspect wherein in one and another of repeating units (C-1A), when either R¹ or R² is an aryl group (including when R¹ is a group presented by R^{A}—R^{B} as described above and when R¹ is a 2n+1 valent group having an aryl group), atoms on the aromatic rings of the aryl groups represented by R¹ and R² are directly bonded by a single bond between one and another of repeating units (C-1A).

The position at which the repeating units are directly bonded to each other in the polycyclic polyphenolic resin of the present embodiment is not particularly limited, and any one carbon atom to which the phenolic hydroxy group and other substituents are not bonded is involved in the direct bonding between the monomers.

From the viewpoint of heat resistance, any one carbon atom of the aromatic ring having a phenolic hydroxy group is preferably involved in direct bonding between aromatic rings. In other words, when two repeating units (C-1A) are bonded to one of repeating units (C-1A), each of the two aryl structures in the formula (C-1A) is preferably bonded to another of repeating units. When each of the two aryl structures is bonded to another of repeating units (C-1A), the positions of the carbon atoms bonded to another of repeating units in each aryl structure may be different from each other, or may be the corresponding positions (for example, bonding to the 7-positions of both naphthalene rings).

From the viewpoint of heat resistance and etching resistance, preferred is an aspect in which based on the total amount, 30 mol % or more, more preferably 50 mol % or more, still more preferably 80 mol % or more, more preferably 90 mol % or more of the repeating units (1A) in the polycyclic polyphenolic resin are directly bonded by a single bond between a carbon atom constituting an aromatic ring represented by an aryl structure in the parenthesis in the formula of one of repeating units (1A) and a carbon atom constituting an aromatic ring represented by an aryl structure in the parenthesis in the formula of another of repeating units (1A).

In the polycyclic polyphenolic resin of the present embodiment, all the repeating units (C-1A) are preferably bonded by a direct bond between aromatic rings, but a repeating unit (C-1A) bonded to another repeating unit via another atom such as oxygen or carbon may also be contained. Although not particularly limited, from the viewpoint of sufficiently exhibiting the effects of the present invention such as heat resistance and etching resistance, it is preferable that 50% or more, more preferably 90% or more of the repeating units (C-1A) on a molar basis are bonded to other repeating units (C-1A) by a direct bond between aromatic rings in all the repeating unit (C-1A) in the polycyclic polyphenolic resin of the present embodiment.

The polycyclic polyphenolic resin of the present embodiment preferably has high solubility in a solvent from the viewpoint of easier application to a wet process, etc. More specifically, in the case of using propylene glycol monomethyl ether (PGME) and/or propylene glycol monomethyl ether acetate (PGMEA) as a solvent, it is preferable that the polycyclic polyphenolic resin of the present embodiment has a solubility of 1% by mass or more in propylene glycol monomethyl ether and/or propylene glycol monomethyl ether acetate. Specifically, the solubility in the solvent at 23° C. is preferably 1% by mass or more, more preferably 5% by mass or more, still more preferably 10% by mass or more, particularly preferably 20% by mass or more, and particularly preferably 30% by mass or more. Here, the solubility in PGME and/or PGMEA is defined as “mass of the resin/(mass of the resin+mass of the solvent)×100 (% by mass)”. For example, 10 g of the polycyclic polyphenolic resin is evaluated as being dissolved in 90 g of PGMEA when the solubility of the polycyclic polyphenolic resin in the PGMEA is “10% by mass or more”; 10 g of the resin is evaluated as being not dissolved in 90 g of PGMEA when the solubility is “less than 10% by mass”.

### [Method for Producing Polycyclic Polyphenol Resin]

A method for producing the polycyclic polyphenolic resin of the present embodiment is not limited to the following, but may include, for example, a step of polymerizing one kind or two or more kinds of the aromatic hydroxy compounds in the presence of an oxidizing agent. In the following, the method for producing the polycyclic polyphenolic resin of the present embodiment and the like will be described using the general formula (1A) and the like as an example in some cases, but the following description can be applied to all of the above-described polycyclic polyphenolic resins.

In carrying out such a step, the contents of K. Matsumoto, Y. Shibasaki, S. Ando and M. Ueda, Polymer, 47, 3043 (2006) can be referred to as appropriate. That is, in the oxidative polymerization of the β-naphthol type monomer, the C—C coupling at the α-position is selectively caused by an oxidative coupling reaction in which a radical subjected to one-electron oxidation due to the monomer is coupled, and for example, regioselective polymerization can be performed by using a copper/amine type catalyst.

The oxidizing agent according to the present embodiment is not particularly limited as long as it causes an oxidative coupling reaction, and examples thereof include metal salts containing copper, manganese, iron, cobalt, ruthenium, chromium, nickel, tin, lead, silver, and palladium; peroxides such as hydrogen peroxide or perchloric acids; and organic peroxides. Among these, metal salts or metal complexes containing at least one selected from the group consisting of copper, manganese, iron, cobalt, ruthenium, chromium, nickel, tin, lead, silver, and palladium are preferable, and metal salts or metal complexes containing copper, manganese, iron, or cobalt can be more preferably used.

Metals such as copper, manganese, iron, cobalt, ruthenium, lead, nickel, silver, tin, chromium or palladium can also be used as oxidizing agents by reduction in the reaction system. These are included in metal salts.

For example, an aromatic hydroxy compound represented by the general formula (1A) is dissolved in organic solvents, metal salts containing copper, manganese or cobalt are added thereto, and the mixture is reacted with, for example, oxygen or an oxygen-containing gas to carry out oxidative polymerization, to obtain a desired polycyclic polyphenolic resin.

According to the method for producing a polycyclic polyphenolic resin by oxidative polymerization as described above, it is relatively easy to control the molecular weight, and since a resin having a small molecular weight distribution can be obtained without leaving a raw material monomer or a low molecular component accompanying the increase in the molecular weight, it tends to be advantageous from the viewpoint of high heat resistance and low sublimation.

As the metal salts, halides such as copper, manganese, cobalt, ruthenium, chromium and palladium, carbonates, acetates, nitrates or phosphates can be used.

The metal complex is not particularly limited, and any of known ones can be used. Specific examples thereof include, but are not limited to, complex catalysts containing copper described in Japanese Patent Laid-Open No. 36-18692, Japanese Patent Laid-Open No. 40-13423, Japanese Patent Laid-Open No. 49-490; complex catalysts containing manganese described in Japanese Patent Laid-Open No. 40-30354, Japanese Patent Laid-Open No. 47-5111, Japanese Patent Laid-Open No. 56-32523, Japanese Patent Laid-Open No. 57-44625, Japanese Patent Laid-Open No. 58-19329, Japanese Patent Laid-Open No. 60-83185; and complex catalysts containing cobalt described in Japanese Patent Laid-Open No. 45-23555.

Examples of organic peroxides include, but are not limited to, t-butyl hydroperoxide, di-t-butyl peroxide, cumene hydroperoxide, dicumyl peroxide, peracetic acid, and perbenzoic acid.

The oxidizing agents can be used alone or can be used in combination. The use amount thereof is not particularly limited, but is preferably 0.002 mol to 10 mol, more preferably 0.003 mol to 3 mol, and still more preferably 0.005 mol to 0.3 mol, based on 1 mol of the aromatic hydroxy compound. That is, the oxidizing agent according to the present embodiment can be used at a low concentration with respect to the monomer.

In the present embodiment, it is preferable to use a base in addition to the oxidizing agent used in the step of oxidative polymerization. The base is not particularly limited, and any of known bases can be used, and specific examples thereof include inorganic bases such as alkali metal hydroxides, alkaline earth metal hydroxides, and alkali metal alkoxides, and organic bases such as primary to tertiary monoamine compounds and diamines. These can be used alone, or can be used in combination.

The oxidation method is not particularly limited, and there is a method of directly using oxygen gas or air, but air oxidation is preferable from the viewpoint of safety and cost. In the case of oxidation using air under atmospheric pressure, a method of introducing air by bubbling into a liquid in a reaction solvent is preferable from the viewpoint of improving the rate of oxidative polymerization and increasing the molecular weight of the resin.

Further, the oxidizing reaction of the present embodiment can also be a reaction under pressurized conditions, and 2 kg/cm² to 15 kg/cm² are preferable from the viewpoint of accelerating reaction, and 3 kg/cm² to 10 kg/cm² are still more preferable from the viewpoint of safety and controllability.

In the present embodiment, the oxidation reaction of the aromatic hydroxy compound can be performed even in the absence of a reaction solvent, but it is generally preferable to perform the reaction in the presence of a solvent. As the solvent, as long as there is no problem in obtaining the polycyclic polyphenolic resin of the present embodiment, various known solvents can be used as long as it dissolve the catalyst to some extent. Generally, alcohols such as methanol, ethanol, propanol, and butanol; ethers such as dioxane, tetrahydrofuran, or ethylene glycol dimethyl ether; solvents such as amides or nitriles; ketones such as acetone, methyl ethyl ketone, methyl isobutyl ketone, cyclohexanone, and cyclopentanone; or mixtures thereof with water are used. Further, the reaction can also be carried out with hydrocarbons such as benzene, toluene or hexane which are not immiscible with water or in a two phase system of those and water.

The reaction conditions may be appropriately adjusted according to the substrate concentration, the type and concentration of the oxidizing agent, but the reaction temperature can be set to a relatively low temperature, preferably 5 to 150° C., and more preferably 20 to 120° C. The reaction time is preferably from 30 minutes to 72 hours, more preferably from 1 hour to 48 hours. The stirring method during the reaction is not particularly limited, and may be any of shaking and stirring using a rotator or a stirring blade. This step may be carried out in a solvent or in an air stream as long as the stirring conditions satisfy the above conditions.

The polycyclic polyphenolic resin of the present embodiment is preferably obtained as a crude product by the above oxidation reaction, and then further purified to remove the residual oxidizing agent. That is, from the viewpoint of prevention of degradation of the resin over time and storage stability, it is preferable to avoid residues of metal salts or metal complexes containing copper, manganese, iron, or cobalt mainly used as metal oxidizing agents derived from the oxidizing agent.

The residual amount of metals derived from the oxidizing agent is preferably less than 10 ppm, more preferably less than 1 ppm, and still more preferably less than 500 ppb for each metal species. When the residual amount is less than 10 ppm, there is a tendency that it is possible to prevent a decrease in solubility of the resins in the solutions due to degradation of the resins, and there is a tendency that it is possible to prevent an increase in haze of the solutions. On the other hand, when the residual amount is less than 500 ppb, there is a tendency that the composition can be used without impairing storage stability even in the form of solutions. Therefore, in the present embodiment, for example, when the polycyclic polyphenolic resins are used in the composition as described below, the content of impurity metals is particularly preferably less than 500 ppb for each metal species, and still more preferably 1 ppb or less. Examples of the impurity metal include, but are not particularly limited to, at least one selected from the group consisting of copper, manganese, iron, cobalt, ruthenium, chromium, nickel, tin, lead, silver, and palladium.

Examples of the purification method include, but are not particularly limited to, the steps of: obtaining a solution (S) by dissolving the polycyclic polyphenolic resin in a solvent; and extracting impurities in the resin by bringing the obtained solution (S) into contact with an acidic aqueous solution (a first extraction step), wherein the solvent used in the step of obtaining the solution (S) contains an organic solvent that does not inadvertently mix with water.

According to the purification method, the contents of various metals that may be contained as impurities in the resin can be reduced.

More specifically, the resin is dissolved in an organic solvent that does not inadvertently mix with water to obtain the solution (S), and further, extraction treatment can be performed by bringing the solution (S) into contact with an acidic aqueous solution. Thereby, metal components contained in the solution (S) are transferred to the aqueous phase, then the organic phase and the aqueous phase are separated, and thus the resin having a reduced metal content can be obtained.

The solvent that does not inadvertently mix with water used in the purification method is not particularly limited, but is preferably an organic solvent that is safely applicable to semiconductor production processes, and specifically it is an organic solvent having a solubility in water at room temperature of less than 30%, and more preferably is an organic solvent having a solubility of less than 20% and particularly preferably less than 10%. The amount of the organic solvent used is preferably 1 to 100 times the total mass of the resin to be used.

Specific examples of the solvent that does not inadvertently mix with water include, but are not limited to, ethers such as diethyl ether and diisopropyl ether, esters such as ethyl acetate, n-butyl acetate, and isoamyl acetate; ketones such as methyl ethyl ketone, methyl isobutyl ketone, ethyl isobutyl ketone, cyclohexanone, cyclopentanone, 2-heptanone, and 2-pentanone; glycol ether acetates such as ethylene glycol monoethyl ether acetate, ethylene glycol monobutyl ether acetate, propylene glycol monomethyl ether acetate (PGMEA), and propylene glycol monoethyl ether acetate; aliphatic hydrocarbons such as n-hexane and n-heptane; aromatic hydrocarbons such as toluene and xylene; and halogenated hydrocarbons such as methylene chloride and chloroform. Among these, toluene, 2-heptanone, cyclohexanone, cyclopentanone, methyl isobutyl ketone, propylene glycol monomethyl ether acetate, ethyl acetate, and the like are preferable, methyl isobutyl ketone, ethyl acetate, cyclohexanone, and propylene glycol monomethyl ether acetate are more preferable, and methyl isobutyl ketone and ethyl acetate are still more preferable. Methyl isobutyl ketone, ethyl acetate, and the like have relatively high saturation solubility for the polycyclic polyphenolic resin and a relatively low boiling point, and it is thus possible to reduce the load in the case of industrially distilling off the solvent and in the step of removing the solvent by drying. These solvents can be each used alone, or can also be used as a mixture of two or more kinds.

The acidic aqueous solution used in the purification method is appropriately selected from aqueous solutions in which organic compounds or inorganic compounds are dissolved in water, generally known as acidic aqueous solutions. Examples of the acidic aqueous solution include, but are not limited to, aqueous solutions of mineral acid in which mineral acids such as hydrochloric acid, sulfuric acid, nitric acid, and phosphoric acid are dissolved in water, or aqueous solutions of organic acid in which organic acids such as acetic acid, propionic acid, oxalic acid, malonic acid, succinic acid, fumaric acid, maleic acid, tartaric acid, citric acid, methanesulfonic acid, phenolsulfonic acid, p-toluenesulfonic acid, and trifluoroacetic acid are dissolved in water. These acidic aqueous solutions can be each used alone, and can be also used as a combination of two or more kinds. Among these acidic aqueous solutions, aqueous solutions of one or more mineral acids selected from the group consisting of hydrochloric acid, sulfuric acid, nitric acid and phosphoric acid, or aqueous solutions of one or more organic acids selected from the group consisting of acetic acid, propionic acid, oxalic acid, malonic acid, succinic acid, fumaric acid, maleic acid, tartaric acid, citric acid, methanesulfonic acid, phenolsulfonic acid, p-toluenesulfonic acid and trifluoroacetic acid are preferable, aqueous solutions of sulfuric acid, nitric acid, and carboxylic acids such as acetic acid, oxalic acid, tartaric acid and citric acid are more preferable, aqueous solutions of sulfuric acid, oxalic acid, tartaric acid and citric acid are still more preferable, and an aqueous solution of oxalic acid is even more preferable. It is considered that polyvalent carboxylic acids such as oxalic acid, tartaric acid and citric acid coordinate with metal ions and provide a chelating effect, and thus tend to be capable of more effectively removing metals. Also, as for water used herein, it is preferable to use water, the metal content of which is small, such as ion exchanged water, according to the purpose of the purification method according to the present embodiment.

The pH of the acidic aqueous solution used in the purification method is not particularly limited, but it is preferable to regulate the acidity of the aqueous solution in consideration of an influence on the resin. Normally, the pH range is about 0 to 5, and is preferably about pH 0 to 3.

The use amount of the acidic aqueous solution used in the purification method is not particularly limited, but it is preferable to regulate the use amount from the viewpoint of reducing the number of extraction operations for removing metals and from the viewpoint of ensuring operability in consideration of the overall amount of fluid. From the above viewpoints, the amount of the acidic aqueous solution to be used is preferably 10 to 200% by mass, and more preferably 20 to 100% by mass, based on 100% by mass of the solution (S).

In the purification method, by bringing the acidic aqueous solution into contact with the solution (S), metal components can be extracted from the resin in the solution (S).

In the purification method, the solution (S) may further contain an organic solvent that inadvertently mixes with water. When the solution (S) contains an organic solvent that inadvertently mixes with water, there is a tendency that the amount of the resin to be charged can be increased, also the fluid separability is improved, and purification can be performed at a high reaction vessel efficiency. The method for adding the organic solvent that inadvertently mixes with water is not particularly limited. For example, any of a method involving adding it to the organic solvent-containing solution in advance, a method involving adding it to water or the acidic aqueous solution in advance, and a method involving adding it after bringing the organic solvent-containing solution into contact with water or the acidic aqueous solution may be employed. Among these, the method involving adding it to the organic solvent-containing solution in advance is preferable in terms of the workability of operations and the ease of managing the amount to be charged.

The organic solvent that inadvertently mixes with water used in the purification method is not particularly limited, but is preferably an organic solvent that is safely applicable to semiconductor production processes. The amount of the organic solvent used that inadvertently mixes with water is not particularly limited as long as the solution phase and the aqueous phase separate, but is preferably 0.1 to 100 times, more preferably 0.1 to 50 times, and still more preferably 0.1 to 20 times the total mass of the resin to be used.

Specific examples of the organic solvent used in the purification method that inadvertently mixes with water include, but are not limited to, ethers such as tetrahydrofuran and 1,3-dioxolane; alcohols such as methanol, ethanol, and isopropanol; ketones such as acetone and N-methylpyrrolidone; aliphatic hydrocarbons such as glycol ethers such as ethylene glycol monoethyl ether, ethylene glycol monobutyl ether, propylene glycol monomethyl ether (PGME), and propylene glycol monoethyl ether. Among these, N-methylpyrrolidone, propylene glycol monomethyl ether and the like are preferable, and N-methylpyrrolidone and propylene glycol monomethyl ether are more preferable. These solvents can be each used alone, or can also be used as a mixture of two or more kinds.

The temperature when extraction treatment is performed is usually in the range of 20 to 90° C., and preferably 30 to 80° C. The extraction operation is performed, for example, by thoroughly mixing by stirring or the like and then leaving the obtained mixed solution to stand still. Thereby, metal components contained in the solution (S) are transferred to the aqueous phase. Also, by this operation, the acidity of the solution is lowered, and the degradation of the resin can be suppressed.

By being left to stand still, the mixed solution is separated into a solution phase containing the resin and the solvents and an aqueous phase, and thus the solution phase is recovered by decantation and the like. The time for leaving the mixed solution to stand still is not particularly limited, but it is preferable to regulate the time for leaving the mixed solution to stand still from the viewpoint of attaining good separation of the solution phase containing the solvents and the aqueous phase. Normally, the time for leaving the mixed solution to stand still is 1 minute or longer, preferably 10 minutes or longer, and still more preferably 30 minutes or longer. While the extraction treatment may be carried out only once, it is also effective to repeat mixing, leaving-to-stand-still, and separating operations multiple times.

It is preferable that the purification method includes the step of extracting impurities in the resin by further bringing the solution phase containing the resin into contact with water after the first extraction step (the second extraction step). Specifically, for example, it is preferable that after the above extraction treatment is performed using an acidic aqueous solution, the solution phase that is extracted and recovered from the aqueous solution and that contains the recovered resin and the solvents is further subjected to extraction treatment with water. The extraction treatment with water is not particularly limited, and can be carried out by, for example, thoroughly mixing the solution phase and water by stirring or the like and then leaving the obtained mixed solution to stand still. The mixed solution after being left to stand still is separated into a solution phase containing the resin and the solvents and an aqueous phase, and thus the solution phase can be recovered by decantation and the like.

Water used herein is preferably water, the metal content of which is small, such as ion exchanged water, according to the purpose of the present embodiment. While the extraction treatment may be performed once, it is effective to repeat mixing, leaving-to-stand-still, and separating operations multiple times. In addition, the proportions of both used in the extraction treatment, and temperature, time and other conditions are not particularly limited, and may be the same as those of the previous contact treatment with the acidic aqueous solution.

Water that is possibly present in the thus-obtained solution containing the resin and the solvents can be easily removed by performing vacuum distillation operation or the like. Also, if required, the concentration of the resin can be regulated to be any concentration by adding a solvent to the solution.

The method for purifying the polycyclic polyphenolic resin according to the present embodiment can also be performed by passing a solution obtained by dissolving the resin in a solvent through a filter. According to the method for purifying the substance according to the present embodiment, the content of various metal components in the resin can be effectively and significantly reduced. The amounts of these metal components can be measured by the method described in Examples below.

Herein, the term “passed through” of the present embodiment means that the above-described solution is passed from the outside of the filter through the inside of the filter and is allowed to move out of the filter again. For example, an aspect in which the solution is simply brought into contact with the surface of the filter and an aspect in which the solution is brought into contact on the surface while being allowed to move outside an ion-exchange resin (that is, an aspect in which the solution is simply brought into contact) are excluded.

### [Filter Purification Step (Liquid Passing Step)]

In the step of passing a liquid through a filter according to the present embodiment, a filter commercially available for liquid filtration can usually be used as the filter used for removing the metal component in the solution containing the resin and the solvent. The filtration accuracy of the filter is not particularly limited, but the nominal pore size of the filter is preferably 0.2 μm or less, more preferably less than 0.2 μm, still more preferably 0.1 μm or less, even more preferably less than 0.1 μm, and still further preferably 0.05 μm or less. The lower limit of the nominal pore size of the filter is not particularly limited, but is usually 0.005 μm. As used herein, the term “nominal pore size” refers to the pore size nominally used to indicate the separation performance of the filter, which is determined, for example, by any method specified by the filter manufacturer, such as a bubble point test, a mercury intrusion test or a standard particle trapping test. When using a commercially available product, the nominal pore size is a value described in the manufacturer's catalog data. The nominal pore size of 0.2 μm or less makes it possible to effectively reduce the contents of the metal components after passing the solution through the filter once. In the present embodiment, the step of passing through the filter may be performed twice or more to reduce the more content of each metal component in the solution.

Forms of the filter to be used can include a hollow fiber membrane filter, a membrane filter, a pleated membrane filter, and a filter filled with a filter medium such as a non-woven fabric, cellulose or diatomaceous earth. Among the above, the filter is preferably one or more selected from the group consisting of a hollow fiber membrane filter, a membrane filter and a pleated membrane filter. Further, it is particularly preferable to use a hollow fiber membrane filter, in particular due to its high precision filtration accuracy and its higher filtration area than other forms.

Examples of a material for the filter can include a polyolefin such as polyethylene and polypropylene; a polyethylene-based resin having a functional group having an ion exchange capacity provided by graft polymerization; a polar group-containing resin such as polyamide, polyester and polyacrylonitrile; and a fluorine-containing resin such as fluorinated polyethylene (PTFE). Among the above, the filter is preferably made of one or more filter media selected from the group consisting of a polyamide, a polyolefin resin and a fluororesin. Further, a polyamide medium is particularly preferable from the viewpoint of the reduction effect of heavy metals such as chromium. From the viewpoint of avoiding metal elution from the filter medium, it is preferable to use a filter other than the sintered metal material.

Examples of the polyamide-based filter can include (hereinafter described under the trade name), but are not limited to: Polyfix nylon series manufactured by KITZ MICROFILTER CORPORATION; Ultipleat P-Nylon 66 and Ultipor N66 manufactured by Nihon Pall Ltd.; and LifeASSURE PSN series and LifeASSURE EF series manufactured by 3M Company.

Examples of polyolefin-based filter can include, but are not limited to: Ultipleat PE Clean and Ion Clean manufactured by Nihon Pall Ltd.; Protego series, Microgard Plus HC10 and Optimizer D manufactured by Entegris Japan Co., Ltd.

Examples of the polyester-based filter can include, but are not limited to: Geraflow DFE manufactured by Central Filter Mfg. Co., Ltd.; and a pleated type PMC manufactured by Nihon Filter Co., Ltd.

Examples of the polyacrylonitrile-based filter can include, but are not limited to: Ultrafilters AIP-0013D, ACP-0013D and ACP-0053D manufactured by Advantec Toyo Kaisha, Ltd.

Examples of the fluororesin-based filter can include, but are not limited to: Emflon HTPFR manufactured by Nihon Pall Ltd.; and LifeASSURE FA series manufactured by 3M Company.

These filters can be used alone or can be used in combination of two or more thereof.

The filter may also contain an ion exchanger such as a cation-exchange resin, or a cation charge controlling agent and the like that causes a zeta potential in an organic solvent solution to be filtered.

Examples of the filter containing an ion exchanger can include, but are not limited to: Protego series manufactured by Entegris Japan Co., Ltd.; and KURANGRAFT manufactured by Kurashiki Textile Manufacturing Co., Ltd.

Examples of the filter containing a material having a positive zeta potential such as a cationic polyamidepolyamine-epichlorohydrin resin include (hereinafter described under the trade name), but are not limited to: Zeta Plus 40QSH and Zeta Plus 020GN and LifeASSURE EF series manufactured by 3M company.

The method for isolating the resin from the obtained solution containing the resin and the solvents is not particularly limited, and publicly known methods can be performed, such as reduced-pressure removal, separation by reprecipitation, and a combination thereof. Publicly known treatments such as concentration operation, filtration operation, centrifugation operation, and drying operation can be performed if required.

The polycyclic polyphenolic resin of the present embodiment may further have a modified portion derived from a crosslinking compound. That is, the polycyclic polyphenolic resin of the present embodiment having the structure described above may have a modified portion obtained by reaction with the crosslinking compound. Such a (modified) polycyclic polyphenolic resin is also excellent in heat resistance and etching resistance, and can be used as a coating agent for semiconductors, a material for resists, and a semiconductor underlayer film forming material.

Examples of the crosslinking compound include, but are not limited to, aldehydes, ketones, carboxylic acids, carboxylic acid halides, a halogen containing compound, an amino compound, an imino compound, an isocyanate compound, and an unsaturated hydrocarbon group containing compound. These can be used alone or in combination as appropriate.

In the present embodiment, the crosslinking compound is preferably an aldehyde or a ketone. More specifically, it is preferably a polycyclic polyphenolic resin obtained by subjecting the polycyclic polyphenolic resin of the present embodiment having the structure described above to a polycondensation reaction with an aldehyde or a ketone in the presence of a catalyst. For example, a polycyclic polyphenolic resin can be obtained by subjecting an aldehyde or a ketone corresponding to a desired structure to a further polycondensation reaction under normal pressure and optionally pressurized conditions under a catalyst.

Examples of the aldehyde include, but are not particularly limited to, methylbenzaldehyde, dimethylbenzaldehyde, trimethylbenzaldehyde, ethylbenzaldehyde, propylbenzaldehyde, butylbenzaldehyde, pentabenzaldehyde, butylmethylbenzaldehyde, hydroxybenzaldehyde, dihydroxybenzaldehyde, and fluoromethylbenzaldehyde. These aldehydes can be used alone as one kind or can be used in combination of two or more kinds. Among them, methylbenzaldehyde, dimethylbenzaldehyde, trimethylbenzaldehyde, ethylbenzaldehyde, propylbenzaldehyde, butylbenzaldehyde, pentabenzaldehyde, butylmethylbenzaldehyde, or the like is preferably used from the viewpoint of imparting high heat resistance.

Examples of the ketone include, but are not particularly limited to, acetylmethylbenzene, acetyldimethylbenzene, acetyltrimethylbenzene, acetylethylbenzene, acetylpropylbenzene, acetylbutylbenzene, acetylpentabenzene, acetylbutylmethylbenzene, acetylhydroxybenzene, acetyldihydroxybenzene, and acetylfluoromethylbenzene. These ketones can be used alone as one kind or can be used in combination of two or more kinds. Among them, acetylmethylbenzene, acetyldimethylbenzene, acetyltrimethylbenzene, acetylethylbenzene, acetylpropylbenzene, acetylbutylbenzene, acetylpentabenzene, or acetylbutylmethylbenzene is preferably used from the viewpoint of imparting high heat resistance.

The acid catalyst used in the above reaction can be appropriately selected for use from publicly known catalysts and is not particularly limited. As the catalyst, an acid catalyst or a base catalyst is preferably used. In order to selectively obtain the objective product in a high yield, a base catalyst is preferred.

Inorganic acids and organic acids are widely known as such acid catalysts. Specific examples of the above acid catalyst include, but are not particularly limited to, inorganic acids such as hydrochloric acid, sulfuric acid, phosphoric acid, hydrobromic acid, and hydrofluoric acid; organic acids such as oxalic acid, malonic acid, succinic acid, adipic acid, sebacic acid, citric acid, fumaric acid, maleic acid, formic acid, p-toluenesulfonic acid, methanesulfonic acid, trifluoroacetic acid, dichloroacetic acid, trichloroacetic acid, trifluoromethanesulfonic acid, benzenesulfonic acid, naphthalenesulfonic acid, and naphthalenedisulfonic acid; Lewis acids such as zinc chloride, aluminum chloride, iron chloride, and boron trifluoride; and solid acids such as tungstosilicic acid, tungstophosphoric acid, silicomolybdic acid, and phosphomolybdic acid. Among them, organic acids and solid acids are preferable from the viewpoint of production, and hydrochloric acid or sulfuric acid is preferably used from the viewpoint of production such as easy availability and handleability.

Among such basic catalysts, examples of amine-containing catalysts are pyridine and ethylenediamine; examples of non-amine basic catalysts are metal salts and especially potassium salts or acetates; suitable catalysts include, but are not limited to, potassium acetate, potassium carbonate, potassium hydroxide, sodium acetate, sodium carbonate, sodium hydroxide and magnesium oxide.

All of the non-amine base catalysts in the present embodiment are commercially available, for example, from EM Science or Aldrich.

The catalysts can be used alone as one kind or can be used in combination of two or more kinds. Further, the amount of the catalyst used can be appropriately set according to, the kind of the raw materials used and the catalyst used and moreover the reaction conditions and is not particularly limited, but is preferably 0.001 to 100 parts by mass based on 100 parts by mass of the reaction raw materials.

Upon the reaction, a reaction solvent may be used. The reaction solvent is not particularly limited as long as the reaction of the aldehyde or the ketone used with the polycyclic polyphenolic resin proceeds, and can be appropriately selected and used from publicly known solvents. Examples thereof include water, methanol, ethanol, propanol, butanol, tetrahydrofuran, dioxane, ethylene glycol dimethyl ether, ethylene glycol diethyl ether, and a mixed solvent thereof. The solvents can be used alone as one kind, or can be used in combination of two or more kinds. Also, the amount of these solvents used can be appropriately set according to the kind of the raw materials used and the acid catalyst used and moreover the reaction conditions. The amount of the solvent used is not particularly limited, but is preferably in the range of 0 to 2000 parts by mass based on 100 parts by mass of the reaction raw materials. Furthermore, the reaction temperature in the reaction can be appropriately selected according to the reactivity of the reaction raw materials. The reaction temperature is not particularly limited, but is usually preferably within the range of 10 to 200° C. The reaction method can be appropriately selected and used from publicly known approaches and is not particularly limited, and there are a method of charging the polycyclic polyphenolic resin of the present embodiment, the aldehyde or the ketone, and the acid catalyst in one portion, and a method of dropping the aldehyde or the ketone in the presence of the acid catalyst. After the polycondensation reaction terminates, isolation of the obtained compound can be performed according to a conventional method, and is not particularly limited. For example, by adopting a commonly used approach in which the temperature of the reaction vessel is elevated to 130 to 230° C. in order to remove unreacted raw materials, acid catalyst, etc. present in the system, and volatile portions are removed at about 1 to 50 mmHg, the compound which is the target compound can be obtained.

### [Composition]

The polycyclic polyphenolic resin of the present embodiment can be used as a composition assuming the various applications. That is, the composition of the present embodiment contains the polycyclic polyphenolic resin of the present embodiment. The composition of the present embodiment preferably further contains a solvent from the viewpoint of facilitating film formation by the application of a wet process, or the like.

Specific examples of the solvent include, but not particularly limited to: ketone-based solvents such as acetone, methyl ethyl ketone, methyl isobutyl ketone, and cyclohexanone; cellosolve-based solvents such as propylene glycol monomethyl ether and propylene glycol monomethyl ether acetate; ester-based solvents such as ethyl lactate, methyl acetate, ethyl acetate, butyl acetate, isoamyl acetate, methyl methoxypropionate, and methyl hydroxyisobutyrate; alcohol-based solvents such as methanol, ethanol, isopropanol, and 1-ethoxy-2-propanol; and aromatic hydrocarbons such as toluene, xylene, and anisole. These solvents can be used alone as one kind, or can be used in combination of two or more kinds.

Among the solvents, propylene glycol monomethyl ether, propylene glycol monomethyl ether acetate, cyclohexanone, cyclopentanone, ethyl lactate, and methyl hydroxyisobutyrate is particularly preferable from the viewpoint of safety.

The content of the solvent is not particularly limited and is preferably 100 to 10,000 parts by mass based on 100 parts by mass of the polycyclic polyphenolic resin of the present embodiment, more preferably 200 to 5,000 parts by mass, and still more preferably 200 to 1,000 parts by mass, from the viewpoint of solubility and film formation.

As described above, in the composition of the present embodiment, the content of impurity metals is preferably less than 500 ppb for each metal species, and more preferably 1 ppb or less. Examples of the impurity metal include, but are not particularly limited to, at least one selected from the group consisting of copper, manganese, iron, cobalt, ruthenium, chromium, nickel, tin, lead, silver, and palladium.

### [Composition for Film Formation]

A composition for film formation of the present embodiment contains a polycyclic polyphenolic resin. The polycyclic polyphenolic resin of the present embodiment is a polycyclic polyphenolic resin having repeating units derived from at least one monomer selected from the group consisting of aromatic hydroxy compounds described above, wherein the repeating units are linked to each other by a direct bonding between aromatic rings. Since the composition for film formation of the present embodiment is configured as described above, it can exhibit excellent heat resistance and etching resistance.

The “film” as used herein refers to a film that can be applied to, for example, a film for lithography, an optical component, and the like (but not limited thereto), and the size and shape thereof are not particularly limited, and typically, the film has a general form as a film for lithography or an optical component. That is, the “composition for film formation” refers to a precursor of such a film, and is clearly distinguished from the “film” in its form and/or composition. Further, the “film for lithography” is a concept that broadly includes a film for lithography applications such as a permanent film for resist and an underlayer film for lithography.

### [Application of Composition for Film Formation]

The composition for film formation of the present embodiment contains the above polycyclic polyphenolic resin, but may have various compositions depending on the specific application thereof, and hereinafter, the composition for film formation may be referred to as a “resist composition”, a “radiation-sensitive composition”, or a “composition for underlayer film formation for lithography” depending on the application or composition thereof.

### [Resist Composition]

A resist composition of the present embodiment comprises the composition for film formation of the present embodiment. That is, the resist composition of the present embodiment contains the polycyclic polyphenolic resin of the present embodiment as an essential component, and may further contain any of various optional components in consideration of use as a resist material. Specifically, the resist composition of the present embodiment preferably further contains at least one selected from the group consisting of a solvent, an acid generating agent, and an acid diffusion controlling agent.

### (Solvent)

Further, the solvent that the resist composition of the present embodiment may contain is not particularly limited, and any of various known organic solvents can be used. For example, those described in International Publication No. WO 2013/024778 can be used. These solvents can be used alone or can be used in combination of two or more kinds.

The solvent used in the present embodiment is preferably a safe solvent, more preferably at least one selected from propylene glycol monomethyl ether acetate (PGMEA), propylene glycol monomethyl ether (PGME), cyclohexanone (CHN), cyclopentanone (CPN), 2-heptanone, anisole, butyl acetate, ethyl propionate, and ethyl lactate, and still more preferably at least one selected from PGMEA, PGME, and CHN.

The amount of the solid component (component other than the solvent in the resist composition of the present embodiment) and the amount of the solvent in the present embodiment is not particularly limited, but preferably the solid component is 1 to 80% by mass and the solvent is 20 to 99% by mass, more preferably the solid component is 1 to 50% by mass and the solvent is 50 to 99% by mass, still more preferably the solid component is 2 to 40% by mass and the solvent is 60 to 98% by mass, and particularly preferably the solid component is 2 to 10% by mass and the solvent is 90 to 98% by mass, based on 100% by mass of the total mass of the amount of the solid component and the solvent.

### (Acid Generating Agent (C))

The resist composition of the present embodiment preferably contains one or more acid generating agents (C) generating an acid directly or indirectly by irradiation of any radiation selected from visible light, ultraviolet, excimer laser, electron beam, extreme ultraviolet (EUV), X-ray, and ion beam. The acid generating agent (C) is not particularly limited, and, for example, an acid generating agent described in International Publication No. WO 2013/024778 can be used. The acid generating agent (C) can be used alone or can be used in combination of two or more kinds.

The amount of the acid generating agent (C) used is preferably 0.001 to 49% by mass of the total mass of the solid component, more preferably 1 to 40% by mass, still more preferably 3 to 30% by mass, and particularly preferably 10 to 25% by mass. By using the acid generating agent (C) within the above range, a pattern profile with high sensitivity and low edge roughness is obtained. In the present embodiment, the acid generation method is not limited as long as an acid is generated in the system. By using excimer laser instead of ultraviolet such as g-ray and i-ray, finer processing is possible, and also by using electron beam, extreme ultraviolet, X-ray or ion beam as a high energy ray, further finer processing is possible.

### (Acid Crosslinking Agent (G))

The resist composition in the present embodiment may contain one or more acid crosslinking agents (G). The acid crosslinking agent (G) is a compound capable of intramolecularly or intermolecularly crosslinking the polycyclic polyphenolic resin of the present embodiment (hereinafter, may be referred to as component (A) in the presence of an acid generated from the acid generating agent (C). Examples of such an acid crosslinking agent (G) can include a compound having one or more groups (hereinafter, referred to as a “crosslinkable group”) capable of crosslinking the component (A).

Examples of such a crosslinkable group can include, but are not particularly limited to, (i) a hydroxyalkyl group such as a hydroxy (C1-C6 alkyl group), a C1-C6 alkoxy (C1-C6 alkyl group), and an acetoxy (C1-C6 alkyl group), or a group derived therefrom; (ii) a carbonyl group such as a formyl group and a carboxy (C1-C6 alkyl group), or a group derived therefrom; (iii) a nitrogenous group-containing group such as a dimethylaminomethyl group, a diethylaminomethyl group, a dimethylolaminomethyl group, a diethylolaminomethyl group, and a morpholinomethyl group; (iv) a glycidyl group-containing group such as a glycidyl ether group, a glycidyl ester group, and a glycidylamino group; (v) a group derived from an aromatic group such as a C1-C6 allyloxy (C1-C6 alkyl group) and a C1-C6 aralkyloxy (C1-C6 alkyl group) such as a benzyloxymethyl group and a benzoyloxymethyl group; and (vi) a polymerizable multiple bond-containing group such as a vinyl group and an isopropenyl group. As the crosslinkable group of the acid crosslinking agent (G) according to the present embodiment, a hydroxyalkyl group and an alkoxyalkyl group or the like are preferable, and an alkoxymethyl group is particularly preferable.

The acid crosslinking agent (G) having the crosslinkable group is not particularly limited, and, for example, an acid crosslinking agent described in International Publication No. WO 2013/024778 can be used. The acid crosslinking agent (G) can be used alone or can be used in combination of two or more kinds.

In the present embodiment, the amount of the acid crosslinking agent (G) used is preferably 0.5 to 49% by mass of the total mass of the solid components, more preferably 0.5 to 40% by mass, still more preferably 1 to 30% by mass, and particularly preferably 2 to 20% by mass. When the content ratio of the acid crosslinking agent (G) is 0.5% by mass or more, the inhibiting effect of the solubility of a resist film in an alkaline developing solution is improved, and a decrease in the film remaining rate, and occurrence of swelling and meandering of a pattern can be inhibited, which is preferable. On the other hand, when the content ratio is 50% by mass or less, a decrease in heat resistance as a resist can be inhibited, which is preferable.

### (Acid Diffusion Controlling Agent (E))

In the present embodiment, the resist composition may contain an acid diffusion controlling agent (E) having a function of controlling diffusion of an acid generated from an acid generating agent by radiation irradiation in a resist film to inhibit any unpreferable chemical reaction in an unexposed region or the like. By using such an acid diffusion controlling agent (E), the storage stability of a resist composition is improved. Also, along with the improvement of the resolution, the line width change of a resist pattern due to variation in the post exposure delay time before radiation irradiation and the post exposure delay time after radiation irradiation can be inhibited, and the composition has extremely excellent process stability. Such an acid diffusion controlling agent (E) is not particularly limited, and examples thereof include a radiation degradable basic compound such as a nitrogen atom-containing basic compound, a basic sulfonium compound, and a basic iodonium compound.

The acid diffusion controlling agent (E) is not particularly limited, and, for example, an acid diffusion controlling agent described in International Publication No. WO 2013/024778 can be used. The acid diffusion controlling agent (E) can be used alone or can be used in combination of two or more kinds.

The content of the acid diffusion controlling agent (E) is preferably 0.001 to 49% by mass of the total mass of the solid component, more preferably 0.01 to 10% by mass, still more preferably 0.01 to 5% by mass, and particularly preferably 0.01 to 3% by mass. Within the above range, a decrease in resolution, and deterioration of the pattern shape and the dimension fidelity or the like can be prevented. Moreover, even though the post exposure delay time from electron beam irradiation to heating after radiation irradiation becomes longer, the shape of the pattern upper layer portion does not deteriorate. When the content is 10% by mass or less, a decrease in sensitivity, and developability of the unexposed portion or the like can be prevented. Also, by using such an acid diffusion controlling agent, the storage stability of a resist composition is improved, also along with improvement of the resolution, the line width change of a resist pattern due to variation in the post exposure delay time before radiation irradiation and the post exposure delay time after radiation irradiation can be inhibited, making the composition extremely excellent in process stability.

### (Further Component (F))

To the resist composition of the present embodiment, if required, as the further component (F), one kind or two or more kinds of various additive agents such as a dissolution promoting agent, a dissolution controlling agent, a sensitizing agent, a surfactant, and an organic carboxylic acid or an oxo acid of phosphorus or derivative thereof can be added.

### (Dissolution Promoting Agent)

A low molecular weight dissolution promoting agent is a component having a function of increasing the solubility of the polycyclic polyphenolic resin of the present embodiment in a developing solution to moderately increase the dissolution rate of the compound upon developing, when the solubility of the compound is too low. The low molecular weight dissolution promoting agent can be used, if required. Examples of the dissolution promoting agent can include a low molecular weight phenolic compound, such as a bisphenol and tris (hydroxyphenyl)methane. These dissolution promoting agents can be used alone, or can be used as a mixture of two or more kinds.

The content of the dissolution promoting agent, which is appropriately adjusted according to the kind of the compound to be used, is preferably 0 to 49% by mass of the total mass of the solid component, more preferably 0 to 5% by mass, still more preferably 0 to 1% by mass, and particularly preferably 0% by mass.

### (Dissolution Controlling Agent)

The dissolution controlling agent is a component having a function of controlling the solubility of the polycyclic polyphenolic resin of the present embodiment in a developing solution to moderately decrease the dissolution rate upon developing, when the solubility of the resin is too high. As such a dissolution controlling agent, the one which does not chemically change in steps such as calcination of resist coating, radiation irradiation, and development is preferable.

The dissolution controlling agent is not particularly limited, and examples thereof can include an aromatic hydrocarbon such as phenanthrene, anthracene and acenaphthene; a ketone such as acetophenone, benzophenone and phenyl naphthyl ketone; and a sulfone such as methyl phenyl sulfone, diphenyl sulfone and dinaphthyl sulfone. These dissolution controlling agents can be used alone or can be used in combination of two or more kinds.

The content of the dissolution controlling agent, which is arbitrarily adjusted according to the kind of the compound to be used, is preferably 0 to 49% by mass of the total mass of the solid component, more preferably 0 to 5% by mass, still more preferably 0 to 1% by mass, and particularly preferably 0% by mass.

### (Sensitizing Agent)

The sensitizing agent is a component having a function of absorbing irradiated radiation energy, transmitting the energy to the acid generating agent (C), and thereby increasing the acid production amount, and improving the apparent sensitivity of a resist. Examples of such a sensitizing agent can include, but are not particularly limited to, a benzophenone, a biacetyl, a pyrene, a phenothiazine and a fluorene. These sensitizing agents can be used alone or can be used in combination of two or more kinds.

The content of the sensitizing agent, which is arbitrarily adjusted according to the kind of the compound to be used, is preferably 0 to 49% by mass of the total mass of the solid component, more preferably 0 to 5% by mass, still more preferably 0 to 1% by mass, and particularly preferably 0% by mass.

### (Surfactant)

The surfactant is a component having a function of improving coatability and striation of the resist composition of the present embodiment, and developability of a resist or the like. Such a surfactant may be any of anionic surfactant, cationic surfactant, nonionic surfactant, and amphoteric surfactant. A preferable surfactant is a nonionic surfactant. The nonionic surfactant has a good affinity with a solvent used in production of resist compositions and more effects. Examples of the nonionic surfactant include, but are not particularly limited to, a polyoxyethylene higher alkyl ether, a polyoxyethylene higher alkyl phenyl ether, and a higher fatty acid diester of polyethylene glycol. Examples of the commercially available product thereof can include, but are not particularly limited to, hereinafter by trade name, EFTOP (manufactured by Jemco Inc.), MEGAFACE (manufactured by DIC Corporation), Fluorad (manufactured by Sumitomo 3M Limited), AsahiGuard, Surflon (hereinbefore, manufactured by Asahi Glass Co., Ltd.), Pepole (manufactured by Toho Chemical Industry Co., Ltd.), KP (manufactured by Shin-Etsu Chemical Co., Ltd.), and Polyflow (manufactured by Kyoeisha Yushi Kagaku Kogyo Co., Ltd.).

The content of the surfactant, which is appropriately adjusted according to the kind of the compound to be used, is preferably 0 to 49% by mass of the total mass of the solid component, more preferably 0 to 5% by mass, still more preferably 0 to 1% by mass, and particularly preferably 0% by mass.

### (Organic Carboxylic Acid or Oxo Acid of Phosphorus or Derivative Thereof)

For the purpose of prevention of sensitivity deterioration or improvement of a resist pattern shape and post exposure delay stability or the like, and as an additional optional component, the composition of the present embodiment can contain an organic carboxylic acid or an oxo acid of phosphorus or derivative thereof. The organic carboxylic acid or the oxo acid of phosphorus or derivative thereof can be used in combination with the acid diffusion controlling agent, or may be used alone. Suitable examples of the organic carboxylic acid include malonic acid, citric acid, malic acid, succinic acid, benzoic acid and salicylic acid. Examples of the oxo acid of phosphorus or derivative thereof include phosphoric acid or derivative thereof such as ester including phosphoric acid, di-n-butyl phosphate and diphenyl phosphate; phosphonic acid or derivative thereof such as ester including phosphonic acid, dimethyl phosphonate, di-n-butyl phosphonate, phenylphosphonic acid, diphenyl phosphonate and dibenzyl phosphonate; and phosphinic acid and derivative thereof such as ester including phosphinic acid and phenylphosphinic acid. Among these, phosphonic acid is particularly preferable.

The organic carboxylic acid or the oxo acid of phosphor or derivative thereof can be used alone or can be used in combination of two or more kinds. The content of the organic carboxylic acid or the oxo acid of phosphor or derivative thereof, which is arbitrarily adjusted according to the kind of the compound to be used, is preferably 0 to 49% by mass of the total mass of the solid component, more preferably 0 to 5% by mass, still more preferably 0 to 1% by mass, and particularly preferably 0% by mass.

(Further Additive Agent Other than Above Additive Agents (Dissolution Promoting Agent, Dissolution Controlling Agent, Sensitizing Agent, Surfactant, and Organic Carboxylic Acid or Oxo Acid of Phosphorus or Derivative Thereof))

Furthermore, the resist composition of the present embodiment can contain one kind or two or more kinds of additive agents other than the dissolution controlling agent, sensitizing agent, surfactant, and organic carboxylic acid or oxo acid of phosphorus or derivative thereof if required. Examples of such an additive agent include a dye, a pigment, and an adhesion aid. For example, when the composition contains the dye or the pigment, a latent image of the exposed portion is visualized and influence of halation upon exposure can be alleviated, which is preferable. In addition, when the composition contains the adhesion aid, adhesiveness to a substrate can be improved, which is preferable. Furthermore, examples of other additive agent can include, but are not particularly limited to, a halation preventing agent, a storage stabilizing agent, a defoaming agent, and a shape improving agent. Specific examples thereof can include 4-hydroxy-4′-methylchalcone.

In the resist composition of the present embodiment, the total content of the optional component (F) is 0 to 99% by mass of the total mass of the solid components, preferably 0 to 49% by mass, more preferably 0 to 10% by mass, still more preferably 0 to 5% by mass, still more preferably 0 to 1% by mass, and particularly preferably 0% by mass.

### [Content Ratio of Each Component in Resist Composition]

In the resist composition of the present embodiment, the content of the polycyclic polyphenolic resin of the present embodiment (the component (A)) is not particularly limited, but is preferably 50 to 99.4% by mass of the total mass of the solid components (summation of the polycyclic polyphenolic resin (A), acid generating agent (C), acid crosslinking agent (G), acid diffusion controlling agent (E), and further component (F) (also referred to as “optional component (F)”), hereinafter the same applies to the resist composition), more preferably 55 to 90% by mass, still more preferably 60 to 80% by mass, and particularly preferably 60 to 70% by mass. In the case of the content, there is a tendency that resolution is further improved and that line edge roughness (LER) is further decreased.

In the resist composition of the present embodiment, the content ratio of the polycyclic polyphenolic resin of the present embodiment (component (A)), the acid generating agent (C), the acid crosslinking agent (G), the acid diffusion controlling agent (E), and the optional component (F) (the component (A)/the acid generating agent (C)/the acid crosslinking agent (G)/the acid diffusion controlling agent (E)/the optional component (F)) is preferably 50 to 99.4% by mass/0.001 to 49% by mass/0.5 to 49% by mass/0.001 to 49% by mass/0 to 49% by mass based on 100% by mass of the solid content of the resist composition, more preferably 55 to 90% by mass/1 to 40% by mass/0.5 to 40% by mass/0.01 to 10% by mass/0 to 5% by mass, still more preferably 60 to 80% by mass/3 to 30% by mass/1 to 30% by mass/0.01 to 5% by mass/0 to 1% by mass, and particularly preferably 60 to 70% by mass/10 to 25% by mass/2 to 20% by mass/0.01 to 3% by mass/0% by mass. The content ratio of each component is selected from each range so that the summation thereof is 100% by mass. Through the above content ratio, there is a tendency that performance such as sensitivity, resolution and developability is excellent. The “solid content” refers to components except for the solvent. “100% by mass of the solid content” refer to 100% by mass of the components except for the solvent.

The resist composition of the present embodiment is usually prepared by dissolving each component in a solvent upon use into a homogeneous solution, and then if required, filtering through a filter or the like with a pore diameter of about 0.2 μm, for example.

The resist composition of the present embodiment can contain an additional resin other than the polycyclic polyphenolic resin of the present embodiment, if required. Examples of the additional resin include, but are not particularly limited to, a novolac resin, a polyvinyl phenol, a polyacrylic acid, a polyvinyl alcohol, a styrene-maleic anhydride resin, and a polymer containing acrylic acid, vinyl alcohol or vinylphenol as a monomeric unit, and derivatives thereof. The content of the additional resin is not particularly limited and is appropriately adjusted according to the kind of the component (A) to be used, and is preferably 30 parts by mass or less based on 100 parts by mass of the component (A), more preferably 10 parts by mass or less, still more preferably 5 parts by mass or less, and particularly preferably 0 parts by mass.

### [Physical Properties and the Like of Resist Composition]

The resist composition of the present embodiment can form an amorphous film by spin coating. Also, the resist composition can be applied to a general semiconductor production process. Any of positive type and negative type resist patterns can be individually prepared depending on the kind of a developing solution to be used.

In the case of a positive type resist pattern, the dissolution rate of the amorphous film formed by spin coating with the resist composition of the present embodiment in a developing solution at 23° C. is preferably 5 angstrom/sec or less, more preferably 0.05 to 5 angstrom/sec, and still more preferably 0.0005 to 5 angstrom/sec. A dissolution rate of 5 angstrom/sec or less results in the fact of being insoluble in a developing solution, which can form a resist. When the amorphous film has a dissolution rate of 0.0005 angstrom/sec or more, the resolution may improve. It is presumed that this is because due to the change in the solubility before and after exposure of the component (A), contrast at the interface between the exposed portion being dissolved in a developing solution and the unexposed portion not being dissolved in a developing solution is increased. Also, there are effects of reducing LER and defects.

In the case of a negative type resist pattern, the dissolution rate of the amorphous film formed by spin coating with the resist composition of the present embodiment in a developing solution at 23° C. is preferably 10 angstrom/sec or more. When the dissolution rate is 10 angstrom/sec or more, the amorphous film more easily dissolves in a developing solution, and is more suitable for a resist. In addition, when the amorphous film has a dissolution rate of 10 angstrom/sec or more, the resolution may be improved. It is presumed that this is because the micro surface portion of the component (A) dissolves, and LER is reduced. Also, there are effects of reducing defects.

The above dissolution rate can be determined by immersing the amorphous film in a developing solution for a predetermined period of time at 23° C. and then measuring the film thickness before and after the immersion by a publicly known method such as visual inspection, ellipsometer, or cross-sectional observation with a scanning electron microscope.

In the case of a positive type resist pattern, the dissolution rate of the portion exposed by radiation such as KrF excimer laser, extreme ultraviolet, electron beam or X-ray, of the amorphous film formed by spin coating with the resist composition of the present embodiment, in a developing solution at 23° C. is preferably 10 angstrom/sec or more. When the dissolution rate is 10 angstrom/sec or more, the above portion more easily dissolves in a developing solution, and the amorphous film is more suitable for a resist. In addition, when the above portion has a dissolution rate of 10 angstrom/sec or more, the resolution may be improved. It is presumed that this is because the micro surface portion of the component (A) dissolves, and LER is reduced. Also, there are effects of reducing defects.

In the case of a negative type resist pattern, the dissolution rate of the portion exposed by radiation such as KrF excimer laser, extreme ultraviolet, electron beam or X-ray, of the amorphous film formed by spin coating with the resist composition of the present embodiment, in a developing solution at 23° C. is preferably 5 angstrom/sec or less, more preferably 0.05 to 5 angstrom/sec, and still more preferably 0.0005 to 5 angstrom/sec. When the dissolution rate is 5 angstrom/sec or less, the above portion is insoluble in a developing solution, and thus the amorphous film can form a resist. When the above portion has a dissolution rate of 0.0005 angstrom/sec or more, the resolution may improve. It is presumed that this is because due to the change in the solubility before and after exposure of the component (A), contrast at the interface between the unexposed portion being dissolved in a developing solution and the exposed portion not being dissolved in a developing solution is increased. Also, there are effects of reducing LER and defects.

### [Radiation-Sensitive Composition]

A radiation-sensitive composition of the present embodiment contains the composition for film formation of the present embodiment, an optically active diazonaphthoquinone compound (B), and a solvent, wherein the content of the solvent is 20 to 99 parts by mass based on 100 parts by mass in total of the radiation-sensitive composition; and the content of components except for the solvent is 1 to 80 parts by mass based on 100 parts by mass in total of the radiation-sensitive composition. That is, the radiation-sensitive composition of the present embodiment contains the polycyclic polyphenolic resin of the present embodiment, the optically active diazonaphthoquinone compound (B), and a solvent as essential components, and may further contain any of various optional components in consideration of being radiation-sensitive.

The radiation-sensitive composition of the present embodiment contains the polycyclic polyphenolic resin of the present embodiment (component (A)) and is used in combination with the optically active diazonaphthoquinone compound (B) and is useful as a base material for positive type resists that becomes a compound easily soluble in a developing solution by irradiation with g-ray, h-ray, i-ray, KrF excimer laser, ArF excimer laser, extreme ultraviolet, electron beam, or X-ray. Although the properties of the component (A) are not largely altered by g-ray, h-ray, i-ray, KrF excimer laser, ArF excimer laser, extreme ultraviolet, electron beam, or X-ray, the optically active diazonaphthoquinone compound (B) poorly soluble in a developing solution is converted to an easily soluble compound so that a resist pattern can be formed in a development step.

As described above, since the component (A) to be contained in the radiation-sensitive composition of the present embodiment is a compound having a relatively low molecular weight, the obtained resist pattern has very small roughness.

The glass transition temperature of the component (A) to be contained in the radiation-sensitive composition of the present embodiment is preferably 100° C. or higher, more preferably 120° C. or higher, still more preferably 140° C. or higher, and particularly preferably 150° C. or higher. The upper limit of the glass transition temperature of the component (A) is not particularly limited and is, for example, 600° C. and may be 400° C. When the glass transition temperature of the component (A) falls within the above range, there is a tendency that the resulting radiation-sensitive composition has heat resistance capable of maintaining a pattern shape in a semiconductor lithography process, and improves performance such as high resolution.

The heat of crystallization determined by the differential scanning calorimetry of the glass transition temperature of the component (A) to be contained in the radiation-sensitive composition of the present embodiment is preferably less than 20 J/g. Also, (Crystallization temperature)−(Glass transition temperature) is preferably 70° C. or more, more preferably 80° C. or more, still more preferably 100° C. or more, and particularly preferably 130° C. or more. When the heat of crystallization is less than 20 J/g or when (Crystallization temperature)−(Glass transition temperature) falls within the above range, there is a tendency that the radiation-sensitive composition easily forms an amorphous film by spin coating, can maintain film formability necessary for a resist over a long period, and can improve resolution.

In the present embodiment, the above heat of crystallization, crystallization temperature, and glass transition temperature can be determined by differential scanning calorimetry using “DSC/TA-50WS” manufactured by SHIMADZU CORPORATION. For example, about 10 mg of a sample is placed in an unsealed container made of aluminum, and the temperature is raised to the melting point or more at a temperature increase rate of 20° C./min in a nitrogen gas stream (50 mL/min). After quenching, again the temperature is raised to the melting point or more at a temperature increase rate of 20° C./min in a nitrogen gas stream (30 mL/min). After further quenching, again the temperature is raised to 400° C. at a temperature increase rate of 20° C./min in a nitrogen gas stream (30 mL/min). The temperature at the middle point (where the specific heat is changed into the half) of steps in the baseline shifted in a step-like pattern is defined as the glass transition temperature (Tg). The temperature of the subsequently appearing exothermic peak is defined as the crystallization temperature. The heat is determined from the area of a region surrounded by the exothermic peak and the baseline and defined as the heat of crystallization.

The component (A) to be contained in the radiation-sensitive composition of the present embodiment is preferably low sublimable at 100 or lower, preferably 120° C. or lower, more preferably 130° C. or lower, still more preferably 140° C. or lower, and particularly preferably 150° C. or lower at normal pressure. The low sublimability means that in thermogravimetry, weight reduction when the radiation-sensitive composition is kept at a predetermined temperature for 10 minutes is 10% or less, preferably 5% or less, more preferably 3% or less, still more preferably 1% or less, and particularly preferably 0.1% or less. The low sublimability can prevent an exposure apparatus from being contaminated by outgassing upon exposure. In addition, a good pattern shape with low roughness can be obtained.

The component (A) to be contained in the radiation-sensitive composition of the present embodiment dissolves at preferably 1% by mass or more, more preferably 5% by mass or more, and still more preferably 10% by mass or more at 23° C. in a solvent that is selected from propylene glycol monomethyl ether acetate (PGMEA), propylene glycol monomethyl ether (PGME), cyclohexanone (CHN), cyclopentanone (CPN), 2-heptanone, anisole, butyl acetate, ethyl propionate, and ethyl lactate and exhibits the highest ability to dissolve the component (A). Further preferably, the component (A) dissolves at 20% by mass or more at 23° C. in a solvent that is selected from PGMEA, PGME, and CHN and exhibits the highest ability to dissolve the component (A). Particularly preferably, the component (A) dissolves at 20% by mass or more at 23° C. in PGMEA. When the above conditions are met, the radiation-sensitive composition can be used in a semiconductor production process at a full production scale.

### (Optically Active Diazonaphthoquinone Compound (B))

The optically active diazonaphthoquinone compound (B) to be contained in the radiation-sensitive composition of the present embodiment is a diazonaphthoquinone substance including a polymer or non-polymer optically active diazonaphthoquinone compound and is not particularly limited as long as it is generally used as a photosensitive component (sensitizing agent) in positive type resist compositions. One kind or two or more kinds can be optionally selected and used.

Such a sensitizing agent is preferably a compound obtained by reacting naphthoquinonediazide sulfonic acid chloride, benzoquinonediazide sulfonic acid chloride, or the like with a low molecular weight compound or a high molecular weight compound having a functional group condensable with these acid chlorides. Here, examples of the above functional group condensable with the acid chlorides include, but are not particularly limited to, a hydroxy group and an amino group. Particularly, a hydroxy group is suitable. Examples of the compound containing a hydroxy group condensable with the acid chlorides can include, but are not particularly limited to, hydroquinone; resorcin; hydroxybenzophenones such as 2,4-dihydroxybenzophenone, 2,3,4-trihydroxybenzophenone, 2,4,6-trihydroxybenzophenone, 2,4,4′-trihydroxybenzophenone, 2,3,4,4′-tetrahydroxybenzophenone, 2,2′,4,4′-tetrahydroxybenzophenone, and 2,2′,3,4,6′-pentahydroxybenzophenone; hydroxyphenylalkanes such as bis(2,4-dihydroxyphenyl)methane, bis(2,3,4-trihydroxyphenyl)methane, and bis(2,4-dihydroxyphenyl)propane; and hydroxytriphenylmethanes such as 4,4′,3″,4″-tetrahydroxy-3,5,3′,5′-tetramethyltriphenylmethane and 4,4′,2″,3″,4″-pentahydroxy-3,5,3′,5′-tetramethyltriphenylmethane.

Also, preferable examples of the acid chloride such as naphthoquinonediazide sulfonic acid chloride or benzoquinonediazide sulfonic acid chloride include 1,2-naphthoquinonediazide-5-sulfonyl chloride and 1,2-naphthoquinonediazide-4-sulfonyl chloride.

The radiation-sensitive composition of the present embodiment is preferably prepared by, for example, dissolving each component in a solvent upon use into a homogeneous solution, and then if required, filtering through a filter or the like with a pore diameter of about 0.2 μm, for example.

### (Solvent)

Examples of the solvent that can be used in the radiation-sensitive composition of the present embodiment include, but are not particularly limited to, propylene glycol monomethyl ether acetate, propylene glycol monomethyl ether, cyclohexanone, cyclopentanone, 2-heptanone, anisole, butyl acetate, ethyl propionate, and ethyl lactate. Among them, propylene glycol monomethyl ether acetate, propylene glycol monomethyl ether, or cyclohexanone is preferable. The solvent may be used alone as one kind or may be used in combination of two or more kinds.

The content of the solvent is 20 to 99 parts by mass based on 100 parts by mass in total of the radiation-sensitive composition, preferably 50 to 99 parts by mass, more preferably 60 to 98 parts by mass, and particularly preferably 90 to 98 parts by mass.

The content of components except for the solvent (solid components) is 1 to 80 parts by mass based on 100 parts by mass in total of the radiation-sensitive composition, preferably 1 to 50 parts by mass, more preferably 2 to 40 parts by mass, and particularly preferably 2 to 10 parts by mass.

### [Properties of Radiation-Sensitive Composition]

The radiation-sensitive composition of the present embodiment can form an amorphous film by spin coating. Also, the radiation-sensitive composition of the present embodiment can be applied to a general semiconductor production process. Any of positive type and negative type resist patterns can be individually prepared depending on the kind of a developing solution to be used.

In the case of a positive type resist pattern, the dissolution rate of the amorphous film formed by spin coating with the radiation-sensitive composition of the present embodiment in a developing solution at 23° C. is preferably 5 angstrom/sec or less, more preferably 0.05 to 5 angstrom/sec, and still more preferably 0.0005 to 5 angstrom/sec. When the dissolution rate is 5 angstrom/sec or less, the amorphous film is insoluble in a developing solution, and thus can form a resist. When the amorphous film has a dissolution rate of 0.0005 angstrom/sec or more, the resolution may improve. It is presumed that this is because due to the change in the solubility before and after exposure of the polycyclic polyphenolic resin of the present embodiment (component (A)), contrast at the interface between the exposed portion being dissolved in a developing solution and the unexposed portion not being dissolved in a developing solution is increased. Also, there are effects of reducing LER and defects.

In the case of a negative type resist pattern, the dissolution rate of the amorphous film formed by spin coating with the radiation-sensitive composition of the present embodiment in a developing solution at 23° C. is preferably 10 angstrom/sec or more. When the dissolution rate is 10 angstrom/sec or more, the amorphous film more easily dissolves in a developing solution, and is more suitable for a resist. In addition, when the amorphous film has a dissolution rate of 10 angstrom/sec or more, the resolution may be improved. It is presumed that this is because the micro surface portion of the component (A) dissolves, and LER is reduced. Also, there are effects of reducing defects.

The dissolution rate can be determined by immersing the amorphous film in a developing solution for a predetermined period of time at 23° C. and then measuring the film thickness before and after immersion by a publicly known method such as visual inspection, ellipsometrer, or QCM method.

In the case of a positive type resist pattern, the dissolution rate of the exposed portion after irradiation with radiation such as KrF excimer laser, extreme ultraviolet, electron beam or X-ray, or after heating at 20 to 500° C., of the amorphous film formed by spin coating with the radiation-sensitive composition of the present embodiment, in a developing solution at 23° C. is preferably 10 angstrom/sec or more, more preferably 10 to 10000 angstrom/sec, and still more preferably 100 to 1000 angstrom/sec. When the dissolution rate is 10 angstrom/sec or more, the above portion more easily dissolves in a developing solution, and the amorphous film is more suitable for a resist. When the above portion has a dissolution rate of 10000 angstrom/sec or less, the resolution may improve. It is presumed that this is because the micro surface portion of the component (A) dissolves, and LER is reduced. Also, there are effects of reducing defects.

In the case of a negative type resist pattern, the dissolution rate of the exposed portion after irradiation with radiation such as KrF excimer laser, extreme ultraviolet, electron beam or X-ray, or after heating at 20 to 500° C., of the amorphous film formed by spin coating with the radiation-sensitive composition of the present embodiment, in a developing solution at 23° C. is preferably 5 angstrom/sec or less, more preferably 0.05 to 5 angstrom/sec, and still more preferably 0.0005 to 5 angstrom/sec. When the dissolution rate is 5 angstrom/sec or less, the above portion is insoluble in a developing solution, and thus the amorphous film can form a resist. When the amorphous film has a dissolution rate of 0.0005 angstrom/sec or more, the resolution may improve. It is presumed that this is because due to the change in the solubility before and after exposure of the micro surface portion of the component (A), contrast at the interface between the unexposed portion being dissolved in a developing solution and the exposed portion not being dissolved in a developing solution is increased. Also, there are effects of reducing LER and defects.

### (Content Ratio of Each Component in Radiation-Sensitive Composition)

In the radiation-sensitive composition of the present embodiment, the content of the polycyclic polyphenolic resin of the present embodiment (component (A)) is preferably 1 to 99% by mass based on the total mass of the solid components (summation of the total mass of the polycyclic polyphenolic resin of the present embodiment, the optically active diazonaphthoquinone compound (B), and optionally used solid components such as further component (D), hereinafter the same applies to the radiation-sensitive composition), more preferably 5 to 95% by mass, still more preferably 10 to 90% by mass, and particularly preferably 25 to 75% by mass. When the content of the polycyclic polyphenolic resin of the present embodiment falls within the above range, the radiation-sensitive composition of the present embodiment can produce a pattern with high sensitivity and low roughness.

In the radiation-sensitive composition of the present embodiment, the content of the optically active diazonaphthoquinone compound (B) is preferably 1 to 99% by mass, more preferably 5 to 95% by mass, still more preferably 10 to 90% by mass, and particularly preferably 25 to 75% by mass, based on the total mass of the solid components. When the content of the optically active diazonaphthoquinone compound (B) falls within the above range, the radiation-sensitive composition of the present embodiment can produce a pattern with high sensitivity and low roughness.

### (Further Component (D))

To the radiation-sensitive composition of the present embodiment, if required, as a component other than the solvent, the component (A) and the optically active diazonaphthoquinone compound (B), one kind or two or more kinds of various additive agents such as the above acid generating agent, acid crosslinking agent, acid diffusion controlling agent, dissolution promoting agent, dissolution controlling agent, sensitizing agent, surfactant, and organic carboxylic acid or oxo acid of phosphorus or derivative thereof can be added. In the radiation-sensitive composition of the present embodiment, the further component (D) may be referred to as an optional component (D).

The content ratio of the component (A), the optically active diazonaphthoquinone compound (B), and the optional component (D) ((A)/(B)/(D)) is preferably 1 to 99% by mass/99 to 1% by mass/0 to 98% by mass based on 100% by mass of the solid content of the radiation-sensitive composition, more preferably 5 to 95% by mass/95 to 5% by mass/0 to 49% by mass, still more preferably 10 to 90% by mass/90 to 10% by mass/0 to 10% by mass, particularly preferably 20 to 80% by mass/80 to 20% by mass/0 to 5% by mass, and most preferably 25 to 75% by mass/75 to 25% by mass/0% by mass.

The content ratio of each component is selected from each range so that the summation thereof is 100% by mass. When the content ratio of each component falls within the above range, the radiation-sensitive composition of the present embodiment is excellent in performance such as sensitivity and resolution, in addition to roughness.

The radiation-sensitive composition of the present embodiment may contain an additional resin other than the polycyclic polyphenolic resin of the present embodiment. Examples of such an additional resin include a novolac resin, a polyvinyl phenol, a polyacrylic acid, a polyvinyl alcohol, a styrene-maleic anhydride resin, and a polymer containing acrylic acid, vinyl alcohol or vinylphenol as a monomeric unit, and derivatives thereof. The content of the additional resin is appropriately adjusted according to the kind of the polycyclic polyphenolic resin of the present embodiment to be used, but is preferably 30 parts by mass or less, more preferably 10 parts by mass or less, still more preferably 5 parts by mass or less, and especially preferably 0 parts by mass based on 100 parts by mass of the polycyclic polyphenolic resin of the present embodiment.

### [Method for Producing Amorphous Film]

The method for producing an amorphous film of the present embodiment comprises the step of forming an amorphous film on a substrate using the radiation-sensitive composition.

### [Resist Pattern Formation Method]

In the present embodiment, the resist pattern can be formed by using the resist composition of the present embodiment or by using the radiation-sensitive composition of the present embodiment. Further, as described below, a resist pattern can also be formed using the composition for underlayer film formation for lithography of the present embodiment.

### [Resist Pattern Formation Method Using Resist Composition]

A resist pattern formation method using the resist composition of the present embodiment includes the steps of: forming a resist film on a substrate using the above resist composition of the present embodiment; exposing at least a portion of the formed resist film; and developing the exposed resist film, thereby forming a resist pattern. The resist pattern according to the present embodiment can also be formed as an upper layer resist in a multilayer process.

### [Resist Pattern Formation Method Using Radiation-Sensitive Composition]

A resist pattern formation method using the radiation-sensitive composition of the present embodiment includes the steps of: forming a resist film on a substrate using the radiation-sensitive composition; exposing at least a portion of the formed resist film; and developing the exposed resist film, thereby forming a resist pattern. Specifically, the same operation as in the following resist pattern formation method using the resist composition can be performed.

Hereinafter, the conditions for carrying out the resist pattern formation method which can be common between the case of using the resist composition of the present embodiment and the case of using the radiation-sensitive composition of the present embodiment will be described.

Examples of the resist pattern formation method include, but are not particularly limited to, the following method. A resist film is formed by coating a conventionally publicly known substrate with the resist composition of the present embodiment using a coating means such as spin coating, flow casting coating, and roll coating. Examples of the conventionally publicly known substrate can include, but are not particularly limited to, a substrate for electronic components, and the one having a predetermined wiring pattern formed thereon, or the like. More specific examples thereof include, but are not particularly limited to, a silicon wafer, a substrate made of a metal such as copper, chromium, iron and aluminum, and a glass substrate. Examples of the wiring pattern material include, but are not particularly limited to, copper, aluminum, nickel and gold. Also if required, the substrate may be a substrate having an inorganic and/or organic film provided thereon. Examples of the inorganic film include, but are not particularly limited to, an inorganic antireflection film (inorganic BARC). Examples of the organic film include, but are not particularly limited to, an organic antireflection film (organic BARC). The substrate may be subjected to surface treatment with hexamethylene disilazane or the like.

Next, the coated substrate is heated if required. The heating conditions vary according to the compounding composition of the resist composition, or the like, but are preferably 20 to 250° C., and more preferably 20 to 150° C. By heating, the adhesiveness of a resist to a substrate may be improved, which is preferable. Then, the resist film is exposed to a desired pattern by any radiation selected from the group consisting of visible light, ultraviolet, excimer laser, electron beam, extreme ultraviolet (EUV), X-ray, and ion beam. The exposure conditions or the like are appropriately selected according to the compounding composition of the resist composition, or the like. In the present embodiment, in order to stably form a fine pattern with a high degree of accuracy in exposure, the resist film is preferably heated after radiation irradiation.

Then, by developing the exposed resist film in a developing solution, a predetermined resist pattern is formed. As the developing solution, it is preferable to select a solvent having a solubility parameter (SP value) close to that of the component (A) to be used. A polar solvent such as a ketone-based solvent, an ester-based solvent, an alcohol-based solvent, an amide-based solvent and an ether-based solvent; and a hydrocarbon-based solvent, or an alkaline aqueous solution can be used. Examples of the solvent and the alkaline aqueous solution include, but are not limited to, those described in International Publication No. WO 2013/024778.

A plurality of the solvents may be mixed, or the solvent may be used by mixing the solvent with a solvent other than those described above or water within the range having performance. Here, from the viewpoint of further enhancing the desired effect of the present embodiment, the water content ratio as the whole developing solution is less than 70% by mass, and is preferably less than 50% by mass, more preferably less than 30% by mass, and still more preferably less than 10% by mass. Particularly preferably, the developing solution is substantially moisture free. That is, the content of the organic solvent in the developing solution is preferably 30% by mass or more and 100% by mass or less based on the total amount of the developing solution, preferably 50% by mass or more and 100% by mass or less, more preferably 70% by mass or more and 100% by mass or less, still more preferably 90% by mass or more and 100% by mass or less, and particularly preferably 95% by mass or more and 100% by mass or less.

Particularly, as the developing solution, a developing solution containing at least one kind of solvent selected from a ketone-based solvent, an ester-based solvent, an alcohol-based solvent, an amide-based solvent, and an ether-based solvent is preferable because it improves resist performance such as resolution and roughness of the resist pattern.

To the developing solution, a surfactant can be added in an appropriate amount, if required. The surfactant is not particularly limited, but an ionic or nonionic, fluorine-based and/or silicon-based surfactant or the like can be used, for example. Examples of the fluorine-based and/or silicon-based surfactant can include the surfactants described in Japanese Patent Laid-Open No. 62-36663, Japanese Patent Laid-Open No. 61-226746, Japanese Patent Laid-Open No. 61-226745, Japanese Patent Laid-Open No. 62-170950, Japanese Patent Laid-Open No. 63-34540, Japanese Patent Laid-Open No. 7-230165, Japanese Patent Laid-Open No. 8-62834, Japanese Patent Laid-Open No. 9-54432, and Japanese Patent Laid-Open No. 9-5988, and U.S. Pat. Nos. 5,405,720, 5,360,692, 5,529,881, 5,296,330, 5,436,098, 5,576,143, 5,294,511, and 5,824,451. The surfactant is preferably a nonionic surfactant. The nonionic surfactant is not particularly limited, but it is still more preferable to use a fluorine-based surfactant or a silicon-based surfactant.

The amount of the surfactant used is usually 0.001 to 5% by mass based on the total amount of the developing solution, preferably 0.005 to 2% by mass, and still more preferably 0.01 to 0.5% by mass.

For the development method, without particular limitations, for example, a method for dipping a substrate in a bath filled with a developing solution for a fixed time (dipping method), a method for raising a developing solution on a substrate surface by the effect of a surface tension and keeping it still for a fixed time, thereby conducting the development (puddle method), a method for spraying a developing solution on a substrate surface (spraying method), and a method for continuously ejecting a developing solution on a substrate rotating at a constant speed while scanning a developing solution ejecting nozzle at a constant rate (dynamic dispense method), or the like may be applied. The time for conducting the pattern development is not particularly limited, but is preferably 10 seconds to 90 seconds.

In addition, after the step of conducting the development, a step of stopping the development by the replacement with another solvent may be carried out.

After the development, it is preferable that a step of washing the resist film with a rinsing solution containing an organic solvent is included.

The rinsing solution used in the rinsing step after the development is not particularly limited as long as the rinsing solution does not dissolve the resist pattern cured by crosslinking. A solution containing a general organic solvent or water may be used as the rinsing solution. As the above rinsing solution, it is preferable to use a rinsing solution containing at least one kind of organic solvent selected from a hydrocarbon-based solvent, a ketone-based solvent, an ester-based solvent, an alcohol-based solvent, an amide-based solvent, and an ether-based solvent. More preferably, after development, a step of washing the film by using a rinsing solution containing at least one kind of organic solvent selected from the group consisting of a ketone-based solvent, an ester-based solvent, an alcohol-based solvent and an amide-based solvent is conducted. Even more preferably, after development, a step of washing the film by using a rinsing solution containing an alcohol-based solvent or an ester-based solvent is conducted. Even more preferably, after the development, a step of washing the film by using a rinsing solution containing a monohydric alcohol is conducted. Particularly preferably, after the development, a step of washing the film by using a rinsing solution containing a monohydric alcohol having 5 or more carbon atoms is conducted. The time for rinsing the pattern is not particularly limited, but is preferably 10 seconds to 90 seconds.

Herein, examples of the monohydric alcohol used in the rinsing step after development include a linear, branched or cyclic monohydric alcohol, and examples thereof include, but are not particularly limited to, those described in International Publication No. WO 2013/024778. As a particularly preferable monohydric alcohol having 5 or more carbon atoms, 1-hexanol, 2-hexanol, 4-methyl-2-pentanol, 1-pentanol, 3-methyl-1-butanol or the like can be used.

A plurality of these components may be mixed, or the component may be used by mixing the component with an organic solvent other than those described above.

The water content ratio in the rinsing solution is preferably 10% by mass or less, more preferably 5% by mass or less, and particularly preferably 3% by mass or less. By setting the water content ratio to 10% by mass or less, better development characteristics can be obtained.

The rinsing solution may also be used after adding an appropriate amount of a surfactant to the rinsing solution.

In the rinsing step, the wafer after the development is subjected to washing treatment using the above organic solvent-containing rinsing solution. The method of washing treatment is not particularly limited. However, for example, a method for continuously ejecting a rinsing solution on a substrate rotating at a constant speed (spin coating method), a method for dipping a substrate in a bath filled with a rinsing solution for a fixed time (dipping method), a method for spraying a rinsing solution on a substrate surface (spraying method), or the like can be applied. Among them, it is preferable to conduct the washing treatment by the spin coating method and after the washing, spin the substrate at a rotational speed of 2,000 rpm to 4,000 rpm, to remove the rinsing solution from the substrate surface.

After forming the resist pattern, a pattern wiring substrate is obtained by etching. Etching can be performed by a publicly known method such as dry etching using plasma gas, and wet etching with an alkaline solution, a cupric chloride solution, a ferric chloride solution or the like.

After forming the resist pattern, plating can also be conducted. Examples of the above plating method include copper plating, solder plating, nickel plating, and gold plating.

The remaining resist pattern after etching can be peeled by an organic solvent. Examples of the above organic solvent are not particularly limited, and examples include PGMEA (propylene glycol monomethyl ether acetate), PGME (propylene glycol monomethyl ether), and EL (ethyl lactate). Examples of the above peeling method are not particularly limited, and examples include a dipping method and a spraying method. In addition, a wiring substrate having a resist pattern formed thereon may be a multilayer wiring substrate, and may have a small diameter through hole.

In the present embodiment, the wiring substrate obtained can also be formed by a method for forming a resist pattern, then depositing a metal in vacuum, and subsequently dissolving the resist pattern in a solution, that is, a liftoff method.

### [Underlayer Film Forming Material for Lithography]

The composition for underlayer film formation for lithography of the present embodiment comprises a composition for film formation. That is, the composition for underlayer film formation for lithography of the present embodiment contains the polycyclic polyphenolic resin of the present embodiment as an essential component, and may further contain any of various optional components in consideration of use as an underlayer film forming material for lithography. Specifically, the composition for underlayer film formation for lithography of the present embodiment preferably further contains at least one selected from the group consisting of a solvent, an acid generating agent, and a crosslinking agent.

The content of the polycyclic polyphenolic resin of the present embodiment in the composition for underlayer film formation for lithography is preferably 1 to 100% by mass, more preferably 10 to 100% by mass, still more preferably 50 to 100% by mass, particularly preferably 100% by mass, based on the total solid components, from the viewpoint of coatability and quality stability.

When the composition for underlayer film formation for lithography of the present embodiment comprises a solvent, the content of the polycyclic polyphenolic resin of the present embodiment is not particularly limited, but is preferably 1 to 33 parts by mass based on 100 parts by mass in total including the solvent, more preferably 2 to 25 parts by mass, and still more preferably 3 to 20 parts by mass.

The composition for underlayer film formation for lithography of the present embodiment is applicable to a wet process and is excellent in heat resistance and etching resistance. Furthermore, the composition for underlayer film formation for lithography of the present embodiment contains the polycyclic polyphenolic resin of the present embodiment and can therefore form an underlayer film that is prevented from deteriorating upon baking at a high temperature and is also excellent in etching resistance against oxygen plasma etching or the like. Moreover, the composition for underlayer film formation for lithography of the present embodiment is also excellent in adhesiveness to a resist layer and can therefore produce an excellent resist pattern. The composition for underlayer film formation for lithography of the present embodiment may contain an already known underlayer film forming material for lithography or the like, within the range not deteriorating the desired effect of the present embodiment.

### (Solvent)

A publicly known solvent can be appropriately used as the solvent used in the composition for underlayer film formation for lithography of the present embodiment as long as at least the above component (A) dissolves.

Specific examples of the solvent include, but are not particularly limited to, solvents described in International Publication No. WO 2013/024779. These solvents can be used alone as one kind, or can be used in combination of two or more kinds.

Among the solvents, cyclohexanone, propylene glycol monomethyl ether, propylene glycol monomethyl ether acetate, ethyl lactate, methyl hydroxyisobutyrate, or anisole is particularly preferable from the viewpoint of safety.

The content of the solvent is not particularly limited and is preferably 100 to 10,000 parts by mass based on 100 parts by mass of the polycyclic polyphenolic resin of the present embodiment, more preferably 200 to 5,000 parts by mass, and still more preferably 200 to 1,000 parts by mass, from the viewpoint of solubility and film formation.

### (Crosslinking Agent)

The composition for underlayer film formation for lithography of the present embodiment may contain a crosslinking agent, if required, from the viewpoint of, for example, suppressing intermixing. The crosslinking agent that may be used in the present embodiment is not particularly limited, but a crosslinking agent described in, for example, International Publication No. WO 2013/024778, International Publication No. WO 2013/024779, or International Publication No. WO 2018/016614 can be used. In the present embodiment, the crosslinking agent can be used alone or can be used in combination of two or more kinds.

Specific examples of the crosslinking agent that may be used in the present embodiment include, but are not particularly limited to, phenol compounds (excluding the polycyclic polyphenolic resin of the present embodiment), epoxy compounds, cyanate compounds, amino compounds, benzoxazine compounds, acrylate compounds, melamine compounds, guanamine compounds, glycoluril compounds, urea compounds, isocyanate compounds, and azide compounds. These crosslinking agents can be used alone as one kind, or can be used in combination of two or more kinds. Among these, a benzoxazine compound, an epoxy compound, or a cyanate compound is preferable, and a benzoxazine compound is more preferable from the viewpoint of improvement in etching resistance. Further, a melamine compound and a urea compound are more preferable in view of obtaining good reactivity. Examples of the melamine compound include a compound represented by the formula (a) (NIKALAC MW-100LM (trade name), manufactured by SANWA Chemical Co., Ltd.) and a compound represented by the formula (b) (NIKALAC MX270 (trade name), manufactured by SANWA Chemical Co., Ltd.).

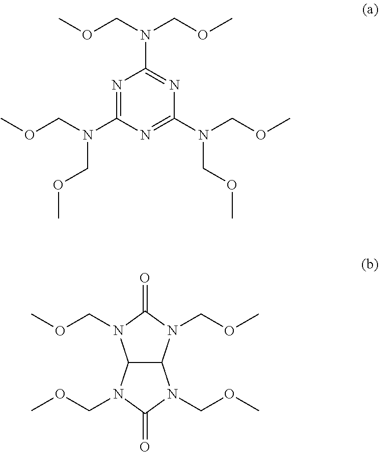

As the phenol compound, a known phenol compound can be used and is not particularly limited, but an aralkyl-based phenolic resin is preferable in terms of heat resistance and solubility.

As the epoxy compound, a known epoxy compound can be used and is not particularly limited, but is preferably an epoxy resin that is in a solid state at normal temperature, such as an epoxy resin obtained from a phenol aralkyl resin or a biphenyl aralkyl resin in terms of heat resistance and solubility.

The cyanate compound is not particularly limited as long as the compound has two or more cyanate groups in one molecule, and a publicly known compound can be used. In the present embodiment, preferable examples of the cyanate compound include cyanate compounds having a structure where hydroxy groups of a compound having two or more hydroxy groups in one molecule are replaced with cyanate groups. Also, the cyanate compound is preferably a cyanate compound that has an aromatic group, and those having a structure where a cyanate group is directly bonded to an aromatic group can be suitably used. Examples of such a cyanate compound include, but are not particularly limited to, cyanate compounds having a structure where hydroxy groups of bisphenol A, bisphenol F, bisphenol M, bisphenol P, bisphenol E, a phenol novolac resin, a cresol novolac resin, a dicyclopentadiene novolac resin, tetramethylbisphenol F, a bisphenol A novolac resin, brominated bisphenol A, a brominated phenol novolac resin, trifunctional phenol, tetrafunctional phenol, naphthalene-based phenol, biphenyl-based phenol, a phenol aralkyl resin, a biphenyl aralkyl resin, a naphthol aralkyl resin, a dicyclopentadiene aralkyl resin, alicyclic phenol, phosphorus-containing phenol, or the like are replaced with cyanate groups. Also, the above cyanate compound may be in any form of a monomer, an oligomer and a resin.

As the amino compound, a known amino compound can be used and is not particularly limited, but 4,4′-diaminodiphenylmethane, 4,4′-diaminodiphenylpropane, or 4,4′-diaminodiphenyl ether is preferable from the viewpoint of heat resistance and availability of raw materials.

As the benzoxazine compound, a known benzoxazine compound can be used and is not particularly limited, but P-d-type benzoxazine obtained from difunctional diamines and monofunctional phenols is preferable from the viewpoint of heat resistance.

As the melamine compound, a known melamine compound can be used and is not particularly limited, but a compound in which 1 to 6 methylol groups of hexamethylol melamine, hexamethoxymethyl melamine, or hexamethylol melamine are methoxymethylated or a mixture thereof is preferable from the viewpoint of availability of raw materials.

As the guanamine compound, a known guanamine compound can be used and is not particularly limited, but tetramethylolguanamine, tetramethoxymethylguanamine, a compound in which 1 to 4 methylol groups of tetramethylolguanamine are methoxymethylated, or a mixture thereof is preferable from the viewpoint of heat resistance.

As the glycol uryl compound, a known glycol uryl compound can be used and is not particularly limited, but tetramethylolglycol uryl and tetramethoxyglycol uryl are preferable from the viewpoint of heat resistance and etching resistance.

As the urea compound, a known urea compound can be used and is not particularly limited, but tetramethylurea and tetramethoxymethylurea are preferable from the viewpoint of heat resistance.

In the present embodiment, a crosslinking agent having at least one allyl group may be used from the viewpoint of improvement in crosslinkability. Among them, an allylphenol such as 2,2-bis(3-allyl-4-hydroxyphenyl)propane, 1,1,1,3,3,3-hexafluoro-2,2-bis(3-allyl-4-hydroxyphenyl)propane, bis(3-allyl-4-hydroxyphenyl)sulfone, bis(3-allyl-4-hydroxyphenyl) sulfide, or bis(3-allyl-4-hydroxyphenyl) ether is preferable.

In the composition for underlayer film formation for lithography of the present embodiment, the content of the crosslinking agent is not particularly limited, but is preferably 5 to 50 parts by mass, and more preferably 10 to 40 parts by mass based on 100 parts by mass of the polycyclic polyphenolic resin of the present embodiment. By setting the content of the crosslinking agent to the above preferable range, occurrence of a mixing event with a resist layer tends to be prevented. Also, an antireflection effect is enhanced, and film formability after crosslinking tends to be enhanced.

### (Crosslinking Promoting Agent)

In the composition for underlayer film formation for lithography of the present embodiment, if required, a crosslinking promoting agent for accelerating crosslinking and curing reaction can be used.

The crosslinking promoting agent is not particularly limited as long as it accelerates crosslinking or curing reaction, and examples thereof include amines, imidazoles, organic phosphines, and Lewis acids. These crosslinking promoting agents can be used alone as one kind, or can be used in combination of two or more kinds. Among these, an imidazole or an organic phosphine is preferable, and an imidazole is more preferable from the viewpoint of decrease in crosslinking temperature.

As the crosslinking promoting agent, a known crosslinking promoting agent can be used, and examples thereof include those described in International Publication No. WO 2018/016614. From the viewpoint of heat resistance and acceleration of curing, 2-methylimidazole, 2-phenylimidazole, and 2-ethyl-4-methylimidazole are particularly preferable.

The content of the crosslinking promoting agent is usually preferably 0.1 to 10 parts by mass based on 100 parts by mass of the total mass of the composition, and is more preferably 0.1 to 5 parts by mass, and still more preferably 0.1 to 3 parts by mass, from the viewpoint of easy control and cost efficiency.

### (Radical Polymerization Initiator)

The composition for underlayer film formation for lithography of the present embodiment can contain, if required, a radical polymerization initiator. The radical polymerization initiator may be a photopolymerization initiator that initiates radical polymerization by light, or may be a thermal polymerization initiator that initiates radical polymerization by heat. The radical polymerization initiator can be at least one selected from the group consisting of a ketone-based photopolymerization initiator, an organic peroxide-based polymerization initiator and an azo-based polymerization initiator.

Such a radical polymerization initiator is not particularly limited, and a radical polymerization initiator conventionally used can be appropriately adopted. For example, examples thereof include those described in International Publication No. WO 2018/016614. Among these, dicumyl peroxide, 2,5-dimethyl-2,5-bis(t-butylperoxy)hexane, and t-butylcumyl peroxide are particularly preferable from the viewpoint of availability of raw materials and storage stability.

As the radical polymerization initiator used for the present embodiment, one kind thereof may be used alone, or two or more kinds may be used in combination. Alternatively, the radical polymerization initiator according to the present embodiment may be used in further combination with an additional publicly known polymerization initiator.

### (Acid Generating Agent)

The composition for underlayer film formation for lithography of the present embodiment may contain an acid generating agent, if required, from the viewpoint of, for example, further accelerating crosslinking reaction by heat. An acid generating agent that generates an acid by thermal decomposition, an acid generating agent that generates an acid by light irradiation, and the like are known, any of which can be used.

The acid generating agent is not particularly limited, and, for example, an acid generating agent described in International Publication No. WO 2013/024779 can be used. In the present embodiment, the acid generating agent can be used alone or can be used in combination of two or more kinds.

In the composition for underlayer film formation for lithography of the present embodiment, the content of the acid generating agent is not particularly limited, but is preferably 0.1 to 50 parts by mass, and more preferably 0.5 to 40 parts by mass based on 100 parts by mass of the polycyclic polyphenolic resin of the present embodiment. By setting the content of the acid generating agent to the above preferable range, crosslinking reaction tends to be enhanced by an increased amount of an acid generated. Also, occurrence of a mixing event with a resist layer tends to be prevented.

### (Basic Compound)

The composition for underlayer film formation for lithography of the present embodiment may further contain a basic compound from the viewpoint of, for example, improving storage stability.

The basic compound plays a role as a quencher against acids in order to prevent crosslinking reaction from proceeding due to a trace amount of an acid generated by the acid generating agent. Examples of such a basic compound include, but are not particularly limited to, primary, secondary or tertiary aliphatic amines, amine blends, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amide derivatives, and imide derivatives.

The basic compound used in the present embodiment is not particularly limited, and, for example, a basic compound described in International Publication No. WO 2013/024779 can be used. In the present embodiment, the basic compound can be used alone or can be used in combination of two or more kinds.

In the composition for underlayer film formation for lithography of the present embodiment, the content of the basic compound is not particularly limited, but is preferably 0.001 to 2 parts by mass, and more preferably 0.01 to 1 parts by mass based on 100 parts by mass of the polycyclic polyphenolic resin according to the present embodiment. By setting the content of the basic compound to the above preferable range, storage stability tends to be enhanced without excessively deteriorating crosslinking reaction.

### (Further Additive Agent)

The composition for underlayer film formation for lithography of the present embodiment may also contain an additional resin and/or compound for the purpose of conferring thermosetting properties or controlling absorbance. Examples of such an additional resin and/or compound include, but are not particularly limited to, a naphthol resin, a xylene resin, a naphthol-modified resin, a phenol-modified resin of a naphthalene resin; a polyhydroxystyrene, a dicyclopentadiene resin, a resin containing (meth)acrylate, dimethacrylate, trimethacrylate, tetramethacrylate, a naphthalene ring such as vinylnaphthalene or polyacenaphthylene, a biphenyl ring such as phenanthrenequinone or fluorene, or a heterocyclic ring having a heteroatom such as thiophene or indene, and a resin not containing an aromatic ring; and a resin or compound containing an alicyclic structure, such as a rosin-based resin, a cyclodextrin, an adamantine (poly)ol, a tricyclodecane (poly)ol, and a derivative thereof. The composition for underlayer film formation for lithography of the present embodiment may further contain a publicly known additive agent. Examples of the publicly known additive agent include, but are not limited to, ultraviolet absorbers, surfactants, colorants, and nonionic surfactants.

### [Underlayer Film for Lithography Formation Method]

The method for forming an underlayer film for lithography according to the present embodiment includes the step of forming an underlayer film on a substrate using the composition for underlayer film formation for lithography of the present embodiment.

### [Resist Pattern Formation Method Using Composition for Underlayer Film Formation for Lithography]

A resist pattern formation method using the composition for underlayer film formation for lithography of the present embodiment has the steps of: forming an underlayer film on a substrate using the composition for underlayer film formation for lithography of the present embodiment (step (A-1)); forming at least one photoresist layer on the underlayer film (step (A-2)). The resist pattern formation method may further include the step of irradiating a predetermined region of the photoresist layer with radiation for development, thereby forming a resist pattern (step (A-3)).

### [Circuit Pattern Formation Method Using Composition for Underlayer Film Formation for Lithography]

A circuit pattern formation method using the composition for underlayer film formation for lithography of the present embodiment has the steps of: forming an underlayer film on a substrate using the composition for underlayer film formation for lithography of the present embodiment (step (B-1)); forming an intermediate layer film on the underlayer film using a resist intermediate layer film material containing a silicon atom (step (B-2)); forming at least one photoresist layer on the intermediate layer film (step (B-3)); after the step (B-3), irradiating a predetermined region of the photoresist layer with radiation for development, thereby forming a resist pattern (step (B-4)); after the step (B-4), etching the intermediate layer film with the resist pattern as a mask, thereby forming an intermediate layer film pattern (step (B-5)); etching the underlayer film with the obtained intermediate layer film pattern as an etching mask, thereby forming an underlayer film pattern (step (B-6)); and etching the substrate with the obtained underlayer film pattern as an etching mask, thereby forming a pattern on the substrate (step (B-7)).

The underlayer film for lithography of the present embodiment is not particularly limited by its formation method as long as it is formed from the composition for underlayer film formation for lithography of the present embodiment. A publicly known approach can be applied thereto. The underlayer film can be formed by, for example, applying the composition for underlayer film formation for lithography of the present embodiment onto a substrate by a publicly known coating method or printing method such as spin coating or screen printing, and then removing an organic solvent by volatilization or the like.

It is preferable to perform baking in the formation of the underlayer film, for preventing occurrence of a mixing event with an upper layer resist while accelerating crosslinking reaction. In this case, the baking temperature is not particularly limited and is preferably in the range of 80 to 450° C., and more preferably 200 to 400° C. The baking time is not particularly limited and is preferably in the range of 10 to 300 seconds. The thickness of the underlayer film can be appropriately selected according to required performance and is not particularly limited, but is usually preferably about 30 to 20,000 nm, and more preferably 50 to 15,000 nm.

After preparing the underlayer film, it is preferable to prepare a silicon-containing resist layer or a usual single-layer resist made of hydrocarbon thereon in the case of a two-layer process, and to prepare a silicon-containing intermediate layer thereon and further a silicon-free single-layer resist layer thereon in the case of a three-layer process. In this case, a publicly known photoresist material can be used for forming this resist layer.

After preparing the underlayer film on the substrate, a silicon-containing resist layer or a usual single-layer resist made of hydrocarbon thereon can be prepared on the underlayer film in the case of a two-layer process. In the case of a three-layer process, a silicon-containing intermediate layer can be prepared on the underlayer film, and a silicon-free single-layer resist layer can be further prepared on the silicon-containing intermediate layer. In these cases, a publicly known photoresist material can be appropriately selected and used for forming the resist layer, without particular limitations.

For the silicon-containing resist material for a two-layer process, a silicon atom-containing polymer such as a polysilsesquioxane derivative or a vinylsilane derivative is used as a base polymer, and a positive type photoresist material further containing an organic solvent, an acid generating agent, and if required, a basic compound or the like is preferably used, from the viewpoint of oxygen gas etching resistance. Here, a publicly known polymer that is used in this kind of resist material can be used as the silicon atom-containing polymer.

A polysilsesquioxane-based intermediate layer is preferably used as the silicon-containing intermediate layer for a three-layer process. By imparting effects as an antireflection film to the intermediate layer, there is a tendency that reflection can be effectively suppressed. For example, use of a material containing a large amount of an aromatic group and having high substrate etching resistance as the underlayer film in a process for exposure at 193 nm tends to increase a k value and enhance substrate reflection. However, the intermediate layer suppresses the reflection so that the substrate reflection can be 0.5% or less. The intermediate layer having such an antireflection effect is not limited, and polysilsesquioxane that crosslinks by an acid or heat in which a light absorbing group having a phenyl group or a silicon-silicon bond is introduced is preferably used for exposure at 193 nm.

Alternatively, an intermediate layer formed by chemical vapour deposition (CVD) may be used. The intermediate layer highly effective as an antireflection film prepared by CVD is not limited, and, for example, a SiON film is known. In general, the formation of an intermediate layer by a wet process such as spin coating or screen printing is more convenient and more advantageous in cost than CVD. The upper layer resist for a three-layer process may be positive type or negative type, and the same as a single-layer resist usually used can be used.

The underlayer film according to the present embodiment can also be used as an antireflection film for usual single-layer resists or an underlying material for suppression of pattern collapse. The underlayer film of the present embodiment is excellent in etching resistance for an underlying process and can be expected to also function as a hard mask for an underlying process.

In the case of forming a resist layer from the photoresist material, a wet process such as spin coating or screen printing is preferably used, as in the case of forming the above underlayer film. After coating with the resist material by spin coating or the like, prebaking is usually performed. This prebaking is preferably performed at 80 to 180° C. in the range of 10 to 300 seconds. Thereafter, exposure, post-exposure baking (PEB), and development can be performed according to a conventional method to obtain a resist pattern. The thickness of the resist film is not particularly limited, and in general, is preferably 30 to 500 nm and more preferably 50 to 400 nm.

The exposure light can be appropriately selected and used according to the photoresist material to be used. General examples thereof can include a high energy ray having a wavelength of 300 nm or less, specifically, excimer laser of 248 nm, 193 nm, or 157 nm, soft x-ray of 3 to 20 nm, electron beam, and X-ray.

In a resist pattern formed by the above method, pattern collapse is suppressed by the underlayer film according to the present embodiment. Therefore, use of the underlayer film according to the present embodiment can produce a finer pattern and can reduce an exposure amount necessary for obtaining the resist pattern.

Next, etching is performed with the obtained resist pattern as a mask. Gas etching is preferably used as the etching of the underlayer film in a two-layer process. The gas etching is suitably etching using oxygen gas. In addition to oxygen gas, an inert gas such as He or Ar, or CO, CO₂, NH₃, SO₂, N₂, NO₂, or H₂ gas may be added. Alternatively, the gas etching may be performed with CO, CO₂, NH₃, N₂, NO₂, or H₂ gas without the use of oxygen gas. Particularly, the latter gas is preferably used for side wall protection in order to prevent the undercut of pattern side walls.

On the other hand, gas etching is also preferably used as the etching of the intermediate layer in a three-layer process. The same gas etching as described in the above two-layer process is applicable. In particular, it is preferable to process the intermediate layer in a three-layer process by using chlorofluorocarbon-based gas and using the resist pattern as a mask. Thereafter, as mentioned above, for example, the underlayer film can be processed by oxygen gas etching with the intermediate layer pattern as a mask.

Herein, in the case of forming an inorganic hard mask intermediate layer film as the intermediate layer, a silicon oxide film, a silicon nitride film, or a silicon oxynitride film (SiON film) is formed by CVD, atomic layer deposition (ALD), or the like. A method for forming the nitride film is not limited, and, for example, a method described in Japanese Patent Laid-Open No. 2002-334869 (Patent Literature 4) or International Publication No. WO 2004/066377 (Patent Literature 5) can be used. Although a photoresist film can be formed directly on such an intermediate layer film, an organic antireflection film (BARC) may be formed on the intermediate layer film by spin coating and a photoresist film may be formed thereon.

A polysilsesquioxane-based intermediate layer is preferably used as the intermediate layer. By imparting effects as an antireflection film to the resist intermediate layer film, there is a tendency that reflection can be effectively suppressed. A specific material for the polysilsesquioxane-based intermediate layer is not limited, and, for example, a material described in Japanese Patent Laid-Open No. 2007-226170 (Patent Literature 6) or Japanese Patent Laid-Open No. 2007-226204 (Patent Literature 7) can be used.

The subsequent etching of the substrate can also be performed by a conventional method. For example, the substrate made of SiO₂ or SiN can be etched mainly using chlorofluorocarbon-based gas, and the substrate made of p-Si, Al, or W can be etched mainly using chlorine- or bromine-based gas. In the case of etching the substrate with chlorofluorocarbon-based gas, the silicon-containing resist of the two-layer resist process or the silicon-containing intermediate layer of the three-layer process is stripped at the same time with substrate processing. On the other hand, in the case of etching the substrate with chlorine- or bromine-based gas, the silicon-containing resist layer or the silicon-containing intermediate layer is separately stripped and in general, stripped by dry etching using chlorofluorocarbon-based gas after substrate processing.

A feature of the underlayer film according to the present embodiment is that it is excellent in etching resistance of these substrates. The substrate can be appropriately selected from publicly known ones and used and is not particularly limited. Examples thereof include Si, α-Si, p-Si, SiO₂, SiN, SiON, W, TiN, and Al. The substrate may be a laminate having a film to be processed (substrate to be processed) on a base material (support). Examples of such a film to be processed include various low-k films such as Si, SiO₂, SiON, SiN, p-Si, α-Si, W, W—Si, Al, Cu, and Al—Si, and stopper films thereof. A material different from that for the base material (support) is usually used. The thickness of the substrate to be processed or the film to be processed is not particularly limited, and usually, it is preferably approximately 50 to 1,000,000 nm and more preferably 75 to 500,000 nm.

### [Resist Permanent Film]

The composition for film formation of the present embodiment can also be used to prepare a resist permanent film. The resist permanent film prepared by coating with the composition for film formation of the present embodiment on a base material or the like is suitable as a permanent film that also remains in a final product, if required, after formation of a resist pattern. Specific examples of the permanent film include, but are not particularly limited to, in relation to semiconductor devices, solder resists, package materials, underfill materials, package adhesive layers for circuit elements and the like, and adhesive layers between integrated circuit elements and circuit substrates, and in relation to thin displays, thin film transistor protecting films, liquid crystal color filter protecting films, black matrixes, and spacers. Particularly, the permanent film made of the composition for film formation of the present embodiment is excellent in heat resistance and humidity resistance and furthermore, also has the excellent advantage that contamination by sublimable components is reduced. Particularly, for a display material, a material that achieves all of high sensitivity, high heat resistance, and hygroscopic reliability with reduced deterioration in image quality due to significant contamination can be obtained.

In the case of using the composition for film formation of the present embodiment for resist permanent films, a curing agent as well as, if required, various additive agents such as an additional resin, a surfactant, a dye, a filler, a crosslinking agent, and a dissolution promoting agent can be further added and dissolved in an organic solvent to prepare a composition for resist permanent films.

The composition for film formation according to the present embodiment is used for resist permanent films, the composition for a resist permanent film can be prepared by adding each of the above components and mixing them using a stirrer or the like. When the composition for film formation of the present embodiment contains a filler or a pigment, the composition for a resist permanent film can be prepared by dispersion or mixing using a dispersion apparatus such as a dissolver, a homogenizer, and a three-roll mill.

### [Composition for Optical Component Formation]

The composition for film formation of the present embodiment can also be used for forming optical components. That is, the composition for optical component formation of the present embodiment contains the composition for film formation of the present embodiment. In other words, the composition for optical component formation of the present embodiment contains the polycyclic polyphenolic resin according to the present embodiment as an essential component. Herein, the “optical component” refers to a component in the form of a film or a sheet as well as a plastic lens (a prism lens, a lenticular lens, a microlens, a Fresnel lens, a viewing angle control lens, a contrast improving lens, etc.), a phase difference film, a film for electromagnetic wave shielding, a prism, an optical fiber, a solder resist for flexible printed wiring, a plating resist, an interlayer insulating film for multilayer printed circuit boards, or a photosensitive optical waveguide. The polycyclic polyphenolic resin of the present embodiment are useful for forming these optical components. The composition for optical component formation of the present embodiment may further contain various optional components in consideration of being used as an optical component forming material. Specifically, the composition for optical component formation of the present embodiment preferably further contains at least one selected from the group consisting of a solvent, an acid generating agent, and a crosslinking agent. Specific examples that can be used as the solvent, the acid generating agent, and the crosslinking agent may be the same as those of the components that may be contained in the composition for underlayer film formation for lithography according to the present embodiment described above, and the blending ratio thereof may be appropriately set in consideration of specific application.

### EXAMPLES

Hereinafter, the present embodiment will be described in more detail based on Examples, and Comparative Examples, but the present embodiment is not limited thereto.

In the following Examples, Examples relating to a compound group related to polycyclic polyphenolic resins having repeating units derived from at least one monomer selected from the group consisting of aromatic hydroxy compounds represented by the formulas (1A) and (1B) (hereinafter referred to as “Compound Group 1”) are referred to as “Example Group 1”, Examples relating to a compound group related to polycyclic polyphenolic resins having repeating units derived from at least one monomer selected from the group consisting of aromatic hydroxy compounds represented by the formulas (D-1A) and (D-2A) (hereinafter referred to as “Compound Group 2”) are referred to as “Example Group 2”, Examples relating to a compound group related to polycyclic polyphenolic resins having a repeating unit derived from an aromatic hydroxy compound represented by the formula (C-1A) (hereinafter referred to as “Compound Group 3”) are referred to as “Example Group 3”. The Example number imparted to the following each Example is individual Example number for each Example Group. That is, for example, Example 1 of Examples according to Compound Group 1 (Example Group 1) is distinguished as being different from Example 1 of Examples according to Compound Group 2 (Example Group 2).

¹H-NMR measurement was performed under the following conditions by using “Advance 60011 spectrometer” manufactured by Bruker Corporation.
Frequency: 400 MHz
Solvent: d6-DMSO
Internal standard: TMS
Measurement temperature: 23° C.

### (Molecular Weight)

The molecular weight of a compound was measured by LC-MS analysis using Acquity UPLC/MALDI-Synapt HDMS manufactured by Waters Corporation.

### (Polystyrene Equivalent Molecular Weight)

The weight-average molecular weight (Mw) and number-average molecular weight (Mn) were determined by gel permeation chromatography (GPC) analysis, and the dispersibility (Mw/Mn) in terms of polystyrene was determined.
Apparatus: Shodex GPC-101 model (manufactured by Showa Denko K.K.)
Column: KF-80M×3
Eluent: 1 mL/min THF
Temperature: 40° C.

The IR measurement was performed using “Spectram100 FT-IR spectrometer” manufactured by PerkinElmer, Inc. under the following conditions.
Measurement method: ATR method
Measurement temperature: 23° C.

### Example Group 1

### (Example Group 1: Synthesis Example 1) Synthesis of BisN-1

To a container (internal capacity: 500 mL) equipped with a stirrer, a condenser tube, and a burette, 34.0 g (200 mmol) of o-phenylphenol (reagent manufactured by Sigma-Aldrich), 18.2 g (100 mmol) of 4-biphenylaldehyde (manufactured by MITSUBISHI GAS CHEMICAL COMPANY, INC.), and 200 mL of 1,4-dioxane were added, and 10 mL of 95% sulfuric acid was added. The reaction solution was stirred at 100° C. for 6 hours and reacted. Next, the reaction solution was neutralized with 24% aqueous sodium hydroxide solution. The reaction product was precipitated by the addition of 100 g of pure water. After cooling to room temperature, the precipitates were separated by filtration. The obtained solid matter was dried and then separated and purified by column chromatography to obtain 25.5 g of the objective compound (BisN-1) represented by the following formula.

The following peaks were found by 400 MHz-¹H-NMR, and the compound was confirmed to have a chemical structure of the following formula.

¹H-NMR: (d-DMSO, internal standard TMS)

δ (ppm) 9.1 (2H, O—H), 7.2-8.5 (25H, Ph-H), 5.6 (1H, C—H)

LC-MS analysis confirmed that the molecular weight was 504 corresponding to the following chemical structure.

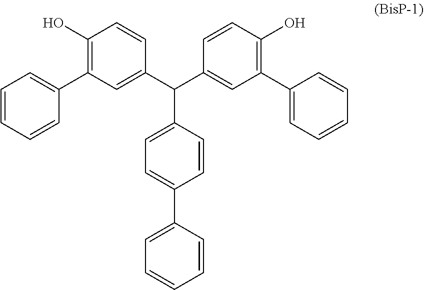 [SMILES: Oc1ccc(C(c2ccc(-c3ccccc3)cc2)c2ccc(O)c(-c3ccccc3)c2)cc1-c1ccccc1]

### (Example Group 1: Synthesis Examples 2 to 5) Synthesis of BisP-2 to BisP-5

Objective compound (BisN-2), (BisN-3), (BisN-4), or (BisN-5) represented by the following formulas was obtained in the same manner as in Synthesis Example 1 except that benzaldehyde, p-methylbenzaldehyde, 1-naphthaldehyde, or 2-naphthaldehyde was used instead of 4-biphenylaldehyde, respectively.

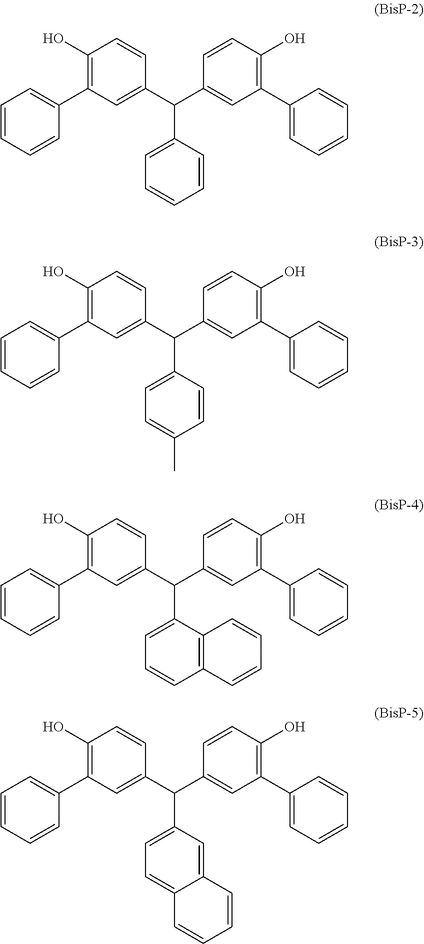

### (Example Group 1: Synthesis Working Example 1) Synthesis of RBisP-1

To a container (internal capacity: 500 mL) equipped with a stirrer, a condenser tube, and a burette, 50 g (105 mmol) of BisP-1 and 10.1 g (20 mmol) of monobutylcopper phthalate were added, and 100 mL of 1-butanol was added as a solvent. The reaction solution was stirred at 100° C. for 6 hours and reacted. After cooling, the precipitate was filtered and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 200 mL of methanol was added to precipitate the reaction product. After cooling to room temperature, the precipitates were separated by filtration. The obtained solid matter was dried to obtain 38.0 g of the objective resin (RBisP-1) having a structure represented by the following formula.

The polystyrene equivalent molecular weight of the obtained resin was measured by the method described above, and as a result, the obtained resin had Mn: 602, Mw: 752, and Mw/Mn: 1.25.

The following peaks were found by NMR measurement performed on the obtained resin under the above measurement conditions, and the resin was confirmed to have a chemical structure of the following formula.

δ (ppm) 9.1 (2H, O—H), 7.2-8.5 (23H, Ph-H), 5.6 (1H, C—H)

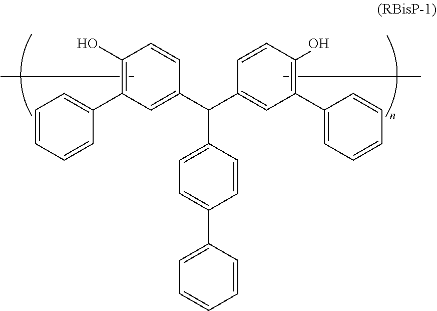

### (Example Group 1: Synthesis Working Examples 2 to 5) Synthesis of RBisP-2 to RBisP-5

Objective compounds (RBisP-2), (RBisP-3), (RBisP-4), and (RBisP-5) represented by the following formulas were obtained in the same manner as in Synthesis Working Example 1 except that BisP-2, BisP-3, BisP-4, and BisP-5 were used instead of BisN-1, respectively.

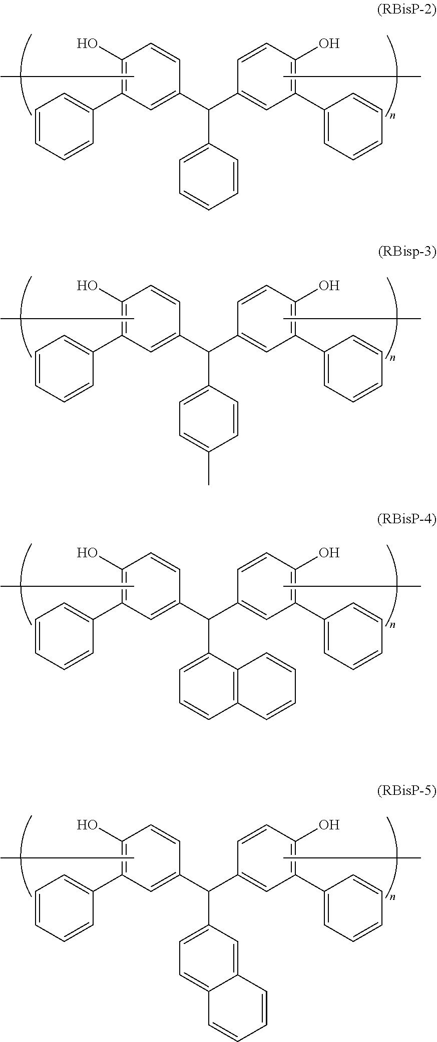

The results of measuring the polystyrene equivalent molecular weight of the resin obtained in Synthesis Working Examples 2 to 5 by the above method are shown below.
(RBisP-2) Mn: 610, Mw: 732, Mw/Mn: 1.20
(RBisP-3) Mn: 624, Mw: 770, Mw/Mn: 1.23
(RBisP-4) Mn: 720, Mw: 802, Mw/Mn: 1.11
(RBisP-5) Mn: 718, Mw: 824, Mw/Mn: 1.15

The following peaks were found by NMR measurement performed on the resin obtained in Synthetic Working Examples 2 to 5 under the above measurement conditions, and the resin was confirmed to have a chemical structure of the following formula.
RBisP-2: δ (ppm) 9.0 (2H, O—H), 7.2-8.5 (19H, Ph-H), 5.5 (1H, C—H)
RBisP-3: δ (ppm) 9.0 (2H, O—H), 7.2-8.5 (18H, Ph-H), 5.6 (1H, C—H), 2.2 (3H, —CH₃)
RBisP-4: δ (ppm) 9.1 (2H, O—H), 7.2-8.5 (21H, Ph-H), 5.6 (1H, C—H)
RBisP-5: δ (ppm) 9.1 (2H, O—H), 7.2-8.5 (21H, Ph-H), 5.6 (1H, C—H)

### (Example Group 1: Synthesis Working Example P1) Synthesis of R-PP-1

To a container (internal capacity: 300 mL) equipped with a stirrer, a condenser tube, and a burette, 17.0 g (100 mmol) of 4-phenylphenol, 2.0 g (20 mmol) of copper (I) chloride, and 12.6 g (80 mmol) of pyridine were added, and 200 mL of 1-butanol was added as a solvent. The reaction solution was stirred at 90° C. for 9 hours and reacted. After cooling, the precipitate was filtered and the resulting crude was dissolved in 600 mL of butyl acetate. Next, 300 mL of sulfuric acid was added for washing, followed by washing twice with water. The butyl acetate solution was concentrated and 200 mL of methanol was added to disperse the reaction product, and the mixture was cooled to room temperature and separated by filtration. The obtained solid matter was dried to obtain 6 g of the objective resin (R-PP-1; resin containing the unit (α) and the unit (β) at n:m=4:1) having a structure represented by the following formula.

The polystyrene equivalent molecular weight of the obtained resin was measured by the method described above, and as a result, the obtained resin had Mn: 767, Mw: 938, and Mw/Mn: 1.22.

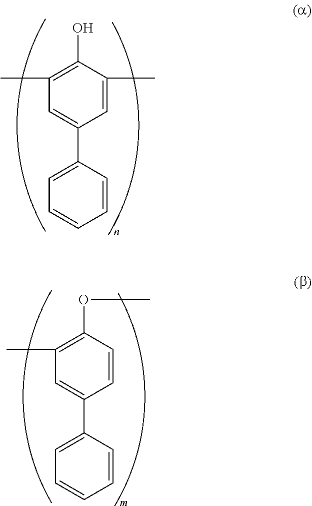

A main component was isolated from the obtained resin and was subjected to NMR measurement under the above measurement conditions. As a result, the following peaks were found, and the resin (R-PP-1) was confirmed to contain a compound having only the unit (α) in the formula and having a structure of n=3 (the compound had a structure in which aromatic rings were directly bonded to each other by a carbon bond).

δ (ppm) 9.00 (3H, O—H), 7.70 (2H, Ph-H), 7.66 (4H, Ph-H), 7.60 (2H, Ph-H), 7.55 (2H, Ph-H), 7.54 (2H, Ph-H), 7.52 (2H, Ph-H), 7.42 (6H, Ph-H), 7.30 (3H, Ph-H), 7.07 (2H, Ph-H)

Further, the proportion of the bondings between the aromatic rings of the resin (R-PP-1) was calculated using the peaks obtained by the NMR measurement and Mn obtained by the GPC, and it was confirmed that 80 mol % of the aromatic rings were directly bonded to each other by a carbon bond and 20 mol % of the aromatic rings were bonded to each other by an ether bond.

Furthermore, by performing IR measurement, the following characteristic peaks were found, and it was confirmed that the resin (R-PP-1) had the chemical structure (units (a) and ($)) of the formula described above.

v (cm⁻¹) 3420-3450 (Ph-OH), 1219 (Ph-O-Ph)

### (Example Group 1: Synthesis Working Example P2) Synthesis of R-PP-2

To a container (internal capacity: 300 mL) equipped with a stirrer, a condenser tube, and a burette, 17.0 g (100 mmol) of 4-phenylphenol, 2.0 g (20 mmol) of copper (I) chloride, and 12.6 g (80 mmol) of pyridine were added, and 200 mL of 1-butanol was added as a solvent. The reaction solution was stirred at 90° C. for 40 hours and reacted. After cooling, the precipitate was filtered and the resulting crude was dissolved in 600 mL of butyl acetate. Next, 300 mL of sulfuric acid was added for washing, followed by washing twice with water. The butyl acetate solution was concentrated, and 200 mL of methanol was added to disperse the reaction product, and the mixture was separated by filtration at room temperature. The obtained solid matter was dried to obtain 9 g of the objective resin (R-PP-2; resin containing the unit (α) and the unit (β) at n:m=85:15) having a structure represented by the above formula.

The polystyrene equivalent molecular weight of the obtained resin was measured by the method described above, and as a result, the obtained resin had Mn: 1162, Mw: 1512, and Mw/Mn: 1.30.

The following peaks were found by NMR measurement performed on the obtained resin under the above measurement conditions, and the resin was confirmed to have a chemical structure of the above formula.

δ (ppm) 9.0 (1H, O—H), 8.0-7.0 (7H, Ph-H)

Further, the proportion of the bondings between the aromatic rings was calculated using the peaks obtained by the NMR measurement and Mn obtained by the GPC, and it was confirmed that 85 mol % of the aromatic rings were directly bonded to each other by a carbon bond and 15 mol % of the aromatic rings were bonded to each other by an ether bond.

### (Example Group 1: Synthesis Working Example P3) Synthesis of R-PP-3

To a container (internal capacity: 300 mL) equipped with a stirrer, a condenser tube, and a burette, 17.0 g (100 mmol) of 4-phenylphenol and 10.1 g (20 mmol) of monobutylcopper phthalate were added, and 200 mL of 1-butanol was added as a solvent. The reaction solution was stirred at 90° C. for 9 hours and reacted. After cooling, the precipitate was filtered and the resulting crude was dissolved in 600 mL of butyl acetate. Next, 300 mL of sulfuric acid was added for washing, followed by washing twice with water. The butyl acetate solution was concentrated, and 200 mL of methanol was added to disperse the reaction product, and the mixture was separated by filtration at room temperature. The obtained solid matter was dried to obtain 7 g of the objective resin (R-PP-3; resin constituted only by the unit (α)) having a structure represented by the above formula.

The polystyrene equivalent molecular weight of the obtained resin was measured by the method described above, and as a result, the obtained resin had Mn: 784, Mw: 1058, and Mw/Mn: 1.35.

The following peaks were found by NMR measurement performed on the obtained resin under the above measurement conditions, and the resin was confirmed to have a chemical structure of the above formula.

δ (ppm) 9.0 (1H, O—H), 8.0-7.0 (7H, Ph-H)

### (Example Group 1: Synthesis Working Example P4) Synthesis of R-PP-4

To a container (internal capacity: 300 mL) equipped with a stirrer, a condenser tube, and a burette, 13.0 g (100 mmol) of 4-phenylphenol, 2.0 g (20 mmol) of copper (I) chloride, and 12.6 g (80 mmol) of dibutylamine were added, and 200 mL of 1-butanol was added as a solvent. The reaction solution was stirred at 90° C. for 9 hours and reacted. After cooling, the precipitate was filtered and the resulting crude was dissolved in 600 mL of butyl acetate. Next, 300 mL of sulfuric acid was added for washing, followed by washing twice with water. The butyl acetate solution was concentrated, and 200 mL of methanol was added to disperse the reaction product, and the mixture was separated by filtration at room temperature. The obtained solid matter was dried to obtain 9 g of the objective resin (R-PP-4; resin containing the unit (α) and the unit (β); provided that m>>n (the amount of hydroxy group observed by NMR was approximately 0) having a structure represented by the following formula.

The polystyrene equivalent molecular weight of the obtained resin was measured by the method described above, and as a result, the obtained resin had Mn: 1284, Mw: 1612, and Mw/Mn: 1.26.

The following peaks were found by NMR measurement performed on the obtained resin under the above measurement conditions, and the resin was confirmed to have a chemical structure of the above formula.

δ (ppm) 9.0 (0.1H, O—H), 8.0-7.0 (7H, Ph-H)

### Example Group 1: Comparative Synthesis Example 1

To a container (internal capacity: 100 ml) equipped with a stirrer, a condenser tube, and a burette, 10 g (21 mmol) of BisN-2, 0.7 g (42 mmol) of paraformaldehyde, 50 mL of glacial acetic acid, and 50 mL of PGME were added, and 8 mL of 95% sulfuric acid was added thereto. The reaction solution was stirred at 100° C. for 6 hours and reacted. Next, the reaction solution was concentrated and 1000 mL of methanol was added to precipitate the reaction product. After cooling to room temperature, the precipitates were separated by filtration. The obtained solid matter was filtered and dried to obtain 7.2 g of the objective resin (NBisN-1) having a structure represented by the following formula.

The polystyrene equivalent molecular weight of the obtained resin was measured by the method described above, and as a result, the obtained resin had Mn: 1278, Mw: 1993, and Mw/Mn: 1.56.

The following peaks were found by NMR measurement performed on the obtained resin under the above measurement conditions, and the resin was confirmed to have a chemical structure of the following formula.

δ (ppm) 9.7 (2H, O—H), 7.2-8.5 (17H, Ph-H), 6.6 (1H, C—H), 4.1 (2H, —CH2)

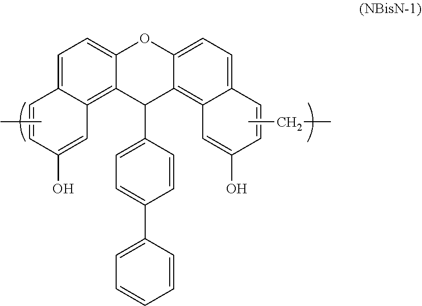

### Example Group 1: Comparative Synthesis Example 2

A 4-neck flask (internal capacity: 10 L) equipped with a Dimroth condenser tube, a thermometer, and a stirring blade and having a detachable bottom was prepared. To this 4-neck flask, 1.09 kg (7 mol) of 1,5-dimethylnaphthalene (manufactured by MITSUBISHI GAS CHEMICAL COMPANY, INC.), 2.1 kg (28 mol as formaldehyde) of 40% by mass of an aqueous formalin solution (manufactured by MITSUBISHI GAS CHEMICAL COMPANY, INC.), and 0.97 mL of 98% by mass of sulfuric acid (manufactured by KANTO CHEMICAL CO., INC.) were fed in the current of nitrogen, and the mixture was reacted for 7 hours while being refluxed at 100° C. at normal pressure. Thereafter, 1.8 kg of ethylbenzene (a special grade reagent manufactured by Wako Pure Chemical Industries, Ltd.) was added as a diluting solvent to the reaction solution, and the mixture was left to stand still, followed by removal of an aqueous phase as a lower phase. Neutralization and washing with water were further performed, and ethylbenzene and unreacted 1,5-dimethylnaphthalene were distilled off under reduced pressure to obtain 1.25 kg of a dimethylnaphthalene formaldehyde resin as a light brown solid.

Then, a four necked flask (internal capacity: 0.5 L) equipped with a Dimroth condenser tube, a thermometer, and a stirring blade was prepared. To this four necked flask, 100 g (0.51 mol) of the dimethylnaphthalene formaldehyde resin obtained as described above, and 0.05 g of p-toluenesulfonic acid were added in a nitrogen stream, and the temperature was raised to 190° C. at which the mixture was then heated for 2 hours, followed by stirring. Subsequently, 52.0 g (0.36 mol) of 1-naphthol was further added thereto, the temperature was further elevated to 220° C., and the mixture was reacted for 2 hours. After dilution with a solvent, neutralization and washing with water were performed, and the solvent was distilled off under reduced pressure to obtain 126.1 g of a modified resin (CR-1) as a black-brown solid.

### Example Group 1: Examples 1 to 5

Table 1 shows the results of evaluating the heat resistance by the evaluation methods shown below using the resins obtained in Synthesis Working Examples 1 to 5 and Comparative Synthesis Example 1.

### <Measurement of Thermal Decomposition Temperature>

EXSTAR 6000 TG/DTA apparatus manufactured by SII NanoTechnology Inc. was used. About 5 mg of a sample was placed in an unsealed container made of aluminum, and the temperature was raised to 700° C. at a temperature increase rate of 10° C./min in a nitrogen gas stream (30 mL/min). The temperature at which a heat loss of 10% by mass was observed was defined as the thermal decomposition temperature (Tg), and the heat resistance was evaluated according to the following criteria.
Evaluation A: The thermal decomposition temperature was 410° C. or higher
Evaluation B: The thermal decomposition temperature was 320° C. or higher
Evaluation C: The thermal decomposition temperature was lower than 320° C.

TABLE 1

| | Heat |
|---|---|
| | resistance |
| Resin | evaluation |

| | | | |
|---|---|---|---|
| Example 1 | Synthesis Working | RBisP-1 | A |
| | Example 1 | | |
| Example 2 | Synthesis Working | RBisP-2 | A |
| | Example 2 | | |
| Example 3 | Synthesis Working | RBisP-3 | A |
| | Example 3 | | |
| Example 4 | Synthesis Working | RBisP-4 | A |
| | Example 4 | | |
| Example P1 | Synthesis Working | R-PP-1 | B |
| | Example P1 | | |
| Example P2 | Synthesis Working | R-PP-2 | A |
| | Example P2 | | |
| Example P3 | Synthesis Working | R-PP-3 | A |
| | Example P3 | | |
| Example P4 | Synthesis Working | R-PP-4 | B |
| | Example P4 | | |
| Example 5 | Synthesis Working | RBisP-5 | A |
| | Example 5 | | |
| Comparative | Comparative | NBisN-1 | C |
| Example 1 | Synthesis Example 1 | | |

As is evident from Table 1, it was able to be confirmed that the resins used in Example 1 to Example 5 have good heat resistance whereas the resins used in Comparative Example 1 is inferior in heat resistance.

As shown in the table below, the following solubility evaluation was performed.

### [Evaluation of Solubility]

The resin (oligomer) in the present embodiment was dissolved in propylene glycol monomethyl ether acetate (PGMEA) at 23° C., and the solubility in PGMEA was evaluated based on the following criteria.
Evaluation S: After dissolution to 30% by mass, it was visually confirmed that there was no precipitate.
Evaluation A: After dissolution of the resin in PGMEA so that the content thereof was 10% by mass, and it was visually confirmed that there was no precipitate.
Evaluation C: After dissolution of the resin in PGMEA so that the content thereof was 10% by mass, and it was visually confirmed that there was precipitate.

TABLE 2

| | |
|---|---|
| | Solubility |
| Resin | evaluation |

| | | | |
|---|---|---|---|
| Example 1′ | Synthesis Working | RBisP-1 | A |
| | Example 1 | | |
| Example 2′ | Synthesis Working | RBisP-2 | A |
| | Example 2 | | |
| Example 3′ | Synthesis Working | RBisP-3 | A |
| | Example 3 | | |
| Example 4′ | Synthesis Working | RBisP-4 | A |
| | Example 4 | | |
| Example P1′ | Synthesis Working | R-PP-1 | S |
| | Example P1 | | |
| Example P2′ | Synthesis Working | R-PP-2 | S |
| | Example P2 | | |
| Example P3′ | Synthesis Working | R-PP-3 | A |
| | Example P3 | | |
| Example P4′ | Synthesis Working | R-PP-4 | A |
| | Example P4 | | |
| Example 5′ | Synthesis Working | RBisP-5 | A |
| | Example 5 | | |
| Comparative | Comparative Synthesis | NBisN-1 | A |
| Example 1′ | Example 1 | | |

As is evident from Table 2, the resins used in Examples 1′ to 5′ had good solubility. In Examples P1′ and P2′, the solubility was particularly good. Further, Examples P1 to P2 gave particularly excellent results.

### Example Group 1: Examples 6 to 10 and Comparative Example 2

### (Preparation of Composition for Underlayer Film Formation for Lithography)

Compositions for underlayer film formation for lithography were prepared according to the composition shown in Table 1. Next, a silicon substrate was spin coated with each of these compositions for underlayer film formation for lithography, and then baked at 240° C. for 60 seconds and further at 400° C. for 120 seconds under a nitrogen gas atmosphere to prepare each underlayer film having a film thickness of 200 to 250 nm.

Next, etching test was conducted under conditions shown below to evaluate etching resistance. The evaluation results are shown in Table 3.

### [Etching Test]

Etching apparatus: RIE-10NR manufactured by Samco International, Inc.
Output: 50 W
Pressure: 20 Pa
Time: 2 min

Etching Gas
Ar gas flow rate:CF₄ gas flow rate:O₂ gas flow rate=50:5:5 (sccm)

### (Evaluation of Etching Resistance)

The evaluation of etching resistance was conducted by the following procedures. First, an underlayer film of novolac was prepared under the same conditions as described above except that novolac (PSM4357 manufactured by Gun Ei Chemical Industry Co., Ltd.) was used. This underlayer film of novolac was subjected to the above etching test, and the etching rate was measured.

Next, underlayer films of Example 6 to Example 10 and Comparative Example 2 were prepared under the same conditions as the underlayer films of novolac and subjected to the etching test described above in the same way as above, and the etching rate was measured. The etching resistance was evaluated according to the following evaluation criteria on the basis of the etching rate of the underlayer film of novolac.

[Evaluation Criteria]
S: The etching rate was less than −30% as compared with the underlayer film of novolac.
A: The etching rate was less than −20% as compared with the underlayer film of novolac.
B: The etching rate was −20% to 0% as compared with the underlayer film of novolac.
C: The etching rate was more than +0% as compared with the underlayer film of novolac.

TABLE 3

| | Resin(parts | | Solvent(parts | Etching |
|---|---|---|---|---|
| | by mass) | | by mass) | evaluation |
| Example 6 | Synthesis Working | RBisP-1 | PGMEA/cyclohexanone | A |
| | Example 1 | (10) | (64/16) | |
| Example 7 | Synthesis Working | RBisP-2 | PGMEA/cyclohexanone | A |
| | Example 2 | (10) | (64/16) | |
| Example 8 | Synthesis Working | RBisP-3 | PGMEA/cyclohexanone | A |
| | Example 3 | (10) | (64/16) | |
| Example 9 | Synthesis Working | RBisP-4 | PGMEA/cyclohexanone | A |
| | Example 4 | (10) | (64/16) | |
| Example P1A | Synthesis Working | R-PP-1 | PGMEA/cyclohexanone | S |
| | Example P1 | (10) | (64/16) | |
| Example P2A | Synthesis Working | R-PP-2 | PGMEA/PGME | S |
| | Example P2 | (10) | (64/16) | |
| Example P3A | Synthesis Working | R-PP-3 | PGMEA/PGME | A |
| | Example P3 | (10) | (64/16) | |
| Example P4A | Synthesis Working | R-PP-4 | PGMEA/cyclohexanone | B |
| | Example P4 | (10) | (64/16) | |
| Example 10 | Synthesis Working | RBisP-5 | PGMEA/PGME | A |
| | Example 5 | (10) | (64/16) | |
| Comparative | Comparative | NBisN-1 | cyclohexanone | B |
| Example 2 | Synthesis Example 1 | (10) | (90) | |

It was found that an excellent etching rate is exerted in Example 6 to Example 10 as compared with the underlayer film of novolac and the resin of Comparative Example 2. On the other hand, it was found that the etching rate of the resin of Comparative Example 2 was equivalent to that of the underlayer film of novolac. Further, Examples P1A to P2A gave particularly excellent results.

The metal content before and after purification of polycyclic polyphenolic resin (composition containing the polycyclic polyphenolic resin) and the storage stability of the solution were evaluated by the following method.

### (Measurement of Various Metal Contents)

The metal contents of the propylene glycol monomethyl ether acetate (PGMEA) solutions of various resins obtained in the following Examples and Comparative Examples were measured using ICP-MS under the following measurement conditions.
Apparatus: AG8900 manufactured by Agilent Technologies
Temperature: 25° C.
Environment: Class 100 clean room

### (Storage Stability Evaluation)

The PGMEA solutions obtained in the following Examples and Comparative Examples were retained at 23° C. for 240 hours, and then the turbidity (HAZE) of the solutions was measured using a color difference/turbidity meter to evaluate the storage stability of the solutions according to the following criteria.

Apparatus: Color difference/turbidity meter COH400 (manufactured by NIPPON DENSHOKU INDUSTRIES CO., LTD.)
Optical path length: 1 cm
Quartz cell use

### [Evaluation Criteria]

0≤HAZE≤1.0: Good
1.0<HAZE≤2.0: Fair
2.0<HAZE: Poor

### (Example Group 1: Example 7) Purification of RBisP-1 with Acid

In a four necked flask (capacity: 1000 mL, with a detachable bottom), 150 g of a solution (10% by mass) formed by dissolving RBisN-1 obtained in Synthesis Working Example 1 in PGMEA was charged, and was heated to 80° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Thereafter, by diluting with PGMEA of EL grade (a reagent manufactured by KANTO CHEMICAL CO., INC.) such that the concentration of the PGMEA solution was adjusted to 10% by mass, a PGMEA solution of RBisP-1 with a reduced metal content was obtained.

### (Example Group 1: Reference Example 1) Purification of RBisP-1 with Ultrapure Water

In the same manner as of Example 7 except that ultrapure water was used instead of the aqueous oxalic acid solution, and by adjusting the concentration to 10% by mass, a PGMEA solution of RBisP-1 was obtained.

For the 10% by mass PGMEA solution of RBisP-1 in before the treatment, and the solutions obtained in Example 7 and Reference Example 1, the contents of various metals were measured by ICP-MS. The measurement results are shown in the following Tables.

### (Example Group 1: Example 8) Purification of RBisP-2 with Acid

In a four necked flask (capacity: 1000 mL, with a detachable bottom), 140 g of a solution (10% by mass) formed by dissolving RBisP-2 obtained in Synthesis Working Example 2 in PGMEA was charged, and was heated to 60° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Thereafter, by diluting with PGMEA of EL grade (a reagent manufactured by KANTO CHEMICAL CO., INC.) such that the concentration of the PGMEA solution was adjusted to 10% by mass, a PGMEA solution of RBisN-2 with a reduced metal content was obtained.

### (Example Group 1: Reference Example 2) Purification of RBisP-2 with Ultrapure Water

In the same manner as of Example 8 except that ultrapure water was used instead of the aqueous oxalic acid solution, and by adjusting the concentration to 10% by mass, a PGMEA solution of RBisN-2 was obtained.

For the 10% by mass PGMEA solution of RBisP-2 before the treatment, and the solutions obtained in Example 8 and Reference Example 2, the contents of various metals were measured by ICP-MS. The measurement results are shown in the following Tables.

### (Example Group 1: Example 9) Purification by Passing Through Filter

In a class 1000 clean booth, 500 g of a solution of 10% by mass concentration of the resin (RBisP-1) obtained in Synthesis Working Example 1 dissolved in propylene glycol monomethyl ether (PGME) was charged in a four necked flask (capacity: 1000 mL, with a detachable bottom), and then the air inside the vessel was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 100 mL per minute to a hollow fiber membrane filter (manufactured by KITZ MICRO FILTER CORPORATION, trade name: Polyfix Nylon Series) made of nylon with a nominal pore size of 0.01 μm. The contents of various metals in the obtained RBisP-1 solution were measured by ICP-MS. The oxygen concentration was measured with an oxygen concentration meter “OM-25MF10” manufactured by AS ONE Corporation (the same applies hereinafter). The measurement results are shown in the following Tables.

### Example Group 1: Synthesis Example 10

The solution was passed through in the same manner as in Example 9 except that a hollow fiber membrane filter (KITZ MICRO FILTER CORPORATION, trade name: Polyfix) made of polyethylene (PE) with a nominal pore size of 0.01 μm was used, and the contents of various metals in the obtained RBisP-1 solution were measured by ICP-MS. The measurement results are shown in the following Tables.

### Example Group 1: Synthesis Example 11

The solution was passed through in the same manner as in Example 9 except that a hollow fiber membrane filter (KITZ MICRO FILTER CORPORATION, trade name: Polyfix) made of nylon with a nominal pore size of 0.04 μm was used, and the contents of various metals in the obtained RBisN-1 were measured by ICP-MS. The measurement results are shown in the following Tables.

### Example Group 1: Synthesis Example 12

The solution was passed through in the same manner as in Example 9 except that a Zeta Plus filter 40QSH (manufactured by 3M Company, having an ion exchange capacity) with a nominal pore size of 0.2 μm was used, and the contents of various metals in the obtained RBisN-1 solution were measured by ICP-MS. The measurement results are shown in the following Tables.

### Example Group 1: Synthesis Example 13

The solution was passed through in the same manner as in Example 9 except that a Zeta Plus filter 020GN (manufactured by 3M Company, having an ion exchange capacity, and having different filtration areas and filter material thicknesses from those of Zeta Plus filter 40QSH) with a nominal pore size of 0.2 μm was used, and the obtained RBisP-1 solution was analyzed under the following conditions. The measurement results are shown in the following Tables.

### Example Group 1: Synthesis Example 14

The solution was passed through in the same manner as in Example 9 except that the resin (RBisN-2) obtained in Synthesis Working Example 2 was used instead of the resin (RBisP-1) in Example 9, and the contents of various metals in the obtained RBisP-2 solutions were measured by ICP-MS. The measurement results are shown in the following Tables.

### Example Group 1: Synthesis Example 15

The solution was passed through in the same manner as in Example 10 except that the resin (RBisP-2) obtained in Synthesis Working Example 2 was used instead of the resin (RBisP-1) in Example 10, and the contents of various metals in the obtained RBisP-2 solutions were measured by ICP-MS. The measurement results are shown in the following Tables.

### Example Group 1: Synthesis Example 16

The solution was passed through in the same manner as in Example 11 except that the resin (RBisP-2) obtained in Synthesis Working Example 2 was used instead of the compound (RBisP-1) in Example 11, and the contents of various metals in the obtained RBisP-2 solutions were measured by ICP-MS. The measurement results are shown in the following Tables.

### Example Group 1: Synthesis Example 17

The solution was passed through in the same manner as in Example 12 except that the resin (RBisP-2) obtained in Synthesis Working Example 2 was used instead of the compound (RBisP-1) in Example 12, and the contents of various metals in the obtained RBisP-2 solutions were measured by ICP-MS. The measurement results are shown in the following Tables.

### Example Group 1: Synthesis Example 18

The solution was passed through in the same manner as in Example 13 except that the resin (RBisP-2) obtained in Synthesis Working Example 2 was used instead of the compound (RBisP-1) in Example 13, and the contents of various metals in the obtained RBisP-2 solutions were measured by ICP-MS. The measurement results are shown in the following Tables.

### (Example Group 1: Example 19) Combination of Acid Washing and Filter Passage 1

In a class 1000 clean booth, 140 g of the 10% by mass PGMEA solution of RBisP-1 with a reduced metal content obtained by Example 7 was prepared in a four necked flask (capacity: 300 mL, with a detachable bottom), and then the air inside the vessel was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, passed through a pressure tube made of fluororesin through a diaphragm pump at a flow rate of 10 mL per minute to an ion exchange filter (manufactured by Nihon Pall Ltd., product name: IonKleen Series) with a nominal pore size of 0.01 μm. Thereafter, the recovered solution was then returned to the four necked flask (capacity: 300 mL), and the filter was changed to a filter made of high-density PE with a nominal diameter of 1 nm (manufactured by Entegris Japan Co., Ltd.), and pumped through the flask in the same manner. The contents of various metals in the obtained RBisP-1 solution were measured by ICP-MS. The oxygen concentration was measured with an oxygen concentration meter “OM-25MF10” manufactured by AS ONE Corporation (the same applies hereinafter). The measurement results are shown in the following Tables.

### (Example Group 1: Example 20) Combination of Acid Washing and Filter Passage 2

In a class 1000 clean booth, 140 g of the 10% by mass PGMEA solution of RBisP-1 with a reduced metal content obtained by Example 7 was prepared in a four necked flask (capacity: 300 mL, with a detachable bottom), and then the air inside the vessel was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 10 mL per minute to a hollow fiber membrane filter (manufactured by KITZ MICRO FILTER CORPORATION, trade name: Polyfix) made of nylon with a nominal pore size of 0.01 μm. Thereafter, the recovered solution was then returned to the four necked flask (capacity: 300 mL), and the filter was changed to a filter made of high-density PE with a nominal diameter of 1 nm (manufactured by Entegris Japan Co., Ltd.), and pumped through the flask in the same manner. The contents of various metals in the obtained RBisP-1 solution were measured by ICP-MS. The oxygen concentration was measured with an oxygen concentration meter “OM-25MF10” manufactured by AS ONE Corporation (the same applies hereinafter). The measurement results are shown in the following Tables.

### (Example Group 1: Example 21) Combination of Acid Washing and Filter Passage 3

The same procedure as in Example 19 was carried out except that the 10% by mass PGMEA solution of RBisP-1 used in Example 19 was changed to the 10% by mass PGMEA solution of RBisP-2 obtained by Example 8 to recover a 10% by mass PGMEA solution of RBisN-2 with a reduced metal amount. The contents of various metals in the obtained solution were measured by ICP-MS. The oxygen concentration was measured with an oxygen concentration meter “OM-25MF10” manufactured by AS ONE Corporation (the same applies hereinafter). The measurement results are shown in the following Tables.

### (Example Group 1: Example 22) Combination of Acid Washing and Filter Passage 4

The same procedure as in Example 20 was carried out except that the 10% by mass PGMEA solution of RBisP-1 used in Example 20 was changed to the 10% by mass PGMEA solution of RBisP-2 obtained by Example 8 to recover a 10% by mass PGMEA solution of RBisN-2 with a reduced metal amount. The contents of various metals in the obtained solution were measured by ICP-MS. The oxygen concentration was measured with an oxygen concentration meter “OM-25MF10” manufactured by AS ONE Corporation (the same applies hereinafter). The measurement results are shown in the following Tables.

TABLE 4

| | Purification | Metal content (ppb) | | | | Storage |
|---|---|---|---|---|---|---|
| | method | Cr | Fe | Cu | Zn | stability |
| before | — | 121 | 473 | 932 | 109 | poor |
| treatment | | | | | | |
| RBisN-1 | | | | | | |
| Example 7 | acid washing | 34 | 27 | 72 | 13 | good |
| Example 9 | hollow fiber | 3 | 11 | 22 | 13 | good |
| | membrane nylon | | | | | |
| | filter | | | | | |
| Example 10 | PE | 89 | 111 | 267 | 95 | fair |
| | filter | | | | | |
| Example 11 | hollow fiber | 13 | 12 | 32 | 10 | good |
| | membrane nylon | | | | | |
| | filter | | | | | |
| Example 12 | zeta potential | 14 | 12 | 25 | 7 | good |
| | filter | | | | | |
| Example 13 | zeta potential | 11 | 18 | 30 | 12 | good |
| | filter | | | | | |
| Example 19 | combined use of | <0.1 | <0.1 | <0.1 | <0.1 | good |
| | acid washing/ion | | | | | |
| | exchange filter/ | | | | | |
| | PE filter | | | | | |
| Example 20 | combined use of | <0.1 | <0.1 | <0.1 | <0.1 | good |
| | acid washing/ | | | | | |
| | hollow fiber | | | | | |
| | membrane nylon | | | | | |
| | filter/ PE filter | | | | | |
| Reference | water washing | 102 | 310 | 641 | 95 | poor |
| Example 1 | | | | | | |
| before | — | 108 | 362 | 850 | 202 | poor |
| treatment | | | | | | |
| RBisN-2 | | | | | | |
| Example 8 | acid washing | 22 | 20 | 52 | 12 | good |
| Example 14 | hollow fiber | 8 | 5 | 32 | 10 | good |
| | membrane nylon | | | | | |
| | filter | | | | | |
| Example 15 | PE | 95 | 145 | 345 | 125 | fair |
| | filter | | | | | |
| Example 16 | hollow fiber | 10 | 12 | 35 | 8 | good |
| | membrane nylon | | | | | |
| | filter | | | | | |
| Example 17 | zeta potential | 12 | 20 | 24 | 4 | good |
| | filter | | | | | |

TABLE 5

| | | | | | | |
|---|---|---|---|---|---|---|
| Example 18 | zeta potential filter | 1.0 | >99 | 6 | 94 | good |
| Example 21 | combined use of acid | <0.1 | <0.1 | <0.1 | <0.1 | good |
| | washing/ion | | | | | |
| | exchange filter/PE | | | | | |
| | filter | | | | | |
| Example 22 | combined use of acid | <0.1 | <0.1 | <0.1 | <0.1 | good |
| | washing/hollow fiber | | | | | |
| | membrane nylon | | | | | |
| | filter/PE filter | | | | | |
| Reference | water washing | 84 | 240 | 530 | 188 | poor |
| Example 2 | | | | | | |

As shown in the tables, it was confirmed that the storage stability of the resin solutions according to the present embodiment was improved by reducing the metal derived from the oxidizing agent through various purification methods.

In particular, the acid washing method and the use of ion exchange or nylon filters can effectively reduce ionic metals, and the combination of high-definition high-density polyethylene particulate removal filters can provide dramatic metal removal effects.

### Example Group 1: Examples 23 to 28 and Comparative Example 3

### (Heat Resistance and Resist Performance)

By using the resins obtained in Synthesis Working Example 1 to Synthesis Working Example 5 and Comparative Synthesis Example 1, the test for heat resistance and evaluation of resist performance below were carried out, and the results thereof are shown in Table 6.

### (Preparation of Resist Composition)

A resist composition was prepared according to the recipe shown in Table 6 using each resin synthesized as described above. For the components of the resist compositions in Table 6, the following acid generating agent (C), acid diffusion controlling agent (E), and solvent were used.

Acid generating agent (C)
P-1: triphenylbenzenesulfonium trifluoromethanesulfonate (Midori Kagaku Co., Ltd.) Acid crosslinking agent (G)
C-1: NIKALAC MW-100LM (SANWA Chemical Co., Ltd.) Acid diffusion controlling agent (E)
Q-1: trioctylamine (TOKYO KASEI KOGYO CO., LTD.) Solvent
S-1: propylene glycol monomethyl ether (TOKYO KASEI KOGYO CO., LTD.)

### (Method for Evaluating Resist Performance of Resist Composition)

A clean silicon wafer was spin coated with the homogeneous resist composition, and then prebaked (PB) before exposure in an oven of 110° C. to form a resist film with a thickness of 60 nm. The obtained resist film was irradiated with electron beams of 1:1 line and space setting with 5 nm interval using an electron beam lithography system (ELS-7500 manufactured by ELIONIX INC.). After the irradiation, the resist film was heated at each predetermined temperature for 90 seconds, and immersed in 2.38% by mass tetramethylammonium hydroxide (TMAH) alkaline developing solution for 60 seconds for development. Thereafter, the resist film was washed with ultrapure water for 30 seconds, and dried to form a positive type resist pattern. Concerning the formed resist pattern, the line and space were observed by a scanning electron microscope (S-4800 manufactured by Hitachi High-Technologies Corporation) to evaluate the reactivity by electron beam irradiation of the resist composition.

TABLE 6

| | | Resist composition | | | | | Resist |
|---|---|---|---|---|---|---|---|
| | | Resin | P-1 | C-1 | Q-1 | S-1 | performance |
| | Resin | [g] | [g] | [g] | [g] | [g] | evaluation |
| Example 23 | RBisP-1 | 1.0 | 0.3 | 0.3 | 0.03 | 50.0 | good |
| Example 24 | RBisP-2 | 1.0 | 0.3 | 0.3 | 0.03 | 50.0 | good |
| Example 25 | RBisP-3 | 1.0 | 0.3 | 0.3 | 0.03 | 50.0 | good |
| Example 26 | RBisP-4 | 1.0 | 0.3 | 0.3 | 0.03 | 50.0 | good |
| Example 27 | RBisP-5 | 1.0 | 0.3 | 0.3 | 0.03 | 50.0 | good |
| Example | Synthesis | 1.0 | 0.3 | 0.3 | 0.03 | 50.0 | good |
| P1B | Working | | | | | | |
| | Example P1 | | | | | | |
| Example | Synthesis | 1.0 | 0.3 | 0.3 | 0.03 | 50.0 | good |
| P2B | Working | | | | | | |
| | Example P2 | | | | | | |
| Example | Synthesis | 1.0 | 0.3 | 0.3 | 0.03 | 50.0 | good |
| P3B | Working | | | | | | |
| | Example P3 | | | | | | |
| Example | Synthesis | 1.0 | 0.3 | 0.3 | 0.03 | 50.0 | good |
| P4B | Working | | | | | | |
| | Example P4 | | | | | | |
| Example 28 | RBisP-1 | 1.0 | 0.3 | 0.3 | 0 | 50.0 | good |
| Comparative | NBisN-1 | 1.0 | 0.3 | 0.3 | 0.03 | 50.0 | poor |
| Example 3 | | | | | | | |

In the resist pattern evaluation, a good resist pattern was obtained by irradiation with electron beams of 1:1 line and space setting with a 50 nm interval in each of Example 23 to Example 28. As for the line edge roughness, a pattern having asperities of less than 50 nm was evaluated to be good. On the other hand, it was not possible to obtain a good resist pattern in Comparative Example 3.

When the resin satisfying the requirements of the present embodiment is used as described above, the resin can have the high heat resistance and can impart a good shape to a resist pattern, as compared with the resin (NBisN-1) of Comparative Example 3 which does not satisfy the requirements. As long as the above requirements of the present embodiment are met, compounds other than the resins described in Examples also exhibit the same effects.

### Example Group 1: Examples 29 to 33 and Comparative Example 4

### (Preparation of Radiation-Sensitive Composition)

The components set forth in the following table were formulated and formed into homogeneous solutions, and the obtained homogeneous solutions were filtered through a Teflon® membrane filter with a pore diameter of 0.1 μm to prepare radiation-sensitive compositions. Each of the prepared radiation-sensitive compositions was evaluated as described below.

TABLE 7

Composition

| | | Optically | |
|---|---|---|---|
| | | active | |
| | Component (A) | compound (B) | Solvent |
| | [g] | [g] | [g] |
| Example 29 | RBisP-1 | B-1 | S-1 |
| | [0.5] | [1.5] | [30.0] |
| Example 30 | RBisP-2 | B-1 | S-1 |
| | [0.5] | [1.5] | [30.0] |
| Example 31 | RBisP-3 | B-1 | S-1 |
| | [0.5] | [1.5] | [30.0] |
| Example 32 | RBisP-4 | B-1 | S-1 |
| | [0.5] | [1.5] | [30.0] |
| Example P1C | R-PP-1 | B-1 | S-1 |
| | [0.5] | [1.5] | [30.0] |
| Example P2C | R-PP-2 | B-1 | S-1 |
| | [0.5] | [1.5] | [30.0] |
| Example P3C | R-PP-3 | B-1 | S-1 |
| | [0.5] | [1.5] | [30.0] |
| Example P4C | R-PP-4 | B-1 | S-1 |
| | [0.5] | [1.5] | [30.0] |
| Example 33 | RBisP-5 | B-1 | S-1 |
| | [0.5] | [1.5] | [30.0] |
| Comparative | PHS-1 | B-1 | S-1 |
| Example 4 | [0.5] | [1.5] | [30.0] |

The following resist base material (component (A)) was used in Comparative Example 4.
PHS-1: polyhydroxystyrene Mw=8000 (Sigma-Aldrich)

The following optically active compound (B) was used.
B-1: naphthoquinonediazide-based sensitizing agent having the following chemical structural formula (G) (4NT-300, Toyo Gosei Co., Ltd.)

The following solvent was used.
S-1: propylene glycol monomethyl ether (TOKYO KASEI KOGYO CO., LTD.)

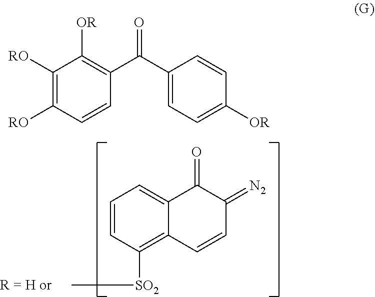

### (Evaluation of Resist Performance of Radiation-Sensitive Composition)

A clean silicon wafer was spin coated with the radiation-sensitive composition obtained as described above, and then prebaked (PB) before exposure in an oven of 110° C. to form a resist film with a thickness of 200 nm. The resist film was exposed to ultraviolet using an ultraviolet exposure apparatus (mask aligner MA-10 manufactured by Mikasa Co., Ltd.). The ultraviolet lamp used was a super high pressure mercury lamp (relative intensity ratio: g-ray:h-ray:i-ray:j-ray=100:80:90:60). After irradiation, the resist film was heated at 110° C. for 90 seconds, and immersed in a 2.38% by mass TMAH alkaline developing solution for 60 seconds for development. Thereafter, the resist film was washed with ultrapure water for 30 seconds, and dried to form a 5 μm positive type resist pattern.

The obtained line and space were observed in the formed resist pattern by a scanning electron microscope (S-4800 manufactured by Hitachi High-Technologies Corporation). As for the line edge roughness, a pattern having asperities of less than 5 nm was evaluated to be good.

In the case of using the radiation-sensitive composition according to each of Example 29 to Example 33, a good resist pattern with a resolution of 5 μm was able to be obtained. The roughness of the pattern was also small and good.

On the other hand, in the case of using the radiation-sensitive composition according to Comparative Example 4, a good resist pattern with a resolution of 5 μm was able to be obtained. However, the roughness of the pattern was large and poor.

As described above, it was found that each of the radiation-sensitive compositions according to Example 29 to Example 33 can form a resist pattern that has small roughness and a good shape, as compared with the radiation-sensitive composition according to Comparative Example 4. As long as the above requirements of the present embodiment are met, radiation-sensitive compositions other than those described in Examples also exhibit the same effects.

Each of the resins obtained in Synthesis Working Example 1 to Synthesis Working Example 5 has a relatively low molecular weight and a low viscosity. As such, it was evaluated that the embedding properties and film surface flatness of underlayer film forming materials for lithography containing these compounds or resins can be relatively advantageously enhanced. Furthermore, each of these compounds or resins has a thermal decomposition temperature of 150° C. or higher (evaluation A) and has high heat resistance, so that it was evaluated that they can be used even under high temperature baking conditions. In order to confirm these points, the following evaluation was performed assuming the application to the underlayer film.

### Example Group 1: Examples 34 to 39 and Comparative Examples 5 and 6

### (Preparation of Composition for Underlayer Film Formation for Lithography)

Compositions for underlayer film formation for lithography were prepared according to the composition shown in Table 8. Next, a silicon substrate was spin coated with each of these compositions for underlayer film formation for lithography, and then baked at 240° C. for 60 seconds and further at 400° C. for 120 seconds to prepare each underlayer film having a film thickness of 200 nm. The following acid generating agent, crosslinking agent, and organic solvent were used.

Acid generating agent: di-tertiary butyl diphenyliodonium nonafluoromethanesulfonate (DTDPI) manufactured by Midori Kagaku Co., Ltd.
Crosslinking agent: NIKALAC MX270 (NIKALAC) manufactured by SANWA Chemical Co., Ltd.
Organic solvent: cyclohexanone, propylene glycol monomethyl ether acetate (PGMEA)
Novolac: PSM4357 manufactured by Gun Ei Chemical Industry Co., Ltd.

Next, etching test was conducted under conditions shown below to evaluate etching resistance. The evaluation results are shown in Table 8.

### [Etching Test]

Etching apparatus: RIE-10NR manufactured by Samco International, Inc.
Output: 50 W
Pressure: 20 Pa
Time: 2 min

Etching Gas
Ar gas flow rate:CF₄ gas flow rate:O₂ gas flow rate=50:5:5 (sccm)

### (Evaluation of Etching Resistance)

The evaluation of etching resistance was conducted by the following procedures. First, an underlayer film of novolac was prepared under the same conditions as described above except that novolac (PSM4357 manufactured by Gun Ei Chemical Industry Co., Ltd.) was used. This underlayer film of novolac was subjected to the above etching test, and the etching rate was measured.

Next, underlayer films of Examples 34 to 39 and Comparative Examples 5 to 6 were prepared under the same conditions as the underlayer films of novolac and subjected to the etching test described above in the same way as above, and the etching rate was measured. The etching resistance was evaluated according to the following evaluation criteria on the basis of the etching rate of the underlayer film of novolac.

[Evaluation Criteria]
S: The etching rate was less than −30% as compared with the underlayer film of novolac.
A: The etching rate was less than −20% as compared with the underlayer film of novolac.
B: The etching rate was −20% to 0% as compared with the underlayer film of novolac.
C: The etching rate was more than +0% as compared with the underlayer film of novolac.

TABLE 8

| | | | Acid | | |
|---|---|---|---|---|---|
| | | | generating | Crosslinking | |
| | Resin | Solvent | agent | agent | |
| | (parts | (parts | (parts | (parts | Etching |
| | by mass) | by mass) | by mass) | by mass) | resistance |
| Example 34 | RBisP-1 | cyclohexanone/PGMEA | DTDPI | NIKALAC | A |
| | (10) | (81/9) | (0.5) | (0.5) | |
| Example 35 | RBisP-2 | cyclohexanone/PGMEA | DTDPI | NIKALAC | A |
| | (10) | (81/9) | (0.5 | (0.5) | |
| Example 36 | RBisP-3 | cyclohexanone/PGMEA | DTDPI | NIKALAC | A |
| | (10) | (81/9) | (0.5) | (0.5) | |
| Example 37 | RBisP-4 | cyclohexanone/PGMEA | DTDPI | NIKALAC | A |
| | (10) | (81/9) | (0.5) | (0.5) | |
| Example 38 | RBisP-5 | cyclohexanone/PGMEA | DTDPI | NIKALAC | A |
| | (10) | (81/9) | (0.5) | (0.5) | |
| Example P1D | R-PP-1 | PGMEA | — | NIKALAC | S |
| | (10) | (90) | | (0.5) | |
| Example P2D | R-PP-2 | PGMEA | — | NIKALAC | S |
| | (10) | (90) | | (0.5) | |
| Example P3D | R-PP-3 | PGMEA | — | NIKALAC | A |
| | (10) | (90) | | (0.5) | |
| Example P4D | R-PP-4 | PGMEA | — | NIKALAC | B |
| | (10) | (90) | | (0.5) | |
| Example 39 | RBisP-1 | PGMEA | — | NIKALAC | A |
| | (10) | (90) | | (0.5) | |
| Comparative | CR-1 | PGMEA | DTDPI | NIKALAC | C |
| Example 5 | (10) | (90) | (0.5) | (0.5) | |
| Comparative | NBisN-1 | PGMEA | DTDPI | NIKALAC | B |
| Example 6 | (10) | (90) | (0.5) | (0.5) | |

It was found that an excellent etching rate is exerted in Examples 34 to 39 as compared with the underlayer film of novolac and the resin of Comparative Example 5 to 6. On the other hand, it was found that in the resin of Comparative Example 5 or 6, the etching rate was equal to or inferior to that of the underlayer film of novolac. Further, Examples P1D to P2D gave particularly excellent results.

### Example Group 1: Examples 40 to 45 and Comparative Example 7

Next, a SiO₂ substrate having a film thickness of 80 nm and a line and space pattern of 60 nm was coated with each of the compositions for underlayer film formation for lithography used in Example 34 to Example 39 and Comparative Example 5, and baked at 240° C. for 60 seconds to form a 90 nm underlayer film.

### (Evaluation of Embedding Properties)

The embedding properties were evaluated by the following procedures. The cross section of the film obtained under the above conditions was cut out and observed under an electron microscope to evaluate the embedding properties. The evaluation results are shown in Table 9.

[Evaluation criteria]
A: The underlayer film was embedded without defects in the asperities of the SiO₂ substrate having a line and space pattern of 60 nm.
C: The asperities of the SiO₂ substrate having a line and space pattern of 60 nm had defects which hindered the embedding of the underlayer film.

TABLE 9

| | Composition for | |
|---|---|---|
| | underlayer film | |
| | formation for | Embedding |
| | lithography | properties |
| Example 40 | Example 34 | A |
| Example 41 | Example 35 | A |
| Example 42 | Example 36 | A |
| Example 43 | Example 37 | A |
| Example 44 | Example 38 | A |
| Example P1E | Example P1D | A |
| Example P2E | Example P2D | A |
| Example P3E | Example P3D | A |
| Example P4E | Example P4D | A |
| Example 45 | Example 39 | A |
| Comparative | Comparative | C |
| Example 7 | Example 5 | |

It was found that embedding properties are good in Examples 40 to 45. On the other hand, it was found that defects are seen in the asperities of the SiO₂ substrate and embedding properties are poor in Comparative Example 7.

### Example Group 1: Examples 46 to 51

Next, a SiO₂ substrate having a film thickness of 300 nm was coated with each composition for underlayer film formation for lithography used in Examples 34 to 39, and baked at 240° C. for 60 seconds and further at 400° C. for 120 seconds to form an underlayer film having a film thickness of 85 nm. This underlayer film was coated with a resist solution for ArF and baked at 130° C. for 60 seconds to form a photoresist layer having a film thickness of 140 nm.

The ArF resist solution used was prepared by containing 5 parts by mass of a compound of the formula (16) given below, 1 part by mass of triphenylsulfonium nonafluoromethanesulfonate, 2 parts by mass of tributylamine, and 92 parts by mass of PGMEA.

The compound of the following formula (16) was prepared as follows. That is, 4.15 g of 2-methyl-2-methacryloyloxyadamantane, 3.00 g of methacryloyloxy-γ-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The product resin thus obtained was solidified and purified, and the resulting white powder was filtered and dried overnight at 40° C. under reduced pressure to obtain a compound represented by the following formula (16).

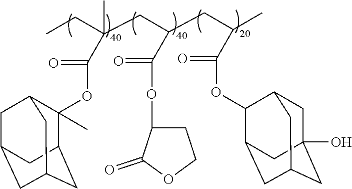

(In the formula (16), 40, 40, and 20 represent the ratio of each constituent unit and do not represent a block copolymer.)

Then, the photoresist layer was exposed using an electron beam lithography system (manufactured by ELIONIX INC.; ELS-7500, 50 keV), baked (PEB) at 115° C. for 90 seconds, and developed for 60 seconds in a 2.38% by mass tetramethylammonium hydroxide (TMAH) aqueous solution to obtain a positive type resist pattern.

### Example Group 1: Comparative Example 8

The same operations as in Example 39 were performed except that no underlayer film was formed so that a photoresist layer was formed directly on a SiO₂ substrate to obtain a positive type resist pattern.

### [Evaluation]

Concerning each of Examples 46 to 51 and Comparative Example 8, the shapes of the obtained 45 nm L/S (1:1) and 80 nm L/S (1:1) resist patterns were observed under an electron microscope manufactured by Hitachi, Ltd. (S-4800). The shapes of the resist patterns after development were evaluated as goodness when having good rectangularity without pattern collapse, and as poorness if this was not the case. The smallest line width having good rectangularity without pattern collapse as a result of this observation was used as an index for resolution evaluation. The smallest electron beam energy quantity capable of lithographing good pattern shapes was used as an index for sensitivity evaluation. The results are shown in Table 10.

TABLE 10

| | Composition for | | | Resist |
|---|---|---|---|---|
| | underlayer film | | | pattern |
| | formation for | Resolution | Sensitivity | shape after |
| | lithography | (nmL/S) | (μC/cm²) | development |
| Example 46 | Example 40 | 45 | 10 | good |
| Example 47 | Example 41 | 45 | 10 | good |
| Example 48 | Example 42 | 45 | 10 | good |
| Example 49 | Example 43 | 45 | 10 | good |
| Example 50 | Example 44 | 45 | 10 | good |
| Example P1F | Example P1E | 45 | 10 | good |
| Example P2F | Example P2E | 45 | 10 | good |
| Example P3F | Example P3E | 45 | 10 | good |
| Example P4F | Example P4E | 45 | 10 | good |
| Example 51 | Example 45 | 45 | 10 | good |
| Comparative | none | 81 | 25 | poor |
| Example 8 | | | | |

As is evident from Table 10, the resist pattern of Examples 46 to 51 was confirmed to be significantly superior in both resolution and sensitivity to Comparative Example 8. Also, the resist pattern shapes after development were confirmed to have good rectangularity without pattern collapse. The difference in the resist pattern shapes after development indicated that the underlayer film forming material for lithography of Examples 40 to 45 has good adhesiveness to a resist material.

### Example Group 1: Example 52

A SiO₂ substrate having a film thickness of 300 nm was coated with the composition for underlayer film formation for lithography used in Example 40, and baked at 240° C. for 60 seconds and further at 400° C. for 120 seconds to form an underlayer film having a film thickness of 90 nm. This underlayer film was coated with a silicon-containing intermediate layer material and baked at 200° C. for 60 seconds to form an intermediate layer film having a film thickness of 35 nm. This intermediate layer film was further coated with the above resist solution for ArF and baked at 130° C. for 60 seconds to form a photoresist layer having a film thickness of 150 nm. The silicon-containing intermediate layer material used was the silicon atom-containing polymer described in <Synthesis Example 1> of Japanese Patent Laid-Open No. 2007-226170.

Then, the photoresist layer was mask exposed using an electron beam lithography system (manufactured by ELIONIX INC.; ELS-7500, 50 keV), baked (PEB) at 115° C. for 90 seconds, and developed for 60 seconds in 2.38% by mass tetramethylammonium hydroxide (TMAH) aqueous solution to obtain a 45 nm L/S (1:1) positive type resist pattern.

Thereafter, the silicon-containing intermediate layer film (SOG) was dry etched with the obtained resist pattern as a mask using RIE-10NR manufactured by Samco International, Inc. Subsequently, dry etching of the underlayer film with the obtained silicon-containing intermediate layer film pattern as a mask and dry etching of the SiO₂ film with the obtained underlayer film pattern as a mask were performed in order.

Respective etching conditions are as shown below.

Etching conditions for resist intermediate layer film with resist pattern
Output: 50 W
Pressure: 20 Pa
Time: 1 min

Etching Gas
Ar gas flow rate:CF₄ gas flow rate:O₂ gas flow rate=50:8:2 (sccm)

Etching conditions for resist underlayer film with resist intermediate film pattern
Output: 50 W
Pressure: 20 Pa
Time: 2 min

Etching Gas
Ar gas flow rate:CF₄ gas flow rate:O₂ gas flow rate=50:5:5 (sccm)

Etching conditions for SiO₂ film with resist underlayer film pattern
Output: 50 W
Pressure: 20 Pa
Time: 2 min

Etching Gas
Ar gas flow rate:C₅F₁₂ gas flow rate:C₂F₆ gas flow rate:O₂ gas flow rate=50:4:3:1 (sccm)

### [Evaluation]

The pattern cross section (the shape of the SiO₂ film after etching) of Example 52 obtained as described above was observed under an electron microscope manufactured by Hitachi, Ltd. (S-4800). As a result, it was confirmed that the shape of the SiO₂ film after etching in a multilayer resist process is a rectangular shape in Examples using the underlayer film of the present invention and is good without defects.

### <Characteristic Evaluation of Resin Film (Resin Single Film)>

### <Preparation of Resin Film>

### Example Group 1: Example A01

Using PGMEA as a solvent, the resin RBisP-1 of Synthesis Working Example 1 was dissolved to prepare a resin solution having a solid content concentration of 10% by mass (resin solution of Example A01).

The prepared resin solution was formed on a 12 inch silicon wafer using a spin coater Lithius Pro (manufactured by Tokyo Electron Ltd.), and after forming a film while adjusting the number of revolutions so as to have a film thickness of 200 nm, the baking was performed under the condition of a baking temperature of 250° C. for 1 minute to prepare a substrate on which a film made of the resin of Synthesis Example 1 was laminated. The prepared substrate was further baked under the condition of 350° C. for 1 minute using a hot plate capable of treating at a high temperature to obtain a cured resin film. At this time, when the change in film thickness before and after immersing the obtained cured resin film in the PGMEA tank for 1 minute was 3% or less, it was determined that the film was cured. When the curing was determined to be insufficient, the curing temperature was changed by 50° C. to investigate the curing temperature, and baking for curing was performed under the condition of the lowest temperature in the curing temperature range.

### <Optical Characteristic Values Evaluation>

The prepared resin film was evaluated for optical characteristic values (refractive index n and extinction coefficient k as optical constants) using spectroscopic ellipsometry VUV-VASE (manufactured by J.A. Woollam).

### Example Group 1: Example A02 to Example A05 and Comparative Example A01

The resin film was prepared in the same manner as in Example A01 except that the resins used were changed from RBisP-1 to the resins shown in Table 11, and the optical characteristic values were evaluated.

[Evaluation Criteria] Refractive Index n
A: 1.4 or more
C: less than 1.4

[Evaluation Criteria] Extinction Coefficient k
A: less than 0.5
C: 0.5 or more

TABLE 11

| | |
|---|---|
| Resin | Optical characteristic values |

| | used | n | k |
|---|---|---|---|
| Example A01 | RBisP-1 | A | A |
| Example A02 | RBisP-2 | A | A |
| Example A03 | RBisP-3 | A | A |
| Example A04 | RBisP-4 | A | A |
| Example AP01 | R-PP-1 | A | A |
| Example AP02 | R-PP-2 | A | A |
| Example AP03 | R-PP-3 | A | A |
| Example AP04 | R-PP-4 | A | A |
| Example A05 | RBisP-5 | A | A |
| Comparative | CR-1 | C | C |
| Example A01 | | | |

From the results of Examples A01 to A05, it was found that a resin film having a high n-value and a low k-value at wavelengths 193 nm used in ArF exposure can be formed by the composition for film formation containing the polycyclic polyphenolic resin of the present embodiment.

### <Heat Resistance Evaluation of Cured Film>

### Example Group 1: Example B01

The heat resistance of the resin film prepared in Example A01 was evaluated by using a lamp annealing oven. For the conditions for heat resistance treatment, the heat treatment was continued at 450° C. under a nitrogen atmosphere, and the film thickness change rate was obtained during the elapsed time of 4 minutes and 10 minutes from the start of heating. The heating was continued at 550° C. under a nitrogen atmosphere, and the film thickness change rate was obtained during the elapsed time of 4 minutes and 550° C. 10 minutes from the start of heating. These film thickness change rates were evaluated as indicators of the heat resistance of the cured film. The film thicknesses before and after the heat resistance test were measured by an interference film thickness meter, and a ratio of the fluctuation value of the film thickness to the film thickness before the heat resistance test treatment was defined as a film thickness change rate (%).

[Evaluation Criteria]
A: Film thickness change rate is less than 10%.
B: Film thickness change rate is 10% to 15%.
C: Film thickness change rate is more than 15%.

### Example Group 1: Example B02 to Example B05 and Comparative Example B01 to Comparative Example B02

Heat resistance was evaluated in the same manner as in Example B01 except that the resins used were changed from RBisP-1 to the resins shown in Table 12.

TABLE 12

| | |
|---|---|
| | Cured film heat resistance Film |
| Resin | thickness change rate % |

| | used | 450° C. | 550° C. |
|---|---|---|---|
| Example B01 | RBisP-1 | A | A |
| Example B02 | RBisP-2 | A | A |
| Example B03 | RBisP-3 | A | A |
| Example B04 | RBisP-4 | A | A |
| Example BP01 | R-PP-1 | A | B |
| Example BP02 | R-PP-2 | A | A |
| Example BP03 | R-PP-3 | A | A |
| Example BP04 | R-PP-4 | B | B |
| Example B05 | RBisP-5 | A | A |
| Comparative | CR-1 | C | C |
| Example B01 | | | |
| Comparative | NBisN-1 | B | B |
| Example B02 | | | |

### Example Group 1: Example C01

### <Evaluation of PE-CVD Film Formation>

A 12 inch silicon wafer was subjected to thermal oxidation treatment, and a resin film was formed on the substrate having the obtained silicon oxide film by the same method as in Example A01 using the resin solution of Example A01 with a thickness of 100 nm. A silicon oxide film having a film thickness of 70 nm was formed on the resin film using a film forming apparatus TELINDY (manufactured by Tokyo Electron Ltd.) and tetraethylsiloxane (TEOS) as a raw material at a substrate temperature of 300° C. The wafer with the cured film in which the prepared silicon oxide film was laminated was further subjected to defect inspection using KLA-Tencor SP-5, and the number of defects of the formed oxide film was evaluated using the number of defects of 21 nm or more as an index.
A number of defects 20
B 20<number of defects≤50
C 50<number of defects≤100
D 100<number of defects≤1000
E 1000<number of defects≤5000
F 5000<number of defects

### <SiN Film>

On a cured film formed on a substrate having a silicon oxide film thermally oxidized on a 12 inch silicon wafer with a thickness of 100 nm by the same method as described above, a film forming apparatus TELINDY (manufactured by Tokyo Electron Ltd.) was used to form a SiN film having a thickness of 40 nm, a refractive index of 1.94, and a film stress of −54 MPa at a substrate temperature of 350° C. using SiH₄ (monosilane) and ammonia as raw materials. The wafer with the cured film in which the prepared SiN film was laminated was further subjected to defect inspection using KLA-Tencor SP-5, and the number of defects of the formed oxide film was evaluated using the number of defects of 21 nm or more as an index.
A number of defects≤20
B 20<number of defects≤50
C 50<number of defects≤100
D 100<number of defects≤1000
E 1000<number of defects≤5000
F 5000<number of defects

### Example Group 1: Example C02 to Example CPO4 and Comparative Example C01 to Comparative Example C02

Heat resistance was evaluated in the same manner as in Example C01 except that the resins used were changed from RBisP-1 to the resins shown in Table 13.

TABLE 13

PE-CVD defect evaluation

| | Resin | Oxide | |
|---|---|---|---|
| | used | film | SiN |
| Example C01 | RBisP-1 | B | B |
| Example C02 | RBisP-2 | B | B |
| Example C03 | RBisP-3 | B | B |
| Example C04 | RBisP-4 | B | B |
| Example C05 | RBisP-5 | B | B |
| Example CP01 | R-PP-1 | A | A |
| Example CP02 | R-PP-2 | A | A |
| Example CP03 | R-PP-3 | B | B |
| Example CP04 | R-PP-4 | A | A |
| Comparative | CR-1 | F | F |
| Example C01 | | | |
| Comparative | NBisN-2 | E | E |
| Example C02 | | | |

In the silicon oxide film or SiN film formed on the resin film of Examples C01 to CP04, the number of defects of 21 nm or more was 50 or less (evaluation B or higher), which was smaller than the number of defects of Comparative Examples C01 or C02.

### Example Group 1: Example D01

<Etching Evaluation after High Temperature Treatment>

A 12 inch silicon wafer was subjected to thermal oxidation treatment, and a resin film was formed on the substrate having the obtained silicon oxide film by the same method as in Example A01 using the resin solution of Example A01 with a thickness of 100 nm. The resin film was further annealed by heating under the condition of 600° C. for 4 minutes using a hot plate which can be further treated at a high temperature in a nitrogen atmosphere to prepare a wafer on which the annealed resin film was laminated. The prepared annealed resin film was carved out, and the carbon content was determined by elemental analysis.

Furthermore, a 12 inch silicon wafer was subjected to thermal oxidation treatment, and a resin film was formed on the substrate having the obtained silicon oxide film by the same method as in Example A01 using the resin solution of Example A01 with a thickness of 100 nm. The resin film was further annealed by heating under the condition of 600° C. for 4 minutes under a nitrogen atmosphere to form a resin film, and then the substrate was subjected to an etching treatment using an etching apparatus TELIUS (manufactured by Tokyo Electron Ltd.) under the conditions of using CF₄/Ar as an etching gas and Cl₂/Ar as an etching gas to evaluate an etching rate. The etching rate was evaluated by using a resin film having a film thickness of 200 nm formed by annealing SU8 (manufactured by Nippon Kayaku Co., Ltd.) at 250° C. for 1 minute as a reference and determining the ratio of the etching rate to the SU8 as a relative value.

### Example Group 1: Example D02 to Example DP04 and Comparative Example D01 to Comparative Example D02

Heat resistance was evaluated in the same manner as in Example D01 except that the resins used were changed from RBisN-1 to the resins shown in Table 14.

TABLE 14

| | | | Etching rate | |
|---|---|---|---|---|
| | | | evaluation(relative | |
| | | | value) | |
| | Resin | Carbon | CF₄/ | Cl₂/ |
| | used | content(%) | Ar | Ar |
| Example D01 | RBisP-1 | A | A | A |
| Example D02 | RBisP-2 | A | A | A |
| Example D03 | RBisP-3 | A | A | A |
| Example D04 | RBisP-4 | A | A | A |
| Example D05 | RBisP-5 | A | A | A |
| Example DP01 | R-PP-1 | B | A | A |
| Example DP02 | R-PP-2 | B | S | S |
| Example DP03 | R-PP-3 | A | S | S |
| Example DP04 | R-PP-4 | B | B | B |
| Comparative | CR-1 | B | B | B |
| Example D01 | | | | |
| Comparative | NBisN-1 | B | B | B |
| Example D02 | | | | |

### <Evaluation of Etching Defects on Laminated Film>

The polycyclic polyphenolic resin obtained in Synthesis Example was subjected to quality evaluation before and after the purification treatment. That is, the resin film formed on the wafer using the polycyclic polyphenolic resin was transferred to the substrate side by etching, and then subjected to defect evaluation to evaluate.

A 12-inch silicon wafer was subjected to thermal oxidation treatment to obtain a substrate having a silicon oxide film having a thickness of 100 nm. The resin solution of the polycyclic polyphenolic resin was formed on the substrate by adjusting the spin coating conditions so as to have a thickness of 100 nm, followed by baking at 150° C. for 1 minute, and then baking at 350° C. for 1 minute to prepare a laminated substrate in which the polycyclic polyphenolic resin was laminated on silicon with a thermal oxide film.

Using TELIUS (manufactured by Tokyo Electron Ltd.) as an etching apparatus, the resin film was etched under the condition of CF₄/O₂/Ar to expose the substrate on the surface of the oxide film. Further, an etching treatment was performed under the condition that the oxide film was etched by 100 nm at the gas composition ratio of CF₄/Ar to prepare an etched wafer.

The prepared etched wafer was measured for the number of defects of 19 nm or more with a defect inspection device SP5 (manufactured by KLA-Tencor Corporation), and was subjected to defect evaluation by etching treatment of the laminated film.
A number of defects≤20
B 20<number of defects≤50
C 50<number of defects≤100
D 100<number of defects≤1000
E 1000<number of defects≤5000
F 5000<number of defects

### (Example Group 1: Example E01) Purification of RBisN-1 with Acid

In a four necked flask (capacity: 1000 mL, with a detachable bottom), 150 g of a solution (10% by mass) formed by dissolving RBisP-1 obtained in Synthesis Working Example 1 in PGMEA was charged, and was heated to 80° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Thereafter, by diluting with PGMEA of EL grade (a reagent manufactured by KANTO CHEMICAL CO., INC.) such that the concentration of the PGMEA solution was adjusted to 10% by mass, a PGMEA solution of RBisP-1 with a reduced metal content was obtained. The polycyclic polyphenolic resin solution thus prepared was filtered with a UPE filter having a nominal pore size of 3 nm, manufactured by Entegris Japan Co., Ltd., under a condition of 0.5 MPa, to prepare a solution sample.

For each of the solution samples before and after the purification treatment, a resin film was formed on the wafer as described above, the resin film was transferred to the substrate side by etching, and then etching defect evaluation on the laminated film was carried out.

### (Example Group 1: Example E02) Purification of RBisN-2 with Acid

In a four necked flask (capacity: 1000 mL, with a detachable bottom), 140 g of a solution (10% by mass) formed by dissolving RBisP-2 obtained in Synthesis Working Example 2 in PGMEA was charged, and was heated to 60° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Thereafter, by diluting with PGMEA of EL grade (a reagent manufactured by KANTO CHEMICAL CO., INC.) such that the concentration of the PGMEA solution was adjusted to 10% by mass, a PGMEA solution of RBisP-2 with a reduced metal content was obtained. The polycyclic polyphenolic resin solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out.

### (Example Group 1: Example E03) Purification by Passing Through Filter

In a class 1000 clean booth, 500 g of a solution of 10% by mass concentration of the resin (RBisP-1) obtained in Synthesis Working Example 1 dissolved in propylene glycol monomethyl ether (PGME) was charged in a four necked flask (capacity: 1000 mL, with a detachable bottom), and then the air inside the vessel was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 100 mL per minute to a hollow fiber membrane filter (manufactured by KITZ MICRO FILTER CORPORATION, product name: Polyfix Nylon Series) made of nylon with a nominal pore size of 0.01 μm under a filtration pressure of 0.5 MPa by pressure filtration. By diluting the resin solution after filtration with PGMEA of EL grade (a reagent manufactured by KANTO CHEMICAL CO., INC.) such that the concentration of the PGMEA solution was adjusted to 10% by mass, a PGMEA solution of RBisP-1 with a reduced metal content was obtained. The polycyclic polyphenolic resin solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out. The oxygen concentration was measured with an oxygen concentration meter “OM-25MF10” manufactured by AS ONE Corporation (the same applies hereinafter).

### Example Group 1: Example E04

As the purification step by the filter, IONKLEEN manufactured by Nihon Pall Ltd., NYLON FILTER manufactured by Nihon Pall Ltd., and a UPE filter with a nominal pore size of 3 nm manufactured by Entegris Japan Co., Ltd. were connected in series in this order to construct a filter line. In the same manner as in Example E03, except that the prepared filter line was used instead of the 0.1 μm hollow fiber membrane filter made of nylon, the solution was passed by pressure filtration so that the conditions of the filtration pressure was 0.5 MPa. By diluting with PGMEA of EL grade (a reagent manufactured by KANTO CHEMICAL CO., INC.) such that the concentration of the PGMEA solution was adjusted to 10% by mass, a PGMEA solution of RBisP-1 with a reduced metal content was obtained. The polycyclic polyphenolic resin solution thus prepared was subjected to pressure filtration with a UPE filter having a nominal pore size of 3 nm, manufactured by Entegris Japan Co., Ltd., under a condition of the filtration pressure of 0.5 MPa, to prepare a solution sample, and then etching defect evaluation on the laminated film was carried out.

### Example Group 1: Example E05

The solvent sample prepared in Example E01 was further subjected to pressure filtration with the filter line prepared in Example E04 under a condition of the filtration pressure of 0.5 MPa, to prepare a solution sample, and then etching defect evaluation on the laminated film was carried out.

### Example Group 1: Example E06

For the RBisP-2 prepared in Synthesis Working Example 2, a solution sample purified by the same method as in Example E05 was prepared, and then etching defect evaluation on the laminated film was carried out.

### Example Group 1: Example E07

For the RBisP-3 prepared in Synthesis Working Example 3, a solution sample purified by the same method as in Example E05 was prepared, and then etching defect evaluation on the laminated film was carried out.

TABLE 15

PE-CVD defect evaluation

| | | Before | After |
|---|---|---|---|
| | Resin | purification | purification |
| | used | treatment | treatment |
| Example E01 | RBisP-1 | A | A |
| Example E02 | RBisP-2 | A | A |
| Example E03 | RBisP-1 | A | A |
| Example E04 | RBisP-1 | A | A |
| Example E05 | RBisP-1 | A | A |
| Example E06 | RBisP-2 | A | A |
| Example E07 | RBisP-3 | A | A |

### Example Group 1: Examples 53 to 58

A SiO₂ substrate having a film thickness of 300 nm was coated with the composition for optical component formation having the same composition as that of the solution of the underlayer film forming material for lithography prepared in each of the above Examples 34 to 39 and Comparative Example 5, and baked at 260° C. for 300 seconds to form each film for optical components with a film thickness of 100 nm. Then, tests for the refractive index and the transparency at a wavelength of 633 nm were carried out by using a vacuum ultraviolet with variable angle spectroscopic ellipsometer (VUV-VASE) manufactured by J.A. Woollam Japan, and the refractive index and the transparency were evaluated according to the following criteria. The evaluation results are shown in Table 16.

[Evaluation Criteria for Refractive Index]
A: The refractive index is 1.65 or more
C: The refractive index is less than 1.65

[Evaluation Criteria for Transparency]
A: The absorption coefficient is less than 0.03.
C: The absorption coefficient is 0.03 or more.

TABLE 16

| | Optical member forming | Refractive | |
|---|---|---|---|
| | composition | index | Transparency |
| Example 53 | same composition as | A | A |
| | Example 34 | | |
| Example 54 | same composition as | A | A |
| | Example 35 | | |
| Example 55 | same composition as | A | A |
| | Example 36 | | |
| Example 56 | same composition as | A | A |
| | Example 37 | | |
| Example 57 | same composition as | A | A |
| | Example 38 | | |
| Example 5P1 | same composition as | A | A |
| | Example P1D | | |
| Example 5P2 | same composition as | A | A |
| | Example P2D | | |
| Example 5P3 | same composition as | A | A |
| | Example P3D | | |
| Example 5P4 | same composition as | A | A |
| | Example P4D | | |
| Example 58 | Example 39 | A | A |
| Comparative | same composition as | C | C |
| Example 9 | Comparative Example 5 | | |

It was found that the compositions for optical component formation of Examples 53 to 58 not only had a high refractive index but also a low absorption coefficient and excellent transparency. On the other hand, it was found that the composition of Comparative Example 9 was inferior in performance as an optical member.

### Example Group 2

### (Example Group 2: Synthesis Example 1) Synthesis of BisN-1

To a container (internal capacity: 500 mL) equipped with a stirrer, a condenser tube, and a burette, 42.8 g (200 mmol) of 3,3′-dimethylbiphenyl-4,4′-diol (manufactured by Honshu Chemical Industry Co., Ltd.), 18.2 g (100 mmol) of 4-biphenylaldehyde (manufactured by MITSUBISHI GAS CHEMICAL COMPANY, INC.), and 200 mL of 1,4-dioxane were added, and 10 mL of 95% sulfuric acid was added. The reaction solution was stirred at 100° C. for 6 hours and reacted. Next, the reaction solution was neutralized with 24% aqueous sodium hydroxide solution. The reaction product was precipitated by the addition of 100 g of pure water. After cooling to room temperature, the precipitates were separated by filtration. The obtained solid matter was dried and then separated and purified by column chromatography to obtain 25.5 g of the objective compound (BisP-1) represented by the following formula.

The following peaks were found by 400 MHz-1H-NMR, and the compound was confirmed to have a chemical structure of the following formula.

¹H-NMR: (d-DMSO, internal standard TMS)

δ (ppm) 9.1 (4H, O—H), 7.2-8.5 (19H, Ph-H), 5.6 (1H, C—H), 2.1 (12H, —CH₃)

LC-MS analysis confirmed that the molecular weight was 592 corresponding to the following chemical structure.

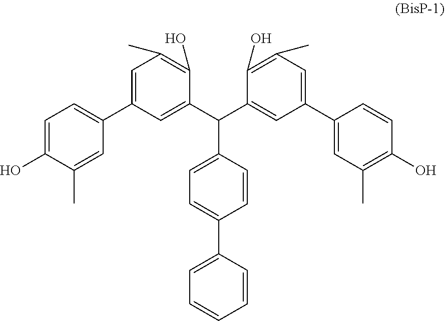 [SMILES: Cc1cc(-c2cc(C)c(O)c(C(c3ccc(-c4ccccc4)cc3)c3cc(-c4ccc(O)c(C)c4)cc(C)c3O)c2)ccc1O]

### (Example Group 2: Synthesis Examples 2 to 5, and 5-1) Synthesis of BisP-2 to BisP-5

Objective compound (BisP-2), (BisP-3), (BisP-4), or (BisP-5) represented by the following formulas was obtained in the same manner as in Synthesis Example 1 except that benzaldehyde, p-methylbenzaldehyde, 1-naphthaldehyde, or 2-naphthaldehyde was used instead of biphenylaldehyde, respectively.

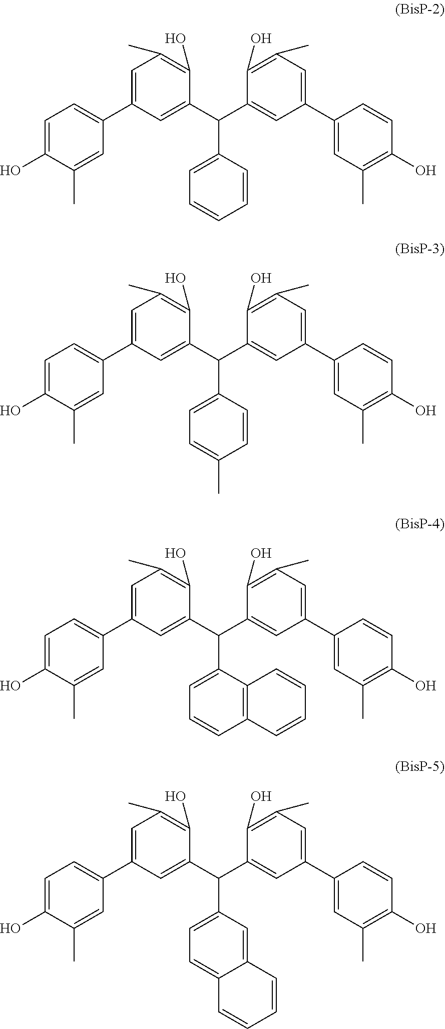 [SMILES: Cc1cc(-c2cc(C)c(O)c(C(c3ccccc3)c3cc(-c4ccc(O)c(C)c4)cc(C)c3O)c2)ccc1O ; Cc1ccc(C(c2cc(-c3ccc(O)c(C)c3)cc(C)c2O)c2cc(-c3ccc(O)c(C)c3)cc(C)c2O)cc1 ; Cc1cc(-c2cc(C)c(O)c(C(c3cc(-c4ccc(O)c(C)c4)cc(C)c3O)c3cccc4ccccc34)c2)ccc1O ; Cc1cc(-c2cc(C)c(O)c(C(c3ccc4ccccc4c3)c3cc(-c4ccc(O)c(C)c4)cc(C)c3O)c2)ccc1O]

### (Example Group 2: Synthesis Working Example 1) Synthesis of RBisP-1

To a container (internal capacity: 500 mL) equipped with a stirrer, a condenser tube, and a burette, 50 g (105 mmol) of BisP-1 and 10.1 g (20 mmol) of monobutylcopper phthalate were added, and 100 mL of 1-butanol was added as a solvent. The reaction solution was stirred at 100° C. for 6 hours and reacted. After cooling, the precipitate was filtered and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 200 mL of methanol was added to precipitate the reaction product. After cooling to room temperature, the precipitates were separated by filtration. The obtained solid matter was dried to obtain 38.0 g of the objective resin (RBisP-1) having a structure represented by the following formula.

The polystyrene equivalent molecular weight of the obtained resin was measured by the method described above, and as a result, the obtained resin had Mn: 1096, Mw: 1422, and Mw/Mn: 1.30.

The following peaks were found by NMR measurement performed on the obtained resin under the above measurement conditions, and the resin was confirmed to have a chemical structure of the following formula.

δ (ppm) 9.1 (4H, O—H), 7.2-8.5 (17H, Ph-H), 5.6 (1H, C—H), 2.1 (12H, —CH₃)

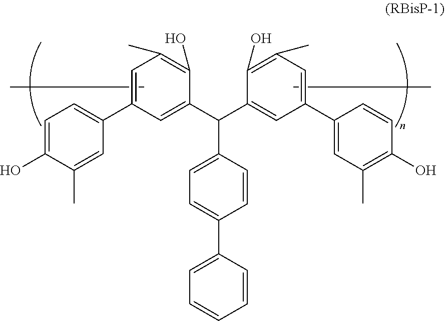

### (Example Group 2: Synthesis Working Examples 2 to 6) Synthesis of RBisP-2 to RBisP-5 and RBP-1

Objective compounds (RBisP-2), (RBisP-3), (RBisP-4), (RBisP-5), and (RBP-1) represented by the following formulas were obtained in the same manner as in Synthesis Working Example 1 except that BisP-2, BisP-3, BisP-4, BisP-5, and 3,3′-dimethylbiphenyl-4,4′-diol (BP-1) were used instead of BisP-1, respectively.

In the following RBisP-2 to RBisP-5 and RBP-1, the following peaks were found by 400 MHz-1H-NMR, and the compound was confirmed that each had the chemical structure of the following formulas. Further, the results of measuring the polystyrene equivalent molecular weight by the above method for each of the obtained resins are also shown.

### RBisP-2

Mn: 2100, Mw: 2890, Mw/Mn: 1.38

δ (ppm) 9.0 (4H, O—H), 7.2-8.4 (13H, Ph-H), 5.6 (1H, C—H), 2.1 (12H, —CH₃)

### RBisP-3

Mn: 2226, Mw: 2988, Mw/Mn: 1.34

δ (ppm) 9.0 (4H, O—H), 7.3-8.6 (12H, Ph-H), 5.5 (1H, C—H), 2.1 (15H, —CH₃)

### RBisP-4

Mn: 1812, Mw: 2648, Mw/Mn: 1.46

δ (ppm) 9.4 (4H, O—H), 7.2-8.5 (15H, Ph-H), 5.6 (1H, C—H), 2.1 (12H, —CH₃)

### RBisP-5

Mn: 1856, Mw: 2654, Mw/Mn: 1.43

δ (ppm) 9.4 (4H, O—H), 7.2-8.5 (15H, Ph-H), 5.6 (1H, C—H), 2.1 (12H, —CH₃)

### RBP-1 Mn: 1322, Mw: 1688, Mw/Mn: 1.28

δ (ppm) 9.5 (2H, O—H), 6.9-7.6 (4H, Ph-H), 2.1 (6H, —CH₃)

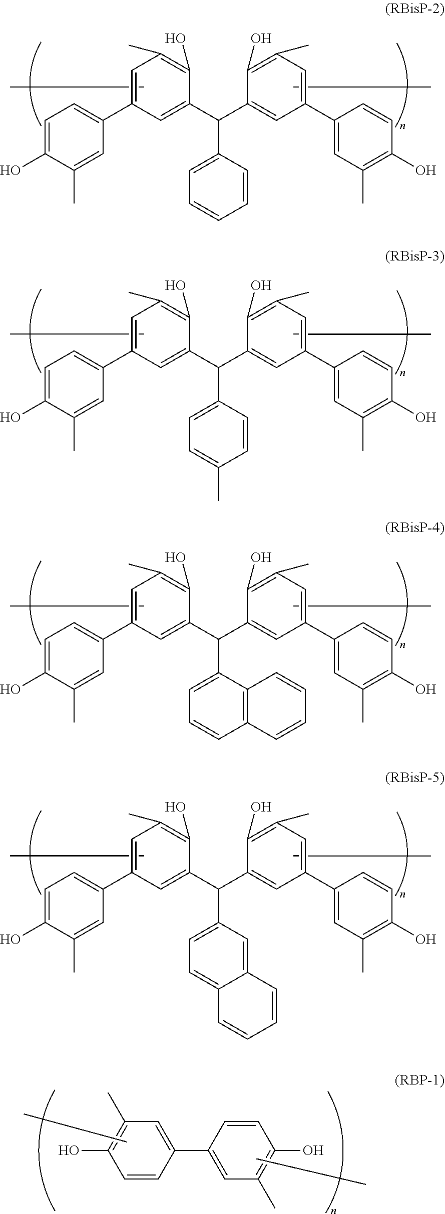

### (Example Group 2: Comparative Synthesis Example 1) Synthesis of NBisN-1

To a container (internal capacity: 500 mL) equipped with a stirrer, a condenser tube, and a burette, 32.0 g (200 mmol) of 2,7-naphthalenediol (reagent manufactured by Sigma-Aldrich), 18.2 g (100 mmol) of 4-biphenylaldehyde (manufactured by MITSUBISHI GAS CHEMICAL COMPANY, INC.), and 200 mL of 1,4-dioxane were added, and 10 mL of 95% sulfuric acid was added. The reaction solution was stirred at 100° C. for 6 hours and reacted. Next, the reaction solution was neutralized with 24% aqueous sodium hydroxide solution. The reaction product was precipitated by the addition of 100 g of pure water. After cooling to room temperature, the precipitates were separated by filtration. The obtained solid matter was dried and then separated and purified by column chromatography to obtain 25.5 g of the objective compound (BisN-1) represented by the following formula.

The following peaks were found by 400 MHz-1H-NMR, and the compound was confirmed to have a chemical structure of the following formula. From the doublets of proton signals at positions 3 and 4, it was confirmed that the substitution position of 2,7-dihydroxynaphthol was position 1.

¹H-NMR: (d-DMSO, internal standard TMS)

δ (ppm) 9.6 (2H, O—H), 7.2-8.5 (19H, Ph-H), 6.6 (1H, C—H)

LC-MS analysis confirmed that the molecular weight was 466 corresponding to the following chemical structure.

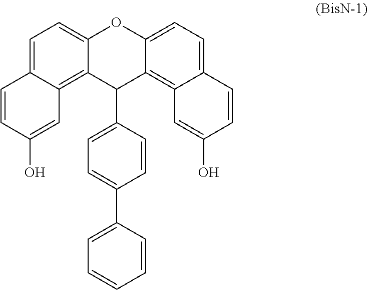 [SMILES: Oc1ccc2ccc3c(c2c1)C(c1ccc(-c2ccccc2)cc1)c1c(ccc2ccc(O)cc12)O3]

To a container (internal capacity: 100 ml) equipped with a stirrer, a condenser tube, and a burette, 10 g (21 mmol) of BisN-1, 0.7 g (42 mmol) of paraformaldehyde, 50 mL of glacial acetic acid, and 50 mL of PGME were added, and 8 mL of 95% sulfuric acid was added thereto. The reaction solution was stirred at 100° C. for 6 hours and reacted. Next, the reaction solution was concentrated and 1000 mL of methanol was added to precipitate the reaction product. After cooling to room temperature, the precipitates were separated by filtration. The obtained solid matter was filtered and dried to obtain 7.2 g of the objective resin (NBisN-1) having a structure represented by the following formula.

The polystyrene equivalent molecular weight of the obtained resin was measured by the method described above, and as a result, the obtained resin had Mn: 1278, Mw: 1993, and Mw/Mn: 1.56.

The following peaks were found by NMR measurement performed on the obtained resin under the above measurement conditions, and the resin was confirmed to have a chemical structure of the following formula.

δ (ppm) 9.7 (2H, O—H), 7.2-8.5 (17H, Ph-H), 6.6 (1H, C—H), 4.1 (2H, —CH2)

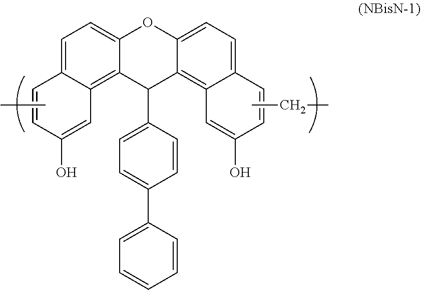

### Example Group 2: Comparative Synthesis Example 2

In the same manner as in Comparative Synthesis Example 2 of Example Group 1, 126.1 g of modified resin (CR-1) was obtained as a black-brown solid.

### (Example Group 2: Comparative Synthesis Example 3) Synthesis of RBisP-6

Objective compound (BisP-6) represented by the following formula was obtained in the same manner as in Synthesis Working Example 1, except that 4,4′-biphenol was used instead of 3,3′-dimethylbiphenyl-4,4′-diol.

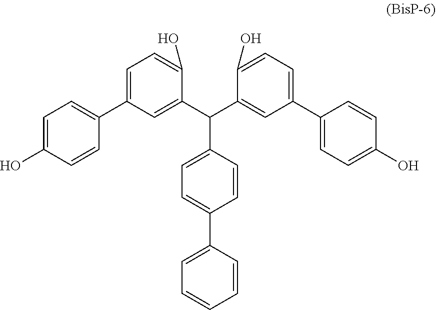 [SMILES: Oc1ccc(-c2ccc(O)c(C(c3ccc(-c4ccccc4)cc3)c3cc(-c4ccc(O)cc4)ccc3O)c2)cc1]

Objective compound (RBisP-6) represented by the following formula was obtained in the same manner as in Synthesis Working Example 1 except that BisP-6 was used instead of BisP-1.

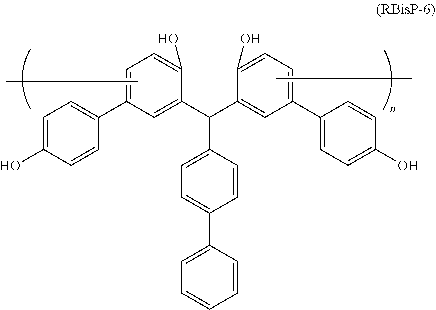

### Example Group 2: Examples 1 to 5-1

Table 1A shows the results of evaluating the heat resistance by the evaluation methods shown below using the resins obtained in Synthesis Example 1 to Synthesis Example 5 and Comparative Synthesis Example 1.

### <Measurement of Thermal Decomposition Temperature>

EXSTAR 6000 TG/DTA apparatus manufactured by SII NanoTechnology Inc. was used. About 5 mg of a sample was placed in an unsealed container made of aluminum, and the temperature was raised to 700° C. at a temperature increase rate of 10° C./min in a nitrogen gas stream (30 mL/min). The temperature at which a heat loss of 10% by mass was observed was defined as the thermal decomposition temperature (Tg), and the heat resistance was evaluated according to the following criteria.
Evaluation A: The thermal decomposition temperature was 430° C. or higher
Evaluation B: The thermal decomposition temperature was 320° C. or higher
Evaluation C: The thermal decomposition temperature was lower than 320° C.

TABLE 1A

| | | | Heat |
|---|---|---|---|
| | | | resistance |
| | Resin | | evaluation |
| Example 1 | Synthesis Working | RBisP-1 | A |
| | Example 1 | | |
| Example 2 | Synthesis Working | RBisP-2 | A |
| | Example 2 | | |
| Example 3 | Synthesis Working | RBisP-3 | A |
| | Example 3 | | |
| Example 4 | Synthesis Working | RBisP-4 | A |
| | Example 4 | | |
| Example 5 | Synthesis Working | RBisP-5 | A |
| | Example 5 | | |
| Example 5-1 | Synthesis Working | RBP-1 | A |
| | Example 6 | | |
| Comparative | Comparative | NBisN-1 | C |
| Example 1 | Synthesis Example 1 | | |

As is evident from Table 1A, it was able to be confirmed that the resins used in Example 1 to Example 5-1 have good heat resistance whereas the resins used in Comparative Example 1 is inferior in heat resistance.

### Example Group 2: Examples 6 to 10 and Comparative Example 2

### (Preparation of Composition for Underlayer Film Formation for Lithography)

Compositions for underlayer film formation for lithography were prepared according to the composition shown in Table 2A. Next, a silicon substrate was spin coated with each of these compositions for underlayer film formation for lithography, and then baked at 240° C. for 60 seconds and further at 400° C. for 120 seconds under a nitrogen gas atmosphere to prepare each underlayer film having a film thickness of 200 to 250 nm.

Next, etching test was conducted under conditions shown below to evaluate etching resistance. The evaluation results are shown in Table 2A. Details of the evaluation method will be described later.

### <Etching Test>

Etching apparatus: “RIE-10NR” manufactured by Samco International, Inc.
Output: 50 W
Pressure: 20 Pa
Time: 2 min

Etching Gas
Ar gas flow rate:CF₄ gas flow rate:O₂ gas flow rate=50:5:5 (sccm)

### (Evaluation of Etching Resistance)

The evaluation of etching resistance was conducted by the following procedures. First, an underlayer film of novolac was prepared under the same conditions as described above except that novolac (“PSM4357” manufactured by Gun Ei Chemical Industry Co., Ltd.) was used. This underlayer film of novolac was subjected to the above etching test, and the etching rate was measured.

Next, underlayer films of Example 6 to Example 10 and Comparative Example 2 were prepared under the same conditions as the underlayer films of novolac and subjected to the etching test described above in the same way as above, and the etching rate was measured. Then, the etching resistance for each of Examples and Comparative Example was evaluated according to the following evaluation criteria on the basis of the etching rate of the underlayer film of novolac.

[Evaluation Criteria]
A: The etching rate was less than −20% as compared with the underlayer film of novolac.
B: The etching rate was −20% or more and 0% or less as compared with the underlayer film of novolac.
C: The etching rate was more than +0% as compared with the underlayer film of novolac.

TABLE 2A

| | Resin (parts | | Solvent (parts | Etching |
|---|---|---|---|---|
| | by mass) | | by mass) | evaluation |
| Example 6 | Synthesis Working | RBisP-1 | PGMEA | A |
| | Example 1 | (10) | (90) | |
| Example 7 | Synthesis Working | RBisP-2 | PGMEA | A |
| | Example 2 | (10) | (90) | |
| Example 8 | Synthesis Working | RBisP-3 | PGMEA | A |
| | Example 3 | (10) | (90) | |
| Example 9 | Synthesis Working | RBisP-4 | PGMEA | A |
| | Example 4 | (10) | (90) | |
| Example 10 | Synthesis Working | RBisP-5 | PGMEA | A |
| | Example 5 | (10) | (90) | |
| Example 10-1 | Synthesis Working | RBP-1 | PGMEA | A |
| | Example 6 | (10) | (90) | |
| Comparative | Comparative | NBisN-1 | cyclohexanone | B |
| Example 2 | Synthesis Example 1 | (10) | (90) | |

It was found that an excellent etching rate is exerted in Example 6 to Example 10-1 as compared with the underlayer film of novolac and the resin of Comparative Example 2. On the other hand, it was found that the etching rate of the resin of Comparative Example 2 was equivalent to that of the underlayer film of novolac.

### <<Purification of Polycyclic Polyphenolic Resin (Composition Containing Polycyclic Polyphenolic Resin)>>

The metal content before and after purification of polycyclic polyphenolic resin (composition containing the polycyclic polyphenolic resin) and the storage stability of the solution were evaluated by the following method.

### <Measurement of Various Metal Contents>

The metal contents of the propylene glycol monomethyl ether acetate (PGMEA) solutions of various resins obtained in the following Examples and Comparative Examples were measured using inductively coupled plasma mass spectrometry (ICP-MS) under the following measurement conditions.
Apparatus: AG8900 manufactured by Agilent Technologies
Temperature: 25° C.
Environment: Class 100 clean room

### <Storage Stability Evaluation>

The PGMEA solutions obtained in the following Examples and Comparative Examples were retained at 23° C. for 240 hours, and then the turbidity (HAZE) of the solutions was measured using a color difference/turbidity meter to evaluate the storage stability of the solutions according to the following criteria.
Apparatus: Color difference/turbidity meter COH400 (manufactured by NIPPON DENSHOKU INDUSTRIES CO., LTD.)
Optical path length: 1 cm

Quartz Cell Use

### [Evaluation Criteria]

0≤HAZE≤1.0: Good
1.0<HAZE≤2.0: Fair
2.0<HAZE: Poor

### (Example Group 2: Example 11) Purification of RBisP-1 with Acid

In a four necked flask (capacity: 1000 mL, with a detachable bottom), 150 g of a solution (10% by mass) formed by dissolving RBisP-1 obtained in Synthesis Working Example 1 in PGMEA was charged, and was heated to 80° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Thereafter, by diluting with PGMEA of EL grade (a reagent manufactured by KANTO CHEMICAL CO., INC.) such that the concentration of the PGMEA solution was adjusted to 10% by mass, a PGMEA solution of RBisP-1 with a reduced metal content was obtained.

### (Example Group 2: Reference Example 1) Purification of RBisP-1 with Ultrapure Water

In the same manner as of Example 11 except that ultrapure water was used instead of the aqueous oxalic acid solution, and by adjusting the concentration to 10% by mass, a PGMEA solution of RBisP-1 was obtained.

For the 10% by mass PGMEA solution of RBisP-1 before the treatment, and the solutions obtained in Example 11 and Reference Example 1, the contents of various metals were measured by ICP-MS. The measurement results are shown in Table 3A.

### (Example Group 2: Example 12) Purification of RBisP-2 with Acid

In a four necked flask (capacity: 1000 mL, with a detachable bottom), 140 g of a solution (10% by mass) formed by dissolving RBisP-2 obtained in Synthesis Working Example 2 in PGMEA was charged, and was heated to 60° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Thereafter, by diluting with PGMEA of EL grade (a reagent manufactured by KANTO CHEMICAL CO., INC.) such that the concentration of the PGMEA solution was adjusted to 10% by mass, a PGMEA solution of RBisP-2 with a reduced metal content was obtained.

### (Example Group 2: Reference Example 2) Purification of RBisP-2 with Ultrapure Water

In the same manner as of Example 12 except that ultrapure water was used instead of the aqueous oxalic acid solution, and by adjusting the concentration to 10% by mass, a PGMEA solution of RBisP-2 was obtained.

For the 10% by mass PGMEA solution of RBisP-2 before the treatment, and the solutions obtained in Example 12 and Reference Example 2, the contents of various metals were measured by ICP-MS. The measurement results are shown in Table 3A.

### (Example Group 2: Example 13) Purification by Passing Through Filter

In a class 1000 clean booth, 500 g of a solution of 10% by mass concentration of the resin (RBisP-1) obtained in Synthesis Working Example 1 dissolved in propylene glycol monomethyl ether (PGME) was charged in a four necked flask (capacity: 1000 mL, with a detachable bottom), and then the air inside the vessel was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 100 mL per minute to a hollow fiber membrane filter (manufactured by KITZ MICRO FILTER CORPORATION, trade name: Polyfix Nylon Series) made of nylon with a nominal pore size of 0.01 μm. The contents of various metals in the obtained RBisP-1 solution were measured by ICP-MS. The oxygen concentration was measured with an oxygen concentration meter “OM-25MF10” manufactured by AS ONE Corporation (the same applies hereinafter). The measurement results are shown in Table 3A.

### Example Group 2: Synthesis Example 14

The solution was passed through in the same manner as in Example 13 except that a hollow fiber membrane filter (KITZ MICRO FILTER CORPORATION, trade name: Polyfix) made of polyethylene (PE) with a nominal pore size of 0.01 μm was used, and the contents of various metals in the obtained RBisP-1 solution were measured by ICP-MS. The measurement results are shown in Table 3A.

### Example Group 2: Synthesis Example 15

The solution was passed through in the same manner as in Example 13 except that a hollow fiber membrane filter (KITZ MICRO FILTER CORPORATION, trade name: Polyfix) made of nylon with a nominal pore size of 0.04 μm was used, and the contents of various metals in the obtained RBisP-1 were measured by ICP-MS. The measurement results are shown in Table 3A.

### Example Group 2: Synthesis Example 16

The solution was passed through in the same manner as in Example 13 except that a Zeta Plus filter 40QSH (manufactured by 3M Company, having an ion exchange capacity) with a nominal pore size of 0.2 μm was used, and the contents of various metals in the obtained RBisP-1 solution were measured by ICP-MS. The measurement results are shown in Table 3A.

### Example Group 2: Synthesis Example 17

The solution was passed through in the same manner as in Example 13 except that a Zeta Plus filter 020GN (manufactured by 3M Company, having an ion exchange capacity, and having different filtration areas and filter material thicknesses from those of Zeta Plus filter 40QSH) with a nominal pore size of 0.2 μm was used, and the obtained RBisP-1 solution was analyzed under the following conditions. The measurement results are shown in Table 3A.

### Example Group 2: Synthesis Example 18

The solution was passed through in the same manner as in Example 13 except that the resin (RBisP-2) obtained in Synthesis Working Example 2 was used instead of the resin (RBisP-1) in Example 13, and the contents of various metals in the obtained RBisP-2 solutions were measured by ICP-MS. The measurement results are shown in Table 3A.

### Example Group 2: Synthesis Example 19

The solution was passed through in the same manner as in Example 14 except that the resin (RBisP-2) obtained in Synthesis Working Example 2 was used instead of the resin (RBisP-1) in Example 14, and the contents of various metals in the obtained RBisP-2 solutions were measured by ICP-MS. The measurement results are shown in Table 3A.

### Example Group 2: Synthesis Example 20

The solution was passed through in the same manner as in Example 15 except that the resin (RBisP-2) obtained in Synthesis Working Example 2 was used instead of the compound (RBisP-1) in Example 15, and the contents of various metals in the obtained RBisP-2 solutions were measured by ICP-MS. The measurement results are shown in Table 3A.

### Example Group 2: Synthesis Example 21

The solution was passed through in the same manner as in Example 16 except that the resin (RBisP-2) obtained in Synthesis Working Example 2 was used instead of the compound (RBisP-1) in Example 16, and the contents of various metals in the obtained RBisP-2 solutions were measured by ICP-MS. The measurement results are shown in Table 3A.

### Example Group 2: Synthesis Example 22

The solution was passed through in the same manner as in Example 17 except that the resin (RBisP-2) obtained in Synthesis Working Example 2 was used instead of the compound (RBisP-1) in Example 17, and the contents of various metals in the obtained RBisP-2 solutions were measured by ICP-MS. The measurement results are shown in Table 3A.

### (Example Group 2: Example 23) Combination of Acid Washing and Filter Passage 1

In a class 1000 clean booth, 140 g of the 10% by mass PGMEA solution of RBisP-1 with a reduced metal content obtained by Example 18 was prepared in a four necked flask (capacity: 300 mL, with a detachable bottom), and then the air inside the vessel was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, passed through a pressure tube made of fluororesin through a diaphragm pump at a flow rate of 10 mL per minute to an ion exchange filter (manufactured by Nihon Pall Ltd., product name: IonKleen Series) with a nominal pore size of 0.01 μm. Thereafter, the recovered solution was then returned to the four necked flask (capacity: 300 mL), and the filter was changed to a filter made of high-density PE with a nominal diameter of 1 nm (manufactured by Entegris Japan Co., Ltd.), and pumped through the flask in the same manner. The contents of various metals in the obtained RBisP-1 solution were measured by ICP-MS. The oxygen concentration was measured with an oxygen concentration meter “OM-25MF10” manufactured by AS ONE Corporation (the same applies hereinafter). The measurement results are shown in Table 3A.

### (Example Group 2: Example 24) Combination of Acid Washing and Filter Passage 2

In a class 1000 clean booth, 140 g of the 10% by mass PGMEA solution of RBisP-1 with a reduced metal content obtained by Example 18 was prepared in a four necked flask (capacity: 300 mL, with a detachable bottom), and then the air inside the vessel was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 10 mL per minute to a hollow fiber membrane filter (manufactured by KITZ MICRO FILTER CORPORATION, trade name: Polyfix) made of nylon with a nominal pore size of 0.01 μm. Thereafter, the recovered solution was then returned to the four necked flask (capacity: 300 mL), and the filter was changed to a filter made of high-density PE with a nominal diameter of 1 nm (manufactured by Entegris Japan Co., Ltd.), and pumped through the flask in the same manner. The contents of various metals in the obtained RBisP-1 solution were measured by ICP-MS. The oxygen concentration was measured with an oxygen concentration meter “OM-25MF10” manufactured by AS ONE Corporation (the same applies hereinafter). The measurement results are shown in Table 3A.

### (Example Group 2: Example 25) Combination of Acid Washing and Filter Passage 3

The same procedure as in Example 23 was carried out except that the 10% by mass PGMEA solution of RBisP-1 used in Example 23 was changed to the 10% by mass PGMEA solution of RBisP-2 obtained by Example 19 to recover a 10% by mass PGMEA solution of RBisP-2 with a reduced metal amount. The contents of various metals in the obtained solution were measured by ICP-MS. The oxygen concentration was measured with an oxygen concentration meter “OM-25MF10” manufactured by AS ONE Corporation (the same applies hereinafter). The measurement results are shown in Table 3A.

### (Example Group 2: Example 26) Combination of Acid Washing and Filter Passage 4

The same procedure as in Example 24 was carried out except that the 10% by mass PGMEA solution of RBisP-1 used in Example 24 was changed to the 10% by mass PGMEA solution of RBisP-2 obtained by Example 19 to recover a 10% by mass PGMEA solution of RBisP-2 with a reduced metal amount. The contents of various metals in the obtained solution were measured by ICP-MS. The oxygen concentration was measured with an oxygen concentration meter “OM-25MF10” manufactured by AS ONE Corporation (the same applies hereinafter). The measurement results are shown in Table 3A.

TABLE 3A

| | | Metal content (ppb) | | | | Storage |
|---|---|---|---|---|---|---|
| | Purification method | Cr | Fe | Cu | Zn | stability |
| before | — | 88 | 430 | 885 | 105 | poor |
| treatment | | | | | | |
| RBisP-1 | | | | | | |
| Example 11 | acid washing | 18 | 20 | 73 | 10 | good |
| Example 13 | hollow fiber membrane nylon filter | 4 | 8 | 22 | 12 | good |
| Example 14 | PE | 50 | 102 | 222 | 93 | fair |
| | filter | | | | | |
| Example 15 | hollow fiber membrane nylon filter | 7 | 11 | 26 | 10 | good |
| Example 16 | zeta potential filter | 6 | 13 | 23 | 6 | good |
| Example 17 | zeta potential filter | 4 | 18 | 30 | 10 | good |
| Example 23 | combined use of acid washing/ ion | <0.1 | <0.1 | <0.1 | <0.1 | good |
| | exchange filter/ PE filter | | | | | |
| Example 24 | combined use of acid washing/ | <0.1 | <0.1 | <0.1 | <0.1 | good |
| | hollow fiber membrane nylon filter/ | | | | | |
| | PE filter | | | | | |
| Reference | water washing | 68 | 310 | 612 | 92 | poor |
| Example 1 | | | | | | |
| before | — | 92 | 334 | 855 | 225 | poor |
| treatment | | | | | | |
| RBisP-2 | | | | | | |
| Example 7 | acid washing | 22 | 20 | 55 | 16 | good |
| Example 18 | hollow fiber membrane nylon filter | 8 | 5 | 32 | | good |
| Example 19 | PE | 95 | 145 | 345 | 130 | fair |
| | filter | | | | | |
| Example 20 | hollow fiber membrane nylon filter | 10 | 12 | 34 | 8 | good |
| Example 21 | zeta potential filter | 12 | 20 | 24 | 6 | good |
| Example 22 | zeta potential filter | 1.0 | >99 | 2 | 88 | good |
| Example 25 | combined use of acid washing/ ion | <0.1 | <0.1 | <0.1 | <0.1 | good |
| | exchange filter/ PE filter | | | | | |
| Example 26 | combined use of acid washing/ | <0.1 | <0.1 | <0.1 | <0.1 | good |
| | hollow fiber membrane nylon filter/ | | | | | |
| | PE filter | | | | | |
| Reference | water washing | 75 | 214 | 503 | 133 | poor |
| Example 2 | | | | | | |

As shown in Table 3A, it was confirmed that the storage stability of the resin solutions according to the present embodiment was improved by reducing the metal derived from the oxidizing agent through various purification methods.

In particular, the acid washing method and the use of ion exchange or nylon filters can effectively reduce ionic metals, and the combination of high-definition high-density polyethylene particulate removal filters can provide dramatic metal removal effects.

### Example Group 2: Examples 27 to 32-1 and Comparative Example 3

### <Resist Performance>

By using the resins obtained in Synthesis Working Example 1 to Synthesis Working Example 6 and Comparative Synthesis Example 1, the evaluation of resist performance below was carried out, and the results thereof are shown in Table 4A.

### (Preparation of Resist Composition)

A resist composition was prepared according to the recipe shown in Table 4A using each resin synthesized as described above. For the components of the resist compositions in Table 4A, the following acid generating agent (C), acid diffusion controlling agent (E), and solvent were used.

Acid generating agent (C)
P-1: triphenylbenzenesulfonium trifluoromethanesulfonate (Midori Kagaku Co., Ltd.)

Acid crosslinking agent (G)
C-1: NIKALAC MW-100LM (SANWA Chemical Co., Ltd.) Acid diffusion controlling agent (E)
Q-1: trioctylamine (TOKYO KASEI KOGYO CO., LTD.) Solvent
S-1: propylene glycol monomethyl ether (TOKYO KASEI KOGYO CO., LTD.)

### (Method for Evaluating Resist Performance of Resist Composition)

A clean silicon wafer was spin coated with the homogeneous resist composition, and then prebaked (PB) before exposure in an oven of 110° C. to form a resist film with a thickness of 60 nm. The obtained resist film was irradiated with electron beams of 1:1 line and space setting with a 50 nm interval using an electron beam lithography system (ELS-7500 manufactured by ELIONIX INC.). After the irradiation, the resist film was heated at each predetermined temperature for 90 seconds, and immersed in 2.38% by mass tetramethylammonium hydroxide (TMAH) alkaline developing solution for 60 seconds for development. Thereafter, the resist film was washed with ultrapure water for 30 seconds, and dried to form a positive type resist pattern. Concerning the formed resist pattern, the line and space were observed by a scanning electron microscope (S-4800 manufactured by Hitachi High-Technologies Corporation) to evaluate the reactivity by electron beam irradiation of the resist composition.

TABLE 4A

| | | Resist composition | | | | | Resist |
|---|---|---|---|---|---|---|---|
| | | Resin | P-1 | C-1 | Q-1 | S-1 | performance |
| | Resin | [g] | [g] | [g] | [g] | [g] | evaluation |
| Example 27 | RBisP-1 | 1.0 | 0.3 | 0.3 | 0.03 | 50.0 | good |
| Example 28 | RBisP-2 | 1.0 | 0.3 | 0.3 | 0.03 | 50.0 | good |
| Example 29 | RBisP-3 | 1.0 | 0.3 | 0.3 | 0.03 | 50.0 | good |
| Example 30 | RBisP-4 | 1.0 | 0.3 | 0.3 | 0.03 | 50.0 | good |
| Example 31 | RBisP-5 | 1.0 | 0.3 | 0.3 | 0.03 | 50.0 | good |
| Example 32 | RBisP-1 | 1.0 | 0.3 | 0.3 | 0 | 50.0 | good |
| Example 32-1 | RBP-1 | 1.0 | 0.3 | 0.3 | 0.03 | 50.0 | good |
| Comparative | NBisN-1 | 1.0 | 0.3 | 0.3 | 0.03 | 50.0 | poor |
| Example 3 | | | | | | | |

In the resist pattern evaluation, a good resist pattern was obtained by irradiation with electron beams of 1:1 line and space setting with 50 nm interval in each of Example 27 to Example 32-1. As for the line edge roughness, a pattern having asperities of less than 5 nm was evaluated to be good. On the other hand, it was not possible to obtain a good resist pattern in Comparative Example 3.

When the resin satisfying the requirements of the present embodiment is used as described above, the resin can impart a good shape to a resist pattern, as compared with the resin (NBisN-1) of Comparative Example 3 which does not satisfy the requirements. As long as the above requirements of the present embodiment are met, compounds other than the resins described in Examples also exhibit the same effects.

### Example Group 2: Examples 33 to 37-1 and Comparative Example 4

### (Preparation of Radiation-Sensitive Composition)

The components set forth in Table 5A were formulated and formed into homogeneous solutions, and the obtained homogeneous solutions were filtered through a Teflon® membrane filter with a pore diameter of 0.1 μm to prepare radiation-sensitive compositions. Each of the prepared radiation-sensitive compositions was evaluated as described below.

TABLE 5A

Composition

| | | Optically | |
|---|---|---|---|
| | | active | |
| | Component (A) | compound (B) | Solvent |
| | [g] | [g] | [g] |
| Example 33 | RBisP-1 | B-1 | S-1 |
| | 0.5 | 1.5 | 30.0 |
| Example 34 | RBisP-2 | B-1 | S-1 |
| | 0.5 | 1.5 | 30.0 |
| Example 35 | RBisP-3 | B-1 | S-1 |
| | 0.5 | 1.5 | 30.0 |
| Example 36 | RBisP-4 | B-1 | S-1 |
| | 0.5 | 1.5 | 30.0 |
| Example 37 | RBisP-5 | B-1 | S-1 |
| | 0.5 | 1.5 | 30.0 |
| Example 37-1 | RBP-1 | B-1 | S-1 |
| | 0.5 | 1.5 | 30.0 |
| Comparative | PHS-1 | B-1 | S-1 |
| Example 4 | 0.5 | 1.5 | 30.0 |

The following resist base material (component (A)) was used in Comparative Example 4.
PHS-1: polyhydroxystyrene Mw=8000 (Sigma-Aldrich)

The following optically active compound (B) was used.
B-1: naphthoquinonediazide-based sensitizing agent having the following chemical structural formula (D-G) (product name “4NT-300”, Toyo Gosei Co., Ltd.)

The following solvent was used.
S-1: propylene glycol monomethyl ether (TOKYO KASEI KOGYO CO., LTD.)

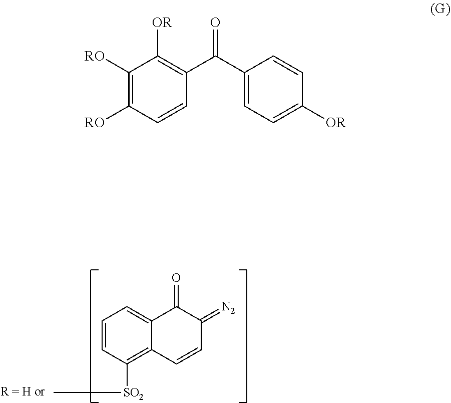

### <Evaluation of Resist Performance of Radiation-Sensitive Composition>

A clean silicon wafer was spin coated with the radiation-sensitive composition obtained as described above, and then prebaked (PB) before exposure in an oven of 110° C. to form a resist film with a thickness of 200 nm. The resist film was exposed to ultraviolet using an ultraviolet exposure apparatus (mask aligner MA-10 manufactured by Mikasa Co., Ltd.). The ultraviolet lamp used was a super high pressure mercury lamp (relative intensity ratio: g-ray:h-ray:i-ray:j-ray=100:80:90:60). After irradiation, the resist film was heated at 110° C. for 90 seconds, and immersed in a 2.38% by mass TMAH alkaline developing solution for 60 seconds for development. Thereafter, the resist film was washed with ultrapure water for 30 seconds, and dried to form a 5 μm positive type resist pattern.

The obtained line and space were observed in the formed resist pattern by a scanning electron microscope (S-4800 manufactured by Hitachi High-Technologies Corporation). As for the line edge roughness, a pattern having asperities of less than 5 nm was evaluated to be good.

In the case of using the radiation-sensitive composition according to each of Example 33 to Example 37, a good resist pattern with a resolution of 5 μm was able to be obtained. The roughness of the pattern was also small and good.

On the other hand, in the case of using the radiation-sensitive composition according to Comparative Example 4, a good resist pattern with a resolution of 5 μm was able to be obtained. However, the roughness of the pattern was large and poor.

As described above, it was found that each of the radiation-sensitive compositions according to Example 33 to Example 37-1 can form a resist pattern that has small roughness and a good shape, as compared with the radiation-sensitive composition according to Comparative Example 4. As long as the above requirements of the present embodiment are met, radiation-sensitive compositions other than those described in Examples also exhibit the same effects.

Each of the resins obtained in Synthesis Working Example 1 to Synthesis Working Example 6 has a relatively low molecular weight and a low viscosity. As such, it was evaluated that the embedding properties and film surface flatness of underlayer film forming materials for lithography containing these compounds or resins can be relatively advantageously enhanced. Furthermore, each of these compounds or resins has a thermal decomposition temperature of 150° C. or higher (evaluation A) and has high heat resistance, so that it was evaluated that they can be used even under high temperature baking conditions. In order to confirm these points, the following evaluation was performed assuming the application to the underlayer film.

### Example Group 2: Examples 38 to 43 and Comparative Examples 5 and 6

### (Preparation of Composition for Underlayer Film Formation for Lithography)

Compositions for underlayer film formation for lithography were prepared according to the composition shown in Table 6A. Next, a silicon substrate was spin coated with each of these compositions for underlayer film formation for lithography, and then baked at 240° C. for 60 seconds and further at 400° C. for 120 seconds to prepare each underlayer film having a film thickness of 200 nm. The following acid generating agent, crosslinking agent, and organic solvent were used.
Acid generating agent: di-tertiary butyl diphenyliodonium nonafluoromethanesulfonate (DTDPI) manufactured by Midori Kagaku Co., Ltd.
Crosslinking agent: NIKALAC MX270 (NIKALAC) manufactured by SANWA Chemical Co., Ltd.
Organic solvent: cyclohexanone
Organic solvent: propylene glycol monomethyl ether acetate (PGMEA)
Novolac: PSM4357 manufactured by Gun Ei Chemical Industry Co., Ltd.

Next, etching test was conducted under conditions shown below to evaluate etching resistance. The evaluation results are shown in Table 6A. Details of the evaluation method will be described later.

### <Etching Test>

Etching apparatus: RIE-10NR manufactured by Samco International, Inc.
Output: 50 W
Pressure: 20 Pa
Time: 2 min

Etching Gas
Ar gas flow rate:CF₄ gas flow rate:O₂ gas flow rate=50:5:5 (sccm)

### <Evaluation of Etching Resistance>

The evaluation of etching resistance was conducted by the following procedures. First, an underlayer film of novolac was prepared under the same conditions as described above except that novolac (“PSM4357” manufactured by Gun Ei Chemical Industry Co., Ltd.) was used. This underlayer film of novolac was subjected to the above etching test, and the etching rate was measured.

Next, underlayer films of Examples 24 to 29 and Comparative Examples 5 to 6 were prepared under the same conditions as the underlayer films of novolac and subjected to the etching test described above in the same way as above, and the etching rate was measured. Then, the etching resistance for each of Examples and Comparative Examples was evaluated according to the following evaluation criteria on the basis of the etching rate of the underlayer film of novolac.

[Evaluation Criteria]
A: The etching rate was less than −20% as compared with the underlayer film of novolac.
B: The etching rate was −20% or more and 0% or less as compared with the underlayer film of novolac.
C: The etching rate was more than +0% as compared with the underlayer film of novolac.

TABLE 6A

| | | | Acid | | |
|---|---|---|---|---|---|
| | | | generating | Crosslinking | |
| | Resin | Solvent | agent | agent | |
| | (parts | (parts | (parts | (parts | Etching |
| | by mass) | by mass) | by mass | by mass) | resistance |
| Example 38 | RBisP-1 | PGMEA | DTDPI | NIKALAC | A |
| | (10) | (90) | (0.5) | (0.5) | |
| Example 39 | RBisP-2 | PGMEA | DTDPI | NIKALAC | A |
| | (10) | (90 | (0.5) | (0.5) | |
| Example 40 | RBisP-3 | PGMEA | DTDPI | NIKALAC | A |
| | (10) | (90) | (0.5 | (0.5) | |
| Example 41 | RBisP-4 | PGMEA | DTDPI | NIKALAC | A |
| | (10) | (90) | (0.5) | (0.5) | |
| Example 42 | RBisP-5 | PGMEA | DTDPI | NIKALAC | A |
| | (10) | (90) | (0.5) | (0.5) | |
| Example 43 | RBisP-1 | cyclohexanone/PGMEA | — | NIKALAC | A |
| | (10) | (81/9) (90) | | (0.5) | |
| Example 43-1 | RBP-1 | PGMEA | DTDPI | NIKALAC | A |
| | (10) | (90) | (0.5) | (0.5) | |
| Comparative | CR-1 | PGMEA | DTDPI | NIKALAC | C |
| Example 5 | (10) | (90) | (0.5) | (0.5) | |
| Comparative | NBisN-1 | PGMEA | DTDPI | NIKALAC | B |
| Example 6 | (10) | (90) | (0.5) | (0.5) | |

It was found that an excellent etching rate is exerted in Examples 38 to 43-1 as compared with the underlayer film of novolac and the resin of Comparative Example 5 to 6. On the other hand, it was found that in the resin of Comparative Example 5 or 6, the etching rate was equal to or inferior to that of the underlayer film of novolac.

### Examples 44 to 49 and Comparative Example 7

Next, a SiO₂ substrate having a film thickness of 80 nm and a line and space pattern of 60 nm was coated with each of the compositions for underlayer film formation for lithography prepared in Examples 38 to 43-1 and Comparative Example 5, and baked at 240° C. for 60 seconds to form a 90 nm underlayer film.

### (Evaluation of Embedding Properties)

The embedding properties were evaluated by the following procedures. The cross section of the film obtained under the above conditions was cut out and observed under an electron microscope to evaluate the embedding properties. The evaluation results are shown in Table 7A.

[Evaluation Criteria]
A: The underlayer film was embedded without defects in the asperities of the SiO₂ substrate having a line and space pattern of 60 nm.
C: The asperities of the SiO₂ substrate having a line and space pattern of 60 nm had defects which hindered the embedding of the underlayer film.

TABLE 7A

| | Composition for | |
|---|---|---|
| | underlayer film | |
| | formation for | Embedding |
| | lithography | properties |
| Example 44 | Example 38 | A |
| Example 45 | Example 39 | A |
| Example 46 | Example 40 | A |
| Example 47 | Example 41 | A |
| Example 48 | Example 42 | A |
| Example 49 | Example 43 | A |
| Example 49-1 | Example 43-1 | A |
| Comparative | Comparative | C |
| Example 7 | Example 5 | |

It was found that embedding properties are good in Examples 44-1 to 49-1. On the other hand, it was found that defects are seen in the asperities of the SiO₂ substrate and embedding properties are poor in Comparative Example 7.

### Example Group 2: Examples 50 to 55

Next, a SiO₂ substrate having a film thickness of 300 nm was coated with each composition for underlayer film formation for lithography prepared in Examples 38 to 43-1, and baked at 240° C. for 60 seconds and further at 400° C. for 120 seconds to form an underlayer film having a film thickness of 85 nm. This underlayer film was coated with a resist solution for ArF and baked at 130° C. for 60 seconds to form a photoresist layer having a film thickness of 140 nm.

The ArF resist solution used was prepared by containing 5 parts by mass of a compound of the formula (16) given below, 1 part by mass of triphenylsulfonium nonafluoromethanesulfonate, 2 parts by mass of tributylamine, and 92 parts by mass of PGMEA.

The compound of the following formula (16) was prepared as follows. That is, 4.15 g of 2-methyl-2-methacryloyloxyadamantane, 3.00 g of methacryloyloxy-γ-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The product resin thus obtained was solidified and purified, and the resulting white powder was filtered and dried overnight at 40° C. under reduced pressure to obtain a compound represented by the following formula (16).

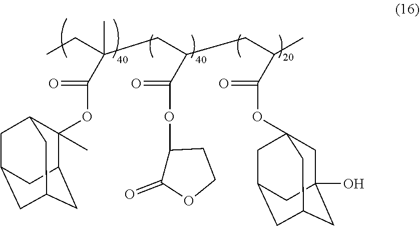

(In the formula (16), 40, 40, and 20 represent the ratio of each constituent unit and do not represent a block copolymer.)

Then, the photoresist layer was exposed using an electron beam lithography system (manufactured by ELIONIX INC.; ELS-7500, 50 keV), baked (PEB) at 115° C. for 90 seconds, and developed for 60 seconds in a 2.38% by mass tetramethylammonium hydroxide (TMAH) aqueous solution to obtain a positive type resist pattern.

### Example Group 2: Comparative Example 8

The same operations as in Example 50 were performed except that no underlayer film was formed so that a photoresist layer was formed directly on a SiO₂ substrate to obtain a positive type resist pattern.

### [Evaluation]

Concerning each of Examples 44 to 49-1 and Comparative Example 8, the shapes of the obtained 45 nm L/S (1:1) and 80 nm L/S (1:1) resist patterns were observed under an electron microscope “S-4800” manufactured by Hitachi, Ltd. The shapes of the resist patterns after development were evaluated as “goodness” when having good rectangularity without pattern collapse, and as “poorness” if this was not the case. The smallest line width having good rectangularity without pattern collapse as a result of this observation was used as an index for resolution evaluation. The smallest electron beam energy quantity capable of lithographing good pattern shapes was used as an index for sensitivity evaluation. The results are shown in Table 8A.

TABLE 8A

| | Composition for | | | Resist |
|---|---|---|---|---|
| | underlayer film | | | pattern |
| | formation for | Resolution | Sensitivity | shape after |
| | lithography | (nmL/S) | (μC/cm²) | development |
| Example 50 | Example 44 | 45 | 10 | good |
| Example 51 | Example 45 | 45 | 10 | good |
| Example 52 | Example 46 | 45 | 10 | good |
| Example 53 | Example 47 | 45 | 10 | good |
| Example 54 | Example 48 | 45 | 10 | good |
| Example 55 | Example 49 | 45 | 10 | good |
| Example 55-1 | Example 49-1 | 45 | 10 | good |
| Comparative | RBisP-1 | 55 | 10 | good |
| Example 8A | changed to | | | |
| | RBisP-6 in | | | |
| | Example 44 | | | |
| Comparative | none | 81 | 25 | poor |
| Example 8 | | | | |

As is evident from Table 8A, the resist pattern of Examples 50 to 55-1 was confirmed to be significantly superior in both resolution and sensitivity to Comparative Example 8. Also, the resist pattern shapes after development were confirmed to have good rectangularity without pattern collapse. The difference in the resist pattern shapes after development indicated that the composition for underlayer film formation for lithography of Examples 44 to 49-1 has good adhesiveness to a resist material.

### Example Group 2: Example 56

A SiO₂ substrate having a film thickness of 300 nm was coated with the composition for underlayer film formation for lithography prepared in Example 44, and baked at 240° C. for 60 seconds and further at 400° C. for 120 seconds to form an underlayer film having a film thickness of 90 nm. This underlayer film was coated with a silicon-containing intermediate layer material and baked at 200° C. for 60 seconds to form an intermediate layer film having a film thickness of 35 nm. This intermediate layer film was further coated with the above resist solution for ArF and baked at 130° C. for 60 seconds to form a photoresist layer having a film thickness of 150 nm. The silicon-containing intermediate layer material used was the silicon atom-containing polymer (polymer 1) described in <Synthesis Example 1> of Japanese Patent Laid-Open No. 2007-226170.

Then, the photoresist layer was mask exposed using an electron beam lithography system (manufactured by ELIONIX INC.; ELS-7500, 50 keV), baked (PEB) at 115° C. for 90 seconds, and developed for 60 seconds in 2.38% by mass tetramethylammonium hydroxide (TMAH) aqueous solution to obtain a 45 nm L/S (1:1) positive type resist pattern.

Thereafter, the silicon-containing intermediate layer film (SOG) was dry etched with the obtained resist pattern as a mask using “RIE-10NR” manufactured by Samco International, Inc. Subsequently, dry etching of the underlayer film using the obtained silicon-containing intermediate layer film pattern as a mask and dry etching of the SiO₂ film using the obtained underlayer layer film pattern as a mask were sequentially performed.

Respective etching conditions are as shown below.

Etching Conditions for Resist Intermediate Layer Film with Resist Pattern
Output: 50 W
Pressure: 20 Pa
Time: 1 min

Etching Gas
Ar gas flow rate:CF₄ gas flow rate:O₂ gas flow rate=50:8:2 (sccm)

Etching Conditions for Resist Underlayer Film with Resist Intermediate Film Pattern
Output: 50 W
Pressure: 20 Pa
Time: 2 min

Etching Gas
Ar gas flow rate:CF₄ gas flow rate:O₂ gas flow rate=50:5:5 (sccm)

Etching Conditions for SiO₂ Film with Resist Underlayer Film Pattern
Output: 50 W
Pressure: 20 Pa
Time: 2 min

Etching Gas
Ar gas flow rate:C₅F₁₂ gas flow rate:C₂F₆ gas flow rate:O₂ gas flow rate=50:4:3:1 (sccm)

### <Evaluation of Pattern Shape>

The pattern cross section (the shape of the SiO₂ film after etching) of Example 56 obtained as described above was observed under an electron microscope manufactured by Hitachi, Ltd. “5-4800”. As a result, it was confirmed that the shape of the SiO₂ film after etching in a multilayer resist process is a rectangular shape in Examples using the underlayer film of the present invention and is good without defects.

### <Characteristic Evaluation of Resin Film (Resin Single Film)>

### <Preparation of Resin Film>

### Example Group 2: Example A01

Using PGMEA as a solvent, the resin RBisP-1 of Synthesis Working Example 1 was dissolved to prepare a resin solution having a solid content concentration of 10% by mass (resin solution of Example A01).

The prepared resin solution was formed on a 12 inch silicon wafer using a spin coater Lithius Pro (manufactured by Tokyo Electron Ltd.), and after forming a film while adjusting the number of revolutions so as to have a film thickness of 200 nm, the baking was performed under the condition of a baking temperature of 250° C. for 1 minute to prepare a substrate on which a film made of the resin of Synthesis Example 1 was laminated. The prepared substrate was further baked under the condition of 350° C. for 1 minute using a hot plate capable of treating at a high temperature to obtain a cured resin film. At this time, when the change in film thickness before and after immersing the obtained cured resin film in the PGMEA tank for 1 minute was 3% or less, it was determined that the film was cured. When the curing was determined to be insufficient, the curing temperature was changed by 50° C. to investigate the curing temperature, and baking for curing was performed under the condition of the lowest temperature in the curing temperature range.

### <Optical Characteristic Values Evaluation>

The prepared resin film was evaluated for optical characteristic values (refractive index n and extinction coefficient k as optical constants) using spectroscopic ellipsometry VUV-VASE (manufactured by J.A. Woollam).

### Example Group 2: Example A02 to Example A06 and Comparative Example A01

The resin film was prepared in the same manner as in Example A01 except that the resins used were changed from RBisP-1 to the resins shown in Table 9A, and the optical characteristic values were evaluated.

### [Evaluation Criteria] Refractive Index n

A: 1.4 or more
C: less than 1.4

### [Evaluation Criteria] Extinction Coefficient k

A: less than 0.5
C: 0.5 or more

TABLE 9A

| | Resin | Optical characteristic values | |
|---|---|---|---|
| | used | n | k |
| Example A01 | RBisP-1 | A | A |
| Example A02 | RBisP-2 | A | A |
| Example A03 | RBisP-3 | A | A |
| Example A04 | RBisP-4 | A | A |
| Example A05 | RBisP-5 | A | A |
| Example A06 | RBP-1 | A | A |
| Comparative | CR-1 (Comparative | C | C |
| Example A01 | Synthesis Example 2) | | |

From the results of Examples A01 to A06, it was found that a resin film having a high n-value and a low k-value at wavelengths 193 nm used in ArF exposure can be formed by the composition for film formation containing the polycyclic polyphenolic resin according to the present embodiment.

### <Heat Resistance Evaluation of Cured Film>

### Example Group 2: Example B01

The heat resistance of the resin film prepared in Example A01 was evaluated by using a lamp annealing oven. As the heat treatment resistance condition, heating was continued at 450° C. in a nitrogen atmosphere, and a film thickness change rate was obtained by comparing the film thickness after an elapsed time of 4 minutes from the start of heating and the film thickness after an elapsed time of 10 minutes. In addition, heating was continued at 550° C. in a nitrogen atmosphere, and a film thickness change rate was obtained by comparing the film thickness after an elapsed time of 4 minutes from the start of heating and the film thickness after an elapsed time of 10 minutes at 550° C. These film thickness change rates were evaluated as indicators of the heat resistance of the cured film. The film thicknesses before and after the heat resistance test were measured by an interference film thickness meter, and a ratio of the fluctuation value of the film thickness to the film thickness before the heat resistance test treatment was defined as a film thickness change rate (%).

[Evaluation Criteria]
A: Film thickness change rate is less than 10%.
B: Film thickness change rate is 10% or more and 15% or less.
C: Film thickness change rate is more than 15%.

### Example Group 2: Examples B02 to B06 and Comparative Examples B01 to B02

Heat resistance was evaluated in the same manner as in Example B01 except that the resins used were changed from RBisP-1 to the resins shown in Table 10A.

TABLE 10A

| | | | Film |
|---|---|---|---|
| | | Cured | thickness |
| | | film heat | change |
| | Resin | resistance | rate % |
| | used | 450° C. | 550° C. |
| Example B01 | RBisP-1 | A | A |
| Example B02 | RBisP-2 | A | A |
| Example B03 | RBisP-3 | A | A |
| Example B04 | RBisP-4 | A | A |
| Example B05 | RBisP-5 | A | A |
| Example B06 | RBP-1 | A | A |
| Comparative | CR-1 | C | C |
| Example B01 | | | |
| Comparative | NBisN-1 | B | B |
| Example B02 | | | |

From the results of Examples B01 to B06, it was found that a resin film having high heat resistance with little change in film thickness even at a temperature of 550° C. can be formed by using a composition for film formation containing the polycyclic polyphenolic resin of the present embodiment as compared with Comparative Examples B01 and B02.

### Example Group 2: Example C01

### <Evaluation of PE-CVD Film Formation>

A 12 inch silicon wafer was subjected to thermal oxidation treatment, and a resin film was formed on the substrate having the obtained silicon oxide film by the same method as in Example A01 using the resin solution of Example A01 with a thickness of 100 nm. A silicon oxide film having a film thickness of 70 nm was formed on the resin film using a film forming apparatus TELINDY (manufactured by Tokyo Electron Ltd.) and tetraethylsiloxane (TEOS) as a raw material at a substrate temperature of 300° C. The wafer with the cured film in which the prepared silicon oxide film was laminated was further subjected to defect inspection using a defect inspection device “SP5” (KLA-Tencor Corporation), and the number of defects of the formed oxide film was evaluated according to the following criteria using the number of defects of 21 nm or more as an index.

### (Criteria)

A number of defects≤20
B 20<number of defects≤50
C 50<number of defects≤100
D 100<number of defects≤1000
E 1000<number of defects≤5000
F 5000<number of defects

### <Evaluation of SiN Film>

On a cured film formed on a substrate having a silicon oxide film thermally oxidized on a 12 inch silicon wafer with a thickness of 100 nm by the same method as described above, a film forming apparatus TELINDY (manufactured by Tokyo Electron Ltd.) was used to form a SiN film having a thickness of 40 nm, a refractive index of 1.94, and a film stress of −54 MPa at a substrate temperature of 350° C. using SiH₄ (k) and ammonia as raw materials. The wafer with the cured film in which the prepared SiN film was laminated was further subjected to defect inspection using a defect inspection device “SP5” (KLA-tencor Corporation), and the number of defects of the formed oxide film was evaluated according to the following criteria using the number of defects of 21 nm or more as an index.

### (Criteria)

A number of defects≤20
B 20<number of defects≤50
C 50<number of defects≤100
D 100<number of defects≤1000
E 1000<number of defects≤5000
F 5000<number of defects

### Example Group 2: Examples C02 to CP06 and Comparative Examples C01 to C02

Defect evaluation of the film was performed in the same manner as in Example C01 except that the resins used were changed from RBisP-1 to the resins shown in Table 11A.

TABLE 11A

| | | PE-CVD defect evaluation | |
|---|---|---|---|
| | Resin | Oxide | SiN |
| | used | film | film |
| Example C01 | RBisP-1 | B | B |
| Example C02 | RBisP-2 | B | B |
| Example C03 | RBisP-3 | B | B |
| Example C04 | RBisP-4 | B | B |
| Example C05 | RBisP-5 | B | B |
| Example C06 | RBP-1 | B | B |
| Comparative | CR-1 (Comparative | F | F |
| Example C01 | Synthesis Example 2) | | |
| Comparative | NBisN-1 | E | E |
| Example C02 | | | |

In the silicon oxide film or SiN film formed on the resin film of Examples C01 to C06, the number of defects of 21 nm or more was 50 or less (B or higher), which was smaller than the number of defects of Comparative Example C01 or C02.

### Example Group 2: Example D01

<Etching Evaluation after High Temperature Treatment>

A 12 inch silicon wafer was subjected to thermal oxidation treatment, and a resin film was formed on the substrate having the obtained silicon oxide film by the same method as in Example A01 using the resin solution of Example A01 with a thickness of 100 nm. The resin film was further annealed by heating under the condition of 600° C. for 4 minutes using a hot plate which can be further treated at a high temperature in a nitrogen atmosphere to prepare a wafer on which the annealed resin film was laminated. The prepared annealed resin film was carved out, and the carbon content was determined by elemental analysis.

Furthermore, a 12 inch silicon wafer was subjected to thermal oxidation treatment, and a resin film was formed on the substrate having the obtained silicon oxide film by the same method as in Example A01 using the resin solution of Example A01 with a thickness of 100 nm. The resin film was further annealed by heating under the condition of 600° C. for 4 minutes under a nitrogen atmosphere to form a resin film, and then the substrate was subjected to an etching treatment using an etching apparatus “TELIUS” (manufactured by Tokyo Electron Ltd.) under the conditions of using CF₄/Ar as an etching gas and Cl₂/Ar as an etching gas to evaluate an etching rate. The etching rate was evaluated by using a resin film having a film thickness of 200 nm formed by annealing a photoresist “SU8 3000” manufactured by Nippon Kayaku Co., Ltd. at 250° C. for 1 minute as a reference and determining the ratio of the etching rate to the SU8 3000 as a relative value.

[Evaluation Criteria]
A: The etching rate was less than −20% as compared with the resin film of SU8 3000.
B: The etching rate was −20% or more and 0% or less as compared with the resin film of SU8 3000.
C: The etching rate was more than +0% as compared with the resin film of SU8 3000.

### Example Group 2: Examples D02 to D06, Reference Example D01, and Comparative Examples D01 to D02

Etching rate was evaluated in the same manner as in Example D01 except that the resins used were changed from RBisN-1 to the resins shown in Table 12A.

TABLE 12A

| | | | Etching rate evaluation | |
|---|---|---|---|---|
| | | | (relative value) | |
| | Resin | Carbon | CF₄/ | Cl₂/ |
| | used | content (%) | Ar | Ar |
| Example D01 | RBisP-1 | A | A | A |
| Example D02 | RBisP-2 | A | A | A |
| Example D03 | RBisP-3 | A | A | A |
| Example D04 | RBisP-4 | A | A | A |
| Example D05 | RBisP-5 | A | A | A |
| Example D06 | RBP-1 | A | A | A |
| Comparative | CR-1 | B | B | B |
| Example D01 | (Comparative | | | |
| | Synthesis | | | |
| | Example 2) | | | |
| Comparative | NBisN-1 | B | B | B |
| Example D02 | | | | |

From the results of Examples D01 to D06, it was found that a resin film excellent in etching resistance after high temperature treatment can be formed when a composition containing the polycyclic polyphenolic resin of the present embodiment is used as compared with Comparative Examples D01 and D02.

### [Defect Evaluation Before and After Purification Treatment]

### <Evaluation of Etching Defects on Laminated Film>

The polycyclic polyphenolic resins obtained in Synthesis Working Examples below were subjected to quality evaluation before and after the purification treatment. That is, before and after the purification treatment described below, the resin film formed on the wafer using the polycyclic polyphenolic resin was transferred to the substrate side by etching, and then subjected to defect evaluation to evaluate.

A 12-inch silicon wafer was subjected to thermal oxidation treatment to obtain a substrate having a silicon oxide film having a thickness of 100 nm. The resin solution of the polycyclic polyphenolic resin was formed on the substrate by adjusting the spin coating conditions so as to have a thickness of 100 nm, followed by baking at 150° C. for 1 minute, and then baking at 350° C. for 1 minute to prepare a laminated substrate in which the polycyclic polyphenolic resin was laminated on silicon with a thermal oxide film.

Using “TELIUS” (manufactured by Tokyo Electron Ltd.) as an etching apparatus, the resin film was etched under the condition of CF₄/O₂/Ar to expose the substrate on the surface of the oxide film. Further, an etching treatment was performed under the condition that the oxide film was etched by 100 nm at the gas composition ratio of CF₄/Ar to prepare an etched wafer.

The prepared etched wafer was measured for the number of defects of 19 nm or more with a defect inspection device SP5 (manufactured by KLA-Tencor Corporation), and was subjected to defect evaluation by etching treatment of the laminated film according to the following criteria.

### (Criteria)

A number of defects≤20
B 20<number of defects≤50
C 50<number of defects≤100
D 100<number of defects≤1000
E 1000<number of defects≤5000
F 5000<number of defects

### (Example Group 2: Example E01) Purification of RBisP-1 with Acid

In a four necked flask (capacity: 1000 mL, with a detachable bottom), 150 g of a solution (10% by mass) formed by dissolving RBisP-1 obtained in Synthesis Working Example 1 in PGMEA was charged, and was heated to 80° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Thereafter, by diluting with PGMEA of EL grade (a reagent manufactured by KANTO CHEMICAL CO., INC.) such that the concentration of the PGMEA solution was adjusted to 10% by mass, a PGMEA solution of RBisP-1 with a reduced metal content was obtained. The polycyclic polyphenolic resin solution thus prepared was filtered with a UPE filter having a nominal pore size of 3 nm, manufactured by Entegris Japan Co., Ltd., under a condition of 0.5 MPa, to prepare a solution sample.

For each of the solution samples before and after the purification treatment, a resin film was formed on the wafer as described above, the resin film was transferred to the substrate side by etching, and then etching defect evaluation was performed on the laminated film.

### (Example Group 2: Example E02) Purification of RBisP-2 with Acid

In a four necked flask (capacity: 1000 mL, with a detachable bottom), 140 g of a solution (10% by mass) formed by dissolving RBisP-2 obtained in Synthesis Working Example 2 in PGMEA was charged, and was heated to 60° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Thereafter, by diluting with PGMEA of EL grade (a reagent manufactured by KANTO CHEMICAL CO., INC.) such that the concentration of the PGMEA solution was adjusted to 10% by mass, a PGMEA solution of RBisP-2 with a reduced metal content was obtained. The polycyclic polyphenolic resin solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out in the same manner as in Example E01.

### (Example Group 2: Example E03) Purification by Passing Through Filter

In a class 1000 clean booth, 500 g of a solution of 10% by mass concentration of the resin (RBisP-1) obtained in Synthesis Working Example 1 dissolved in propylene glycol monomethyl ether (PGME) was charged in a four necked flask (capacity: 1000 mL, with a detachable bottom), and then the air inside the vessel was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 100 mL per minute to a hollow fiber membrane filter (manufactured by KITZ MICRO FILTER CORPORATION, product name: Polyfix Nylon Series) made of nylon with a nominal pore size of 0.01 μm under a filtration pressure of 0.5 MPa by pressure filtration. By diluting the resin solution after filtration with PGMEA of EL grade (a reagent manufactured by KANTO CHEMICAL CO., INC.) such that the concentration of the PGMEA solution was adjusted to 10% by mass, a PGMEA solution of RBisP-1 with a reduced metal content was obtained. The polycyclic polyphenolic resin solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out in the same manner as in Example E01. The oxygen concentration was measured with an oxygen concentration meter “OM-25MF10” manufactured by AS ONE Corporation (the same applies hereinafter)

### Example Group 2: Example E04

As the purification step by the filter, “IONKLEEN” manufactured by Nihon Pall Ltd., “NYLON FILTER” manufactured by Nihon Pall Ltd., and a UPE filter with a nominal pore size of 3 nm manufactured by Entegris Japan Co., Ltd. were connected in series in this order to construct a filter line. In the same manner as in Example E03, except that the prepared filter line was used instead of the 0.1 μm hollow fiber membrane filter made of nylon, the solution was passed by pressure filtration so that the conditions of the filtration pressure was 0.5 MPa. By diluting with PGMEA of EL grade (a reagent manufactured by KANTO CHEMICAL CO., INC.) such that the concentration of the PGMEA solution was adjusted to 10% by mass, a PGMEA solution of RBisP-1 with a reduced metal content was obtained. The polycyclic polyphenolic resin solution thus prepared was subjected to pressure filtration with a UPE filter having a nominal pore size of 3 nm, manufactured by Entegris Japan Co., Ltd., under a condition of the filtration pressure of 0.5 MPa, to prepare a solution sample, and then etching defect evaluation on the laminated film was carried out in the same manner as in Example E01.

### Example Group 2: Example E05

The solvent sample prepared in Example E01 was further subjected to pressure filtration with the filter line prepared in Example E04 under a condition of the filtration pressure of 0.5 MPa, to prepare a solution sample, and then etching defect evaluation on the laminated film was carried out in the same manner as in Example E01.

### Example Group 2: Example E06

For the RBisP-2 prepared in (Synthesis Working Example 2), a solution sample purified by the same method as in Example E05 was prepared, and then etching defect evaluation on the laminated film was carried out in the same manner as in Example E01.

### Example Group 2: Example E06-1

For the RBP-1 prepared in (Synthesis Working Example 6), a solution sample purified by the same method as in Example E05 was prepared, and then etching defect evaluation on the laminated film was carried out in the same manner as in Example E01.

### Example Group 2: Example E07

For the RBisP-3 prepared in (Synthesis Working Example 3), a solution sample purified by the same method as in Example E05 was prepared, and then etching defect evaluation on the laminated film was carried out.

TABLE 13A

PE-CVD defect evaluation

| | | Before | After |
|---|---|---|---|
| | Resin | purification | purification |
| | used | treatment | treatment |
| Example E01 | RBisP-1 | B | A |
| Example E02 | RBisP-2 | B | A |
| Example E03 | RBisP-1 | B | A |
| Example E04 | RBisP-1 | B | A |
| Example E05 | RBisP-1 | B | A |
| Example E06 | RBisP-2 | B | A |
| Example E06-1 | RBP-1 | B | A |
| Example E07 | RBisP-3 | B | A |

From the results of Examples E01 to E07, it was found that the quality of the obtained resin film was further improved when a composition containing the polycyclic polyphenolic resin of the present embodiment was used, as compared with when the polycyclic polyphenolic resin before purification treatment was used.

### Example Group 2: Examples 57 to 62

A SiO₂ substrate having a film thickness of 300 nm was coated with the composition for optical member formation having the same composition as that of the solution of the underlayer film forming material for lithography prepared in each of the above Examples 38 to 43-1 and Comparative Example 5, and baked at 260° C. for 300 seconds to form each film for optical members with a film thickness of 100 nm. Then, tests for the refractive index and the transparency at a wavelength of 633 nm were carried out by using a vacuum ultraviolet with variable angle spectroscopic ellipsometer “VUV-VASE” manufactured by J.A. Woollam Japan, and the refractive index and the transparency were evaluated according to the following criteria. The evaluation results are shown in Table 14A.

### [Evaluation Criteria for Refractive Index]

A: The refractive index is 1.65 or more
C: The refractive index is less than 1.65

### [Evaluation Criteria for Transparency]

A: The absorption coefficient is less than 0.03.
C: The absorption coefficient is 0.03 or more.

TABLE 14A

| | Composition for optical | Refractive | |
|---|---|---|---|
| | member formation | index | Transparency |
| Example 57 | same composition as | A | A |
| | Example 38 | | |
| Example 58 | same composition as | A | A |
| | Example 39 | | |
| Example 59 | same composition as | A | A |
| | Example 40 | | |
| Example 60 | same composition as | A | A |
| | Example 41 | | |
| Example 61 | same composition as | A | A |
| | Example 42 | | |
| Example 62 | same composition as | A | A |
| | Example 43 | | |
| Example 62-1 | same composition as | A | A |
| | Example 43-1 | | |
| Comparative | Comparative same | C | C |
| Example 9 | composition as Example 5 | | |

It was found that the compositions for optical member formation of Examples 57 to 62-1 not only had a high refractive index but also a low absorption coefficient and excellent transparency. On the other hand, it was found that the composition of Comparative Example 9 was inferior in performance as an optical member.

### Example Group 3

### [Example Group 3: Synthesis Example 1] Synthesis of BisN-1

To a container (internal capacity: 500 mL) equipped with a stirrer, a condenser tube, and a burette, 32.0 g (200 mmol) of 2,6-naphthalenediol (reagent manufactured by Sigma-Aldrich), 18.2 g (100 mmol) of 4-biphenylaldehyde (manufactured by MITSUBISHI GAS CHEMICAL COMPANY, INC.), and 200 mL of 1-butanol were added, and 34.0 g of potassium-t-butoxide was added. The reaction solution was stirred at 100° C. for 6 hours and reacted. Next, the reaction product was precipitated by the addition of 100 g of pure water, cooled to room temperature, and then separated by filtration. The obtained solid matter was dried and then separated and purified by column chromatography to obtain 28.5 g of the objective compound (BisN-1) represented by the following formula.

The following peaks were found by 400 MHz-¹H-NMR, and the compound was confirmed to have a chemical structure of the following formula.

¹H-NMR: (d-DMSO, internal standard TMS)

δ (ppm) 9.7 (4H, O—H), 7.2-8.5 (17H, Ph-H), 6.6 (1H, C—H)

LC-MS analysis confirmed that the molecular weight was 484 corresponding to the following chemical structure.

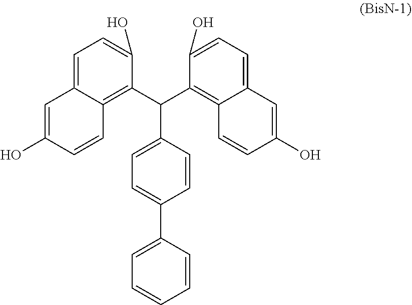 [SMILES: Oc1ccc2c(C(c3ccc(-c4ccccc4)cc3)c3c(O)ccc4cc(O)ccc34)c(O)ccc2c1]

### [Example Group 3: Synthesis Examples 2 to 6] Synthesis of BisN-2 to BisN-6

Objective compounds (BisN-2) to (BisN-6) represented by the following formulas were obtained in the same manner as in Synthesis Example 1 except that 2,7-naphthalenediol, 2,3-naphthalenediol, 1,5-naphthalenediol, 1,6-naphthalenediol, and 1,4-naphthalenediol were used instead of 2,6-naphthalenediol. (BisN-5) is a mixture of three structures.

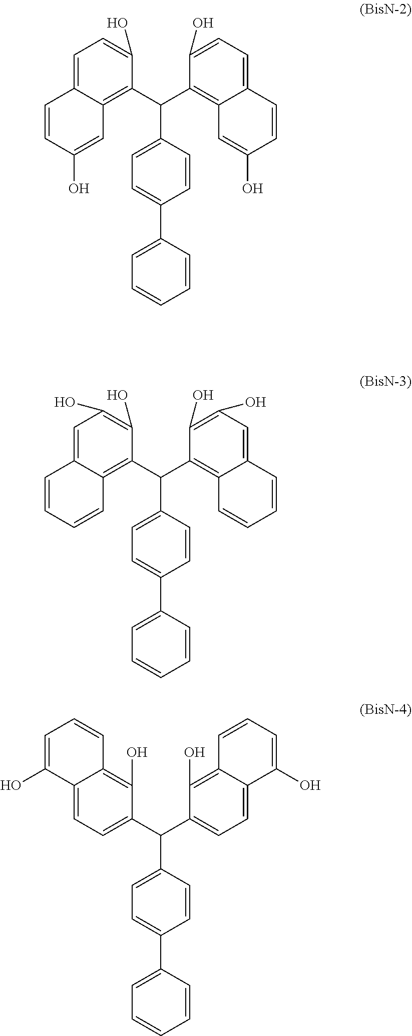 [SMILES: Oc1ccc2ccc(O)c(C(c3ccc(-c4ccccc4)cc3)c3c(O)ccc4ccc(O)cc34)c2c1 ; Oc1cc2ccccc2c(C(c2ccc(-c3ccccc3)cc2)c2c(O)c(O)cc3ccccc23)c1O ; Oc1cccc2c(O)c(C(c3ccc(-c4ccccc4)cc3)c3ccc4c(O)cccc4c3O)ccc12]

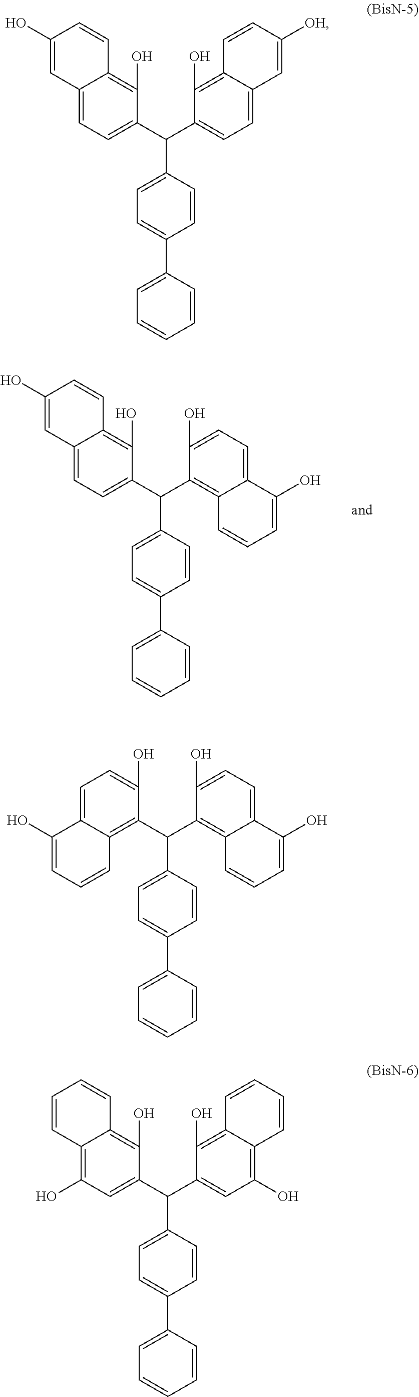 [SMILES: Oc1ccc2c(O)c(C(c3ccc(-c4ccccc4)cc3)c3ccc4cc(O)ccc4c3O)ccc2c1 ; Oc1ccc2c(O)c(C(c3ccc(-c4ccccc4)cc3)c3c(O)ccc4c(O)cccc34)ccc2c1 ; Oc1ccc2c(O)cccc2c1C(c1ccc(-c2ccccc2)cc1)c1c(O)ccc2c(O)cccc12 ; Oc1cc(C(c2ccc(-c3ccccc3)cc2)c2cc(O)c3ccccc3c2O)c(O)c2ccccc12]

### [Example Group 3: Synthesis Working Example 1] Synthesis of RBisN-1

To a container (internal capacity: 500 mL) equipped with a stirrer, a condenser tube, and a burette, 51 g (105 mmol) of BisN-1 and 10.1 g (20 mmol) of monobutylcopper phthalate were added, and 100 mL of 1-butanol was added as a solvent. The reaction solution was stirred at 100° C. for 6 hours and reacted. After cooling, the precipitate was filtered and the resulting crude was dissolved in 100 mL of ethyl acetate. Next, 5 mL of hydrochloric acid was added, and the mixture was stirred at room temperature, and neutralized with sodium hydrogen carbonate. The ethyl acetate solution was concentrated and 200 mL of methanol was added to precipitate the reaction product. After cooling to room temperature, the precipitates were separated by filtration. The obtained solid matter was dried to obtain 29.8 g of the objective resin (RBisN-1) having a structure represented by the following formula.

The polystyrene equivalent molecular weight of the obtained resin was measured by the method described above, and as a result, the obtained resin had Mn: 2200, Mw: 3100, and Mw/Mn: 1.41.

The following peaks were found by NMR measurement performed on the obtained resin under the above measurement conditions, and the resin was confirmed to have a chemical structure of the following formula.

δ (ppm) 9.3-9.7 (4H, O—H), 7.2-8.5 (15H, Ph-H), 6.7-6.9 (1H, C—H)

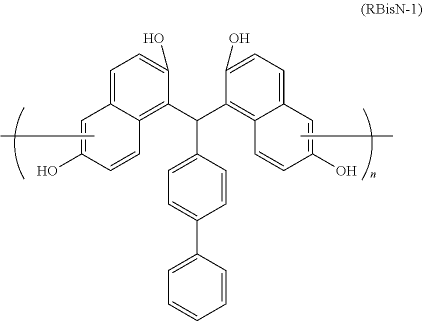

### [Example Group 3: Synthesis Working Examples 2 to 6] Synthesis of RBisN-2 to RBisN-6

Objective compounds (RBisN-2) to (RBisN-6) represented by the following formulas were obtained in the same manner as in Synthesis Working Example 1 except that BisN-2 to BisN-6 were used instead of BisN-1, respectively.

(RBisN-5) was a copolymer containing the following three structures as repeating units.

In the following RBisN-2 to RBisN-6, the following peaks were found by 400 MHz-¹H-NMR, and the compound was confirmed that each had the chemical structure of the following formulas. Further, the results of measuring the polystyrene equivalent molecular weight by the above method for each of the obtained resins are also shown.

### (RBisP-2)

Mn: 1610, Mw: 2188, Mw/Mn: 1.37

δ (ppm) 9.3-9.6 (4H, O—H), 7.2-8.6 (15H, Ph-H), 6.7-6.9 (1H, C—H)

### (RBisP-3)

Mn: 1490, Mw: 2102, Mw/Mn: 1.41

δ (ppm) 9.2-9.4 (4H, O—H), 7.2-8.5 (15H, Ph-H), 6.7-6.9 (1H, C—H)

### (RBisP-4)

Mn: 1028, Mw: 1462, Mw/Mn: 1.42

δ (ppm) 9.0-9.2 (4H, O—H), 7.2-8.4 (15H, Ph-H), 6.7-6.9 (1H, C—H)

### (RBisP-5)

Mn: 1702, Mw: 2162, Mw/Mn: 1.27

δ (ppm) 9.2-9.7 (4H, O—H), 7.2-8.5 (15H, Ph-H), 6.7-6.9 (1H, C—H)

### (RBisP-6)

Mn: 902, Mw: 1222, Mw/Mn: 1.35

δ (ppm) 9.0-9.5 (4H, O—H), 7.2-8.4 (15H, Ph-H), 6.7-6.9 (1H, C—H)

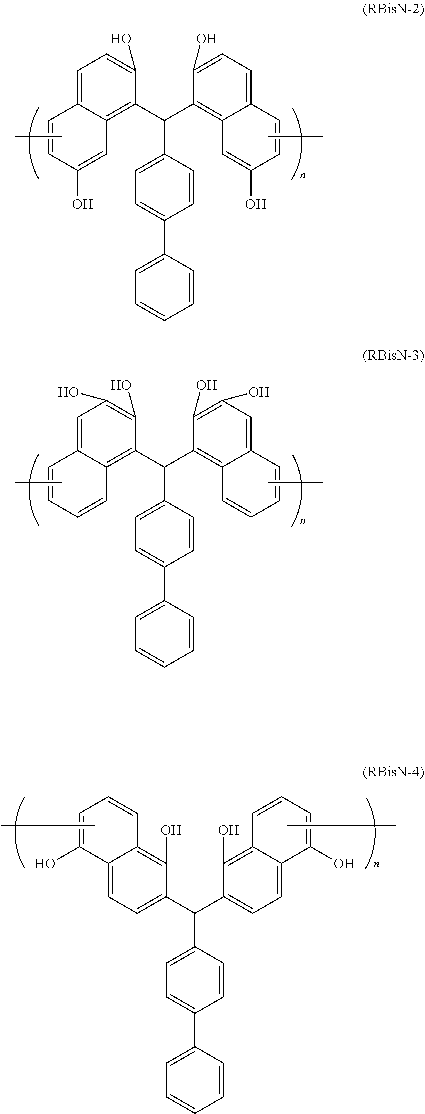

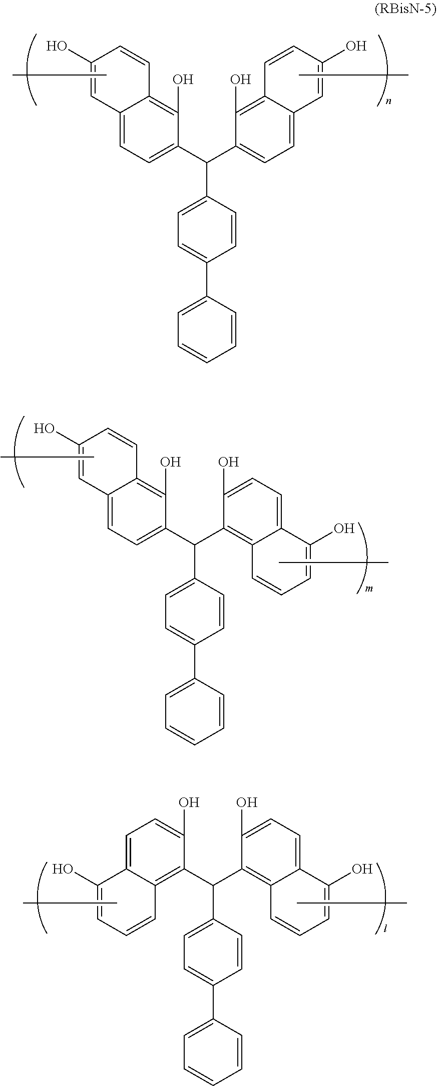

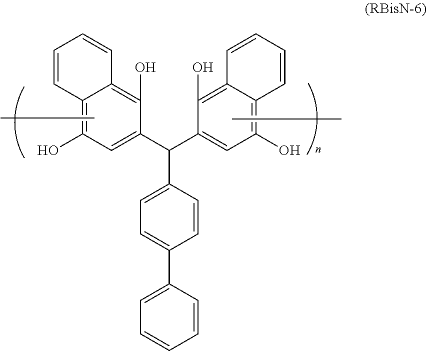

### Example Group 3: Comparative Synthesis Example 1

To a container (internal capacity: 100 ml) equipped with a stirrer, a condenser tube, and a burette, 10 g (21 mmol) of BisN-2, 0.7 g (42 mmol) of paraformaldehyde, 50 mL of glacial acetic acid, and 50 mL of PGME were added, and 8 mL of 95% sulfuric acid was added thereto. The reaction solution was stirred at 100° C. for 6 hours and reacted. Next, the reaction solution was concentrated and 1000 mL of methanol was added to precipitate the reaction product. After cooling to room temperature, the precipitates were separated by filtration. The obtained solid matter was filtered and dried to obtain 7.2 g of the objective resin (NBisN-2) having a structure represented by the following formula.

The polystyrene equivalent molecular weight of the obtained resin was measured by the method described above, and as a result, the obtained resin had Mn: 1278, Mw: 1993, and Mw/Mn: 1.56.

The following peaks were found by NMR measurement performed on the obtained resin under the above measurement conditions, and the resin was confirmed to have a chemical structure of the following formula.

δ (ppm) 9.7 (2H, O—H), 7.2-8.5 (17H, Ph-H), 6.6 (1H, C—H), 4.1 (2H, —CH2)

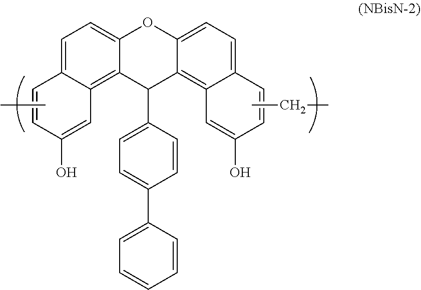

### Example Group 3: Comparative Synthesis Example 2

In the same manner as in Comparative Synthesis Example 2 of Example Group 1, 126.1 g of modified resin (CR-1) was obtained as a black-brown solid.

### Example Group 3: Examples 1 to 6

Table 1 shows the results of evaluating the heat resistance by the evaluation methods shown below using the resins obtained in Synthesis Working Examples 1 to 6 and Comparative Synthesis Example 1B.

### <Measurement of Thermal Decomposition Temperature>

EXSTAR 6000 TG/DTA apparatus manufactured by SII NanoTechnology Inc. was used. About 5 mg of a sample was placed in an unsealed container made of aluminum, and the temperature was raised to 700° C. at a temperature increase rate of 10° C./min in a nitrogen gas stream (30 mL/min). The temperature at which a heat loss of 10% by mass was observed was defined as the thermal decomposition temperature (Tg), and the heat resistance was evaluated according to the following criteria.
Evaluation A: The thermal decomposition temperature was 410° C. or higher
Evaluation B: The thermal decomposition temperature was 320° C. or higher and lower than 410° C.
Evaluation C: The thermal decomposition temperature was lower than 320° C.

TABLE 1B

| | |
|---|---|
| | Heat |
| | resistance |
| Resin | evaluation |

| | | | |
|---|---|---|---|
| Example 1 | Synthesis Working | RBisN-1 | A |
| | Example 1 | | |
| Example 2 | Synthesis Working | RBisN-2 | A |
| | Example 2 | | |
| Example 3 | Synthesis Working | RBisN-3 | A |
| | Example 3 | | |
| Example 4 | Synthesis Working | RBisN-4 | A |
| | Example 4 | | |
| Example 5 | Synthesis Working | RBisN-5 | A |
| | Example 5 | | |
| Example 6 | Synthesis Working | RBisN-6 | A |
| | Example 6 | | |
| Comparative | Comparative | NBisN-2 | C |
| Example 1 | Synthesis Example 1 | | |

As is evident from Table 1B, it was able to be confirmed that the resins used in Examples 1 to 6 have good heat resistance whereas the resins used in Comparative Example 1 is inferior in heat resistance.

### Example Group 3: Examples 7 to 12 and Comparative Example 2

### (Preparation of Composition for Underlayer Film Formation for Lithography)

Compositions for underlayer film formation for lithography were prepared according to the composition shown in Table 2B. Next, a silicon substrate was spin coated with each of these compositions for underlayer film formation for lithography, and then baked at 240° C. for 60 seconds and further at 400° C. for 120 seconds under a nitrogen gas atmosphere to prepare each underlayer film having a film thickness of 200 to 250 nm.

Next, etching test was conducted under conditions shown below to evaluate etching resistance. The evaluation results are shown in Table 2B. Details of the evaluation method will be described later.

### <Etching Test>

Etching apparatus: “RIE-10NR” manufactured by Samco International, Inc.
Output: 50 W
Pressure: 20 Pa
Time: 2 min

Etching Gas
Ar gas flow rate:CF₄ gas flow rate:O₂ gas flow rate=50:5:5 (sccm)

### (Evaluation of Etching Resistance)

The evaluation of etching resistance was conducted by the following procedures. First, an underlayer film of novolac was prepared under the same conditions as described above except that novolac (“PSM4357” manufactured by Gun Ei Chemical Industry Co., Ltd.) was used. This underlayer film of novolac was subjected to the above etching test, and the etching rate was measured.

Next, for the underlayer films of Examples 7 to 12 and Comparative Example 2, the etching test was performed in the same manner, and the etching rate was measured. Then, the etching resistance for each of Examples and Comparative Example was evaluated according to the following evaluation criteria on the basis of the etching rate of the underlayer film of novolac.

[Evaluation Criteria]
A: The etching rate was less than −20% as compared with the underlayer film of novolac.
B: The etching rate was −20% or more and 0% or less as compared with the underlayer film of novolac.
C: The etching rate was more than +0% as compared with the underlayer film of novolac.

TABLE 2B

| | | | | Etching |
|---|---|---|---|---|
| | Resin (parts | | Solvent (parts | evalu- |
| | by mass) | | by mass) | ation |
| Example 7 | Synthesis Working | RBisN-1 | PGMEA | A |
| | Example 1 | (10) | (90) | |
| Example 8 | Synthesis Working | RBisN-2 | PGMEA | A |
| | Example 2 | (10) | (90) | |
| Example 9 | Synthesis Working | RBisN-3 | PGMEA | A |
| | Example 3 | (10) | (90) | |
| Example 10 | Synthesis Working | RBisN-4 | PGMEA | A |
| | Example 4 | (10) | (90) | |
| Example 11 | Synthesis Working | RBisN-5 | PGMEA | A |
| | Example 5 | (10) | (90 | |
| Example 12 | Synthesis Working | RBisN-6 | PGMEA | A |
| | Example 6 | (10) | (90) | |
| Comparative | Comparative | NBisN-2 | cyclohexanone | B |
| Example 2 | Synthesis | (10) | (90) | |
| | Example 1 | | | |

It was found that an excellent etching rate is exerted in Examples 7 to 12 as compared with the underlayer film of novolac and the resin of Comparative Example 2. On the other hand, it was found that the etching rate of the resin of Comparative Example 2 was equivalent to that of the underlayer film of novolac.

### <<Purification of Polycyclic Polyphenolic Resin (Composition Containing Polycyclic Polyphenolic Resin)>>

The metal content before and after purification of polycyclic polyphenolic resin (composition containing the polycyclic polyphenolic resin) and the storage stability of the solution were evaluated by the following method.

### <Measurement of Various Metal Contents>

The metal contents of the propylene glycol monomethyl ether acetate (PGMEA) solutions of various resins obtained in the following Examples and Comparative Examples were measured using inductively coupled plasma mass spectrometry (ICP-MS) under the following measurement conditions.
Apparatus: AG8900 manufactured by Agilent Technologies
Temperature: 25° C.
Environment: Class 100 clean room

### <Storage Stability Evaluation>

The PGMEA solutions obtained in the following Examples and Comparative Examples were retained at 23° C. for 240 hours, and then the turbidity (HAZE) of the solutions was measured using a color difference/turbidity meter to evaluate the storage stability of the solutions according to the following criteria.
Apparatus: Color difference/turbidity meter COH400 (manufactured by NIPPON DENSHOKU INDUSTRIES CO., LTD.)
Optical path length: 1 cm

Quartz Cell Use

### [Evaluation Criteria]

0≤HAZE≤1.0: Good
1.0<HAZE≤2.0: Fair
2.0<HAZE: Poor

### [Example Group 3: Example 13] Purification of RBisN-1 with Acid

In a four necked flask (capacity: 1000 mL, with a detachable bottom), 150 g of a solution (10% by mass) formed by dissolving RBisN-1 obtained in Synthesis Working Example 1 in PGMEA was charged, and was heated to 80° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Thereafter, by diluting with PGMEA of EL grade (a reagent manufactured by KANTO CHEMICAL CO., INC.) such that the concentration of the PGMEA solution was adjusted to 10% by mass, a PGMEA solution of RBisN-1 with a reduced metal content was obtained.

### [Example Group 3: Reference Example 1] Purification of RBisN-1 with Ultrapure Water

In the same manner as of Example 13 except that ultrapure water was used instead of the aqueous oxalic acid solution, and by adjusting the concentration to 10% by mass, a PGMEA solution of RBisN-1 was obtained.

For the 10% by mass PGMEA solution of RBisN-1 before the treatment, and the solutions obtained in Example 13 and Reference Example 1, the contents of various metals were measured by ICP-MS. The measurement results are shown in Table 3B.

### [Example Group 3: Example 14] Purification of RBisN-2 with Acid

In a four necked flask (capacity: 1000 mL, with a detachable bottom), 140 g of a solution (10% by mass) formed by dissolving RBisN-2 obtained in Synthesis Working Example 2 in PGMEA was charged, and was heated to 60° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Thereafter, by diluting with PGMEA of EL grade (a reagent manufactured by KANTO CHEMICAL CO., INC.) such that the concentration of the PGMEA solution was adjusted to 10% by mass, a PGMEA solution of RBisN-2 with a reduced metal content was obtained.

### [Example Group 3: Reference Example 2] Purification of RBisN-2 with Ultrapure Water

In the same manner as of Example 14 except that ultrapure water was used instead of the aqueous oxalic acid solution, and by adjusting the concentration to 10% by mass, a PGMEA solution of RBisN-2 was obtained.

For the 10% by mass of PGMEA solution of RBisN-2 before the treatment, and the solutions obtained in Example 14 and Reference Example 2, the contents of various metals were measured by ICP-MS. The measurement results are shown in Table 3B.

### [Example Group 3: Example 15] Purification by Passing Through Filter

In a class 1000 clean booth, 500 g of a solution of 10% by mass concentration of the resin (RBisN-1) obtained in Synthesis Working Example 1 dissolved in propylene glycol monomethyl ether (PGME) was charged in a four necked flask (capacity: 1000 mL, with a detachable bottom), and then the air inside the vessel was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 100 mL per minute to a hollow fiber membrane filter (manufactured by KITZ MICRO FILTER CORPORATION, trade name: Polyfix Nylon Series) made of nylon with a nominal pore size of 0.01 μm. The contents of various metals in the obtained RBisN-1 solution were measured by ICP-MS. The oxygen concentration was measured with an oxygen concentration meter “OM-25MF10” manufactured by AS ONE Corporation (the same applies hereinafter). The measurement results are shown in Table 3B.

### Example Group 3: Example 16

The solution was passed through in the same manner as in Example 15 except that a hollow fiber membrane filter (KITZ MICRO FILTER CORPORATION, trade name: Polyfix) made of polyethylene (PE) with a nominal pore size of 0.01 μm was used, and the contents of various metals in the obtained RBisN-1 solution were measured by ICP-MS. The measurement results are shown in Table 3B.

### Example Group 3: Example 17

The solution was passed through in the same manner as in Example 15 except that a hollow fiber membrane filter (KITZ MICRO FILTER CORPORATION, trade name: Polyfix) made of nylon with a nominal pore size of 0.04 μm was used, and the contents of various metals in the obtained RBisN-1 were measured by ICP-MS. The measurement results are shown in Table 3B.

### Example Group 3: Example 18

The solution was passed through in the same manner as in Example 15 except that a Zeta Plus filter 40QSH (manufactured by 3M Company, having an ion exchange capacity) with a nominal pore size of 0.2 μm was used, and the contents of various metals in the obtained RBisN-1 solution were measured by ICP-MS. The measurement results are shown in Table 3B.

### Example Group 3: Example 19

The solution was passed through in the same manner as in Example 15 except that a Zeta Plus filter 020GN (manufactured by 3M Company, having an ion exchange capacity, and having different filtration areas and filter material thicknesses from those of Zeta Plus filter 40QSH) with a nominal pore size of 0.2 μm was used, and the obtained RBisN-1 solution was analyzed under the following conditions. The measurement results are shown in Table 3B.

### Example Group 3: Example 20

The solution was passed through in the same manner as in Example 15 except that the resin (RBisN-2) obtained in Synthesis Working Example 2 was used instead of the resin (RBisN-1) in Example 15, and the contents of various metals in the obtained RBisN-2 solutions were measured by ICP-MS. The measurement results are shown in Table 3B.

### Example Group 3: Example 21

The solution was passed through in the same manner as in Example 16 except that the resin (RBisN-2) obtained in Synthesis Working Example 2 was used instead of the resin (RBisN-1) in Example 16, and the contents of various metals in the obtained RBisN-2 solutions were measured by ICP-MS. The measurement results are shown in Table 3B.

### Example Group 3: Example 22

The solution was passed through in the same manner as in Example 17 except that the resin (RBisN-2) obtained in Synthesis Working Example 2 was used instead of the compound (RBisN-1) in Example 17, and the contents of various metals in the obtained RBisN-2 solutions were measured by ICP-MS. The measurement results are shown in Table 3B.

### Example Group 3: Example 23

The solution was passed through in the same manner as in Example 18 except that the resin (RBisN-2) obtained in Synthesis Working Example 2 was used instead of the compound (RBisN-1) in Example 18, and the contents of various metals in the obtained RBisN-2 solutions were measured by ICP-MS. The measurement results are shown in Table 3B.

### Example Group 3: Example 24

The solution was passed through in the same manner as in Example 19 except that the resin (RBisN-2) obtained in Synthesis Working Example 2 was used instead of the compound (RBisN-1) in Example 19, and the contents of various metals in the obtained RBisN-2 solutions were measured by ICP-MS. The measurement results are shown in Table 3B.

### [Example Group 3: Example 25] Combination of Acid Washing and Filter Passage 1

In a class 1000 clean booth, 140 g of the 10% by mass PGMEA solution of RBisN-1 with a reduced metal content obtained by Example 13 was prepared in a four necked flask (capacity: 300 mL, with a detachable bottom), and then the air inside the vessel was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, passed through a pressure tube made of fluororesin through a diaphragm pump at a flow rate of 10 mL per minute to an ion exchange filter (manufactured by Nihon Pall Ltd., product name: IonKleen Series) with a nominal pore size of 0.01 μm. The recovered solution was then returned to the four necked flask (capacity: 300 mL), and the filter was changed to a filter made of high-density PE with a nominal diameter of 1 nm (manufactured by Entegris Japan Co., Ltd.), and pumped through the flask in the same manner. The contents of various metals in the obtained RBisN-1 solution were measured by ICP-MS. The oxygen concentration was measured with an oxygen concentration meter “OM-25MF10” manufactured by AS ONE Corporation (the same applies hereinafter). The measurement results are shown in Table 3B.

### [Example Group 3: Example 26] Combination of Acid Washing and Filter Passage 2

In a class 1000 clean booth, 140 g of the 10% by mass PGMEA solution of RBisN-1 with a reduced metal content obtained by Example 13 was prepared in a four necked flask (capacity: 300 mL, with a detachable bottom), and then the air inside the vessel was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 10 mL per minute to a hollow fiber membrane filter (manufactured by KITZ MICRO FILTER CORPORATION, trade name: Polyfix) made of nylon with a nominal pore size of 0.01 μm. The recovered solution was then returned to the four necked flask (capacity: 300 mL), and the filter was changed to a filter made of high-density PE with a nominal diameter of 1 nm (manufactured by Entegris Japan Co., Ltd.), and pumped through the flask in the same manner. The contents of various metals in the obtained RBisN-1 solution were measured by ICP-MS. The oxygen concentration was measured with an oxygen concentration meter “OM-25MF10” manufactured by AS ONE Corporation (the same applies hereinafter). The measurement results are shown in Table 3B.

### [Example Group 3: Example 27] Combination of Acid Washing and Filter Passage 3

The same procedure as in Example 25 was carried out except that the 10% by mass PGMEA solution of RBisN-1 used in Example 25 was changed to the 10% by mass PGMEA solution of RBisN-2 obtained by Example 14 to recover a 10% by mass PGMEA solution of RBisN-2 with a reduced metal amount. The contents of various metals in the obtained RBisN-1 solution were measured by ICP-MS. The oxygen concentration was measured with an oxygen concentration meter “OM-25MF10” manufactured by AS ONE Corporation (the same applies hereinafter). The measurement results are shown in Table 3B.

### [Example Group 3: Example 28] Combination of Acid Washing and Filter Passage 4

The same procedure as in Example 26 was carried out except that the 10% by mass PGMEA solution of RBisN-1 used in Example 26 was changed to the 10% by mass PGMEA solution of RBisN-2 obtained by Example 14 to recover a 10% by mass PGMEA solution of RBisN-2 with a reduced metal amount. The contents of various metals in the obtained RBisN-1 solution were measured by ICP-MS. The oxygen concentration was measured with an oxygen concentration meter “OM-25MF10” manufactured by AS ONE Corporation (the same applies hereinafter). The measurement results are shown in Table 3B.

TABLE 3B

| | | Metal content (ppb) | | | | |
|---|---|---|---|---|---|---|
| | Purification method | Cr | Fe | Cu | Zn | Storage stability |
| before | — | 126 | 465 | 912 | 100 | poor |
| treatment | | | | | | |
| RBisN-1 | | | | | | |
| Example 13 | acid washing | 18 | 20 | 74 | 10 | good |
| Example 15 | hollow fiber membrane nylon | 8 | 8 | 18 | 14 | good |
| | filter | | | | | |
| Example 16 | PE | 112 | 102 | 270 | 90 | fair |
| | filter | | | | | |
| Example 17 | hollow fiber membrane nylon | 13 | 12 | 24 | 10 | good |
| | filter | | | | | |
| Example 18 | zeta potential filter | 15 | 11 | 24 | 6 | good |
| Example 19 | zeta potential filter | 13 | 18 | 30 | 12 | good |
| Example 25 | combined use of acid washing/ | <0.1 | <0.1 | <0.1 | <0.1 | good |
| | ion exchange filter/ PE filter | | | | | |
| Example 26 | combined use of acid washing/ | <0.1 | <0.1 | <0.1 | <0.1 | good |
| | hollow fiber membrane nylon | | | | | |
| | filter/ PE filter | | | | | |
| Reference | water washing | 101 | 310 | 641 | 94 | poor |
| Example 1 | | | | | | |
| before | — | 109 | 365 | 865 | 195 | poor |
| treatment | | | | | | |
| RBisN-2 | | | | | | |
| Example 14 | acid washing | 24 | 24 | 52 | 18 | good |
| Example 20 | hollow fiber membrane nylon | 10 | 10 | 29 | 13 | good |
| | filter | | | | | |
| Example 21 | PE | 93 | 146 | 355 | 132 | fair |
| | filter | | | | | |
| Example 22 | hollow fiber membrane nylon | 10 | 12 | 35 | 8 | good |
| | filter | | | | | |
| Example 23 | zeta potential filter | 12 | 20 | 24 | 5 | good |
| Example 24 | zeta potential filter | 10 | >99 | 3 | 97 | good |
| Example 27 | combined use of acid washing/ | <0.1 | <0.1 | <0.1 | <0.1 | good |
| | ion exchange filter/ PE filter | | | | | |
| Example 28 | combined use of acid washing/ | <0.1 | <0.1 | <0.1 | <0.1 | good |
| | hollow fiber membrane nylon | | | | | |
| | filter/ PE filter | | | | | |
| Reference | water washing | 90 | 242 | 530 | 185 | poor |
| Example 2 | | | | | | |

As shown in Table 3B, it was confirmed that the storage stability of the resin solutions according to the present embodiment was improved by reducing the metal derived from the oxidizing agent through various purification methods.

In particular, the acid washing method and the use of ion exchange or nylon filters can effectively reduce ionic metals, and the combination of high-definition high-density polyethylene particulate removal filters can provide dramatic metal removal effects.

### Example Group 3: Examples 29 to 35 and Comparative Example 3

### <Heat Resistance and Resist Performance>

By using the resins obtained in Synthesis Working Examples 1 to 6 and Comparative Synthesis Example 1, the test for heat resistance and evaluation of resist performance below were carried out, and the results thereof are shown in Table 4B.

### (Preparation of Resist Composition)

A resist composition was prepared according to the recipe shown in Table 4B using each resin synthesized as described above. For the components of the resist compositions in Table 4B, the following acid generating agent (C), acid diffusion controlling agent (E), and solvent were used.

Acid Generating Agent (C)
P-1: triphenylbenzenesulfonium trifluoromethanesulfonate (Midori Kagaku Co., Ltd.)

Acid Crosslinking Agent (G)
C-1: NIKALAC MW-100LM (SANWA Chemical Co., Ltd.) Acid diffusion controlling agent (E)
Q-1: trioctylamine (TOKYO KASEI KOGYO CO., LTD.) Solvent
S-1: propylene glycol monomethyl ether (TOKYO KASEI KOGYO CO., LTD.)

### (Method for Evaluating Resist Performance of Resist Composition)

A clean silicon wafer was spin coated with the homogeneous resist composition, and then prebaked (PB) before exposure in an oven of 110° C. to form a resist film with a thickness of 60 nm. The obtained resist film was irradiated with electron beams of 1:1 line and space setting with a 50 nm interval using an electron beam lithography system (ELS-7500 manufactured by ELIONIX INC.). After the irradiation, the resist film was heated at each predetermined temperature for 90 seconds, and immersed in 2.38% by mass tetramethylammonium hydroxide (TMAH) alkaline developing solution for 60 seconds for development. Thereafter, the resist film was washed with ultrapure water for 30 seconds, and dried to form a positive type resist pattern. Concerning the formed resist pattern, the line and space were observed by a scanning electron microscope (S-4800 manufactured by Hitachi High-Technologies Corporation) to evaluate the reactivity by electron beam irradiation of the resist composition.

TABLE 4B

| | | Resist composition | | | | | Resist |
|---|---|---|---|---|---|---|---|
| | | Resin | P-1 | C-1 | Q-1 | S-1 | performance |
| | Resin | [g] | [g] | [g] | [g] | [g] | evaluation |
| Example 29 | RBisN-1 | 1.0 | 0.3 | 0.3 | 0.03 | 50.0 | good |
| Example 30 | RBisN-2 | 1.0 | 0.3 | 0.3 | 0.03 | 50.0 | good |
| Example 31 | RBisN-3 | 1.0 | 0.3 | 0.3 | 0.03 | 50.0 | good |
| Example 32 | RBisN-4 | 1.0 | 0.3 | 0.3 | 0.03 | 50.0 | good |
| Example 33 | RBisN-5 | 1.0 | 0.3 | 0.3 | 0.03 | 50.0 | good |
| Example 34 | RBisN-6 | 1.0 | 0.3 | 0.3 | 0.03 | 50.0 | good |
| Example 35 | RBisN-1 | 1.0 | 0.3 | 0.3 | 0 | 50.0 | good |
| Comparative | NBisN-2 | 1.0 | 0.3 | 0.3 | 0.03 | 50.0 | poor |
| Example 3 | | | | | | | |

In the resist pattern evaluation, a good resist pattern was obtained by irradiation with electron beams of 1:1 line and space setting with 5 nm interval in each of Examples 29 to 35. As for the line edge roughness, a pattern having asperities of less than 5 nm was evaluated to be good. On the other hand, it was not possible to obtain a good resist pattern in Comparative Example 3.

When the resin satisfying the requirements of the present embodiment is used as described above, the resin can have the high heat resistance and can impart a good shape to a resist pattern, as compared with the resin (NBisN-2) of Comparative Example 3 which does not satisfy the requirements. As long as the above requirements of the present embodiment are met, compounds other than the resins described in Examples also exhibit the same effects.

### Example Group 3: Examples 36 to 41 and Comparative Example 4

### (Preparation of Radiation-Sensitive Composition)

The components set forth in the following Table 5 were formulated and formed into homogeneous solutions, and the obtained homogeneous solutions were filtered through a Teflon® membrane filter with a pore diameter of 0.1 μm to prepare radiation-sensitive compositions. Each of the prepared radiation-sensitive compositions was evaluated as described below.

TABLE 5B

Composition

| | | Optically | |
|---|---|---|---|
| | | active | |
| | Component (A) | compound (B) | Solvent |
| | [g] | [g] | [g] |
| Example 36 | RBisN-1 | B-1 | S-1 |
| | 0.5 | 1.5 | 30.0 |
| Example 37 | RBisN-2 | B-1 | S-1 |
| | 0.5 | 1.5 | 30.0 |
| Example 38 | RBisN-3 | B-1 | S-1 |
| | 0.5 | 1.5 | 30.0 |
| Example 39 | RBisN-4 | B-1 | S-1 |
| | 0.5 | 1.5 | 30.0 |
| Example 40 | RBisN-5 | B-1 | S-1 |
| | 0.5 | 1.5 | 30.0 |
| Example 41 | RBisN-6 | B-1 | S-1 |
| | 0.5 | 1.5 | 30.0 |
| Comparative | PHS-1 | B-1 | S-1 |
| Example 4 | 0.5 | 1.5 | 30.0 |

The following resist base material (component (A)) was used in Comparative Example 4.
PHS-1: polyhydroxystyrene Mw=8000 (Sigma-Aldrich)

The following optically active compound (B) was used.
B-1: naphthoquinonediazide-based sensitizing agent having the following chemical structural formula (C-G) (product name “4NT-300”, Toyo Gosei Co., Ltd.)

The following solvent was used.
S-1: propylene glycol monomethyl ether (TOKYO KASEI KOGYO CO., LTD.)

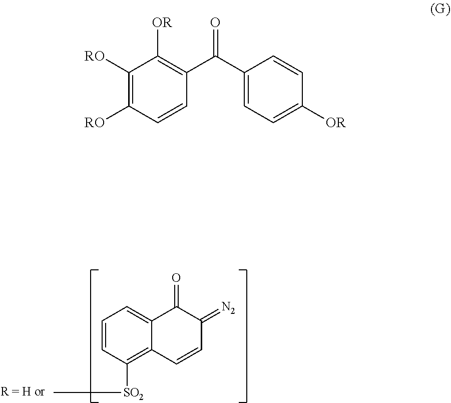

### <Evaluation of Resist Performance of Radiation-Sensitive Composition>

A clean silicon wafer was spin coated with the radiation-sensitive composition obtained as described above, and then prebaked (PB) before exposure in an oven of 110° C. to form a resist film with a thickness of 200 nm. The resist film was exposed to ultraviolet using an ultraviolet exposure apparatus (mask aligner MA-10 manufactured by Mikasa Co., Ltd.). The ultraviolet lamp used was a super high pressure mercury lamp (relative intensity ratio: g-ray:h-ray:i-ray:j-ray=100:80:90:60). After irradiation, the resist film was heated at 110° C. for 90 seconds, and immersed in a 2.38% by mass TMAH alkaline developing solution for 60 seconds for development. Thereafter, the resist film was washed with ultrapure water for 30 seconds, and dried to form a 5 μm positive type resist pattern.

The obtained line and space were observed in the formed resist pattern by a scanning electron microscope (“S-4800” manufactured by Hitachi High-Technologies Corporation). As for the line edge roughness, a pattern having asperities of less than 5 nm was evaluated to be good.

In the case of using the radiation-sensitive composition according to each of Examples 36 to 41, a good resist pattern with a resolution of 5 μm was able to be obtained. The roughness of the pattern was also small and good.

On the other hand, in the case of using the radiation-sensitive composition according to Comparative Example 4, a good resist pattern with a resolution of 5 μm was able to be obtained. However, the roughness of the pattern was large and poor.

As described above, it was found that each of the radiation-sensitive compositions according to Examples 36 to 41 can form a resist pattern that has small roughness and a good shape, as compared with the radiation-sensitive composition according to Comparative Example 4. As long as the above requirements of the present embodiment are met, radiation-sensitive compositions other than those described in Examples also exhibit the same effects.

Each of the resins obtained in Synthesis Working Examples 1 to 6 has a relatively low molecular weight and a low viscosity. As such, it was evaluated that the embedding properties and film surface flatness of underlayer film forming materials for lithography containing these compounds or resins can be relatively advantageously enhanced. Furthermore, each of these compounds or resins has a thermal decomposition temperature of 150° C. or higher (evaluation A) and has high heat resistance, so that it was evaluated that they can be used even under high temperature baking conditions. In order to confirm these points, the following evaluation was performed assuming the application to the underlayer film.

### Example Group 3: Examples 42 to 48 and Comparative Examples 5 to 6

### (Preparation of Composition for Underlayer Film Formation for Lithography)

Compositions for underlayer film formation for lithography were prepared according to the composition shown in Table 6B. Next, a silicon substrate was spin coated with each of these compositions for underlayer film formation for lithography, and then baked at 240° C. for 60 seconds and further at 400° C. for 120 seconds to prepare each underlayer film having a film thickness of 200 nm. The following acid generating agent, crosslinking agent, and organic solvent were used.
Acid generating agent: di-tertiary butyl diphenyliodonium nonafluoromethanesulfonate (DTDPI) manufactured by Midori Kagaku Co., Ltd.
Crosslinking agent: “NIKALAC MX270” (NIKALAC) manufactured by SANWA Chemical Co., Ltd.
Organic solvent: cyclohexanone Organic solvent: propylene glycol monomethyl ether acetate (PGMEA)

Next, etching test was conducted under conditions shown below to evaluate etching resistance. The evaluation results are shown in Table 6B. Details of the evaluation method will be described later.

### <Etching Test>

Etching apparatus: “RIE-10NR” manufactured by Samco International, Inc.
Output: 50 W
Pressure: 20 Pa
Time: 2 min

Etching Gas
Ar gas flow rate:CF₄ gas flow rate:O₂ gas flow rate=50:5:5 (sccm)

### <Evaluation of Etching Resistance>

The evaluation of etching resistance was conducted by the following procedures. First, an underlayer film of novolac was prepared under the same conditions as described above except that novolac (“PSM4357” manufactured by Gun Ei Chemical Industry Co., Ltd.) was used. This underlayer film of novolac was subjected to the above etching test, and the etching rate was measured.

Next, for the underlayer films of Examples 42 to 48 and Comparative Examples 5 and 6, the etching test was performed in the same manner, and the etching rate was measured. Then, the etching resistance for each of Examples and Comparative Example was evaluated according to the following evaluation criteria on the basis of the etching rate of the underlayer film of novolac.

[Evaluation Criteria]
A: The etching rate was less than −20% as compared with the underlayer film of novolac.
B: The etching rate was −20% or more and 0% or less as compared with the underlayer film of novolac.
C: The etching rate was more than +0% as compared with the underlayer film of novolac.

TABLE 6B

| | | | Acid | | |
|---|---|---|---|---|---|
| | | | generating | Crosslinking | |
| | Resin | Solvent | agent | agent at | |
| | (parts | (parts | (parts | (parts | Etching |
| | by mass) | by mass) | by mass) | by mass) | resistance |
| Example 42 | RBisN-1 | PGMEA | DTDPI | NIKALAC | A |
| | (10) | (90) | (0.5 | (0.5) | |
| Example 43 | RBisN-2 | PGMEA | DTDPI | NIKALAC | A |
| | (10) | (90) | (0.5) | (0.5) | |
| Example 44 | RBisN-3 | PGMEA | DTDPI | NIKALAC | A |
| | (10) | (90) | (0.5 | (0.5) | |
| Example 45 | RBisN-4 | PGMEA | DTDPI | NIKALAC | A |
| | (10) | (90) | (0.5) | (0.5) | |
| Example 46 | RBisN-5 | PGMEA | DTDPI | NIKALAC | A |
| | (10) | (90) | (0.5 | (0.5) | |
| Example 47 | RBisN-6 | PGMEA | DTDPI | NIKALAC | A |
| | (10) | (90) | (0.5) | (0.5) | |
| Example 48 | RBisN-1 | cyclohexanone/ | — | NIKALAC | A |
| | (10) | PGMEA | | (0.5) | |
| | | (81/9) | | | |
| Comparative | CR-1 | PGMEA | DTDPI | NIKALAC | C |
| Example 5 | (Comparative | (90) | (0.5 | (0.5) | |
| | Synthesis | | | | |
| | Example 2) | | | | |
| | (10) | | | | |
| Comparative | NBisN-2 | PGMEA | DTDPI | NIKALAC | B |
| Example 6 | (10) | (90) | (0.5) | (0.5) | |

It was found that an excellent etching rate is exerted in Examples 42 to 48 as compared with the underlayer film of novolac and the resin of Comparative Example 5 to 6. On the other hand, it was found that in the resin of Comparative Example 5 or 6, the etching rate was equal to or inferior to that of the underlayer film of novolac.

### Example Group 3: Examples 49 to 55 and Comparative Example 7

Next, a SiO₂ substrate having a film thickness of 80 nm and a line and space pattern of 60 nm was coated with each of the compositions for underlayer film formation for lithography prepared in Examples 42 to 48 and Comparative Example 5, and baked at 240° C. for 60 seconds to form a 90 nm underlayer film.

### (Evaluation of Embedding Properties)

The embedding properties were evaluated by the following procedures. The cross section of the film obtained under the above conditions was cut out and observed under an electron microscope to evaluate the embedding properties. The evaluation results are shown in Table 7B.

[Evaluation Criteria]
A: The underlayer film was embedded without defects in the asperities of the SiO₂ substrate having a line and space pattern of 60 nm.
C: The asperities of the SiO₂ substrate having a line and space pattern of 60 nm had defects which hindered the embedding of the underlayer film.

TABLE 7B

| | Composition for | |
|---|---|---|
| | underlayer film | |
| | formation for | Embedding |
| | lithography | properties |
| Example 49 | Example 42 | A |
| Example 50 | Example 43 | A |
| Example 51 | Example 44 | A |
| Example 52 | Example 45 | A |
| Example 53 | Example 46 | A |
| Example 54 | Example 47 | A |
| Example 55 | Example 48 | A |
| Comparative | Comparative | C |
| Example 7 | Example 5 | |

It was found that embedding properties are good in Examples 49 to 55. On the other hand, it was found that defects are seen in the asperities of the SiO₂ substrate and embedding properties are poor in Comparative Example 7.

### Example Group 3: Examples 56 to 62

Next, a SiO₂ substrate having a film thickness of 300 nm was coated with each composition for underlayer film formation for lithography used in Examples 42 to 48, and baked at 240° C. for 60 seconds and further at 400° C. for 120 seconds to form an underlayer film having a film thickness of 85 nm.

This underlayer film was coated with a resist solution for ArF and baked at 130° C. for 60 seconds to form a photoresist layer having a film thickness of 140 nm.

The ArF resist solution used was prepared by containing 5 parts by mass of a compound of the formula (16) given below, 1 part by mass of triphenylsulfonium nonafluoromethanesulfonate, 2 parts by mass of tributylamine, and 92 parts by mass of PGMEA.

The compound of the following formula (16) was prepared as follows. That is, 4.15 g of 2-methyl-2-methacryloyloxyadamantane, 3.00 g of methacryloyloxy-γ-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The product resin thus obtained was solidified and purified, and the resulting white powder was filtered and dried overnight at 40° C. under reduced pressure to obtain a compound represented by the following formula (16).

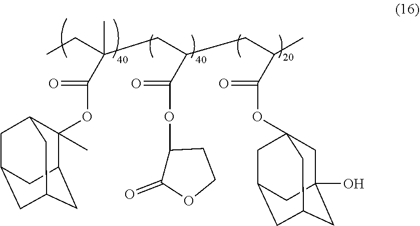

(In the formula (16), 40, 40, and 20 represent the ratio of each repeating unit and do not represent a block copolymer.)

Then, the photoresist layer was exposed using an electron beam lithography system (manufactured by ELIONIX INC.; ELS-7500, 50 keV), baked (PEB) at 115° C. for 90 seconds, and developed for 60 seconds in a 2.38% by mass tetramethylammonium hydroxide (TMAH) aqueous solution to obtain a positive type resist pattern.

### Example Group 3: Comparative Example 8

The same operations as in Example 56 were performed except that no underlayer film was formed so that a photoresist layer was formed directly on a SiO₂ substrate to obtain a positive type resist pattern.

### <Evaluation of Resist Pattern>

Concerning each of Examples 56 to 62 and Comparative Example 8, the shapes of the obtained 45 nm L/S (1:1) and 80 nm L/S (1:1) resist patterns were observed under an electron microscope manufactured by Hitachi, Ltd. “S-4800”. The shapes of the resist patterns after development were evaluated as “goodness” when having good rectangularity without pattern collapse, and as “poorness” if this was not the case. The smallest line width having good rectangularity without pattern collapse as a result of this observation was used as an index for resolution evaluation. The smallest electron beam energy quantity capable of lithographing good pattern shapes was used as an index for sensitivity evaluation. The results are shown in Table 8B.

TABLE 8B

| | Composition for | | | Resist |
|---|---|---|---|---|
| | underlayer film | | | pattern |
| | formation for | Resolution | Sensitivity | shape after |
| | lithography | (nmL/S) | (μC/cm²) | development |
| Example 56 | Example 42 | 45 | 10 | good |
| Example 57 | Example 43 | 45 | 10 | good |
| Example 58 | Example 44 | 45 | 10 | good |
| Example 59 | Example 45 | 45 | 10 | good |
| Example 60 | Example 46 | 45 | 10 | good |
| Example 61 | Example 47 | 45 | 10 | good |
| Example 62 | Example 48 | 45 | 10 | good |
| Comparative | none | 81 | 25 | poor |
| Example 8 | | | | |

As is evident from Table 8B, the resist pattern of Examples 56 to 62 was confirmed to be significantly superior in both resolution and sensitivity to Comparative Example 8. Also, the resist pattern shapes after development were confirmed to have good rectangularity without pattern collapse. The difference in the resist pattern shapes after development indicated that the composition for underlayer film formation for lithography of Examples 42 to 48 has good adhesiveness to a resist material.

### Example Group 3: Example 63

A SiO₂ substrate having a film thickness of 300 nm was coated with the composition for underlayer film formation for lithography prepared in Example 42, and baked at 240° C. for 60 seconds and further at 400° C. for 120 seconds to form an underlayer film having a film thickness of 90 nm. This underlayer film was coated with a silicon-containing intermediate layer material and baked at 200° C. for 60 seconds to form an intermediate layer film having a film thickness of 35 nm. This intermediate layer film was further coated with the above resist solution for ArF and baked at 130° C. for 60 seconds to form a photoresist layer having a film thickness of 150 nm. The silicon-containing intermediate layer material used was the silicon atom-containing polymer (polymer 1) described in <Synthesis Example 1> of Japanese Patent Laid-Open No. 2007-226170.

Then, the photoresist layer was mask exposed using an electron beam lithography system (manufactured by ELIONIX INC.; “ELS-7500, 50 keV”), baked (PEB) at 115° C. for 90 seconds, and developed for 60 seconds in 2.38% by mass tetramethylammonium hydroxide (TMAH) aqueous solution to obtain a 45 nm L/S (1:1) positive type resist pattern.

Thereafter, the silicon-containing intermediate layer film (SOG) was dry etched with the obtained resist pattern as a mask using “RIE-10NR” manufactured by Samco International, Inc. Subsequently, dry etching of the underlayer film with the obtained silicon-containing intermediate layer film pattern as a mask and dry etching of the SiO₂ film with the obtained underlayer film pattern as a mask were performed in order.

Respective etching conditions are as shown below.

Etching Conditions for Resist Intermediate Layer Film with Resist Pattern
Output: 50 W
Pressure: 20 Pa
Time: 1 min

Etching Gas
Ar gas flow rate:CF₄ gas flow rate:O₂ gas flow rate=50:8:2 (sccm)
   Etching Conditions for Resist Underlayer Film with Resist Intermediate Film Pattern
Output: 50 W
Pressure: 20 Pa
Time: 2 min

Etching Gas
Ar gas flow rate:CF₄ gas flow rate:O₂ gas flow rate=50:5:5 (sccm)
   Etching Conditions for SiO₂ Film with Resist Underlayer Film Pattern
Output: 50 W
Pressure: 20 Pa
Time: 2 min

Etching Gas
Ar gas flow rate:C₅F₁₂ gas flow rate:C₂F₆ gas flow rate:O₂ gas flow rate=50:4:3:1 (sccm)

### <Evaluation of Pattern Shape>

The pattern cross section (the shape of the SiO₂ film after etching) of Example 63 obtained as described above was observed under an electron microscope manufactured by Hitachi, Ltd. “5-4800”. As a result, it was confirmed that the shape of the SiO₂ film after etching in a multilayer resist process is a rectangular shape in Examples using the underlayer film of the present invention and is good without defects.

### <Characteristic Evaluation of Resin Film (Resin Single Film)>

### <Preparation of Resin Film>

### Example Group 3: Example A01

Using PGMEA as a solvent, the resin RBisN-1 of Synthesis Working Example 1 was dissolved to prepare a resin solution having a solid content concentration of 10% by mass (resin solution of Example A01).

The prepared resin solution was formed on a 12 inch silicon wafer using a spin coater Lithius Pro (manufactured by Tokyo Electron Ltd.), and after forming a film while adjusting the number of revolutions so as to have a film thickness of 200 nm, the baking was performed under the condition of a baking temperature of 250° C. for 1 minute to prepare a substrate on which a film made of the resin of Synthesis Working Example 1 was laminated. The prepared substrate was further baked under the condition of 350° C. for 1 minute using a hot plate capable of treating at a high temperature to obtain a cured resin film. At this time, when the change in film thickness before and after immersing the obtained cured resin film in the PGMEA tank for 1 minute was 3% or less, it was determined that the film was cured. When the curing was determined to be insufficient, the curing temperature was changed by 50° C. to investigate the curing temperature, and baking for curing was performed under the condition of the lowest temperature in the curing temperature range.

### <Optical Characteristic Values Evaluation>

The prepared resin film was evaluated for optical characteristic values (refractive index n and extinction coefficient k as optical constants) using “spectroscopic ellipsometry VUV-VASE” (manufactured by J.A. Woollam).

### Example Group 3: Examples A02 to A06 and Comparative Example A01

The resin film was prepared in the same manner as in Example A01 except that the resins used were changed from RBisN-1 to the resins shown in Table 9B, and the optical characteristic values were evaluated.

### [Evaluation Criteria] Refractive Index n

A: 1.4 or more
C: less than 1.4

### [Evaluation Criteria] Extinction Coefficient k

A: less than 0.5
C: 0.5 or more

TABLE 9B

| | Resin | Optical characteristic values | |
|---|---|---|---|
| | used | n | k |
| Example A01 | RBisN-1 | A | A |
| Example A02 | RBisN-2 | A | A |
| Example A03 | RBisN-3 | A | A |
| Example A04 | RBisN-4 | A | A |
| Example A05 | RBisN-5 | A | A |
| Example A06 | RBisN-6 | A | A |
| Comparative | CR-1 (Comparative | C | C |
| Example A01 | Synthesis | | |
| | Example 2) | | |

From the results of Examples A01 to A06, it was found that a polymer film having a high n-value and a low k-value at wavelengths 193 nm used in ArF exposure can be formed by the composition for film formation containing the polycyclic polyphenolic resin of the present embodiment.

### <Heat Resistance Evaluation of Cured Film>

### Example Group 3: Example B01

The heat resistance of the resin film prepared in Example A01 was evaluated by using a lamp annealing oven. As the heat treatment resistance condition, heating was continued at 450° C. in a nitrogen atmosphere, and a film thickness change rate was obtained by comparing the film thickness after an elapsed time of 4 minutes from the start of heating and the film thickness after an elapsed time of 10 minutes. In addition, heating was continued at 550° C. in a nitrogen atmosphere, and a film thickness change rate was obtained by comparing the film thickness after an elapsed time of 4 minutes from the start of heating and the film thickness after an elapsed time of 10 minutes at 550° C. These film thickness change rates were evaluated as indicators of the heat resistance of the cured film. The film thicknesses before and after the heat resistance test were measured by an interference film thickness meter, and a ratio of the fluctuation value of the film thickness to the film thickness before the heat resistance test treatment was defined as a film thickness change rate (%).

[Evaluation Criteria]
A: Film thickness change rate is less than 10%.
B: Film thickness change rate is 10% to 15%.
C: Film thickness change rate is more than 15%.

### Example Group 3: Example B02 to Example B06 and Comparative Example B01 to Comparative Example B02

Heat resistance was evaluated in the same manner as in Example B01 except that the resins used were changed from RBisN-1 to the resins shown in Table 10B.

TABLE 10B

| | | | Film |
|---|---|---|---|
| | | Cured | thickness |
| | | film heat | change |
| | Resin | resistance | rate % |
| | used | 450° C. | 550° C. |
| Example B01 | RBisN-1 | A | A |
| Example B02 | RBisN-2 | A | A |
| Example B03 | RBisN-3 | A | A |
| Example B04 | RBisN-4 | A | A |
| Example B05 | RBisN-5 | A | A |
| Example B06 | RBisN-6 | A | A |
| Comparative | CR-1 (Comparative | C | C |
| Example B01 | Synthesis | | |
| | Example 2) | | |
| Comparative | NBisN-2 | B | B |
| Example B02 | | | |

From the results of Examples B01 to B06, it was found that a resin film having high heat resistance with little change in film thickness even at a temperature of 550° C. can be formed by using a composition for film formation containing the polycyclic polyphenolic resin of the present embodiment as compared with Comparative Examples B01 and B02.

### Example Group 3: Example C01

### <Evaluation of PE-CVD Film Formation>

A 12 inch silicon wafer was subjected to thermal oxidation treatment, and a resin film was formed on the substrate having the obtained silicon oxide film by the same method as in Example A01 using the resin solution of Example A01 with a thickness of 100 nm. A silicon oxide film having a film thickness of 70 nm was formed on the resin film using a film forming apparatus “TELINDY” (manufactured by Tokyo Electron Ltd.) and tetraethylsiloxane (TEOS) as a raw material at a substrate temperature of 300° C.

The wafer with the cured film in which the prepared silicon oxide film was laminated was further subjected to defect inspection using a defect inspection device “SP5” (KLA-Tencor Corporation), and the number of defects of the formed oxide film was evaluated according to the following criteria using the number of defects of 21 nm or more as an index.

### (Criteria)

A number of defects 20
B 20<number of defects≤50
C 50<number of defects≤100
D 100<number of defects≤1000
E 1000<number of defects≤5000
F 5000<number of defects

<Evaluation of SiN Film>

On a cured film formed on a substrate having a silicon oxide film thermally oxidized on a 12 inch silicon wafer with a thickness of 100 nm by the same method as described above, a film forming apparatus “TELINDY” (manufactured by Tokyo Electron Ltd.) was used to form a SiN film having a thickness of 40 nm, a refractive index of 1.94, and a film stress of −54 MPa at a substrate temperature of 350° C. using SiH4 (monosilane) and ammonia as raw materials.

The wafer with the cured film in which the prepared SiN film was laminated was further subjected to defect inspection using a defect inspection device “SP5” (KLA-Tencor Corporation), and the number of defects of the formed oxide film was evaluated according to the following criteria using the number of defects of 21 nm or more as an index.

### (Criteria)

A number of defects≤20
B 20<number of defects≤50
C 50<number of defects≤100
D 100<number of defects≤1000
E 1000<number of defects≤5000
F 5000<number of defects

### Example Group 3: Examples C02 to C6 and Comparative Examples C01 to C02

Defect evaluation of the film was performed in the same manner as in Example C01 except that the resins used were changed from RBisN-1 to the resins shown in Table 11B.

TABLE 11B

| | | PE-CVD defect evaluation | |
|---|---|---|---|
| | Resin | Oxide | SiN |
| | used | film | film |
| Example C01 | RBisN-1 | B | B |
| Example C02 | RBisN-2 | B | B |
| Example C03 | RBisN-3 | B | B |
| Example C04 | RBisN-4 | B | B |
| Example C05 | RBisN-5 | B | B |
| Example C06 | RBisN-6 | B | B |
| Comparative | CR-1 (Comparative | F | F |
| Example C01 | Synthesis | | |
| | Example 2) | | |
| Comparative | NBisN-2 | E | E |
| Example C02 | | | |

In the silicon oxide film or SiN film formed on the resin film of Examples C01 to C06, the number of defects of 21 nm or more was 50 or less (evaluation B or higher), which was smaller than the number of defects of Comparative Example C01 or C02.

### Example Group 3: Example D01

<Etching Evaluation after High Temperature Treatment>

A 12 inch silicon wafer was subjected to thermal oxidation treatment, and a resin film was formed on the substrate having the obtained silicon oxide film by the same method as in Example A01 using the resin solution of Example A01 with a thickness of 100 nm. The resin film was further annealed by heating under the condition of 600° C. for 4 minutes using a hot plate which can be further treated at a high temperature in a nitrogen atmosphere to prepare a wafer on which the annealed resin film was laminated. The prepared annealed resin film was carved out, and the carbon content was determined by elemental analysis.

Furthermore, a 12 inch silicon wafer was subjected to thermal oxidation treatment, and a resin film was formed on the substrate having the obtained silicon oxide film by the same method as in Example A01 using the resin solution of Example A01 with a thickness of 100 nm. The resin film was further annealed by heating under the condition of 600° C. for 4 minutes under a nitrogen atmosphere to form a resin film, and then the substrate was subjected to an etching treatment using an etching apparatus “TELIUS” (manufactured by Tokyo Electron Ltd.) under the conditions of using CF₄/Ar as an etching gas and Cl₂/Ar as an etching gas to evaluate an etching rate. The etching rate was evaluated by using a resin film having a film thickness of 200 nm formed by annealing a photoresist “SU8 3000” manufactured by Nippon Kayaku Co., Ltd. at 250° C. for 1 minute as a reference and determining the ratio of the etching rate to the SU8 as a relative value.

### [Evaluation Criteria]

A: The etching rate was less than −20% as compared with the resin film of SU8 3000.
B: The etching rate was −20% or more and 0% or less as compared with the resin film of SU8 3000.
C: The etching rate was more than +0% as compared with the resin film of SU8 3000.

### Example Group 3: Examples D02 to D06 and Comparative Examples D01 to D02

Etching rate was evaluated in the same manner as in Example D01 except that the resins used were changed from RBisN-1 to the resins shown in Table 12B.

TABLE 12B

| | | | Etching rate evaluation | |
|---|---|---|---|---|
| | | | (relative value) | |
| | Resin | Carbon | CF₄/ | Cl₂/ |
| | used | content (%) | Ar | Ar |
| Example D01 | RBisN-1 | A | A | A |
| Example D02 | RBisN-2 | A | A | A |
| Example D03 | RBisN-3 | A | A | A |
| Example D04 | RBisN-4 | A | A | A |
| Example D05 | RBisN-5 | A | A | A |
| Example D06 | RBisN-6 | A | A | A |
| Comparative | CR-1 | B | B | B |
| Example D01 | (Comparative | | | |
| | Synthesis | | | |
| | Example 2) | | | |
| Comparative | NBisN-2 | B | B | B |
| Example D02 | | | | |

From the results of Examples D01 to D06, it was found that a resin film excellent in etching resistance after high temperature treatment can be formed when a composition containing the polycyclic polyphenolic resin of the present embodiment is used as compared with Comparative Examples D01 and D02.

### [Defect Evaluation Before and After Purification Treatment]

### <Evaluation of Etching Defects on Laminated Film>

The polycyclic polyphenolic resins obtained in Synthesis Working Examples below were subjected to quality evaluation before and after the purification treatment. That is, before and after the purification treatment described below, the resin film formed on the wafer using the polycyclic polyphenolic resin was transferred to the substrate side by etching, and then subjected to defect evaluation to evaluate.

A 12-inch silicon wafer was subjected to thermal oxidation treatment to obtain a substrate having a silicon oxide film having a thickness of 100 nm. The resin solution of the polycyclic polyphenolic resin was formed on the substrate by adjusting the spin coating conditions so as to have a thickness of 100 nm, followed by baking at 150° C. for 1 minute, and then baking at 350° C. for 1 minute to prepare a laminated substrate in which the polycyclic polyphenolic resin was laminated on silicon with a thermal oxide film.

Using “TELIUS” (manufactured by Tokyo Electron Ltd.) as an etching apparatus, the resin film was etched under the condition of CF₄/O₂/Ar to expose the substrate on the surface of the oxide film. Further, an etching treatment was performed under the condition that the oxide film was etched by 100 nm at the gas composition ratio of CF₄/Ar to prepare an etched wafer.

The prepared etched wafer was measured for the number of defects of 19 nm or more with a defect inspection device “SP5” (manufactured by KLA-Tencor Corporation), and was subjected to defect evaluation by etching treatment of the laminated film according to the following criteria.

### (Criteria)

A number of defects≤20
B 20<number of defects≤50
C 50<number of defects≤100
D 100<number of defects≤1000
E 1000<number of defects≤5000
F 5000<number of defects

### [Example Group 3: Example E01] Purification of RBisN-1 with Acid

In a four necked flask (capacity: 1000 mL, with a detachable bottom), 150 g of a solution (10% by mass) formed by dissolving RBisN-1 obtained in Synthesis Working Example 1 in PGMEA was charged, and was heated to 80° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Thereafter, by diluting with PGMEA of EL grade (a reagent manufactured by KANTO CHEMICAL CO., INC.) such that the concentration of the PGMEA solution was adjusted to 10% by mass, a PGMEA solution of RBisN-1 with a reduced metal content was obtained. The polycyclic polyphenolic resin solution thus prepared was filtered with a UPE filter having a nominal pore size of 3 nm, manufactured by Entegris Japan Co., Ltd., under a condition of 0.5 MPa, to prepare a solution sample.

For each of the solution samples before and after the purification treatment, a resin film was formed on the wafer as described above, the resin film was transferred to the substrate side by etching, and then etching defect evaluation was performed on the laminated film.

### [Example Group 3: Example E02] Purification of RBisN-2 with Acid

In a four necked flask (capacity: 1000 mL, with a detachable bottom), 140 g of a solution (10% by mass) formed by dissolving RBisN-2 obtained in Synthesis Working Example 2 in PGMEA was charged, and was heated to 60° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and PGMEA were concentrated and distilled off by heating to 80° C. and reducing the pressure in the flask to 200 hPa or less. Thereafter, by diluting with PGMEA of EL grade (a reagent manufactured by KANTO CHEMICAL CO., INC.) such that the concentration of the PGMEA solution was adjusted to 10% by mass, a PGMEA solution of RBisN-2 with a reduced metal content was obtained. The polycyclic polyphenolic resin solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out in the same manner as in Example E01.

### [Example Group 3: Example E03] Purification by Passing Through Filter

In a class 1000 clean booth, 500 g of a solution of 10% by mass concentration of the resin (RBisN-1) obtained in Synthesis Working Example 1 dissolved in propylene glycol monomethyl ether (PGME) was charged in a four necked flask (capacity: 1000 mL, with a detachable bottom), and then the air inside the vessel was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 100 mL per minute to a hollow fiber membrane filter (manufactured by KITZ MICRO FILTER CORPORATION, product name: Polyfix Nylon Series) made of nylon with a nominal pore size of 0.01 μm under a filtration pressure of 0.5 MPa by pressure filtration. By diluting the resin solution after filtration with PGMEA of EL grade (a reagent manufactured by KANTO CHEMICAL CO., INC.) such that the concentration of the PGMEA solution was adjusted to 10% by mass, a PGMEA solution of RBisN-1 with a reduced metal content was obtained. The polycyclic polyphenolic resin solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out in the same manner as in Example E01. The oxygen concentration was measured with an oxygen concentration meter “OM-25MF10” manufactured by AS ONE Corporation (the same applies hereinafter)

### Example Group 3: Example E04

As the purification step by the filter, “IONKLEEN” manufactured by Nihon Pall Ltd., NYLON FILTER manufactured by Nihon Pall Ltd., and a UPE filter with a nominal pore size of 3 nm manufactured by Entegris Japan Co., Ltd. were connected in series in this order to construct a filter line. In the same manner as in Example E03, except that the prepared filter line was used instead of the 0.1 μm hollow fiber membrane filter made of nylon, the solution was passed by pressure filtration so that the conditions of the filtration pressure was 0.5 MPa. By diluting with PGMEA of EL grade (a reagent manufactured by KANTO CHEMICAL CO., INC.) such that the concentration of the PGMEA solution was adjusted to 10% by mass, a PGMEA solution of RBisN-1 with a reduced metal content was obtained. The polycyclic polyphenolic resin solution thus prepared was subjected to pressure filtration with a UPE filter having a nominal pore size of 3 nm, manufactured by Entegris Japan Co., Ltd., under a condition of the filtration pressure of 0.5 MPa, to prepare a solution sample, and then etching defect evaluation on the laminated film was carried out in the same manner as in Example E01.

### Example Group 3: Example E05

The solvent sample prepared in Example E01 was further subjected to pressure filtration with the filter line prepared in Example E04 under a condition of the filtration pressure of 0.5 MPa, to prepare a solution sample, and then etching defect evaluation on the laminated film was carried out in the same manner as in Example E01.

### Example Group 3: Example E06

For RBisN-2 synthesized in Synthesis Working Example 2, a solution sample purified by the same method as in Example E05 was prepared, and then etching defect evaluation on the laminated film was carried out in the same manner as in Example E01.

### Example Group 3: Example E07

For RBisN-3 synthesized in Synthesis Working Example 3, a solution sample purified by the same method as in Example E05 was prepared, and then etching defect evaluation on the laminated film was carried out in the same manner as in Example E01.

TABLE 13B

PE-CVD defect evaluation

| | | Before | After |
|---|---|---|---|
| | Resin | purification | purification |
| | used | treatment | treatment |
| Example E01 | RBisN-1 | B | A |
| Example E02 | RBisN-2 | B | A |
| Example E03 | RBisN-1 | B | A |
| Example E04 | RBisN-1 | B | A |
| Example E05 | RBisN-1 | B | A |
| Example E06 | RBisN-2 | B | A |
| Example E07 | RBisN-3 | B | A |

From the results of Examples E01 to E07, it was found that the quality of the obtained resin film was further improved when the polycyclic polyphenolic resin after purification treatment was used, as compared with when the polycyclic polyphenolic resin before purification treatment was used.

### Example Group 3: Examples 64 to 70 and Comparative Example 9

A SiO₂ substrate having a film thickness of 300 nm was coated with the composition for optical member formation having the same composition as that of the solution of the underlayer film forming material for lithography prepared in each of the above Examples 42 to 28 and Comparative Example 5, and baked at 260° C. for 300 seconds to form each film for optical members with a film thickness of 100 nm.

Then, tests for the refractive index and the transparency at a wavelength of 633 nm were carried out by using a vacuum ultraviolet with variable angle spectroscopic ellipsometer “VUV-VASE” manufactured by J.A. Woollam Japan, and the refractive index and the transparency were evaluated according to the following criteria. The evaluation results are shown in Table 14B.

### [Evaluation Criteria for Refractive Index]

A: The refractive index is 1.65 or more
C: The refractive index is less than 1.65

### [Evaluation Criteria for Transparency]

A: The absorption coefficient is less than 0.03.
C: The absorption coefficient is 0.03 or more.

TABLE 14B

| | Composition for optical | Refractive | |
|---|---|---|---|
| | member formation | index | Transparency |
| Example 64 | same composition as | A | A |
| | Example 42 | | |
| Example 65 | same composition as | A | A |
| | Example 43 | | |
| Example 66 | same composition as | A | A |
| | Example 44 | | |
| Example 67 | same composition as | A | A |
| | Example 45 | | |
| Example 68 | same composition as | A | A |
| | Example 46 | | |
| Example 69 | same composition as | A | A |
| | Example 47 | | |
| Example 70 | same composition as | A | A |
| | Example 48 | | |
| Comparative | Comparative same | C | C |
| Example 9 | composition as | | |
| | Example 5 | | |

It was found that the compositions for optical member formation of Examples 64 to 70 not only had a high refractive index but also a low absorption coefficient and excellent transparency. On the other hand, it was found that the composition of Comparative Example 9 was inferior in performance as an optical member.

The disclosure of Japanese Patent Application No. 2020-121288, Japanese Patent Application No. 2020-121595, and Japanese Patent Application No. 2020-121615 filed on Jul. 15, 2020 are incorporated herein by reference in its entirety.

All reference documents, patent applications, and technical standards described in the specification are incorporated by reference herein to the same extent as if each of those reference documents, patent applications, and technical standards were specifically and individually described as being incorporated by reference.

### INDUSTRIAL APPLICABILITY

The present invention provides a novel polycyclic polyphenolic resin in which aromatic hydroxy compounds having a specific skeleton are linked without a crosslinking group, that is, aromatic rings are linked to each other by a direct bonding. Such a polycyclic polyphenolic resin is excellent in heat resistance, etching resistance, heat flow property, solvent solubility and the like, particularly excellent in heat resistance and etching resistance, and can be used as a coating agent for semiconductors, a material for resists, and a semiconductor underlayer film forming material.

The present invention has industrial applicability as a composition that can be used in optical members, photoresist components, resin raw materials for materials for electric or electronic components, raw materials for curable resins such as photocurable resins, resin raw materials for structural materials, or resin curing agents, etc.

1. A polycyclic polyphenolic resin having repeating units derived from at least one monomer selected from the group consisting of aromatic hydroxy compounds represented by the formulas (1A) and (1B); or a polycyclic polyphenolic resin having repeating units derived from an aromatic hydroxy compound represented by the formula (C-1A),
wherein the repeating units are linked to each other by a direct bonding between aromatic rings: 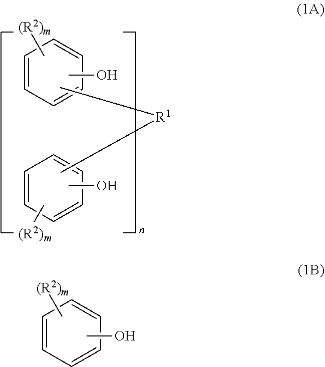
wherein in the formula (1A), R¹ is a 2n-valent group having 1 to 60 carbon atoms or a single bond, each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group, and each m is independently an integer of 0 to 3; each n is independently an integer of 1 to 4; and in the formula (1B), R² and m are as defined in the formula (1A), and 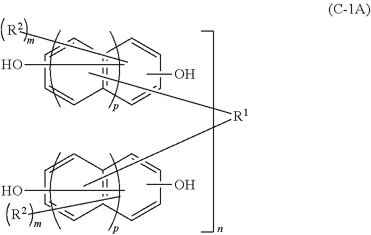
wherein in the formula (C-1A), R¹ is a 2n-valent group having 1 to 60 carbon atoms or a single bond, each R² is independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms and optionally having a substituent, an alkoxy group having 1 to 40 carbon atoms and optionally having a substituent, a halogen atom, a thiol group, an amino group, a nitro group, a cyano group, a nitro group, a heterocyclic group, a carboxyl group or a hydroxy group, and each m is independently an integer of 0 to 9; and n is an integer of 1 to 4, and each p is independently an integer of 0 to 3.

2. (canceled)

3. (canceled)

4. (canceled)

5. (canceled)

6. (canceled)

7. (canceled)

8. (canceled)

9. The polycyclic polyphenolic resin according to claim 1, further comprising a modified portion derived from a crosslinking compound.

10. The polycyclic polyphenolic resin according to claim 1, further comprising, as another repeating unit, a repeating unit having an ether bond formed by condensation of a phenolic hydroxy group.

11. (canceled)

12. The polycyclic polyphenolic resin according to claim 1, comprising two or more different repeating units derived from aromatic hydroxy compounds.

13. The polycyclic polyphenolic resin according to claim 1, which has a weight-average molecular weight of 400 to 100,000.

14. The polycyclic polyphenolic resin according to claim 1, which has a solubility in 1-methoxy-2-propanol and/or propylene glycol monomethyl ether acetate of 1% by mass or more.

15. (canceled)

16. (canceled)

17. A composition comprising the polycyclic polyphenolic resin according to claim 1.

18. The composition according to claim 17, further comprising a solvent.

19. (canceled)

20. The composition according to claim 17, wherein a content of impurity metal is less than 500 ppb for each metal species.

21. (canceled)

22. (canceled)

23. A method for producing the polycyclic polyphenolic resin according to claim 1, comprising the step of:
polymerizing one kind or two or more kinds of the aromatic hydroxy compounds in the presence of an oxidizing agent.

24. (canceled)

25. A composition for film formation comprising the polycyclic polyphenolic resin according to claim 1.

26. A resist composition comprising the composition for film formation according to claim 25.

27. The resist composition according to claim 26, further comprising at least one selected from the group consisting of a solvent, an acid generating agent, and an acid diffusion controlling agent.

28. A resist pattern formation method, comprising the steps of:
forming a resist film on a substrate using the resist composition according to claim 26;
exposing at least a portion of the formed resist film; and
developing the exposed resist film, thereby forming a resist pattern.

29. A radiation-sensitive composition comprising the composition for film formation according to claim 25, an optically active diazonaphthoquinone compound, and a solvent,
wherein a content of the solvent is 20 to 99 parts by mass based on 100 parts by mass in total of the radiation-sensitive composition, and
a content of a solid content except for the solvent is 1 to 80 parts by mass based on 100 parts by mass in total of the radiation-sensitive composition.

30. A resist pattern formation method, comprising the steps of:
forming a resist film on a substrate using the radiation-sensitive composition according to claim 29;
exposing at least a portion of the formed resist film; and
developing the exposed resist film, thereby forming a resist pattern.

31. A composition for underlayer film formation for lithography comprising the composition for film formation according to claim 25.

32. The composition for underlayer film formation for lithography according to claim 31, further comprising at least one selected from the group consisting of a solvent, an acid generating agent, and a crosslinking agent.

33. A method for producing an underlayer film for lithography, comprising the step of forming an underlayer film on a substrate using the composition for underlayer film formation for lithography according to claim 31.

34. A resist pattern formation method, comprising the steps of:
forming an underlayer film on a substrate using the composition for underlayer film formation for lithography according to claim 31;
forming at least one photoresist layer on the underlayer film; and
irradiating a predetermined region of the photoresist layer with radiation for development, thereby forming a resist pattern.

35. A circuit pattern formation method, comprising the steps of:
forming an underlayer film on a substrate using the composition for underlayer film formation for lithography according to claim 31;
forming an intermediate layer film on the underlayer film using a resist intermediate layer film material containing a silicon atom;
forming at least one photoresist layer on the intermediate layer film;
irradiating a predetermined region of the photoresist layer with radiation for development, thereby forming a resist pattern;
etching the intermediate layer film with the resist pattern as a mask, thereby forming an intermediate layer film pattern;
etching the underlayer film with the intermediate layer film pattern as an etching mask, thereby forming an underlayer film pattern; and
etching the substrate with the underlayer film pattern as an etching mask, thereby forming a pattern on the substrate.

36. A composition for optical member formation comprising the composition for film formation according to claim 26.

37. (canceled)
